(19) United States
(12) Patent Application Publication
(10) Pub. No.: US 2026/0181947 A1
(43) Pub. Date: Jun. 25, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yukinori SHIMA, Tatebayashi, Gunma (JP); Junichi KOEZUKA, Tochigi, Tochigi (JP); Masami JINTYOU, Shimotsuga, Tochigi (JP); Kayo KUMAKURA, Tochigi, Tochigi (JP); Masataka NAKADA, Tochigi, Tochigi (JP); Koji KUSUNOKI, Isehara, Kanagawa (JP); Tomoaki ATSUMI, Hadano, Kanagawa (JP)

(21) Appl. No.: 19/127,221

(22) PCT Filed: Nov. 2, 2023
(86) PCT No.: PCT/IB2023/061021

§ 371 Date: May 5, 2025

(30) Foreign Application Priority Data
Nov. 10, 2022 (JP) 2022-180548
Nov. 30, 2022 (JP) 2022-191861
Mar. 15, 2023 (JP) 2023-040932
May 12, 2023 (JP) 2023-079417
Sep. 8, 2023 (JP) 2023-146385

(51) Int. Cl. H10D 30/67

(52) U.S. Cl. CPC H10D 30/6725; H10D 30/673

(57) ABSTRACT

A semiconductor device that occupies a small area is provided. The semiconductor device includes a transistor and a first insulating layer. The transistor includes a first conductive layer, a second conductive layer including a region overlapping with the first conductive layer with the first insulating layer therebetween, and a semiconductor layer. The second conductive layer includes a first opening in the region overlapping with the first conductive layer. The first insulating layer includes a second opening reaching the first conductive layer in a region overlapping with the first opening. In the first opening and the second opening, the semiconductor layer is in contact with the top surface of the first conductive layer, the side surface of the first insulating layer, and the side surface of the second conductive layer. The diffusion coefficient of oxygen in the first insulating layer at 350° C. is preferably higher than or equal to 5×10⁻¹² cm²/sec.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display apparatus including a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

In this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic device themselves are semiconductor devices and each of them includes a semiconductor device in some cases.

### BACKGROUND ART

Semiconductor devices including transistors are applied to a wide range of electronic devices. In addition, uses for a display apparatus are diversified in recent years, and for example, the display apparatus is used for a portable information terminal, a television device for home use (also referred to as a TV or a television receiver), digital signage, a PID (Public Information Display), and the like. Examples of the display apparatus include a display apparatus including an organic EL (Electro Luminescence) element or a light-emitting diode (LED), a display apparatus including a liquid crystal element, and electronic paper performing display by an electrophoretic method.

In a display apparatus, for example, when the area occupied by transistors is reduced, the pixel size can be reduced and resolution can be increased. Furthermore, when the area occupied by transistors is reduced, the aperture ratio can be increased. Thus, minute transistors have been required.

As devices requiring high-resolution display apparatuses, for example, devices for virtual reality (VR), augmented reality (AR), substitutional reality (SR), or mixed reality (MR) have been actively developed.

Patent Document 1 discloses a high-resolution display apparatus using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor having a minute size. Another object is to provide a transistor having a short channel length. Another object is to provide a transistor having high on-state current. Another object is to provide a transistor having favorable electrical characteristics. Another object is to provide a semiconductor device that occupies a small area. Another object is to provide a semiconductor device having low wiring resistance. Another object is to provide a semiconductor device or a display apparatus having low power consumption. Another object is to provide a transistor, a semiconductor device, or a display apparatus having high reliability. Another object is to provide a high-resolution display apparatus. Another object is to provide a method for manufacturing a semiconductor device or a display apparatus having high productivity. Another object is to provide a novel transistor, a novel semiconductor device, a novel display apparatus, and manufacturing methods thereof.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a transistor and a first insulating layer. The transistor includes a first conductive layer, a second conductive layer including a region overlapping with the first conductive layer with the first insulating layer therebetween, and a semiconductor layer. The second conductive layer includes a first opening in the region overlapping with the first conductive layer. The first insulating layer includes a second opening reaching the first conductive layer in a region overlapping with the first opening. In the first opening and the second opening, the semiconductor layer is in contact with a top surface of the first conductive layer, a side surface of the first insulating layer, and a side surface of the second conductive layer. A diffusion coefficient of oxygen in the first insulating layer at 350° C. is higher than or equal to 5×10⁻¹² cm²/sec.

In the above semiconductor device, the diffusion coefficient of oxygen is preferably calculated by thermal desorption spectroscopy or secondary ion mass spectrometry.

In the above semiconductor device, the semiconductor layer preferably includes a metal oxide.

The above semiconductor device preferably includes a second insulating layer and a third insulating layer. The second insulating layer is preferably positioned between the first insulating layer and the first conductive layer. The third insulating layer is preferably positioned between the first insulating layer and the second conductive layer. The first insulating layer preferably includes an oxide or an oxynitride. The second insulating layer and the third insulating layer each preferably include a nitride or a nitride oxide.

The above semiconductor device preferably includes a fourth insulating layer. The fourth insulating layer is preferably positioned between the second insulating layer and the first conductive layer. The fourth layer preferably includes a region containing more hydrogen than the second insulating layer.

The above semiconductor device preferably includes a fifth insulating layer. The fifth insulating layer is preferably positioned between the third insulating layer and the second conductive layer. The fifth insulating layer preferably includes a region containing more hydrogen than the third insulating layer.

One embodiment of the present invention is a semiconductor device including a first transistor, a second transistor, and a first insulating layer. The first transistor includes a first conductive layer, a second conductive layer including a region overlapping with the first conductive layer with the first insulating layer therebetween, and a first semiconductor layer. The second conductive layer includes a first opening in the region overlapping with the first conductive layer. The first insulating layer includes a second opening reaching the first conductive layer in a region overlapping with the first opening. In the first opening and the second opening, the first semiconductor layer is in contact with a top surface of the first conductive layer, a side surface of the first insulating layer, and a side surface of the second conductive layer. The second transistor includes a third conductive layer over the first insulating layer, a second semiconductor layer, and a second insulating layer positioned between the third conductive layer and the second semiconductor layer. The second insulating layer is in contact with a top surface and a side surface of the third conductive layer. A diffusion coefficient of oxygen in the first insulating layer is higher than a diffusion coefficient of oxygen in the second insulating layer.

In the above semiconductor device, the diffusion coefficient of oxygen is preferably calculated by thermal desorption spectroscopy or secondary ion mass spectrometry.

One embodiment of the present invention is a semiconductor device including a first transistor, a second transistor, and a first insulating layer. The first transistor includes a first conductive layer, a second conductive layer including a region overlapping with the first conductive layer with the first insulating layer therebetween, and a first semiconductor layer. The second conductive layer includes a first opening in the region overlapping with the first conductive layer. The first insulating layer includes a second opening reaching the first conductive layer in a region overlapping with the first opening. In the first opening and the second opening, the first semiconductor layer is in contact with a top surface of the first conductive layer, a side surface of the first insulating layer, and a side surface of the second conductive layer. The second transistor includes a third conductive layer over the first insulating layer, a second semiconductor layer, and a second insulating layer positioned between the third conductive layer and the second semiconductor layer. The second insulating layer is in contact with a top surface and a side surface of the third conductive layer. An etching rate of the first insulating layer with respect to an etchant is higher than an etching rate of the second insulating layer.

In the above semiconductor device, the etchant preferably contains hydrofluoric acid. In the above semiconductor device, the first semiconductor layer and the second semiconductor layer each preferably include a metal oxide.

In the above semiconductor device, the second conductive layer and the third conductive layer preferably include different materials.

Alternatively, in the above semiconductor device, the second conductive layer and the third conductive layer preferably include the same material.

The above semiconductor device preferably includes a third insulating layer and a fourth insulating layer. The third insulating layer is preferably positioned between the first insulating layer and the first conductive layer. The fourth insulating layer is preferably positioned between the first insulating layer and the second conductive layer. The fourth insulating layer is preferably positioned between the first insulating layer and the third conductive layer. The first insulating layer preferably includes an oxide or an oxynitride. The third insulating layer and the fourth insulating layer each preferably include a nitride or a nitride oxide.

The above semiconductor device preferably includes a fifth insulating layer. The fifth insulating layer is preferably positioned between the third insulating layer and the first conductive layer. The fifth insulating layer preferably includes a region containing more hydrogen than the third insulating layer.

The above semiconductor device preferably includes a sixth insulating layer. The sixth insulating layer is preferably positioned between the fourth insulating layer and the second conductive layer. The sixth insulating layer is preferably positioned between the fourth insulating layer and the third conductive layer. The sixth insulating layer preferably includes a region containing more hydrogen than the fourth insulating layer.

### Effect of the Invention

One embodiment of the present invention can provide a transistor having a minute size. Alternatively, a transistor having a short channel length can be provided. Alternatively, a transistor having high on-state current can be provided. Alternatively, a transistor having favorable electrical characteristics can be provided. Alternatively, a semiconductor device that occupies a small area can be provided. Alternatively, a semiconductor device having low wiring resistance can be provided. Alternatively, a semiconductor device or a display apparatus having low power consumption can be provided. Alternatively, a transistor, a semiconductor device, or a display apparatus having high reliability can be provided. Alternatively, a high-resolution display apparatus can be provided. Alternatively, a method for manufacturing a semiconductor device or a display apparatus having high productivity can be provided. Alternatively, a novel transistor, a novel semiconductor device, a novel display apparatus, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A and FIG. 2B are perspective views illustrating an example of a semiconductor device.

FIG. 3 is a cross-sectional view illustrating an example of a semiconductor device.

FIG. 4A is a top view illustrating an example of a semiconductor device. FIG. 4B is a cross-sectional view illustrating the example of the semiconductor device.

FIG. 5A is a top view illustrating an example of a semiconductor device. FIG. 5B and FIG. 5C are cross-sectional views illustrating the example of the semiconductor device.

FIG. 6A and FIG. 6B are cross-sectional views illustrating examples of a semiconductor device.

FIG. 7A is a top view illustrating an example of a semiconductor device. FIG. 7B is a cross-sectional view illustrating the example of the semiconductor device.

FIG. 8A is a top view illustrating an example of a semiconductor device. FIG. 8B and FIG. 8C are cross-sectional views illustrating the example of the semiconductor device.

FIG. 9A is a top view illustrating an example of a semiconductor device. FIG. 9B and FIG. 9C are cross-sectional views illustrating the example of the semiconductor device.

FIG. 10A and FIG. 10B are cross-sectional views illustrating an example of a semiconductor device.

FIG. 11A to FIG. 11C are cross-sectional views illustrating an example of a semiconductor device.

FIG. 12A and FIG. 12B are cross-sectional views illustrating examples of a semiconductor device.

FIG. 13A is a top view illustrating an example of a semiconductor device. FIG. 13B and FIG. 13C are cross-sectional views illustrating the example of the semiconductor device.

FIG. 14A and FIG. 14B are equivalent circuit diagrams of a semiconductor device. FIG. 14C is a top view illustrating an example of the semiconductor device.

FIG. 15 is a cross-sectional view illustrating an example of a semiconductor device.

FIG. 16 is a perspective view illustrating an example of a semiconductor device.

FIG. 17A to FIG. 17D are perspective views illustrating an example of a semiconductor device.

FIG. 18A and FIG. 18B are equivalent circuit diagrams of a semiconductor device. FIG. 18C is a top view illustrating an example of the semiconductor device.

FIG. 19 is a cross-sectional view illustrating an example of a semiconductor device.

FIG. 20 is a perspective view illustrating an example of a semiconductor device.

FIG. 21A to FIG. 21D are perspective views illustrating an example of a semiconductor device.

FIG. 22A to FIG. 22D are cross-sectional views illustrating an example of a method for manufacturing a semiconductor device.

FIG. 23A to FIG. 23C are cross-sectional views illustrating the example of the method for manufacturing the semiconductor device.

FIG. 24A to FIG. 24C are cross-sectional views illustrating the example of the method for manufacturing the semiconductor device.

FIG. 25A to FIG. 25C are cross-sectional views illustrating the example of the method for manufacturing the semiconductor device.

FIG. 26A and FIG. 26B are cross-sectional views illustrating the example of the method for manufacturing the semiconductor device.

FIG. 27A is a perspective view illustrating an example of a display apparatus. FIG. 27B is a block diagram illustrating the example of the display apparatus.

FIG. 28A is a circuit diagram of a latch circuit. FIG. 28B is a circuit diagram of an inverter circuit.

FIG. 29A and FIG. 29B are circuit diagrams of pixel circuits. FIG. 29C is a cross-sectional view illustrating an example of the pixel circuit.

FIG. 30 is a circuit diagram of a pixel circuit.

FIG. 31 is a top view illustrating a layout example of a pixel.

FIG. 32 is a top view illustrating a layout example of a pixel.

FIG. 33 is a top view illustrating a layout example of a pixel.

FIG. 34 is a cross-sectional view illustrating a layout example of a pixel.

FIG. 35A and FIG. 35B are cross-sectional views illustrating a layout example of a pixel.

FIG. 36A to FIG. 36C are top views illustrating a layout example of a pixel.

FIG. 37A to FIG. 37C are top views illustrating a layout example of a pixel.

FIG. 38 is a top view illustrating a layout example of pixels.

FIG. 39 is a top view illustrating a layout example of pixels.

FIG. 40A and FIG. 40B are top views illustrating a layout example of pixels.

FIG. 41A and FIG. 41B are top views illustrating a layout example of pixels.

FIG. 42A and FIG. 42B are top views illustrating a layout example of pixels.

FIG. 43A and FIG. 43B are cross-sectional views illustrating examples of display apparatuses.

FIG. 44 is a cross-sectional view illustrating an example of a display apparatus.

FIG. 45A to FIG. 45C are cross-sectional views illustrating an example of a display apparatus.

FIG. 46A and FIG. 46B are cross-sectional views illustrating examples of display apparatuses.

FIG. 47 is a cross-sectional view illustrating an example of a display apparatus.

FIG. 48 is a cross-sectional view illustrating an example of a display apparatus.

FIG. 49 is a cross-sectional view illustrating an example of a display apparatus.

FIG. 50A and FIG. 50B are cross-sectional views illustrating examples of display apparatuses.

FIG. 51A to FIG. 51F are cross-sectional views illustrating an example of a method for manufacturing a display apparatus.

FIG. 52A to FIG. 52D are diagrams illustrating examples of electronic devices.

FIG. 53A to FIG. 53F are diagrams illustrating examples of electronic devices.

FIG. 54A to FIG. 54G are diagrams illustrating examples of electronic devices.

FIG. 55 is a SEM image of a transistor of Example.

FIG. 56A and FIG. 56B are STEM images of a transistor of Example.

FIG. 57 is a diagram showing Id-Vg characteristics of transistors of Example.

FIG. 58A and FIG. 58B are diagrams showing electrical characteristics of transistors of Example.

FIG. 59 is a diagram showing electrical characteristics of transistors of Example.

FIG. 60 is a diagram showing electrical characteristics of transistors of Example.

FIG. 61 is a diagram showing reliability of transistors of Example.

FIG. 62A and FIG. 62B are photographs of display states of an OLED panel of Example.

FIG. 63 is a diagram showing I-V characteristics of samples of Example.

FIG. 64 is a diagram showing sheet resistance and a carrier concentration of samples of Example.

FIG. 65 is a diagram showing Id-Vg characteristics of transistors of Example.

FIG. 66 is a diagram showing electrical characteristics of transistors of Example.

FIG. 67A is a diagram showing electrical characteristics of transistors of Example. FIG. 67B is a diagram showing Id-Vg characteristics of transistors of Example.

FIG. 68 is a diagram showing Id-Vg characteristics of transistors of Example.

FIG. 69A and FIG. 69B are diagrams showing electrical characteristics of transistors of Example.

FIG. 70 is a diagram showing electrical characteristics of transistors of Example.

FIG. 71A is a diagram showing Id-Vg characteristics of transistors of Example. FIG. 71B is a diagram showing electrical characteristics of the transistors of Example.

FIG. 72 is a diagram showing reliability of transistors of Example.

FIG. 73 is a photograph of a display state of an OLED panel of Example.

FIG. 74A to FIG. 74C are cross-sectional views illustrating a structure of a sample of Example.

FIG. 75A and FIG. 75B are cross-sectional TEM images and diagrams showing crystal orientations of Example.

FIG. 76A and FIG. 76B are cross-sectional TEM images and diagrams showing crystal orientation of Example.

FIG. 77A and FIG. 77B are diagrams showing Id-Vg characteristics of transistors of Example.

FIG. 78 is a diagram illustrating a method for evaluating off-state current of transistors of Example.

FIG. 79A and FIG. 79B are diagrams showing off-state current of transistors of Example.

FIG. 80 is a diagram showing Id-Vg characteristics of transistors of Example.

FIG. 81A and FIG. 81B show TDS spectra of Example.

FIG. 82 is a diagram showing diffusion coefficients of oxygen of Example.

FIG. 83A and FIG. 83B are diagrams showing TDS measurement results of Example.

FIG. 84A and FIG. 84B are diagrams showing Id-Vg characteristics of transistors of Example.

FIG. 85A and FIG. 85B are diagrams showing Id-Vg characteristics of transistors of Example.

FIG. 86A and FIG. 86B are diagrams showing electrical characteristics of transistors of Example.

FIG. 87A to FIG. 87F show TDS spectra of Example.

FIG. 88 shows a TDS spectrum of Example.

FIG. 89 is a diagram showing TDS measurement results of Example.

FIG. 90 is a diagram showing electrical characteristics of transistors of Example.

FIG. 91A and FIG. 91B are diagrams showing reliability of transistors of Example.

FIG. 92 is a diagram showing drain breakdown voltage of a transistor of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

In this specification and the like, when a plurality of components are denoted by the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

The position, size, range, or the like of each component illustrated in drawings does not represent the actual position, size, range, or the like in some cases for easy understanding. Therefore, the disclosed invention is not necessarily limited to the position, size, range, and the like disclosed in the drawings.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be interchanged with each other depending on circumstances. For example, the term “conductive layer” can be changed into the term “conductive film”. As another example, the term “insulating film” can be changed into the term “insulating layer”.

A transistor is a kind of semiconductor element and can achieve a function of amplifying current or voltage, a switching operation for controlling electrical continuity or discontinuity, and the like. An IGFET (Insulated Gate Field Effect Transistor) and a thin film transistor (TFT) are in the category of a transistor in this specification and the like.

Functions of a “source” and a “drain” are sometimes replaced with each other when a transistor of opposite polarity is used or when the direction of current is changed in circuit operation, for example. Thus, the terms “source” and “drain” can be used interchangeably in this specification and the like. Note that a source and a drain of a transistor can also be referred to as a source terminal and a drain terminal or a source electrode and a drain electrode, for example, as appropriate depending on circumstances.

A “gate” and a “back gate” can be interchanged with each other. Thus, the terms “gate” and “back gate” can be used interchangeably in this specification and the like. Note that a gate and a back gate of a transistor can also be referred to as a gate electrode and a back gate electrode, for example, as appropriate depending on circumstances.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Unless otherwise specified, off-state current in this specification and the like refers to leakage current between a source and a drain of a transistor in an off state (also referred to as a non-conduction state or a cutoff state). Unless otherwise specified, the off state refers to a state where a gate-source voltage (also referred to as Vgs or Vg) is lower than a threshold voltage (also referred to as Vth) in an n-channel transistor, and refers to a state where a gate-source voltage is higher than a threshold voltage in a p-channel transistor.

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of the side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat and may be substantially flat with a slight curvature or substantially flat with slight unevenness.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure. Note that a device having the MML (metal maskless) structure can be manufactured without using a metal mask, and thus can break through the resolution limit due to alignment accuracy of the metal mask. Furthermore, the device having the MML structure can eliminate the need for the manufacturing facilities for metal masks and the washing process for metal masks. In addition, the device having the MML structure can be manufactured at low cost, and thus is suitable for mass production.

In this specification and the like, a structure where light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

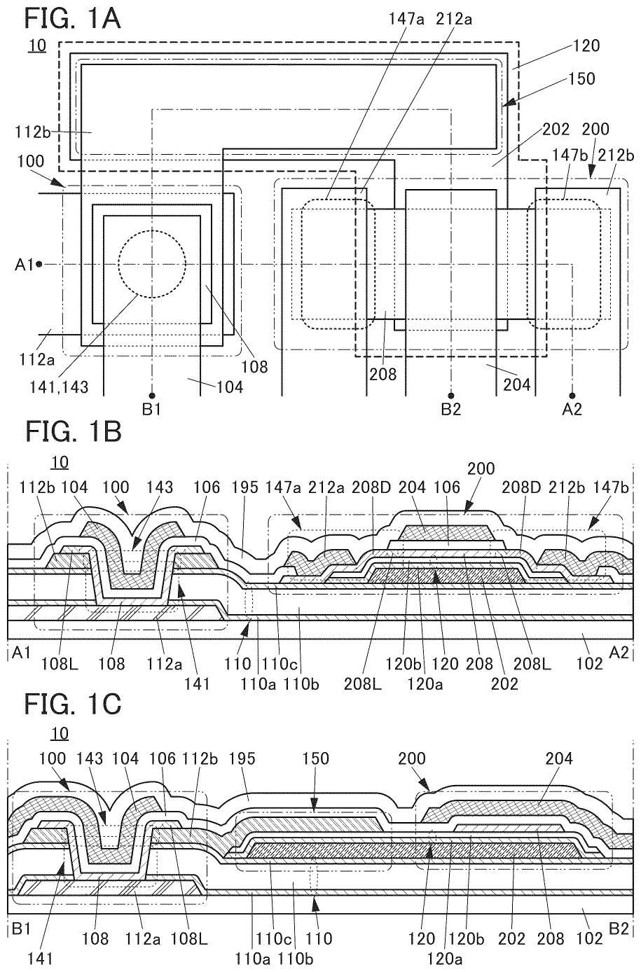

In this embodiment, a semiconductor device of one embodiment of the present invention is described with reference to FIG. 1 to FIG. 21.

One embodiment of the present invention is a semiconductor device including a transistor and a first insulating layer.

The transistor includes a first conductive layer, a second conductive layer including a region overlapping with the first conductive layer with the first insulating layer therebetween, a semiconductor layer, a gate insulating layer, and a gate electrode. The second conductive layer includes a first opening in the region overlapping with the first conductive layer. The first insulating layer includes a second opening reaching the first conductive layer in a region overlapping with the first opening. In the first opening and the second opening, the semiconductor layer is in contact with the top surface of the first conductive layer, the side surface of the first insulating layer, and the side surface of the second conductive layer. The gate insulating layer is provided over the semiconductor layer and the gate electrode is provided over the gate insulating layer. In the transistor, the first conductive layer functions as one of a source electrode and a drain electrode and the second conductive layer functions as the other. In the transistor, the source electrode, a layer including a channel formation region, and the drain electrode can be provided to overlap with each other and the occupied area can be reduced accordingly. The region of the semiconductor layer that is in contact with the first insulating layer functions as the channel formation region. Consequently, the channel length of the transistor can be shorter than the resolution limit of a light exposure apparatus and the on-state current of the transistor can be high.

The semiconductor layer preferably includes a metal oxide. For the first insulating layer, a material releasing oxygen is preferably used. Thus, oxygen can be supplied from the first insulating layer to the semiconductor layer (in particular, the channel formation region) to reduce oxygen vacancies (Vₒ) in the semiconductor layer.

In a transistor with a short channel length, the amount of oxygen supplied from the first insulating layer to the semiconductor layer is preferably as large as possible. In addition, the diffusion coefficient of oxygen in the first insulating layer is preferably high. Specifically, the diffusion coefficient of oxygen in the first insulating layer at 350° C. is preferably higher than or equal to 5×10⁻¹² cm²/sec. Under such conditions, oxygen is diffused into the first insulating layer at high speed and oxygen can be effectively supplied to the semiconductor layer. This allows even a transistor with a short channel length to achieve both excellent electrical characteristics and high reliability.

### Structure Example 1

The semiconductor device of one embodiment of the present invention will be described.

FIG. 1A is a top view (also referred to as a plan view) of a semiconductor device 10. FIG. 1B is a cross-sectional view of a cut plane along the dashed-dotted line A1-A2 in FIG. 1A, and FIG. 1C is a cross-sectional view of a cut plane along the dashed-dotted line B1-B2. Note that in FIG. 1A, some components (e.g., an insulating layer) of the semiconductor device 10 are not illustrated. Some components are not illustrated in top views of semiconductor devices in the following diagrams, as in FIG. 1A.

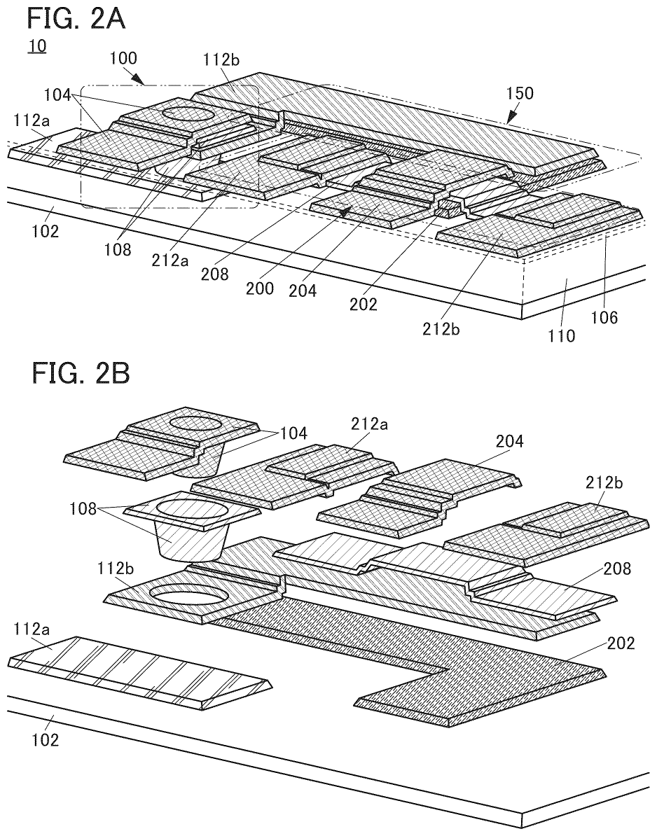

FIG. 2A and FIG. 2B are perspective views of the semiconductor device 10. In FIG. 2B, some components illustrated in FIG. 2A are illustrated to be shifted in the normal direction of a surface of a substrate 102.

The semiconductor device 10 includes a transistor 100, a transistor 200, a capacitor 150, and an insulating layer 110. The transistor 100, the transistor 200, and the capacitor 150 are provided over the substrate 102. The transistor 100 has a structure different from that of the transistor 200. Some formation steps can be common between the transistor 100, the transistor 200, and the capacitor 150.

The transistor 100 includes a conductive layer 104, an insulating layer 106, a semiconductor layer 108, a conductive layer 112a, and a conductive layer 112b. In the transistor 100, the conductive layer 104 functions as a gate electrode (also referred to as a first gate electrode), and part of the insulating layer 106 functions as a gate insulating layer (also referred to as a first gate insulating layer). The conductive layer 112a functions as one of a source electrode and a drain electrode, and the conductive layer 112b functions as the other. The layers forming the transistor 100 may each have a single-layer structure or a stacked-layer structure. Note that in FIG. 2A, the insulating layer 110 and the insulating layer 106 are transparent, and their outlines are indicated by dashed lines.

The conductive layer 112a is provided over the substrate 102, and the insulating layer 110 is provided over the conductive layer 112a. The insulating layer 110 is provided to cover the top surface and the side surface of the conductive layer 112a. The insulating layer 110 has an opening 141 reaching the conductive layer 112a. It can be said that the conductive layer 112a is exposed in the opening 141.

The conductive layer 112b is provided over the insulating layer 110. The conductive layer 112b includes a region overlapping with the conductive layer 112a with the insulating layer 110 therebetween. The conductive layer 112b has an opening 143 in the region overlapping with the conductive layer 112a. The opening 143 is provided in a region overlapping with the opening 141.

The semiconductor layer 108 is provided to cover the opening 141 and the opening 143. The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a. The semiconductor layer 108 includes a region overlapping with the conductive layer 112a with the insulating layer 110 therebetween. It can also be said that the insulating layer 110 includes a region interposed between the conductive layer 112a and the semiconductor layer 108.

In the semiconductor layer 108, the region in contact with the conductive layer 112a functions as one of a source region and a drain region, and the region in contact with the conductive layer 112b functions as the other. In the semiconductor layer 108, the channel formation region is provided between the source region and the drain region.

The insulating layer 106 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface and the side surface of the semiconductor layer 108, the top surface and the side surface of the conductive layer 112b, and the top surface of the insulating layer 110.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, the drain current can also be regarded as flowing in the vertical direction or the substantially vertical direction. Accordingly, the transistor of one embodiment of the present invention can be referred to as a vertical-channel transistor, a vertical transistor, or a VFET (Vertical Field-Effect Transistor).

The channel length of the transistor 100 can be controlled by the thickness of the insulating layer 110 (specifically, an insulating layer 110b) provided between the conductive layer 112a and the conductive layer 112b. Thus, a transistor with a channel length shorter than the resolution limit of a light exposure apparatus used for manufacturing the transistor can be manufactured with high accuracy. Furthermore, variation in characteristics among the transistors 100 are also reduced. Accordingly, the operation of the semiconductor device including the transistor 100 can be stabilized and the reliability thereof can be improved. When the variation in characteristics are reduced, the circuit design flexibility is increased and the operation voltage of the semiconductor device can be reduced. Thus, power consumption of the semiconductor device can be reduced.

In the transistor 100, since the source electrode, the layer including the channel formation region, and the drain electrode can be provided to overlap with each other, the area occupied by the transistor can be significantly reduced as compared with a so-called planar transistor in which a layer including a channel formation region is provided in a planar shape.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

The transistor 200 includes a conductive layer 204, a conductive layer 212a, a conductive layer 212b, the insulating layer 106, a semiconductor layer 208, an insulating layer 120, and a conductive layer 202. In the transistor 200, the conductive layer 204 functions as a gate electrode (also referred to as a first gate electrode), and part of the insulating layer 106 functions as a gate insulating layer (also referred to as a first gate insulating layer). The conductive layer 202 functions as a back gate electrode (also referred to as a second gate electrode), and part of the insulating layer 120 functions as a back gate insulating layer (also referred to as a second gate insulating layer). The conductive layer 212a functions as one of the source electrode and the drain electrode, and the conductive layer 212b functions as the other. The layers forming the transistor 200 may each have a single-layer structure or a stacked-layer structure. Note that the transistor 200 does not necessarily include the conductive layer 202. Note that the insulating layer 120 is omitted in FIG. 2A.

In the semiconductor layer 208 between the source electrode and the drain electrode, the whole region overlapping with the gate electrode with the gate insulating layer therebetween functions as a channel formation region. The semiconductor layer 208 includes a pair of regions 208L between which a channel formation region is interposed and a pair of regions 208D outside the pair of regions 208L.

The regions 208L and the regions 208D each include an impurity element. As the impurity element, one or more of hydrogen, boron, carbon, nitrogen, fluorine, phosphorus, sulfur, arsenic, aluminum, magnesium, silicon, and a noble gas can be used. Note that typical examples of a noble gas include helium, neon, argon, krypton, and xenon. It is particularly preferable to use one or more of boron, phosphorus, aluminum, magnesium, and silicon as the impurity element.

An impurity element is supplied (also expressed as “added” or “implanted”) to the semiconductor layer 208 using the conductive layer 204, the conductive layer 212a, and the conductive layer 212b as masks. Thus, the regions 208D are formed in the regions of the semiconductor layer 208 that overlap with none of the conductive layer 204, the conductive layer 212a, the conductive layer 212b, and the insulating layer 106, and the regions 208L are formed in the regions of the semiconductor layer 208 that overlap with none of the conductive layer 204, the conductive layer 212a, and the conductive layer 212b and overlap with the insulating layer 106.

In the semiconductor layer 208, a region in contact with the conductive layer 212a and the region 208D adjacent to the region function as one of a source region and a drain region. In the semiconductor layer 208, a region in contact with the conductive layer 212b and the region 208D adjacent to the region function as the other of the source region and the drain region.

The conductive layer 202 is provided over the insulating layer 110, and the insulating layer 120 is provided over the conductive layer 202. The insulating layer 120 is provided to cover the top surface and the side surface of the conductive layer 202. The insulating layer 120 includes a portion protruding beyond an end portion of the conductive layer 202. An end portion of the insulating layer 120 is in contact with the top surface of the insulating layer 110.

The semiconductor layer 208 is provided over the insulating layer 120. The semiconductor layer 208 includes a region overlapping with the conductive layer 202 with the insulating layer 120 therebetween. The semiconductor layer 208 can be formed using the same material as the semiconductor layer 108. The semiconductor layer 208 can be formed in the same step as the semiconductor layer 108. For example, a film to be the semiconductor layer 108 and the semiconductor layer 208 is formed and then processed, whereby the semiconductor layer 108 and the semiconductor layer 208 can be formed.

The insulating layer 106 is provided over the semiconductor layer 208. One part of the insulating layer 106 functions as the gate insulating layer of the transistor 100 and another part of the insulating layer 106 functions as the gate insulating layer of the transistor 200. The insulating layer 106 has an opening 147a and an opening 147b in regions overlapping with the semiconductor layer 208.

The conductive layer 204, the conductive layer 212a, and the conductive layer 212b are provided over the insulating layer 106. The conductive layer 204 includes a region overlapping with the semiconductor layer 208 with the insulating layer 106 therebetween. The conductive layer 204 includes a region overlapping with the conductive layer 202 with the semiconductor layer 208 therebetween. The conductive layer 212a and the conductive layer 212b are provided to cover part of the opening 147a and part of the opening 147b, respectively. The conductive layer 212a is electrically connected to the semiconductor layer 208 through the opening 147a and the conductive layer 212b is electrically connected to the semiconductor layer 208 through the opening 147b. The conductive layer 204, the conductive layer 212a, and the conductive layer 212b can be formed using the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and then processed, whereby the conductive layer 104, the conductive layer 204, the conductive layer 212a, and the conductive layer 212b can be formed.

The transistor 200 is a planar transistor in which the semiconductor layer 208 is provided in a planar shape. In addition, the transistor 200 is what is called a top-gate transistor including the gate electrode above the semiconductor layer 208. For example, when an impurity element is supplied to the semiconductor layer 208 with the conductive layer 204, which functions as the gate electrode, used as a mask, the regions 208D functioning as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 has a value larger than or equal to that of the resolution limit of a light-exposure apparatus used for manufacture of the transistor. That is, the channel length of the transistor 200 can be longer than the channel length of the transistor 100. The transistor with a long channel length can have favorable saturation characteristics.

In this specification and the like, the state where the change in current is small in the saturation region of the Id-Vd characteristics of a transistor is sometimes described using the expression “favorable saturation characteristics”.

The transistor 100 with a short channel length and the transistor 200 with a long channel length can be formed over the same substrate by the formation steps some of which are shared. For example, when the transistor 100 is used as the transistor required to have a high on-state current and the transistor 200 is used as the transistor required to have favorable saturation characteristics, the semiconductor device can achieve high performance.

When the semiconductor device of one embodiment of the present invention is used for a pixel circuit of a display apparatus, for example, the area occupied by the pixel circuit can be reduced and the display apparatus can have high resolution. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel, for example.

The capacitor 150 includes the conductive layer 112b and the conductive layer 202 functioning as a pair of electrodes and the insulating layer 120. The conductive layer 112b functions as the other of the source electrode and the drain electrode of the transistor 100 and also functions as one of the pair of electrodes of the capacitor 150. The conductive layer 202 functions as the back gate electrode of the transistor 200 and also functions as the other of the pair of electrodes of the capacitor 150. In the insulating layer 120, a region interposed between the conductive layer 112b and the conductive layer 202 functions as a dielectric of the capacitor 150. When the conductive layer 112b and the conductive layer 202 are formed in different steps, the capacitor 150 including these conductive layers as the pair of electrodes can be formed. Forming the conductive layer 112b and the conductive layer 202 in different steps allows the conductive layer 112b and the conductive layer 202 to be formed using different materials, offering a wider range of material choices.

Although the capacitor 150 is formed of the conductive layer 112b, the conductive layer 202, and the insulating layer 120 in the examples described with FIG. 1A and the like, there is no limitation on the structure of the capacitor 150. Furthermore, the capacitor 150 is not necessarily included in the semiconductor device 10. In the case where the capacitor 150 formed of the conductive layer 112b, the conductive layer 202, and the insulating layer 120 is not provided, the conductive layer 112b and the conductive layer 202 may be formed in the same step.

Although the other of the source electrode and the drain electrode of the transistor 100 is electrically connected to one of the pair of electrodes of the capacitor 150 and one of the source electrode and the drain electrode of the transistor 200 is electrically connected to the other of the pair of electrodes of the capacitor 150 in the structures illustrated in FIG. 1A and the like, there is no limitation on the electrical connection relation between the transistor 100, the transistor 200, and the capacitor 150.

An insulating layer 195 is provided to cover the transistor 100, the transistor 200, and the capacitor 150. The insulating layer 195 functions as a protective layer for the transistor 100, the transistor 200, and the capacitor 150. Note that the insulating layer 195 is omitted in the perspective views shown in FIG. 2A and FIG. 2B.

Next, components of the transistor 100 and the transistor 200 are described in detail.

A semiconductor material that can be used for each of the semiconductor layer 108 and the semiconductor layer 208 is not particularly limited. For example, a single-element semiconductor or a compound semiconductor can be used. Examples of a single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may contain an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). The transistor including amorphous silicon in the channel formation region can be formed over a large glass substrate, and can be manufactured at low cost. A transistor including polycrystalline silicon in the channel formation region has high field-effect mobility and enables high-speed operation. A transistor including microcrystalline silicon in the channel formation region has higher field-effect mobility and enables higher-speed operation than the transistor including amorphous silicon.

Each of the semiconductor layer 108 and the semiconductor layer 208 preferably includes a metal oxide exhibiting semiconductor characteristics (also referred to as an oxide semiconductor).

The band gaps of the metal oxides used for the semiconductor layer 108 and the semiconductor layer 208 are each preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, a semiconductor device can have lower power consumption by including the OS transistor.

The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

In this specification and the like, an oxynitride refers to a material that contains more oxygen than nitrogen in its composition. A nitride oxide refers to a material that contains more nitrogen than oxygen in its composition.

The insulating layer 110 includes a region in contact with the semiconductor layer 108. In the case where the semiconductor layer 108 is formed using a metal oxide, at least part of the region of the insulating layer 110 that is in contact with the semiconductor layer 108 preferably contains oxygen to improve the characteristics of the interface between the semiconductor layer 108 and the insulating layer 110. Specifically, the portion of the insulating layer 110 that is in contact with the channel formation region of the semiconductor layer 108 preferably contains oxygen. One or more of an oxide and an oxynitride is suitably used for the portion of the insulating layer 110 that is in contact with the channel formation region of the semiconductor layer 108.

The insulating layer 110 preferably has a stacked-layer structure. FIG. 1B and the like illustrate a structure where the insulating layer 110 includes an insulating layer 110a, the insulating layer 110b over the insulating layer 110a, and an insulating layer 110c over the insulating layer 110b.

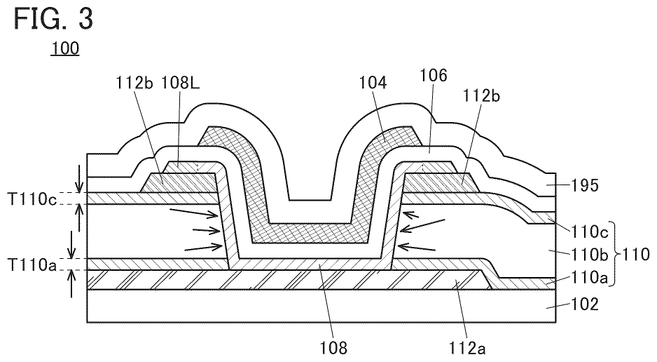

FIG. 3 is an enlarged view of the transistor 100 illustrated in FIG. 1B. The region of the semiconductor layer 108 that is in contact with the insulating layer 110b functions as the channel formation region. The insulating layer 110b preferably contains oxygen, and is preferably formed using any one or more of the oxides and oxynitrides described above. Specifically, one or both of silicon oxide and silicon oxynitride can be suitably used for the insulating layer 110b.

It is further preferable that a film from which oxygen is released by heating be used as the insulating layer 110b. When the insulating layer 110b releases oxygen by heat applied in the manufacturing process of the transistor 100, the oxygen can be supplied to the semiconductor layer 108. Supply of oxygen from the insulating layer 110b to the semiconductor layer 108, particularly to the channel formation region, can repair oxygen vacancies (Vₒ) and reduce oxygen vacancies (Vₒ). Consequently, a transistor with favorable electrical characteristics and high reliability can be obtained.

For example, the insulating layer 110b can be supplied with oxygen when heat treatment in an atmosphere containing oxygen or plasma treatment in an atmosphere containing oxygen is performed. Alternatively, an oxide film may be formed over the top surface of the insulating layer 110b by a sputtering method in an atmosphere containing oxygen to supply oxygen. After that, the oxide film may be removed. Note that a method for supplying oxygen to the insulating layer 110b will be described in Embodiment 2.

The insulating layer 110b is preferably formed by a film formation method such as a sputtering method or a plasma-enhanced chemical vapor deposition (PECVD, also referred to as plasma CVD) method. In particular, when the insulating layer 110b is formed by a sputtering method, which is a method that does not use a gas containing hydrogen as a film formation gas, the insulating layer 110b can be a film having an extremely low hydrogen content. Thus, supply of hydrogen to the channel formation region is inhibited and the electrical characteristics of the transistor 100 can be stabilized.

In the insulating layer 110b, a substance (e.g., an atom, a molecule, or an ion) is preferably easily diffused. In other words, the diffusion coefficient of a substance in the insulating layer 110b is preferably high. Preferably, oxygen in particular is easily diffused in the insulating layer 110b. That is, the diffusion coefficient of oxygen in the insulating layer 110b is preferably high. Oxygen contained in the insulating layer 110b is diffused in the insulating layer 110b and supplied to the semiconductor layer 108 through the interface between the insulating layer 110b and the semiconductor layer 108. In FIG. 3, arrows schematically show diffusion of oxygen contained in the insulating layer 110b to the interface between the insulating layer 110b and the semiconductor layer 108. The insulating layer 110b that easily allows diffusion of oxygen enables efficient supply of oxygen contained in the insulating layer 110b to the semiconductor layer 108 (in particular, the channel formation region).

The diffusion coefficient of oxygen in the insulating layer 110b at 350° C. is preferably higher than or equal to 5×10⁻¹² cm²/sec, further preferably higher than or equal to 1×10⁻¹¹ cm²/sec, still further preferably higher than or equal to 5×10⁻¹¹ cm²/sec, yet still further preferably higher than or equal to 1×10⁻¹⁰ cm²/sec. Accordingly, oxygen contained in the insulating layer 110b can be supplied to the semiconductor layer 108 efficiently. Since the diffusion coefficient is preferably as high as possible, the upper limit thereof is not set. The diffusion coefficient can be calculated by thermal desorption spectroscopy (TDS), for example. Alternatively, secondary ion mass spectrometry (SIMS) may be used.

The formation of the insulating layer 110b will be specifically described. Here, an example where silicon oxynitride is formed by a PECVD method is described.

A gas including a deposition gas containing silicon and an oxidizing gas can be used as the source gas of the insulating layer 110b. As the deposition gas containing silicon, one or more of silane (SiH₄), disilane (Si₂H₆), trisilane (Si₃H₈), silane fluoride (SiF₄), and TEOS (Tetraethoxysilane, Si(OC₂H₅)₄) can be used, for example. As the oxidizing gas, a gas containing oxygen can be suitably used. As the oxidizing gas, for example, one or more of oxygen (O₂), ozone (O₃), dinitrogen monoxide (N₂O), nitrogen monoxide (NO), and nitrogen dioxide (NO₂) can be used. In the case where silane (SiH₄) is used as the deposition gas containing silicon, dinitrogen monoxide (N₂O) is preferably used as the oxidizing gas, in which case the number of particles can be smaller than that of the case where oxygen (O₂) is used. Alternatively, in the case where silicon oxide is formed as the insulating layer 110b and TEOS is used as the deposition gas containing silicon, oxygen (O₂) can be suitably used as the oxidizing gas.

When the plasma density with respect to the flow rate of the deposition gas is reduced, that is, when the ratio of the plasma density to the flow rate of the deposition gas is reduced, in the formation of the insulating layer 110b by a PECVD method, the insulating layer can have a high diffusion coefficient. Here, in the case where an RF power source is used to bring the source gas into a plasma state, the plasma density can be reduced by reducing the power of the RF power source (hereinafter also referred to as RF power). By reducing the RF power with respect to the flow rate of the deposition gas (reducing the ratio of the RF power to the flow rate of the deposition gas), the insulating layer can have a high diffusion coefficient. By reducing the ratio of the RF power to the flow rate of the deposition gas (hereinafter also referred to as an F ratio), the diffusion coefficient of oxygen in the insulating layer 110b is increased, so that oxygen contained in the insulating layer 110b can be efficiently supplied to the semiconductor layer 108 (in particular, the channel formation region). However, in the case where a gas containing hydrogen (e.g., SiH₄) is used as the source gas, too low an F ratio might increase the amount of hydrogen contained in the insulating layer 110b. A large amount of hydrogen contained in the insulating layer 110b might cause the insulating layer 110b to release a large amount of impurities containing hydrogen (e.g., water, hydrogen, and ammonia).

When the unit of the gas flow rate is represented by sccm (Standard Cubic Centimeters Per Minute) and that of the RF power is represented by W (Watt), the F ratio is preferably less than or equal to 12, less than or equal to 10, less than or equal to 9, less than or equal to 8, less than or equal to 7, less than or equal to 6, or less than or equal to 5 and greater than or equal to 2 or greater than or equal to 3. For example, in the case where the flow rate of silane (SiH₄) is 290 sccm and the RF power is 1160 W, the F ratio is 4. When the F ratio is within the above range, oxygen contained in the insulating layer 110b can be efficiently supplied to the semiconductor layer 108 (in particular, the channel formation region) and the amount of impurities released from the insulating layer 110b can be reduced.

In this specification and the like, sccm represents a flow rate at 1 atmospheric pressure and 0° C. (273.15 K). Although the F ratio of the case where the unit of a gas flow rate is represented by sccm and that of the RF power is represented by W is shown, when a different unit is used, the unit can be converted into the above unit to calculate the F ratio. For example, in the case where the flow rate is 0.3 SLM (Standard Liter Per Minute), the F ratio can be calculated by converting 0.3 SLM into 300 sccm.

The electrical characteristics of the transistor 100 with a shorter channel length are more affected by oxygen vacancies (Vₒ) and VₒH in the channel formation region than those of a transistor with a longer channel length. Therefore, it is extremely important to efficiently supply oxygen from the insulating layer 110b to the semiconductor layer 108 (in particular, the channel formation region) and to reduce the amount of impurities released from the insulating layer 110b. When the F ratio in the formation of the insulating layer 110b is within the above range, the transistor can have favorable electrical characteristics and high reliability.

When a gas is released from a film by heat application to the film, diffusion in the film and reaction at the film surface can be the bottleneck processes for the gas release, for example. Diffusion is less likely to be the bottleneck in a film that easily allows diffusion of a substance, and thus the temperature at which a gas starts to be released when heat is applied (hereinafter, also referred to as a release temperature) is low. By contrast, diffusion is the bottleneck in a film that does not easily allow diffusion of a substance, and thus the release temperature of a gas is high. As described above, a film that easily allows diffusion of a substance is preferably used for the insulating layer 110b. Thus, the release temperature of a gas when heat is applied to the insulating layer 110b is preferably low. For example, the release temperature of a gas in TDS of the insulating layer 110b is preferably low. In particular, the release temperature of oxygen (¹⁶O₂, m/z=32) in TDS of the insulating layer 110b is preferably low.

Note that oxygen may be supplied from the insulating layer 110b to the semiconductor layer 108 in the manufacturing process of the semiconductor device 10 to reduce the amount of oxygen that can be released from the insulating layer 110b in the semiconductor device 10 after the manufacturing process. Thus, in the case where TDS is performed on the semiconductor device 10, the amount of released oxygen is sometimes small. Note that in a film that easily allows diffusion of oxygen, a substance other than oxygen is also easily diffused; thus, when the release temperature of a released gas other than oxygen is low, the film is probably a film that easily allows diffusion of oxygen. For example, when the release temperature of nitrogen (¹⁴N₂, m/z=28) is low in TDS of the semiconductor device 10, it is presumed that the release temperature of oxygen is also low and oxygen is easily diffused in the film. In TDS of the semiconductor device 10, the release temperature of nitrogen (¹⁴N₂, m/z=28) is preferably lower than or equal to 250° C., lower than or equal to 200° C., lower than or equal to 180° C., lower than or equal to 170° C., or lower than or equal to 160° C. and higher than or equal to 140° C. In that case, oxygen contained in the insulating layer 110b can be efficiently supplied to the semiconductor layer 108 (in particular, the channel formation region) and the amount of impurities released from the insulating layer 110b can be reduced. Note that in the case where TDS is performed on the semiconductor device 10, the layers above the insulating layer 110b are preferably removed to expose the insulating layer 110b. Note that in this embodiment, the temperature rising rate of the sample surface temperature in TDS is approximately 14° C./min. The temperature rising rate of the stage where the sample is placed can be approximately 32° C./min, for example.

An example of a method for calculating the release temperature in TDS is described. In a graph where the X axis represents the sample surface temperature and the Y axis represents the detection intensity (e.g., current value) of the mass analyzer, a tangent is drawn at a point where the slope on a low temperature side of a peak becomes the maximum, and the intersection of the tangent and the X axis (Y=0) can be the release temperature. The detection intensity of the mass analyzer is preferably subjected to background processing. An example of the background processing is a method in which the minimum value of the detection intensity in the entire temperature range of the measurement is subtracted as a background value from a measured value.

Note that in film formation, the etching rate with respect to an etchant is low when the F ratio is high, whereas the etching rate with respect to an etchant is high when the F ratio is low; thus, the etching rate can be used as an indicator of ease of diffusion. As the etchant, an etchant containing hydrofluoric acid can be used, for example. Specific examples include hydrofluoric acid and BHF (Buffered Hydrofluoric acid). Note that BHF is an etchant containing hydrofluoric acid and a buffer agent (e.g., ammonium fluoride (NH₄F)). Alternatively, any of these etchants to which a surface-active agent is added may be used. For example, in the case where silicon oxide or silicon oxynitride is used for the insulating layer 110b, the etching rate of the insulating layer 110b with respect to 0.5 wt % hydrofluoric acid at 25° C. is preferably higher than or equal to 8 nm/min, higher than or equal to 9 nm/min, higher than or equal to 10 nm/min, higher than or equal to 11 nm/min, or higher than or equal to 12 nm/min and lower than or equal to 15 nm/min. Note that the etching rate can be calculated by dividing a difference between the thickness of a target film before the etching and the thickness of the target film after the etching by the etching time.

The use of a material having high electrical conductivity for the semiconductor layer 108 enables the transistor to have a high on-state current. However, the use of a material having high electrical conductivity facilitates the formation of oxygen vacancies (Vₒ); the increased oxygen vacancies (Vₒ) in the channel formation region shift the threshold voltage of the transistor, which might increase the drain current flowing at a gate voltage of 0 V (hereinafter, also referred to as cut-off current). For example, a negative shift of the threshold voltage might increase the cut-off current in the case of an n-channel transistor. The insulating layer 110b enables oxygen supply to at least the region of the semiconductor layer 108 that is in contact with the insulating layer 110b, i.e., the channel formation region, reducing the oxygen vacancies (Vₒ) in the channel formation region. This prevents the threshold voltage shift and allows the transistor to have both a low cut-off current and a high on-state current. Consequently, the semiconductor device can have both low power consumption and high performance.

In the semiconductor layer 108, the region in contact with the conductive layer 112a functions as one of the source region and the drain region of the transistor 100, and the region in contact with the conductive layer 112b functions as the other. The source and drain regions have lower electric resistance than the channel formation region. In other words, the source region and the drain region are each a region having a higher carrier concentration or a higher oxygen vacancy density than the channel formation region.

The insulating layer 110a is provided between the insulating layer 110b and the conductive layer 112a. The insulating layer 110c is provided between the insulating layer 110b and the conductive layer 112b. It is preferable that the insulating layer 110a and the insulating layer 110c themselves release a small amount of impurity (e.g., hydrogen and water) and not easily transmit impurities. Thus, the impurities contained in the insulating layer 110a and the insulating layer 110c can be inhibited from being diffused into the channel formation region. Consequently, a transistor with favorable electrical characteristics and high reliability can be obtained.

For each of the insulating layer 110a and the insulating layer 110c, a film that does not easily transmit oxygen is preferably used. Accordingly, oxygen contained in the insulating layer 110b can be inhibited from being diffused into the conductive layer 112a through the insulating layer 110a. Similarly, oxygen contained in the insulating layer 110b can be inhibited from being diffused into the conductive layer 112b through the insulating layer 110c. This can inhibit the conductive layer 112a and the conductive layer 112b from being oxidized and having increased electric resistance. At the same time, oxygen contained in the insulating layer 110b can be inhibited from being diffused to the insulating layer 110a side and the insulating layer 110c side, which increases the amount of oxygen supplied to the channel formation region from the insulating layer 110b and can reduce oxygen vacancies (Vₒ) and VₒH in the channel formation region.

When a film that does not easily allow diffusion of oxygen is used for each of the insulating layer 110a and the insulating layer 110c, oxygen can be effectively supplied from the insulating layer 110b to the channel formation region. Note that one or both of the insulating layer 110a and the insulating layer 110c are not necessarily provided.

It is preferable that the insulating layer 110a and the insulating layer 110c each contain nitrogen and be each formed using any one or more of the nitrides and nitride oxides described above. For example, silicon nitride or silicon nitride oxide can be suitably used for each of the insulating layer 110a and the insulating layer 110c. Alternatively, any one or more of oxide and oxynitride may be used for one or both of the insulating layer 110a and the insulating layer 110c. For example, aluminum oxide can be suitably used for each of the insulating layer 110a and the insulating layer 110c. Note that the insulating layer 110a and the insulating layer 110c may be formed using the same material or different materials.

Note that in this specification and the like, different materials mean materials in which some or all of constituent elements are different or materials having the same constituent elements and different compositions.

For example, a thickness T110a of the insulating layer 110a can be greater than or equal to 3 nm, greater than or equal to 5 nm, greater than or equal to 10 nm, greater than or equal to 20 nm, greater than or equal to 50 nm, or greater than or equal to 70 nm and less than 1 μm or less than or equal to 500 nm, less than or equal to 400 nm, less than or equal to 300 nm, less than or equal to 200 nm, less than or equal to 150 nm, or less than or equal to 120 nm. The thickness T110a can be the shortest distance between the formation surface of the insulating layer 110a (the top surface of the conductive layer 112a here) and the bottom surface of the insulating layer 110b in a cross-sectional view, as illustrated in FIG. 3.

If the thickness T110a of the insulating layer 110a is large, more impurities might be released from the insulating layer 110a, resulting in an increase in impurities being diffused into the channel formation region. Meanwhile, if the thickness T110a is small, oxygen contained in the insulating layer 110b might be diffused to the conductive layer 112a side through the insulating layer 110a, resulting in a reduction in the amount of oxygen supplied to the channel formation region. When the thickness T110a is set within the above-described range, the oxygen vacancies (Vₒ) and VₒH in the channel formation region can be reduced. Furthermore, the conductive layer 112a can be inhibited from being oxidized by oxygen contained in the insulating layer 110b and from having increased electric resistance.

For example, a thickness T110c of the insulating layer 110c can be greater than or equal to 3 nm, greater than or equal to 5 nm, greater than or equal to 10 nm, greater than or equal to 15 nm, or greater than or equal to 20 nm and less than or equal to 1 μm or less than or equal to 500 nm, less than or equal to 300 nm, less than or equal to 200 nm, less than or equal to 150 nm, or less than or equal to 120 nm, or less than or equal to 100 nm. The thickness T110c can be the shortest distance between the formation surface of the insulating layer 110c (the top surface of the conductive layer 110b here) and the bottom surface of the insulating layer 112b in a cross-sectional view, as illustrated in FIG. 3.

If the thickness T110c of the insulating layer 110c is large, more impurities might be released from the insulating layer 110c, resulting in an increase in the amount of impurities being diffused into the channel formation region. Meanwhile, if the thickness T110c is small, oxygen contained in the insulating layer 110b might be diffused to the conductive layer 112b side through the insulating layer 110c, resulting in a reduction in the amount of oxygen supplied to the channel formation region. When the thickness T110c is set within the above-described range, the oxygen vacancies (Vₒ) and VₒH in the channel formation region can be reduced. Furthermore, the conductive layer 112b can be inhibited from being oxidized by oxygen contained in the insulating layer 110b and from having increased electric resistance.

In the semiconductor layer 108, at least one of the region in contact with the insulating layer 110a and the region in contact with the insulating layer 110c may be a region having lower electric resistance than the channel formation region (hereinafter, also referred to as a low-resistance region). In other words, the region is a region having a higher carrier concentration or a higher oxygen vacancy density than the channel formation region. When a material that releases an impurity (e.g., water and hydrogen) is used for the insulating layer 110a, the region of the semiconductor layer 108 that is in contact with the insulating layer 110a can be a low-resistance region. In the semiconductor layer 108, the low-resistance region can be formed between the channel formation region and the region in contact with the conductive layer 112a (one of the source region and the drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be formed between the channel formation region and the region in contact with the conductive layer 112b (the other of the source region and the drain region). The low-resistance region can function as a buffer region for relieving a drain electric field. These low-resistance regions may function as the source region and the drain region.

The low-resistance region between the drain region and the channel formation region inhibits generation of a high electric field in the vicinity of the drain region, so that generation of hot carriers is inhibited to prevent the deterioration of the transistor. For example, in the case where the conductive layer 112a functions as the drain electrode, the conductive layer 112b functions as the source electrode, and the region of the semiconductor layer 108 that is in contact with the insulating layer 110a serves as the low-resistance region, a high electric field is not easily generated in the vicinity of the drain region, so that generation of hot carriers is inhibited to prevent the deterioration of the transistor. In the case where the conductive layer 112a functions as the source electrode, the conductive layer 112b functions as the drain electrode, and the region of the semiconductor layer 108 that is in contact with the insulating layer 110c serves as the low-resistance region, a high electric field is not easily generated in the vicinity of the drain region, so that generation of hot carriers is inhibited to prevent the deterioration of the transistor.

As described above, when an excessive amount of impurities is released from the insulating layer 110a and the insulating layer 110c, impurities might be diffused into the channel formation region. Even when a material that releases impurities is used for the insulating layer 110a and the insulating layer 110c, the amount of released impurities is preferably small.

Note that the insulating layer 110 preferably includes at least the insulating layer 110b. For example, one or more of the insulating layer 110a and the insulating layer 110c are not necessarily provided. The insulating layer 110 may have a single-layer structure or a stacked-layer structure of two or four or more layers.

There is no limitation on the top surface shapes of the opening 141 and the opening 143, and the shapes can be polygons such as a circle, an ellipse, a triangle, a tetragon (including a rectangle, a rhombus, and a square), and a pentagon; and polygons with rounded corners, for example. Note that the polygon may be a concave polygon (a polygon at least one of the interior angles of which is greater than 180°) or a convex polygon (a polygon all the interior angles of which are less than or equal to) 180°. The top surface shapes of the opening 141 and the opening 143 are preferably circles as illustrated in FIG. 1A and the like. When the top surface shapes of the openings are circles, processing accuracy in forming the openings can be high, whereby the openings can be formed to have minute sizes. In this specification and the like, a circle is not limited to a perfect circle.

In this specification and the like, the top surface shape of the opening 141 refers to the shape of the end portion of the top surface of the insulating layer 110 on the opening 141 side. The top surface shape of the opening 143 refers to the shape of the end portion of the bottom surface of the conductive layer 112b on the opening 143 side.

As illustrated in FIG. 1A and the like, the top surface shape of the opening 141 and the top surface shape of the opening 143 can be the same or substantially the same. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 1B, FIG. 1C, and the like. The bottom surface of the conductive layer 112b refers to the surface thereof on the insulating layer 110 side. The top surface of the insulating layer 110 refers to the surface thereof on the conductive layer 112b side.

Note that the top surface shape of the opening 141 and the top surface shape of the opening 143 are not necessarily the same. In the case where the top surface shapes of the opening 141 and the opening 143 are circles, the opening 141 and the opening 143 may be, but not necessarily, arranged concentrically.

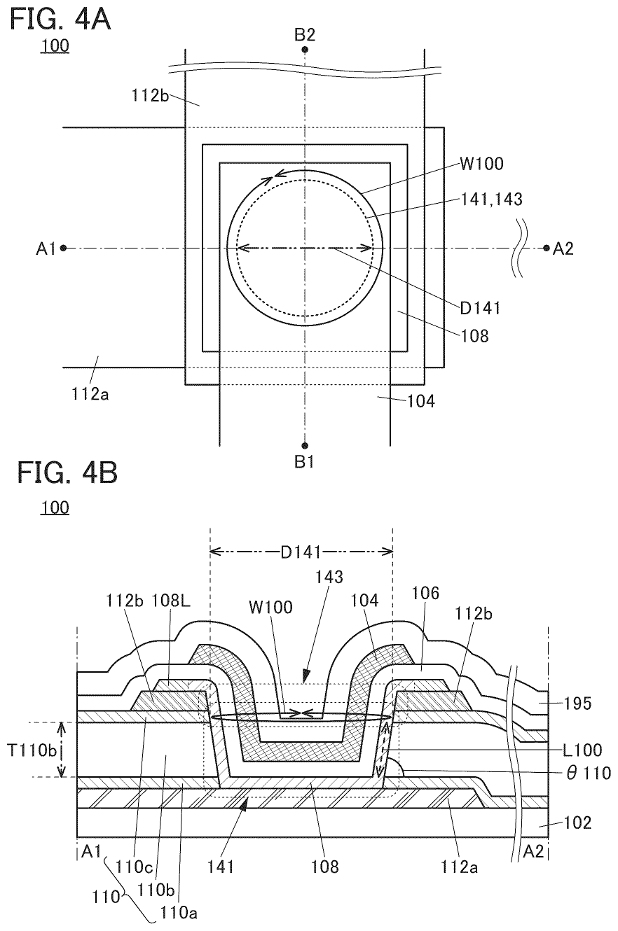

The channel length, channel width, and the like of the transistor 100 are described with reference to FIG. 4A and FIG. 4B. FIG. 4A and FIG. 4B are enlarged views of the transistor 100 illustrated in FIG. 1A and FIG. 1B.

In FIG. 4B, a channel length L100 of the transistor 100 is indicated by a dashed double-headed arrow. The channel length L100 of the transistor 100 corresponds to the length of the side surface of the insulating layer 110b on the opening 141 side in a cross-sectional view. In other words, the channel length L100 depends on a thickness T110b of the insulating layer 110b and an angle θ110 formed by the side surface of the insulating layer 110b on the opening 141 side and the formation surface of the insulating layer 110b (which is the top surface of the insulating layer 110a here). Thus, the channel length L100 can be a value smaller than that of the resolution limit of a light-exposure apparatus, which enables a transistor having a minute size. Specifically, a transistor with an extremely short channel length that could not be achieved with a conventional light-exposure apparatus for mass production of flat panel displays (the minimum line width: approximately 2 μm or approximately 1.5 μm, for example) can be achieved. Moreover, it is also possible to obtain a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be manufactured. Furthermore, the area occupied by the circuit can be reduced. Therefore, a semiconductor device with a small size can be obtained. The application of the semiconductor device of one embodiment of the present invention to a large display apparatus or a high-resolution display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110b of the insulating layer 110b and the angle θ110, the channel length L100 can be controlled. Note that in FIG. 4B, the thickness T110b of the insulating layer 110b is indicated by the dashed-dotted double-headed arrow.

The thickness T110b of the insulating layer 110b can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The side surface of the insulating layer 110 on the opening 141 side preferably has a tapered shape. The angle θ110 is preferably less than 90°. By reducing the angle θ110, the coverage with a layer (e.g., the semiconductor layer 108) formed over the insulating layer 110 can be improved. The smaller the angle θ110 is, the longer the channel length L100 can be. The larger the angle θ110 is, the shorter the channel length L100 can be.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than 90°, less than or equal to 85°, or less than or equal to 80°. The angle θ110 may be less than or equal to 75°, less than or equal to 70°, less than or equal to 65°, or less than or equal to 60°.

Although FIG. 4B and the like illustrate a structure where the side surface of the insulating layer 110 on the opening 141 side is linear in a cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110b and the channel length L100 is difficult to control in some cases. Accordingly, it is preferable that the top surface shape of the opening 143 be the same as the top surface shape of the opening 141, or the opening 143 encompasses the opening 141 in the top view (also referred to as a plan view).

In FIG. 4A and FIG. 4B, a width D141 of the opening 141 is indicated by a dashed double-dotted double-headed arrow. FIG. 4A illustrates an example where the top surface shape of the opening 141 is a circle. In this case, the width D141 corresponds to the diameter of the circle, and a channel width W100 of the transistor 100 is the length of the circumference of the circle. That is, the channel width W100 is π×D141. As described above, in the case where the top surface shape of the opening 141 is a circle, the channel width W100 of the transistor can be small as compared with the case where the top surface shape is any other shape.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level thereof, and the diameter at the midpoint between these levels. For another example, any of the diameter at the highest level of the insulating layer 110b (or the insulating layer 110) in the cross-sectional view, the diameter at the lowest level thereof, and the diameter at the midpoint between these levels can be used as the diameter of the opening 141.

In the case where the opening 141 is formed by a photolithography method, the width D141 of the opening 141 is larger than or equal to the resolution limit of a light-exposure apparatus. The width D141 can be, for example, greater than or equal to 200 nm, greater than or equal to 300 nm, greater than or equal to 400 nm, or greater than or equal to 500 nm and less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

In the case where the channel length L100 of the transistor 100 is short, the insulating layer 110a and the insulating layer 110c are each preferably formed using a material that releases as little hydrogen as possible. When formed using a material that releases even a small amount of hydrogen, the insulating layer 110a and the insulating layer 110c preferably have small thicknesses. For example, when the channel length L100 is less than or equal to 100 nm, the thickness T110a of the insulating layer 110a and the thickness T110c of the insulating layer 110c are each preferably greater than or equal to 1 nm, greater than or equal to 3 nm, or greater than or equal to 5 nm and less than or equal to 50 nm, less than or equal to 40 nm, less than or equal to 30 nm, less than or equal to 20 nm, less than or equal to 15 nm, or less than or equal to 10 nm. Accordingly, the amount of impurities being diffused into the channel formation region can be reduced, and the transistor can have favorable electrical characteristics and high reliability even with the short channel length L100.

Although the structure where the region of the semiconductor layer 108 that is in contact with the insulating layer 110b functions as the channel formation region is described as an example, one embodiment of the present invention is not limited thereto. The region of the semiconductor layer 108 that is in contact with the insulating layer 110a may also function as the channel formation region. Similarly, the region that is in contact with the insulating layer 110c may also function as the channel formation region.

Although FIG. 1B and the like illustrate an example where the semiconductor layer 108, the insulating layer 106, and the conductive layer 104 cover the opening 141 and the opening 143 in the transistor 100, one embodiment of the present invention is not limited thereto. A step may be formed between the insulating layer 110 and the conductive layer 112a, and the semiconductor layer 108, the insulating layer 106, and the conductive layer 104 may be provided along the step.

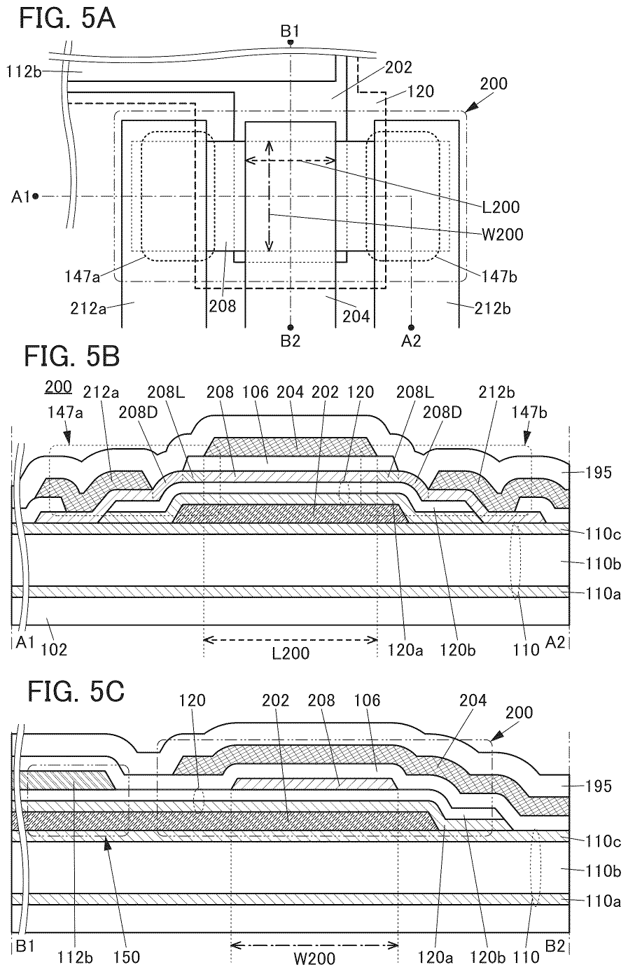

Next, the structure of the transistor 200 is described in detail with reference to FIG. 5A to FIG. 5C. FIG. 5A to FIG. 5C are enlarged views of the transistor 200 illustrated in FIG. 1A to FIG. 1C.

The channel length of the transistor 200 is the length of the region between the pair of regions 208D where the semiconductor layer 208 and the conductive layer 204 overlap with each other. In FIG. 5A and FIG. 5B, a channel length L200 of the transistor 200 is indicated by a dashed double-headed arrow. The channel length L200 of the transistor 200 depends on the length of the conductive layer 204 and has a value larger than or equal to that of the resolution limit of the light-exposure apparatus used for manufacture of the transistor. For example, the channel length L200 can be greater than or equal to 1.5 μm. The transistor with a long channel length can have favorable saturation characteristics.

In the channel length direction, the conductive layer 202 functioning as the back electrode gate of the transistor 200 preferably extends beyond the end portion of a region where the conductive layer 204 and the semiconductor layer 208 overlap with each other. That is, in the channel length direction, the size of the conductive layer 202 is preferably larger than the size of the region where the conductive layer 204 and the semiconductor layer 208 overlap with each other. Specifically, the conductive layer 202 preferably has a portion that protrudes beyond the end portion of the conductive layer 204 in the channel length direction.

Note that for easy explanation in this specification and the like, the portion of the semiconductor layer 208 overlapping with the conductive layer 204 is sometimes described as the channel formation region; however, a channel can be actually formed in a portion not overlapping with the conductive layer 204 and overlapping with the conductive layer 202.

The channel width of the transistor 200 is the width of the region where the semiconductor layer 208 and the conductive layer 204 overlap with each other in the direction orthogonal to the channel length direction. In FIG. 5A and FIG. 5C, a channel width W200 of the transistor 200 is indicated by a dashed-dotted double-headed arrow.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, when the transistor 100 is used as the transistor required to have a high on-state current and the transistor 200 is used as the transistor required to have favorable saturation characteristics, the semiconductor device 10 can achieve high performance by utilizing the advantages of the transistors. Furthermore, some formation steps can be common between the transistor 100 and the transistor 200. Specifically, the semiconductor layer 108 and the semiconductor layer 208 can be formed in the same step. One part of the insulating layer 106 functions as the gate insulating layer of the transistor 100 and another part of the insulating layer 106 functions as the gate insulating layer of the transistor 200. The conductive layer 104, the conductive layer 204, the conductive layer 212a, and the conductive layer 212b can be formed in the same step. This allows higher productivity and lower manufacturing cost of the semiconductor device 10.

As illustrated in FIG. 5A and FIG. 5C, the conductive layer 204 and the conductive layer 202 preferably protrude outward from the end portion of the semiconductor layer 208 in the channel width direction of the transistor 200. In that case, as illustrated in FIG. 5C, the whole of the semiconductor layer 208 in the channel width direction is covered with the conductive layer 204 with the insulating layer 106 therebetween and also covered with the conductive layer 202 with the insulating layer 120 therebetween. In such a structure, the semiconductor layer 208 can be electrically surrounded by electric fields generated by a pair of gate electrodes.

FIG. 5A and FIG. 5C illustrate a structure where the conductive layer 204 and the conductive layer 202 are not electrically connected to each other. A constant potential may be supplied to one of the pair of gate electrodes, and a signal for driving the transistor 200 may be supplied to the other of the pair of gate electrodes. At this time, the potential supplied to one of the gate electrodes can control the threshold voltage at the time of driving the transistor 200 with the other gate electrode.

The conductive layer 204 and the conductive layer 202 may be electrically connected to each other. When the same potential is supplied to the conductive layer 204 and the conductive layer 202, electric fields for inducing a channel can be effectively applied to the semiconductor layer 208, whereby the on-state current of the transistor 200 can be increased. Thus, the transistor 200 can also be miniaturized. For example, an opening reaching the conductive layer 202 is provided in the insulating layer 106 and the insulating layer 120 and the conductive layer 204 can be formed to cover the opening.

The conductive layer 202 may be electrically connected to the conductive layer 212a or the conductive layer 212b. For example, an opening reaching the conductive layer 202 is provided in the insulating layer 120 and the conductive layer 212a or the conductive layer 212b can be formed to cover the opening.

A material that can be used for the insulating layer 110 can be used for the insulating layer 120 that is provided to be in contact with the top surface and the side surface of the conductive layer 202.

The insulating layer 120 preferably has a stacked-layer structure. FIG. 5B and the like illustrate a structure where the insulating layer 120 has a stacked-layer structure of an insulating layer 120a and an insulating layer 120b over the insulating layer 120a. For each of the insulating layer 120a and the insulating layer 120b, a material that can be used for the insulating layer 110 can be used.

As the insulating layer 120b in contact with the channel formation region of the semiconductor layer 208, a film from which oxygen is released by heating is preferably used. When the insulating layer 120b releases oxygen by heat applied in the manufacturing process of the transistor 200, the oxygen can be supplied to the semiconductor layer 208, particularly to the channel formation region of the semiconductor layer 208. Oxygen contained in the insulating layer 120b is diffused into the insulating layer 120b and supplied to the semiconductor layer 208 through the interface between the insulating layer 120b and the semiconductor layer 208. When oxygen is supplied from the insulating layer 120b to the semiconductor layer 208, particularly to the channel formation region, oxygen vacancies (Vₒ) can be repaired, resulting in reduced oxygen vacancies (Vₒ). Consequently, a transistor with favorable electrical characteristics and high reliability can be obtained.

The diffusion coefficient of oxygen in the insulating layer 120b at 350° C. is preferably higher than or equal to 1×10⁻¹² cm²/sec, further preferably higher than or equal to 5×10⁻¹² cm²/sec.

For the insulating layer 120b, a material that can be used for the insulating layer 110b can be used. The insulating layer 120b preferably contains oxygen and is suitably formed using any one or more of an oxide and an oxynitride. Specifically, for example, silicon oxide or silicon oxynitride can be suitably used for the insulating layer 120b.

The formation of the insulating layer 120b will be specifically described. Here, an example where silicon oxynitride is formed by a PECVD method is described.

A gas including a deposition gas containing silicon and an oxidizing gas can be used as the source gas of the insulating layer 120b. For the deposition gas containing silicon and the oxidizing gas, the above description can be referred to.

In the formation of the insulating layer 120b by a PECVD method, the F ratio is preferably less than or equal to 20, less than or equal to 18, less than or equal to 16, less than or equal to 14, less than or equal to 13, less than or equal to 12, or less than or equal to 11 and greater than or equal to 4, greater than or equal to 6, greater than or equal to 7, greater than or equal to 8, or greater than or equal to 9. As described above, the diffusion coefficient of oxygen in the insulating layer 120b may be lower than the diffusion coefficient of oxygen in the insulating layer 110b. Thus, the F ratio in the formation of the insulating layer 120b can be higher than the F ratio in the formation of the insulating layer 110b. With a high F ratio, the film formation rate of the insulating layer 120b can be increased and the productivity can be increased. For example, in the case where silicon oxide or silicon oxynitride is used for the insulating layer 120b, the etching rate of the insulating layer 120b with respect to 0.5 wt % hydrofluoric acid at 25° C. is preferably higher than or equal to 5 nm/min, higher than or equal to 6 nm/min, or higher than or equal to 7 nm/min and lower than or equal to 15 nm/min.

Here, the electrical characteristics of the transistor 200 with a longer channel length are less affected by the oxygen vacancies (Vₒ) and VₒH in the channel formation region than those of the transistor 100 with a shorter channel length. Accordingly, the amount of oxygen supplied from the insulating layer 120b to the semiconductor layer 208 may be smaller than the amount of oxygen supplied from the insulating layer 110b to the semiconductor layer 108. The amount of oxygen released from the insulating layer 120b may be smaller than the amount of oxygen released from the insulating layer 110b.

The diffusion coefficient of a substance in the insulating layer 110b is preferably higher than the diffusion coefficient of the substance in the insulating layer 120b. In particular, the diffusion coefficient of oxygen in the insulating layer 110b is preferably higher than the diffusion coefficient of oxygen in the insulating layer 120b. This allows the transistor 100 having a short channel length to have favorable electrical characteristics and high reliability. The F ratio in the formation of the insulating layer 110b is preferably lower than the F ratio in the formation of the insulating layer 120b. The etching rate of the insulating layer 110b is preferably higher than the etching rate of the insulating layer 120b with respect to an etchant.

For the insulating layer 120a in contact with the conductive layer 202, a material that does not easily allow diffusion of a metal element contained in the conductive layer 202 is preferably used. This inhibits the metal element contained in the conductive layer 202 from being diffused into the channel formation region of the semiconductor layer 208 through the insulating layer 120.

For the insulating layer 120a, a material that can be used for the insulating layer 110a and the insulating layer 110c is preferably used. The insulating layer 120a preferably contains nitrogen and is suitably formed using one or more of a nitride and a nitride oxide. Specifically, for example, silicon nitride can be suitably used for the insulating layer 120a. Alternatively, any one or more of an oxide and an oxynitride may be used for the insulating layer 120a. For the insulating layer 120a, aluminum oxide can be suitably used, for example. For the insulating layer 120a, the insulating layer 110a, and the insulating layer 110c, the same material or different materials may be used.

The insulating layer 120a itself preferably releases a small amount of impurities (e.g., water and hydrogen). In that case, impurities contained in the insulating layer 120a can be inhibited from being diffused into the channel formation region of the semiconductor layer 208 through the insulating layer 120b, whereby the transistor can have excellent electrical characteristics and high reliability.

Although the insulating layer 120 has a two-layer structure here, one embodiment of the present invention is not limited thereto. The insulating layer 120 may have a stacked-layer structure of three or more layers or a single-layer structure.

Preferably, the insulating layer 120 is provided in at least a portion in contact with the channel formation region of the semiconductor layer 208 to cover the top surface and the side surface of the conductive layer 202. FIG. 5B and the like illustrate a structure where the semiconductor layer 208 includes a portion protruding beyond the end portion of the insulating layer 120. The semiconductor layer 208 includes a region in contact with the side surface of the insulating layer 120. Part of the end portion of the semiconductor layer 208 is in contact with the top surface of the insulating layer 120 and another part of the end portion is in contact with the top surface of the insulating layer 110. In other words, part of the bottom surface of the semiconductor layer 208 is in contact with the top surface of the insulating layer 120 and another part of the bottom surface is in contact with the top surface of the insulating layer 110. Alternatively, the insulating layer 120 may be provided in a region where the semiconductor layer 208 is provided such that the bottom surface of the semiconductor layer 208 is entirely in contact with the top surface of the insulating layer 120.

Although the thickness of the semiconductor layer 208 is uniform without varying from place to place in the example illustrated in FIG. 5B and the like, one embodiment of the present invention is not limited to this example. The thickness of the semiconductor layer 208 may be different between the region overlapping with the insulating layer 106 and the region not overlapping with the insulating layer 106. For example, when the opening 147a and the opening 147b are formed, the semiconductor layer 208 is sometimes partly removed, so that the semiconductor layer 208 has a thickness smaller in the region not overlapping with the insulating layer 106 than in the region overlapping with the insulating layer 106. Alternatively, the thickness of the semiconductor layer 208 may be different between the region overlapping with any of the insulating layer 106, the conductive layer 212a, and the conductive layer 212b and the region overlapping with none of them. For example, when the conductive layer 212a and the conductive layer 212b are formed, the semiconductor layer 208 is sometimes partly removed, so that the semiconductor layer 208 has a thickness smaller in the region overlapping with none of the insulating layer 106, the conductive layer 212a, and the conductive layer 212b than in the region overlapping with any of them. Alternatively, the thickness of the semiconductor layer 208 may be different among the region overlapping with the insulating layer 106, the region overlapping with any of the insulating layer 106, the conductive layer 212a, and the conductive layer 212b, and the region overlapping with none of them.

In the semiconductor layer 208, the region 208D is a region having lower electric resistance than the channel formation region. In other words, the region 208D is a region having a higher carrier concentration, a region having a higher oxygen vacancy density, or a region having a higher impurity concentration than the channel formation region.

A region 208L is a region whose electric resistance is substantially equal to or higher than that of the channel formation region. The region 208L can be referred to as a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Furthermore, the region 208L is a region whose electric resistance is substantially equal to or higher than that of the region 208D. The region 208L can be referred to as a region whose carrier concentration is substantially equal to or lower than that of the region 208D, a region whose oxygen vacancy density is substantially equal to or lower than that of the region 208D, or a region whose impurity concentration is substantially equal to or lower than that of the region 208D.

The region 208L functions as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can function as an LDD (Lightly Doped Drain) region. The region 208L functioning as the LDD region is provided between the channel formation region and the region 208D, whereby the transistor 200 can have a high drain breakdown voltage.

The carrier concentration in the semiconductor layer 208 preferably has a distribution such that the concentration is lowest in the channel formation region and increases in the order of the region 208L and the region 208D. Providing the region 208L between the channel formation region and the region 208D can keep the carrier concentration of the channel formation region extremely low even when an impurity such as hydrogen is diffused from the region 208D in the manufacturing process, for example.

Note that the carrier concentration in the region 208L is not necessarily uniform and sometimes has a gradient such that the carrier concentration decreases from the region 208D side toward the channel formation region. For example, one or both of the hydrogen concentration and the oxygen vacancy concentration in the region 208L may have a gradient such that the concentration decreases from the region 208D side to the channel formation region side.

As illustrated in FIG. 5A and FIG. 5B, end portions of parts of the conductive layer 212a and the conductive layer 212b are preferably positioned in the opening 147a and the opening 147b, respectively. In other words, the end portions of parts of the conductive layer 212a and the conductive layer 212b are preferably in contact with the semiconductor layer 208 in the opening 147a and the opening 147b, respectively. Accordingly, the region in contact with the conductive layer 212a can be adjacent to one of the pair of regions 208D and the region in contact with the conductive layer 212b can be adjacent to the other of the pair of regions 208D.

There is no limitation on the top surface shapes of the opening 147a and the opening 147b. The top surface shapes of the opening 147a and the opening 147b can be any of the shapes that can be used for the opening 141 and the opening 143. Although the top surface shapes of the opening 147a and the opening 147b are quadrangles with rounded corners unlike the top surface shapes of the opening 141 and the opening 143 in the structure illustrated in FIG. 5A and the like, one embodiment of the present invention is not limited thereto. The top surface shapes of the opening 147a and the opening 147b may be the same as the top surface shapes of the opening 141 and the opening 143.

When the region 208L and the region 208D are formed by adding an impurity element to the semiconductor layer 208, the impurity element may be supplied to the semiconductor layer 108 through the insulating layer 106 using the conductive layer 104 as a mask. In that case, a region 108L is formed in the region of the semiconductor layer 108 not overlapping with the conductive layer 104. Note that in the transistor 100, the region of the semiconductor layer 108 that is in contact with the conductive layer 112b functions as the source region or the drain region. The region 108L is formed in part of the source region or the drain region. Note that the impurity element concentration in the region 108L may be different from the impurity element concentration in the region 208L. The region 108L is not necessarily formed. For example, in the case where the conductive layer 104 extends to cover the end portion of the semiconductor layer 108, the conductive layer 104 masks the whole semiconductor layer 108; thus, the impurity element is not supplied to the semiconductor layer 108 and the region 108L is not formed.

Although the conductive layer 212a and the conductive layer 212b are formed in the same step as the conductive layer 204 here, one embodiment of the present invention is not limited thereto. The conductive layer 212a and the conductive layer 212b may be formed in a step different from that in which the conductive layer 204 is formed. For example, the conductive layer 104 and the conductive layer 204 are formed over the insulating layer 106 and an impurity element is supplied to the semiconductor layer 208 using the conductive layer 204 as a mask, whereby the source region and the drain region are formed. The insulating layer 195 is formed over the conductive layer 104 and the conductive layer 204, an opening reaching the source region and an opening reaching the drain region are formed in the insulating layer 106 and the insulating layer 195, and the conductive layer 212a and the conductive layer 212b can be formed to cover the openings.

### [Semiconductor Layer 108 and Semiconductor Layer 208]

Metal oxides that can be used for the semiconductor layer 108 and the semiconductor layer 208 are specifically described. Examples of the metal oxide include indium oxide, gallium oxide, and zinc oxide. The metal oxide preferably contains at least indium or zinc. The metal oxide preferably contains two or three kinds selected from indium, the element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably one or more of gallium and tin. In this specification and the like, a metal element and a metalloid element may be collectively referred to as a “metal element”, and a “metal element” in this specification and the like may refer to a metalloid element.

For each of the semiconductor layer 108 and the semiconductor layer 208, an indium zinc oxide (also referred to as In—Zn oxide or IZO (registered trademark)), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used, for example. Alternatively, an indium tin oxide containing silicon (also referred to as ITSO), a gallium tin oxide (Ga—Sn oxide), an aluminum tin oxide (Al—Sn oxide), or the like can be used.

When the proportion of the number of indium atoms in the total number of atoms of all the metal elements contained in the metal oxide is increased, the field-effect mobility of the transistor can be increased. In addition, the transistor can have high on-state current.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a larger period number can have high field-effect mobility in some cases. Examples of the metal element with a larger period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of the element M atoms in the total number of atoms of all the metal elements contained in the metal oxide, oxygen vacancies (Vₒ) can be inhibited from being formed in the metal oxide. Thus, generation of carriers due to oxygen vacancies (Vₒ) is inhibited, which makes the off-state current of the transistor low. Furthermore, a change in electrical characteristics of the transistor can be inhibited, and the reliability of the transistor can be improved.

The compositions of the metal oxides used for the semiconductor layer 108 and the semiconductor layer 208 affect the electrical characteristics and reliability of the transistors. Therefore, by changing the composition of the metal oxide in accordance with the electrical characteristics and reliability required for the transistor, the semiconductor device can have both excellent electrical characteristics and high reliability.

When a metal oxide is an In-M-Zn oxide, the atomic proportion of In is preferably higher than or equal to the atomic proportion of the element M in the In-M-Zn oxide. Examples of the atomic ratio of the metal elements in such an In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and a composition in the neighborhood of any of these atomic ratios. Note that a composition in the neighborhood includes the range of +30% of an intended atomic ratio. By increasing the proportion of the number of indium atoms in the metal oxide, the on-state current, field-effect mobility, or the like of the transistor can be improved.

The atomic proportion of In may be lower than the atomic proportion of the element M in the In-M-Zn oxide. Examples of the atomic ratio of the metal elements in such an In-M-Zn oxide include In:M:Zn=1:3:2, In:M:Zn=1:3:3, and In:M:Zn=1:3:4 and a composition in the neighborhood of any of these atomic ratios. By increasing the proportion of the number of M atoms in the metal oxide, generation of oxygen vacancies (Vₒ) can be inhibited.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

The use of a material with a high indium content percentage for the semiconductor layer 108 and the semiconductor layer 208 can increase the on-state current, field-effect mobility, or the like of the transistors. Furthermore, with the element M, generation of oxygen vacancies (Vₒ) can be inhibited. The content percentage of the element M (the proportion of the number of atoms of the element M in the total number of atoms of all the metal elements contained) is preferably higher than or equal to 0.1% and lower than or equal to 3%, further preferably higher than or equal to 0.1% and lower than or equal to 2%. Accordingly, a transistor with favorable electrical characteristics can be provided. For example, a metal oxide with In:M:Zn of 40:1:10 or the neighborhood thereof is preferably used. The element M is preferably one or more kinds of the above elements, further preferably one or more kinds selected from aluminum, gallium, tin, and yttrium. Specifically, a metal oxide with In:Sn:Zn of 40:1:10 or the neighborhood thereof can be suitably used. Alternatively, a metal oxide with In:Al:Zn of 40:1:10 or the neighborhood thereof can be suitably used.

Here, in the case where a metal oxide having a polycrystalline structure is used for the semiconductor layer 108 and the semiconductor layer 208, the grain boundary becomes a recombination center and captures carriers and thus might reduce the on-state current of the transistor. In the case where a metal oxide with a composition that tends to form a polycrystalline structure is used, the metal oxide preferably contains an element that hinders crystallization. For example, an indium tin oxide containing silicon (ITSO) is less likely to have a polycrystalline structure than an indium tin oxide (ITO), and thus can be suitably used for the semiconductor layer 108 and the semiconductor layer 208. In the case where ITSO is used, the content percentage of silicon (the proportion of the number of silicon atoms in the total number of atoms of all the metal elements contained) is preferably higher than or equal to 1% and lower than or equal to 20%, further preferably higher than or equal to 3% and lower than or equal to 20%, further preferably higher than or equal to 3% and lower than or equal to 15%, still further preferably higher than or equal to 5% and lower than or equal to 15%. Specifically, a metal oxide with In:Sn:Si of 45:5:4, In:Sn:Si of 95:5:8, or the neighborhood thereof can be suitably used.

For analysis of the compositions of the semiconductor layer 108 and the semiconductor layer 208, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage or difficult to quantify, or the element M may be below the lower detection limit.

A sputtering method or an atomic layer deposition (ALD) method can be suitably used for formation of the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 108 and the semiconductor layer 208 may each have a stacked-layer structure including two or more metal oxide layers. The two or more metal oxide layers included in each of the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in each of the semiconductor layer 108 and the semiconductor layer 208 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably used. In particular, gallium, aluminum, or tin is preferably used as the element M. The element M in the first metal oxide layer and that in the second metal oxide layer may be the same or different from each other. For example, the first metal oxide layer and the second metal oxide layer may be IGZO layers having different compositions.

For example, a stacked-layer structure of the first metal oxide layer having In:Zn=4:1 [atomic ratio] or a composition in the neighborhood thereof and the second metal oxide layer having In:M:Zn=1:1:1 [atomic ratio] or a composition in the neighborhood thereof and being provided over the first metal oxide layer can be suitably used.

A stacked-layer structure of any one selected from an indium oxide, an indium gallium oxide, and IGZO and any one selected from IAZO, IAGZO, and ITZO (registered trademark) may be used, for example.

In the case where the first metal oxide layer containing a first metal oxide and the second metal oxide layer containing a second metal oxide form a stacked-layer structure and the first metal oxide and the second metal oxide have the same composition or substantially the same compositions, the boundary (interface) between the first metal oxide layer and the second metal oxide layer cannot clearly be observed in some cases.

It is preferable to use a metal oxide having crystallinity for the semiconductor layer 108 and the semiconductor layer 208. Examples of the structure of a metal oxide having crystallinity include a CAAC (c-axis aligned crystalline) structure, a polycrystalline structure, and a nano-crystal (nc) structure. With use of a metal oxide having crystallinity, the density of defect states in the semiconductor layer 108 and the semiconductor layer 208 can be reduced, which enables the semiconductor device to have high reliability.

The semiconductor layer 108 and the semiconductor layer 208 are each preferably formed using a CAAC-OS or an nc-OS.

The CAAC-OS includes a plurality of layered crystals. The c-axis of the crystal is aligned in the normal direction of the formation surface. The semiconductor layer 108 and the semiconductor layer 208 each preferably include a layered crystal parallel or substantially parallel to the formation surface. For example, the semiconductor layer 108 preferably includes a layered crystal parallel or substantially parallel to the top surface of the conductive layer 112b in a region in contact with the top surface, and a layered crystal parallel or substantially parallel to the side surface of the conductive layer 112b in a region in contact with the side surface. In particular, in the opening 141, the semiconductor layer 108 preferably includes a layered crystal parallel or substantially parallel to the side surface of the insulating layer 110 serving as the formation surface. With such a structure, the layered crystals of the semiconductor layer 108 are formed substantially parallel to the channel length direction of the transistor 100, so that the on-state current of the transistor can be increased. Similarly, the semiconductor layer 208 preferably includes a layered crystal parallel or substantially parallel to the formation surface (here, the top surface and the side surface of the insulating layer 120 and the top surface of the insulating layer 110). In particular, in a region overlapping with the conductive layer 204, the semiconductor layer 208 preferably includes a layered crystal parallel or substantially parallel to the top surface of the insulating layer 120 serving as the formation surface.

The use of a metal oxide having high crystallinity in a channel formation region can reduce the density of defect states in the channel formation region. By contrast, the use of a metal oxide having low crystallinity enables a transistor to flow a large amount of current.

The higher the substrate temperature at the time of forming of the metal oxide is, the higher the crystallinity of the formed metal oxide can be. For example, the substrate temperature at the time of formation can be adjusted by the temperature of the stage on which the substrate is placed at the time of formation. Furthermore, the higher the proportion of the flow rate of an oxygen gas to the total flow rate of the film formation gas used for the formation (also referred to as an oxygen flow rate ratio) or the oxygen partial pressure in a treatment chamber is, the higher the crystallinity of the formed metal oxide layer can be.

The crystallinity of the semiconductor layer 108 and the semiconductor layer 208 can be analyzed with X-ray diffraction (XRD), a transmission electron microscope (TEM), electron diffraction (ED), or the like, for example. Alternatively, these methods may be combined for the analysis.

In the case where a metal oxide is used for the semiconductor layer 108 and the semiconductor layer 208, VOH in the channel formation regions is preferably reduced as much as possible so that the semiconductor layer 108 and the semiconductor layer 208 become highly purified intrinsic or substantially highly purified intrinsic semiconductor layers. In order to obtain such a metal oxide with sufficiently reduced VₒH, it is important to remove impurities such as water and hydrogen in the metal oxide (this treatment is sometimes referred to as dehydration or dehydrogenation treatment) and supply oxygen to the metal oxide to repair oxygen vacancies (Vₒ). When a metal oxide in which impurities such as VₒH are sufficiently reduced is used for a channel formation region of a transistor, stable electrical characteristics can be given. Supplying oxygen to a metal oxide to repair oxygen vacancies (Vₒ) is sometimes referred to as oxygen adding treatment.

When a metal oxide is used for each of the semiconductor layer 108 and the semiconductor layer 208, the carrier concentration in the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration in the channel formation region is not particularly limited and can be, for example, 1×10⁻⁹ cm⁻³.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material functioning as a semiconductor and having high two-dimensional electrical conductivity is used for a channel formation region, a transistor having high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a channel formation region of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Conductive Layer 112a, Conductive Layer 112b, Conductive Layer 104, Conductive Layer 204, Conductive Layer 212a, Conductive Layer 212b, and Conductive Layer 202]

The conductive layer 112a, the conductive layer 112b, the conductive layer 104, the conductive layer 204, the conductive layer 212a, the conductive layer 212b, and the conductive layer 202 may each have a single-layer structure or a stacked-layer structure of two or more layers. The conductive layer 112a, the conductive layer 112b, the conductive layer 104, the conductive layer 204, the conductive layer 212a, the conductive layer 212b, and the conductive layer 202 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, the conductive layer 104, the conductive layer 204, the conductive layer 212a, the conductive layer 212b, and the conductive layer 202, a conductive material with low electrical resistivity that contains one or more of copper, silver, gold, and aluminum can be suitably used. Copper or aluminum is particularly preferable because of its high mass-productivity.

For each of the conductive layer 112a, the conductive layer 112b, the conductive layer 104, the conductive layer 204, the conductive layer 212a, the conductive layer 212b, and the conductive layer 202, a conductive metal oxide (also referred to as an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A metal oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a, the conductive layer 112b, the conductive layer 104, the conductive layer 204, the conductive layer 212a, the conductive layer 212b, and the conductive layer 202 may each have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 204, the conductive layer 212a, the conductive layer 212b, and the conductive layer 202. The use of a Cu—X alloy film can reduce the manufacturing cost because a wet etching method can be used in the processing.

Note that the conductive layer 112a, the conductive layer 112b, the conductive layer 104, the conductive layer 204, the conductive layer 212a, the conductive layer 212b, and the conductive layer 202 may be formed using the same material or different materials.

The conductive layer 112a and the conductive layer 112b each include a region that is in contact with the semiconductor layer 108. In the case where a metal oxide is used for the semiconductor layer 108, when the conductive layer 112a and the conductive layer 112b are formed using a metal that is easily oxidized (e.g., aluminum), an insulating oxide (e.g., aluminum oxide) might be formed between the conductive layer 112a and the semiconductor layer 108 and between the conductive layer 112b and the semiconductor layer 108 to prevent electrical continuity between these layers. Thus, a conductive material that is not easily oxidized, a conductive material that maintains low electric resistance even after being oxidized, or an oxide conductor is preferably used for the conductive layer 112a and the conductive layer 112b.

For the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are not easily oxidized or materials that maintain low electric resistance even after being oxidized. In the case where the conductive layer 112a has a stacked-layer structure, at least the layer thereof that is in contact with the semiconductor layer 108 is preferably formed using a conductive material that is not easily oxidized. The same applies to the conductive layer 112b.

The above-described oxide conductor can be used for each of the conductive layer 112a and the conductive layer 112b. Specifically, a metal oxide such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For the conductive layer 112a and the conductive layer 112b, a nitride conductor may be used. Examples of the nitride conductor include tantalum nitride and titanium nitride.

In the capacitor 150, the conductive layer 112b is provided over the insulating layer 120b. As described above, a conductive material that is not easily oxidized, a conductive material that maintains low electric resistance even after being oxidized, or an oxide conductor is preferably used for the conductive layer 112b. The amount of oxygen released from the insulating layer 120b is smaller than the amount of oxygen released from the insulating layer 110b. Accordingly, oxidization of the conductive layer 112b including the region in contact with the insulating layer 120b to increase the electric resistance of the conductive layer 112b is less likely to occur.

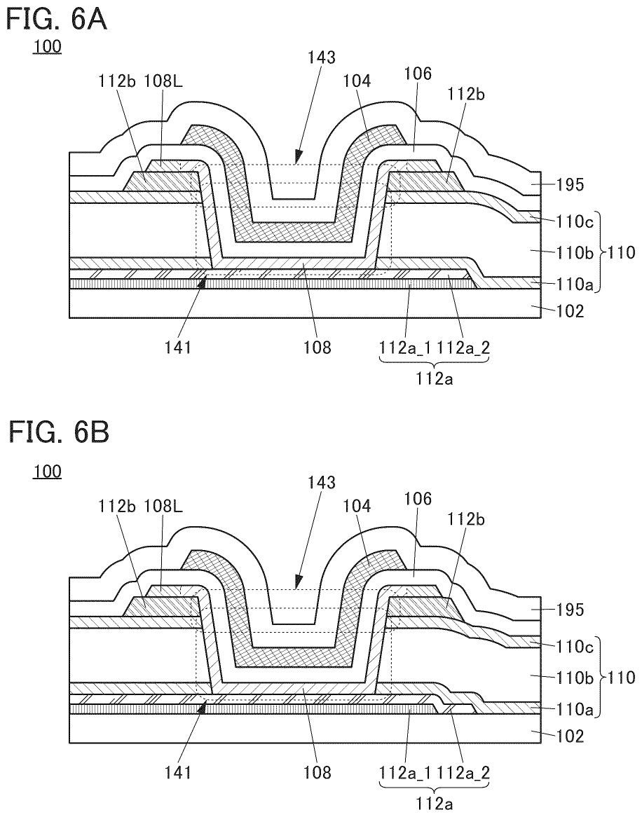

The conductive layer 112a, the conductive layer 112b, and the conductive layer 104 may each have a stacked-layer structure. FIG. 6A and FIG. 6B each illustrate a structure where the conductive layer 112a has a stacked-layer structure of a conductive layer 112a_1 and a conductive layer 112a_2 over the conductive layer 112a_1.

A conductive material that is not easily oxidized, a conductive material that maintains low electric resistance even after being oxidized, or an oxide conductor is preferably used for the conductive layer 112a_2 including a region in contact with the semiconductor layer 108. The description of the conductive layer 112a can be referred to for the material that can be used for the conductive layer 112a_2.

The conductive layer 112a_1 does not include a region in contact with the semiconductor layer 108 and there is no limitation on the material to be used. For example, the conductive layer 112a_1 is preferably formed using a material having lower electric resistivity than the conductive layer 112a_2. Thus, the electric resistance of the conductive layer 112a can be reduced. For example, In—Sn—Si oxide (ITSO) can be suitably used for the conductive layer 112a_2, and copper or tungsten can be suitably used for the conductive layer 112a_1.

Although FIG. 6A and FIG. 6B each illustrate a structure where the thickness of the conductive layer 112a_1 and the thickness of the conductive layer 112a_2 are the same or substantially the same, one embodiment of the present invention is not limited thereto. The thickness of the conductive layer 112a_1 and the thickness of the conductive layer 112a_2 may be different from each other. For example, the conductive layer 112a_1 may be formed using a material having lower electric resistivity than the conductive layer 112a_2, and the thickness of the conductive layer 112a_1 may be larger than the thickness of the conductive layer 112a_2. In that case, the electric resistance of the conductive layer 112a can be reduced.

As illustrated in FIG. 6A, the end portion of the conductive layer 112a_2 may be aligned or substantially aligned with the end portion of the conductive layer 112a_1. For example, a first film to be the conductive layer 112a_1 and a second film to be the conductive layer 112a_2 are formed and then the first film and the second film are processed, so that the conductive layer 112a can be formed.

The end portion of the conductive layer 112a_2 is not necessarily aligned with the end portion of the conductive layer 112a_1. As illustrated in FIG. 6B, the conductive layer 112a_2 can be provided to cover the conductive layer 112a_1. The conductive layer 112a_2 is in contact with the top surface and the side surface of the conductive layer 112a_1. In other words, the conductive layer 112a_2 includes a portion protruding beyond the end portion of the conductive layer 112a_1. For example, it is possible to form the conductive layer 112a_1, form a film to be the conductive layer 112a_2 over the conductive layer 112a_1, and process the film to form the conductive layer 112a_2.

Note that the structure of the conductive layer 112a illustrated in FIG. 6A and FIG. 6B can be applied to other structure examples.

### [Insulating Layer 106]

The insulating layer 106 may have a single-layer structure or a stacked-layer structure of two or more layers. The insulating layer 106 preferably includes one or more inorganic insulating films. Examples of a material that can be used for the inorganic insulating film include an oxide, a nitride, an oxynitride, and a nitride oxide. For the insulating layer 106, a material that can be used for the insulating layer 110 can be used.

The insulating layer 106 includes a region in contact with the semiconductor layer 108 and a region in contact with the semiconductor layer 208. In the case where a metal oxide is used for the semiconductor layer 108 and the semiconductor layer 208, any of the above-described oxides and oxynitrides is preferably used for at least a film of the insulating layer 106 that is in contact with the semiconductor layer 108 and the semiconductor layer 208. A film from which oxygen is released by heating is further preferably used for the insulating layer 106.

Specifically, in the case where the insulating layer 106 has a single-layer structure, the insulating layer 106 is preferably formed using an oxide or an oxynitride. Specifically, silicon oxide or silicon oxynitride can be suitably used for the insulating layer 106.

In the case where the insulating layer 106 has a stacked-layer structure, an insulating film in contact with the semiconductor layer 108 and the semiconductor layer 208 preferably includes an oxide or an oxynitride, and an insulating film in contact with the conductive layer 104 and the conductive layer 204 preferably includes a nitride or an nitride oxide. As the oxide or the oxynitride, for example, silicon oxide or silicon oxynitride can be suitably used. As the nitride or the nitride oxide, silicon nitride or silicon nitride oxide can be suitably used.

Silicon nitride and silicon nitride oxide each have a feature of a small release amount of impurities and low permeability of oxygen and hydrogen, and thus can be suitably used for the insulating layer 106. Diffusion of impurities from the insulating layer 106 to the semiconductor layer 108 and the semiconductor layer 208 is inhibited, whereby the transistors can have favorable electrical characteristics and high reliability.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

The insulating layer 195 functioning as a protective layer of the transistor 100, the transistor 200, and the capacitor 150 is preferably formed using a material that does not easily allow diffusion of impurities. Providing the insulating layer 195 can effectively inhibit diffusion of impurities into the transistors from the outside and increase the reliability of the semiconductor device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. The shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

A structure example which is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 2

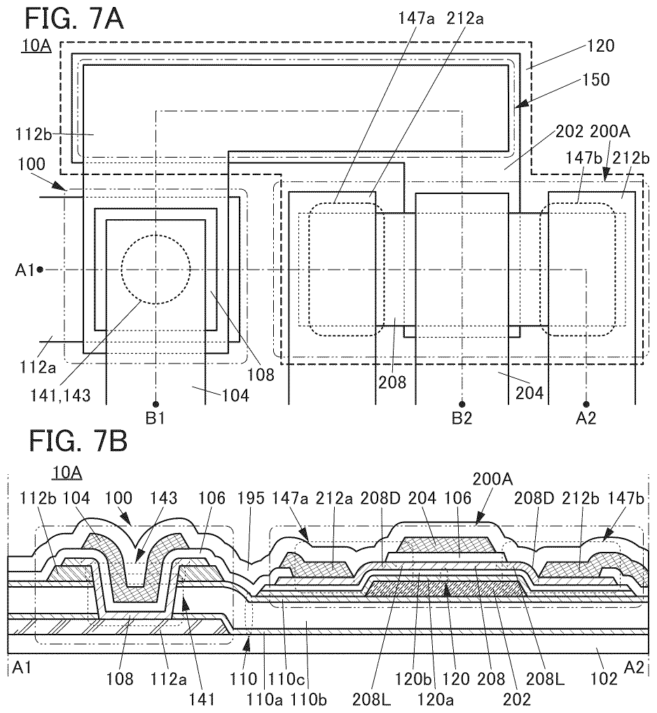

FIG. 7A is a top view of a semiconductor device 10A of one embodiment of the present invention. FIG. 7B is a cross-sectional view of a cut plane along the dashed-dotted line A1-A2 in FIG. 7A. FIG. 1C can be referred to for a cross-sectional view of a cut plane along the dashed-dotted line B1-B2.

The semiconductor device 10A includes the transistor 100, a transistor 200A, the capacitor 150, and the insulating layer 110. The transistor 200A is different from the transistor 100 illustrated in FIG. 1C and the like mainly in that the side surface of the insulating layer 120 is not in contact with the semiconductor layer 208.

The insulating layer 120 is provided in the entire region where the semiconductor layer 208 is provided, and the entire bottom surface of the semiconductor layer 208 is in contact with the top surface of the insulating layer 120. This reduces a step in the formation surface of the semiconductor layer 208 and can improve the coverage with the semiconductor layer 208.

Note that the structure of the insulating layer 120 described in Structure example 2 can also be applied to other structure examples.

### Structure Example 3

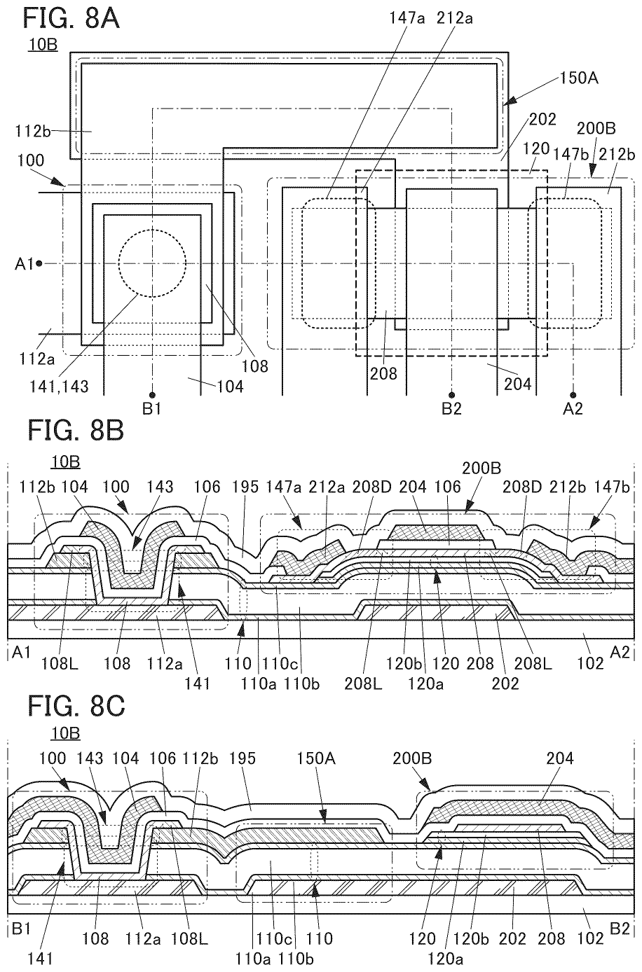

FIG. 8A is a top view of a semiconductor device 10B of one embodiment of the present invention. FIG. 8B is a cross-sectional view of a cut plane along the dashed-dotted line A1-A2 in FIG. 8A, and FIG. 8C is a cross-sectional view of a cut plane along the dashed-dotted line B1-B2.

The semiconductor device 10B includes the transistor 100, a transistor 200B, a capacitor 150A, and the insulating layer 110. The transistor 200B is different from the transistor 200 illustrated in FIG. 1C and the like mainly in that the conductive layer 202 is provided between the insulating layer 110 and the substrate 102. The capacitor 150A is different from the capacitor 150 mainly in including the insulating layer 110 instead of the insulating layer 120.

The conductive layer 202 is provided over the substrate 102. The conductive layer 202 can be formed in the same step as the conductive layer 112a. For example, a film to be the conductive layer 202 and the conductive layer 112a is formed and then the film is processed, so that the conductive layer 202 and the conductive layer 112a can be formed. When the conductive layer 202 and the conductive layer 112a are formed in the same step, the productivity of the semiconductor device 10B can be increased and the manufacturing cost can be reduced.

In the transistor 200B, part of the insulating layer 110 and part of the insulating layer 120 function as a back gate insulating layer (a second gate insulating layer).

The capacitor 150A includes the conductive layer 112b and the conductive layer 202 functioning as a pair of electrodes and the insulating layer 110 interposed therebetween. Although FIG. 8C and the like illustrate a structure where the insulating layer 120 is not provided between the conductive layer 112a and the insulating layer 110, one embodiment of the present invention is not limited thereto. The insulating layer 120 may be provided between the conductive layer 112a and the insulating layer 110, and the insulating layer 110 and the insulating layer 120 may function as a dielectric of the capacitor 150A.

Note that the structure of the conductive layer 202 described in Structure example 3 can also be applied to other structure examples.

### Structure Example 4

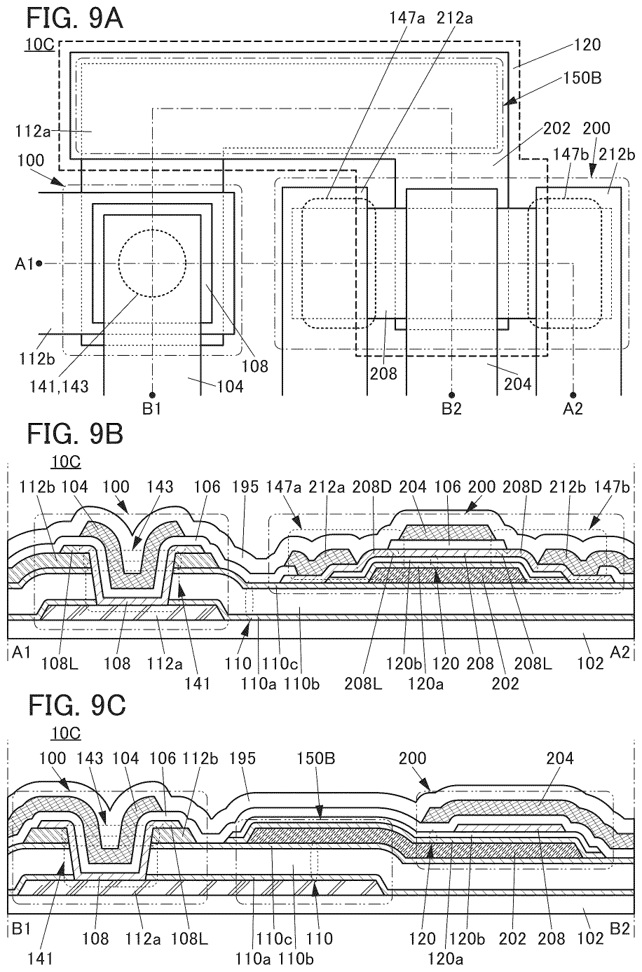

FIG. 9A is a top view of a semiconductor device 10C of one embodiment of the present invention. FIG. 9B is a cross-sectional view of a cut plane along the dashed-dotted line A1-A2 in FIG. 9A, and FIG. 9C is a cross-sectional view of a cut plane along the dashed-dotted line B1-B2.

The semiconductor device 10C includes the transistor 100, the transistor 200, a capacitor 150B, and the insulating layer 110. The capacitor 150B is different from the capacitor 150 illustrated in FIG. 1C and the like mainly in including the conductive layer 112a instead of the conductive layer 112b and including the insulating layer 110 instead of the insulating layer 120.

The capacitor 150B includes the conductive layer 112a and the conductive layer 202 functioning as a pair of electrodes and the insulating layer 110 interposed therebetween. The conductive layer 112a functions as one of the source electrode and the drain electrode of the transistor 100 and also functions as one of the pair of electrodes of the capacitor 150.

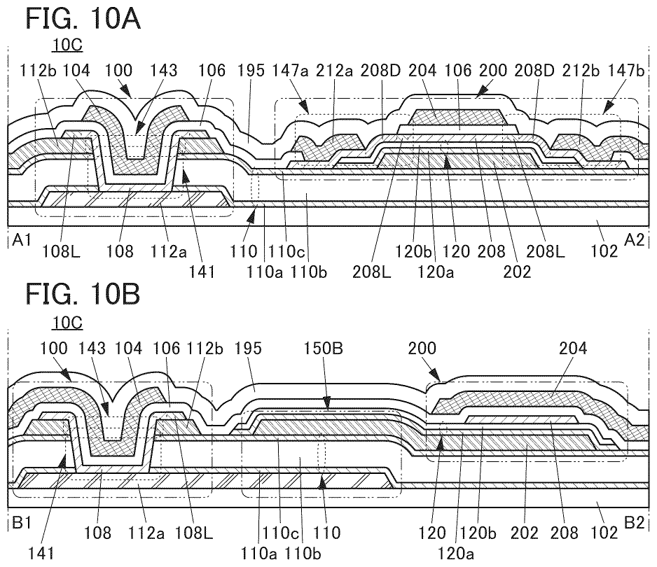

The conductive layer 202 and the conductive layer 112b may be formed using the same material in the same step. In FIG. 10A and FIG. 10B, the conductive layer 202 and the conductive layer 112b are shown with the same hatching pattern. For example, a film to be the conductive layer 202 and the conductive layer 112b is formed over the insulating layer 110 and then the film is processed, so that the conductive layer 202 and the conductive layer 112b can be formed. When the conductive layer 202 and the conductive layer 112b are formed in the same step, the productivity of the semiconductor device 10C can be increased and the manufacturing cost can be reduced.

Note that the structure of the capacitor 150B described in Structure example 4 can also be applied to other structure examples.

### Structure Example 5

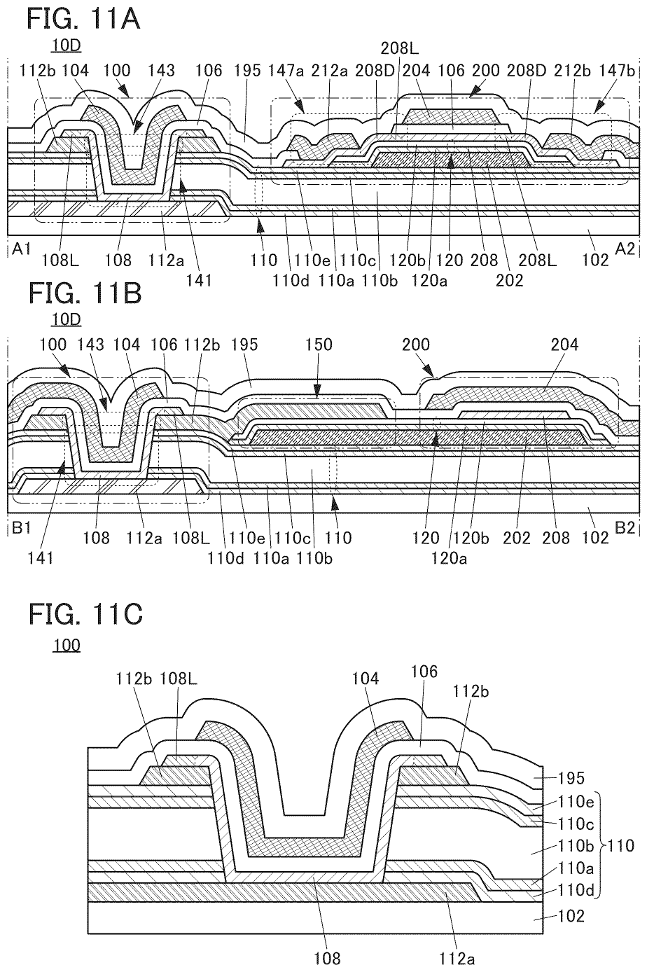

FIG. 11A and FIG. 11B are cross-sectional views of a semiconductor device 10D of one embodiment of the present invention. FIG. 1A can be referred to for a top view of the semiconductor device 10D. FIG. 11A is a cross-sectional view of a cut plane along the dashed-dotted line A1-A2 in FIG. 1A, and FIG. 11B is a cross-sectional view of a cut plane along the dashed-dotted line B1-B2 in FIG. 1A.

The semiconductor device 10D is different from the semiconductor device 10 illustrated in FIG. 1B and the like mainly in including an insulating layer 110d and an insulating layer 110e.

FIG. 11C is an enlarged view of the transistor 100 and the vicinity thereof in FIG. 11A. The insulating layer 110 includes the insulating layer 110d between the conductive layer 112a and the insulating layer 110a, and includes the insulating layer 110e between the conductive layer 112b and the insulating layer 110c. For each of the insulating layer 110d and the insulating layer 110e, a material that can be used for the insulating layer 110a and the insulating layer 110c can be used. For example, silicon nitride or silicon nitride oxide can be suitably used for each of the insulating layer 110d and the insulating layer 110e.

When a material that releases impurities (e.g., water and hydrogen) is used for the insulating layer 110d, the region of the semiconductor layer 108 that is in contact with the insulating layer 110d can be a low-resistance region. In the semiconductor layer 108, the low-resistance region can be formed between the channel formation region and the region in contact with the conductive layer 112a (one of the source region and the drain region). Similarly, when a material that releases impurities is used for the insulating layer 110e, the region of the semiconductor layer 108 that is in contact with the insulating layer 110e can be a low-resistance region. In the semiconductor layer 108, the low-resistance region can be formed between the channel formation region and the region in contact with the conductive layer 112b (the other of the source region and the drain region). The low-resistance region can function as a buffer region for relieving a drain electric field. These low-resistance regions may function as the source region and the drain region.

The low-resistance region between the drain region and the channel formation region inhibits generation of a high electric field in the vicinity of the drain region, so that generation of hot carriers is inhibited to prevent the deterioration of the transistor. For example, in the case where the conductive layer 112a functions as the drain electrode, the conductive layer 112b functions as the source electrode, and the region of the semiconductor layer 108 that is in contact with the insulating layer 110d functions as the low-resistance region, a high electric field is not easily generated in the vicinity of the drain region, so that generation of hot carriers is inhibited to prevent deterioration of the transistor. In the case where the conductive layer 112a functions as the source electrode, the conductive layer 112b functions as the drain electrode, and the region of the semiconductor layer 108 that is in contact with the insulating layer 110e functions as the low-resistance region, a high electric field is not easily generated in the vicinity of the drain region, so that generation of hot carriers is inhibited to prevent the deterioration of the transistor.

In the case where the region of the semiconductor layer 108 that is in contact with the insulating layer 110d functions as the source region or the drain region, the distance from the source region in the semiconductor layer 108 to the gate electrode and the distance from the drain region to the gate electrode can be made more equal. Thus, the electric field of the gate electrode applied to the channel formation region can be more uniform.

It is preferable that the insulating layer 110a positioned between the insulating layer 110d and the insulating layer 110b release a small amount of impurities and not easily transmit impurities. In that case, impurities can be inhibited from being diffused into the channel formation region and its vicinity of the semiconductor layer 108 through the insulating layer 110a and the insulating layer 110b, whereby the transistor can have excellent electrical characteristics and high reliability.

The insulating layer 110d preferably includes a region containing more hydrogen than the insulating layer 110a. The hydrogen content of the insulating layer 110 can be analyzed by secondary ion mass spectrometry (SIMS), for example.

When the film formation conditions for the insulating layer 110d are different from those for the insulating layer 110a, the amount of released hydrogen can be adjusted. Specifically, the film formation conditions for the insulating layer 110d may be different from those for the insulating layer 110a in any one or more of the film formation power (film formation power density), the film formation pressure, the kind of film formation gas, the flow rate ratio of a film formation gas, the film formation temperature, and the distance between the substrate and the electrode during formation. For example, the film formation power density for the insulating layer 110d may be lower than the film formation power density for the insulating layer 110a, in which case the insulating layer 110d can have a higher hydrogen content than the insulating layer 110a. Accordingly, the amount of hydrogen released from the insulating layer 110d due to heat applied thereto can be increased.

The film formation gas used for the formation of the insulating layer 110d preferably contains more hydrogen than the film formation gas used for the formation of the insulating layer 110a. Specifically, when a silicon nitride film or a silicon nitride oxide film is formed as each of the insulating layer 110d and the insulating layer 110a by using a PECVD method, the proportion of a flow rate of an ammonia gas to the whole film formation gas used for the formation of the insulating layer 110d (hereinafter also referred to as ammonia flow rate ratio) is preferably higher than the proportion of a flow rate of an ammonia gas to the whole film formation gas used for the formation of the insulating layer 110a. The formation of the insulating layer 110d under the condition where the ammonia flow rate ratio is high can increase the hydrogen content in the insulating layer 110d. Furthermore, the amount of hydrogen released from the insulating layer 110d due to heat applied thereto can be increased. It is possible to use an ammonia gas for the formation of the insulating layer 110d and not to use an ammonia gas for the formation of the insulating layer 110a. In particular, in the case where the channel length L100 is short (e.g., less than or equal to 100 nm) or a material having high conductivity is used for the semiconductor layer 108, an ammonia gas is not necessarily used for the formation of the insulating layer 110a. In these cases, an increased amount of hydrogen released from the insulating layer 110a might further increase the influence on the electrical characteristics. When an ammonia gas is not used for the formation of the insulating layer 110a, the amount of hydrogen in the insulating layer 110a can be reduced, so that the transistor can have favorable electrical characteristics.

The film density of the insulating layer 110a is preferably higher than the film density of the insulating layer 110d. In that case, hydrogen contained in the insulating layer 110d can be inhibited from being diffused into the channel formation region and its vicinity of the semiconductor layer 108 through the insulating layer 110a and the insulating layer 110b. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Thus, the transmission electron (TE) image of the insulating layer 110a is a dark-colored (dark) image compared to the insulating layer 110d in some cases. Note that since the insulating layer 110d and the insulating layer 110a have different film densities even when including the same materials, it is sometimes possible to identify the boundary between these insulating layers by a difference in contrast in a TEM image of a cross section.

It is preferable that the insulating layer 110c positioned between the insulating layer 110e and the insulating layer 110b release a small amount of impurity and not easily transmit impurities. In that case, impurities can be inhibited from being diffused into the channel formation region and its vicinity of the semiconductor layer 108 through the insulating layer 110c and the insulating layer 110b, whereby the transistor can have excellent electrical characteristics and high reliability. The film density of the insulating layer 110c is preferably higher than the film density of the insulating layer 110e. The description of the insulating layer 110a can be referred to for the insulating layer 110c, and the description of the insulating layer 110d can be referred to for the insulating layer 110e.

Note that one of the insulating layer 110d and the insulating layer 110e is not necessarily provided.

Note that the structure of the insulating layer 110 described in Structure example 5 can also be applied to other structure examples.

### Structure Example 6

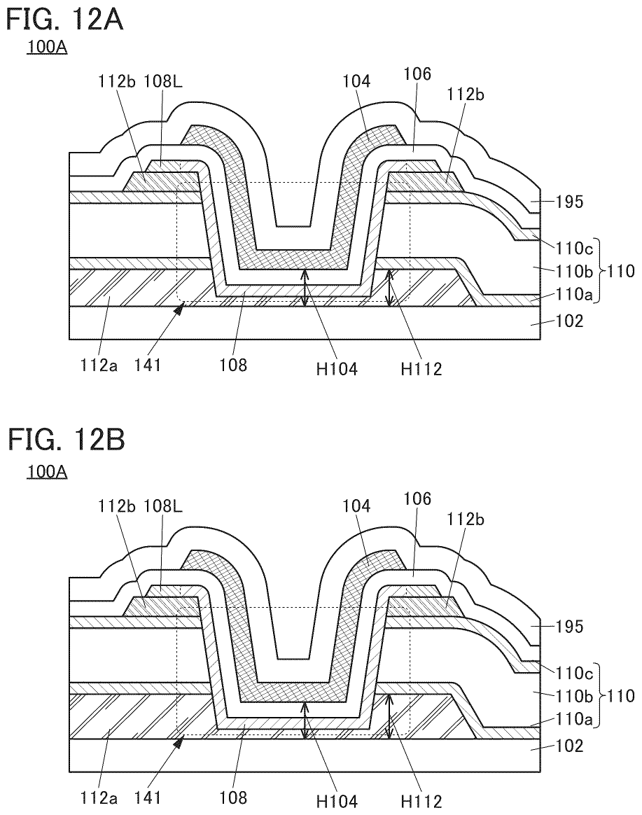

FIG. 12A is a cross-sectional view of the transistor 100A that can be used in the semiconductor device of one embodiment of the present invention. The top view of the transistor 100 illustrated in FIG. 1A can be referred to for that of the transistor 100A. FIG. 12A is a cross-sectional view of a cross section of a cut plane along the dashed-dotted line A1-A2 in FIG. 1A.

The transistor 100A is different from the transistor 100 illustrated in FIG. 1B and the like mainly in that the thickness of a region of the conductive layer 112a that is in contact with the bottom surface of the semiconductor layer 108 is different from the thickness of a region of the conductive layer 112a that is not in contact with the semiconductor layer 108.

As illustrated in FIG. 12A, the thickness of the region of the conductive layer 112a that is in contact with the bottom surface of the semiconductor layer 108 is preferably smaller than the thickness of the region of the conductive layer 112a that is not in contact with the semiconductor layer 108. FIG. 12A illustrates a height H104 from the formation surface of the conductive layer 112a (here, the top surface of the substrate 102) to the lowest position of the bottom surface of the conductive layer 104. FIG. 12A also illustrates a height H112 from the formation surface of the conductive layer 112a (here, the top surface of the substrate 102) to the highest position of the region where the conductive layer 112a and the semiconductor layer 108 are in contact with each other. As illustrated in FIG. 12B, the height H104 is preferably equal or substantially equal to the height H112. Alternatively, as illustrated in FIG. 12B, the height H104 is preferably smaller than the height H112.

When the height H104 to the lowest position of the bottom surface of the conductive layer 104 is equal to the height H112 to the highest position of the region where the conductive layer 112a and the semiconductor layer 108 are in contact with each other or smaller than the height H112, the electric field of the gate electrode applied to the channel formation region in the vicinity of the conductive layer 112a can be increased and the on-state current of the transistor 100A can be increased. In addition, the electric field of the gate electrode applied to the channel formation region can be more uniform.

Here, in the case where the electric field of the gate electrode applied to the channel formation region is not uniform, the electrical characteristics in the case where the conductive layer 112a is the source electrode and the conductive layer 112b is the drain electrode might be different from the electrical characteristics in the case where the conductive layer 112a is the drain electrode and the conductive layer 112b is the source electrode. By making the electric field of the gate electrode applied to the channel formation region of the transistor 100A more uniform, the electrical characteristics in the both cases can be made equivalent to each other. Thus, the transistor 100A can be suitably used in a circuit structure where a source and a drain are interchanged with each other.

Note that the thickness of the conductive layer 112a is adjusted as appropriate so that the height H104 is equal to the height H112 or smaller than the height H112.

Note that the structure of the conductive layer 112a described in Structure example 6 can also be applied to other structure examples.

### Structure Example 7

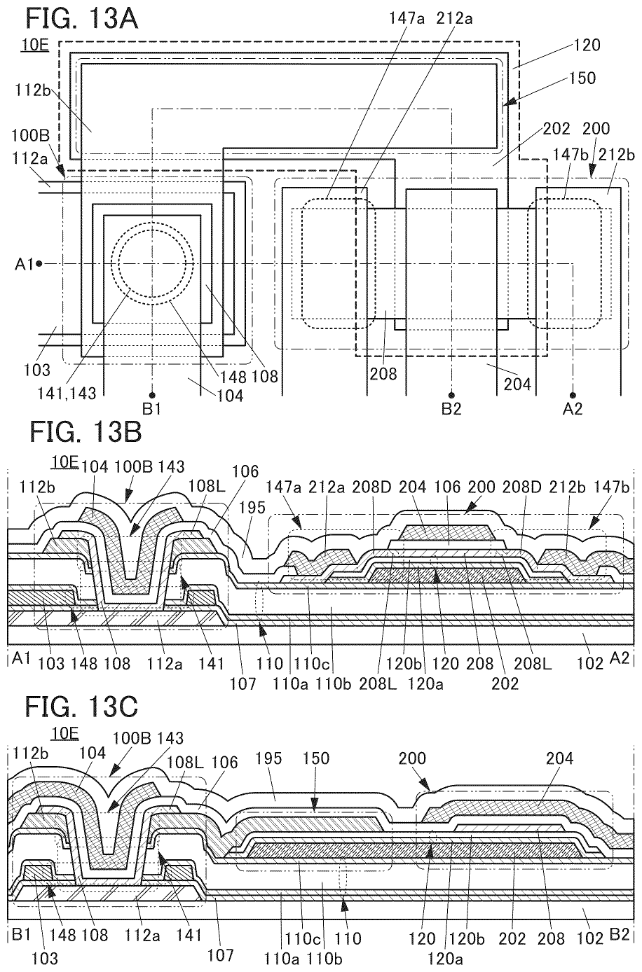

FIG. 13A is a top view of a semiconductor device 10E of one embodiment of the present invention. FIG. 13B is a cross-sectional view of a cut plane along the dashed-dotted line A1-A2 in FIG. 13A, and FIG. 13C is a cross-sectional view of a cut plane along the dashed-dotted line B1-B2.

The semiconductor device 10E includes a transistor 100B, the transistor 200, the capacitor 150, and the insulating layer 110. The transistor 100B is different from the transistor 100 illustrated in FIG. 1B and the like mainly in including a conductive layer 103 and an insulating layer 107 between the conductive layer 112a and the insulating layer 110.

The insulating layer 107 is positioned over the conductive layer 112a. The insulating layer 107 is provided to cover the top surface and the side surface of the conductive layer 112a.

The conductive layer 103 is positioned over the insulating layer 107. The conductive layer 112a and the conductive layer 103 are electrically insulated from each other by the insulating layer 107. In the conductive layer 103, an opening 148 reaching the insulating layer 107 is provided in a region overlapping with the conductive layer 112a.

The insulating layer 110 is provided over the insulating layer 107 and the conductive layer 103. The insulating layer 110 is provided to cover the top surface and the side surface of the conductive layer 103 and the top surface of the insulating layer 107. The opening 141 reaching the conductive layer 112a is provided in the insulating layer 110 and the insulating layer 107.

The insulating layer 110a is positioned over the insulating layer 107 and the conductive layer 103. The insulating layer 110a is provided to cover the top surface and the side surface of the conductive layer 103. In addition, the insulating layer 110a is provided to cover part of the opening 148. The insulating layer 110a is in contact with the insulating layer 107 through the opening 148.

There is no particular limitation on the top surface shape of the opening 148. The top surface shape of the opening 148 can be a shape that can be employed for the opening 141. The top surface shapes of the opening 141 and the opening 148 are preferably circles as illustrated in FIG. 13A. When the top surface shapes of the openings are circles, processing accuracy in forming the openings can be high, whereby the openings can be formed to have minute sizes.

In this specification and the like, the top surface shape of the opening 148 refers to the shape of the end portion of the top surface or the end portion of the bottom surface of the conductive layer 103 on the opening 148 side.

When the top surface shapes of the opening 141 and the opening 148 are circles, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

In the transistor 100B, the semiconductor layer 108 includes a region overlapping with the conductive layer 104 with the insulating layer 106 therebetween and overlapping with the conductive layer 103 with part of the insulating layer 110 (specifically, the insulating layer 110a and the insulating layer 110b) therebetween. In other words, the semiconductor layer 108 includes a region interposed between the conductive layer 104 and the conductive layer 103, with the insulating layer 106 positioned between the region and the conductive layer 104 and with part of the insulating layer 110 (specifically, the insulating layer 110a and the insulating layer 110b) positioned between the region and the conductive layer 103.

The conductive layer 103 functions as a back gate electrode (also referred to as a second gate electrode) of the transistor 100B. Part of the insulating layer 110 functions as a back gate insulating layer (also referred to as a second gate insulating layer) of the transistor 100B. The conductive layer 103 can be formed using a material that can be used for the conductive layer 112a and the conductive layer 104. In addition, the conductive layer 103 is not necessarily provided.

When the transistor 100B includes a back gate electrode, the potential of the semiconductor layer 108 on the back gate electrode side (also referred to as back channel side) is fixed, so that the saturation characteristics in the Id-Vd characteristics can be improved.

Since the transistor 100B includes the back gate electrode, the potential on the back gate electrode side of the semiconductor layer 108 can be fixed and a shift of the threshold voltage can be inhibited. A shift in the threshold voltage of the transistor might increase the drain current flowing at a gate voltage of 0 V (hereinafter, also referred to as cut-off current). When the shift in the threshold voltage is inhibited, the cut-off current of the transistor can be reduced. Thus, a semiconductor device with low power consumption can be obtained.

For the insulating layer 107, a material that can be used for the insulating layer 110 can be used. An insulating layer containing nitrogen is preferably used as the insulating layer 107 in contact with the conductive layer 112a and the conductive layer 103. For the insulating layer 107, a material that can be used for the insulating layer 110a and the insulating layer 110c can be suitably used. For example, silicon nitride can be suitably used for the insulating layer 107. Although the insulating layer 107 has a single-layer structure in this embodiment, one embodiment of the present invention is not limited thereto. The insulating layer 107 may have a stacked-layer structure of two or more layers.

The conductive layer 103 and the conductive layer 112a may be electrically connected to each other. For example, when an opening is provided in a region of the insulating layer 107 overlapping with the conductive layer 112a and the conductive layer 103 is provided to cover the opening, the conductive layer 103 and the conductive layer 112a can be in contact with each other. When the conductive layer 112a functioning as the source electrode or the drain electrode and the conductive layer 103 functioning as the back gate electrode are electrically connected to each other, the back gate electrode can have the same potential as the source electrode or the drain electrode. For example, in the case where the conductive layer 112a functions as the source electrode, a shift in the threshold voltage of the transistor 100B can be inhibited. In addition, the reliability of the transistor 100B can be improved. Note that the conductive layer 103 may be formed in contact with the top surface of the conductive layer 112a without providing the insulating layer 107.

The conductive layer 103 may be electrically connected to the conductive layer 104. For example, when an opening is provided in regions of the insulating layer 106 and the insulating layer 110 overlapping with the conductive layer 103 and the conductive layer 104 is provided to cover the opening, the conductive layer 103 and the conductive layer 104 can be in contact with each other. When the conductive layer 104 functioning as the gate electrode and the conductive layer 103 functioning as the back gate electrode are electrically connected to each other, the back gate electrode and the gate electrode can have the same potential, so that the on-state current of the transistor 100B can be increased.

The thickness of the conductive layer 103 may be larger than the thickness T110b of the insulating layer 110. Accordingly, the potential of the back gate electrode side of the semiconductor layer 108 can be fixed in a wide range between the source region and the drain region in the semiconductor layer 108.

In a region of the transistor 100B, the conductive layer 103, the insulating layer 110, the semiconductor layer 108, the insulating layer 106, and the conductive layer 104 are stacked in this order in one direction with no any other layer provided between these layers. The direction can be perpendicular to the channel length direction. When the above region is wide, the potential of the back gate electrode side of the semiconductor layer 108 can be controlled more reliably.

The thickness of the conductive layer 103 can be larger than the sum of the thickness of a portion of the semiconductor layer 108 that is in contact with the conductive layer 112a inside the opening 141 and the thickness of the insulating layer 106 in contact with the portion.

Note that the structures of the conductive layer 103 and the insulating layer 107 described in Structure example 7 can also be applied to other structure examples.

### Structure Example 8

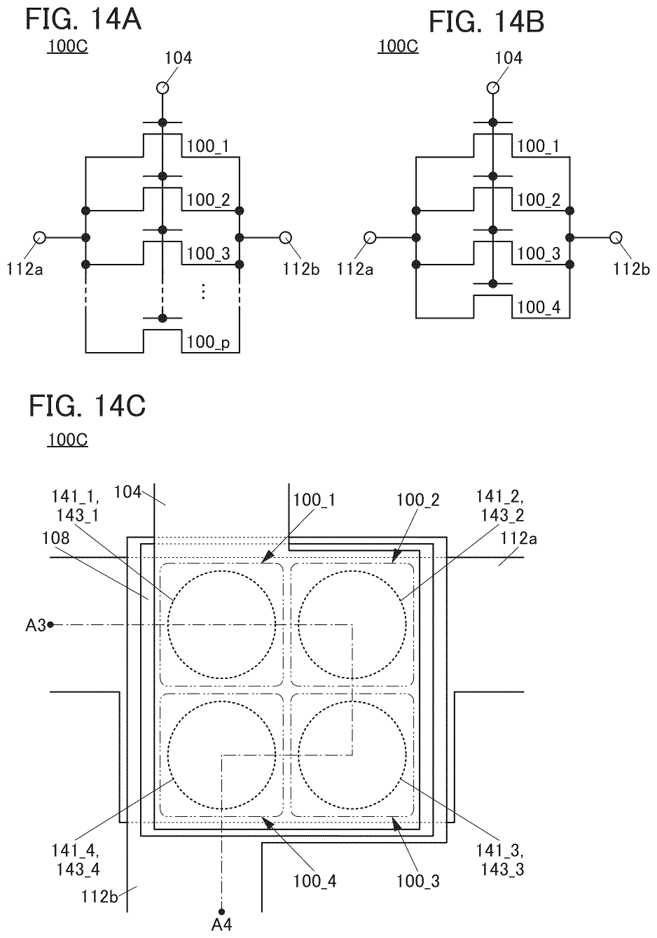

FIG. 14A is an equivalent circuit diagram of a transistor 100C that can be used in the semiconductor device of one embodiment of the present invention. The transistor 100C is a transistor group including a transistor 100_1 to a transistor 100_p (p is an integer greater than or equal to 2). The transistor 100C can be regarded as one transistor, in which the transistor 100_1 to the transistor 100_p are connected in parallel.

Gate electrodes of the transistor 100_1 to the transistor 100_p are electrically connected to each other. Source electrodes of the transistor 100_1 to the transistor 100_p are electrically connected to each other. Drain electrodes of the transistor 100_1 to the transistor 100_p are electrically connected to each other.

Although the transistor 100_1 to the transistor 100_p are illustrated as n-channel transistors in FIG. 14A, one embodiment of the present invention is not limited thereto. The transistor 100_1 to the transistor 100_p may be p-channel transistors.

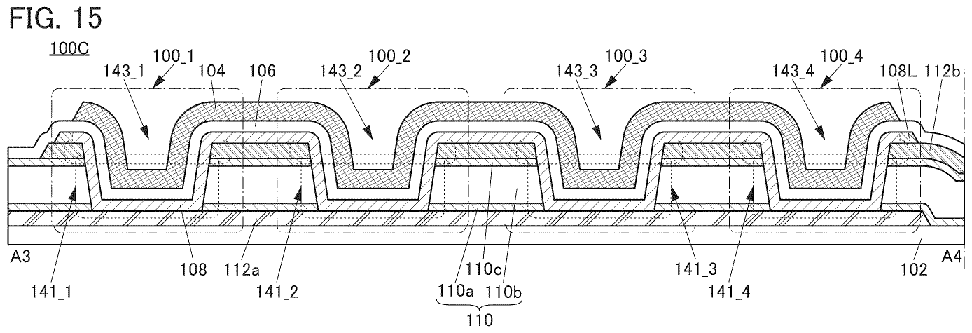

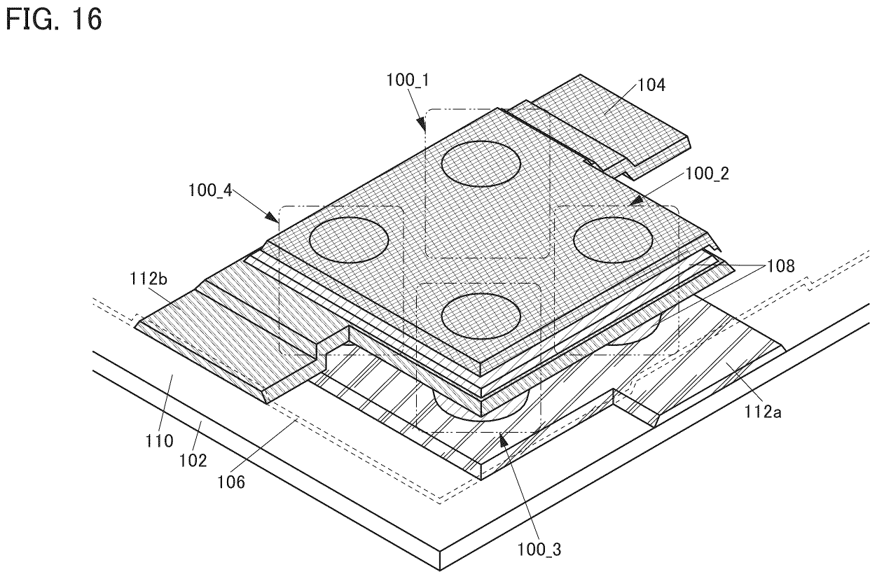

The case where p is 4 is specifically described as an example. FIG. 14B is an equivalent circuit diagram of the transistor 100C that is one embodiment of the present invention. FIG. 14C is a top view of the transistor 100C. FIG. 15 is a cross-sectional view of a cut plane along the dashed-dotted line A3-A4 in FIG. 14C. FIG. 16 is a perspective view of the transistor 100C.

The transistor 100C includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100D may be used as the transistor 100_1 to the transistor 100_4.

Although the transistor 100_1 to the transistor 100_4 are arranged in two rows and two columns in FIG. 14C and the like, there is no limitation on the transistor arrangement. For example, the transistor 100_1 to the transistor 100_4 may be arranged in one row and four columns. The transistor arrangement may be in a matrix and is not necessarily in a matrix.

The transistor 100_1 to the transistor 100_4 each include the conductive layer 104, the insulating layer 106, the semiconductor layer 108, the conductive layer 112a, and the conductive layer 112b. The conductive layer 104 functions as the gate electrode of each of the transistor 100_1 to the transistor 100_4. Part of the insulating layer 106 functions as a gate insulating layer of each of the transistor 100_1 to the transistor 100_4. The conductive layer 112b functions as one of the source electrode and the drain electrode, and the conductive layer 112a functions as the other in each of the transistor 100_1 to the transistor 100_4.

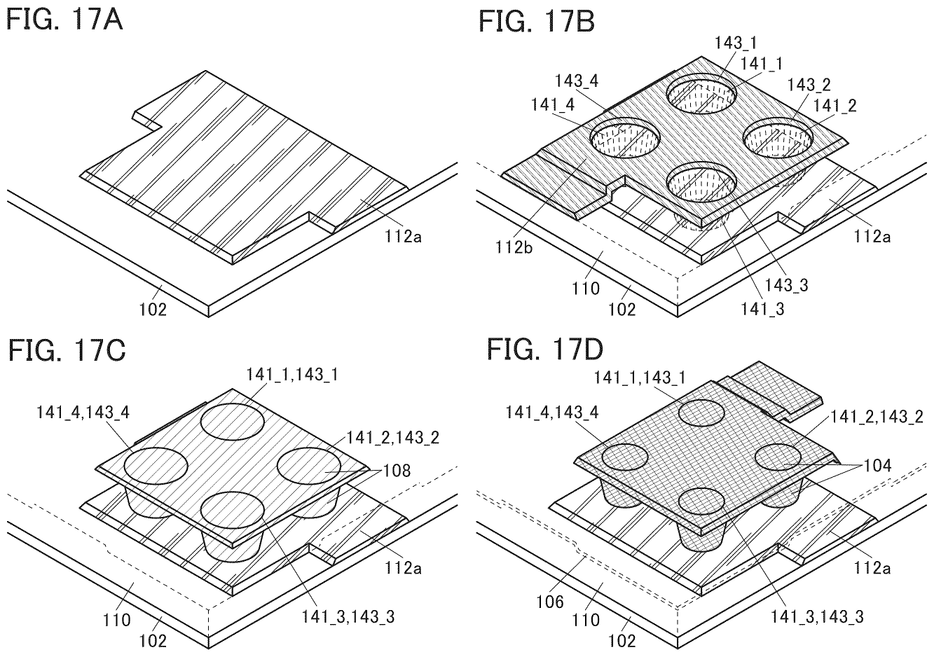

FIG. 17A is a perspective view selectively illustrating the conductive layer 112a.

FIG. 17B is a perspective view selectively illustrating the conductive layer 112a, the conductive layer 112b, an opening 141_1 to an opening 141_4, and an opening 143_1 to an opening 143_4. The opening 141_1 to the opening 141_4 provided in the insulating layer 110 are indicated by dashed lines. The description of the opening 141 and the opening 143 can be referred to for the opening 141_1 to the opening 141_4 and the opening 143_1 to the opening 143_4; thus, the detailed description thereof is omitted.

In the case where the transistor 100C is regarded as one transistor, the channel width of the transistor is the sum of the channel widths of the transistor 100_1 to the transistor 100_4. For example, in the case where the top surface shapes of the opening 141_1 to the opening 141_4 are circles and the width D141 corresponds to the width of each of the opening 141_1 to the opening 141_4, the transistor 100C can be regarded as a transistor having a channel width of “D141×π×4—” (see FIG. 4A and FIG. 4B). The transistor 100C composed of p transistors can be regarded as a transistor having a channel width of “D141×π×p”. Note that the transistor 100C can be regarded as a transistor having the channel length L100 (see FIG. 4B). A plurality of transistors connected in parallel can have a larger channel width and a higher on-state current. By adjusting the number (p) of transistors connected in parallel, the channel width can be changed. The number (p) of transistors connected in parallel is determined so that a desired on-state current is obtained.

FIG. 17C is a perspective view selectively illustrating the conductive layer 112a and the semiconductor layer 108. The semiconductor layer 108 is provided to cover the opening 141_1 to the opening 141_4 and the opening 143_1 to the opening 143_4. Although FIG. 17C and the like illustrate the structure where the transistor 100_1 to the transistor 100_4 share the semiconductor layer 108, one embodiment of the present invention is not limited thereto. The semiconductor layer 108 may be separated for each of the transistor 100_1 to the transistor 100_4.

FIG. 17D is a perspective view selectively illustrating the conductive layer 112a and the conductive layer 104. The conductive layer 104 is provided to cover the opening 141_1 to the opening 141_4 and the opening 143_1 to the opening 143_4.

Note that the structure of the transistor 100C described in Structure example 8 can also be applied to other structure examples. For example, the transistor 100C may be used as one or more of the transistors included in the semiconductor devices illustrated in FIG. 1 to FIG. 13.

### Structure Example 9

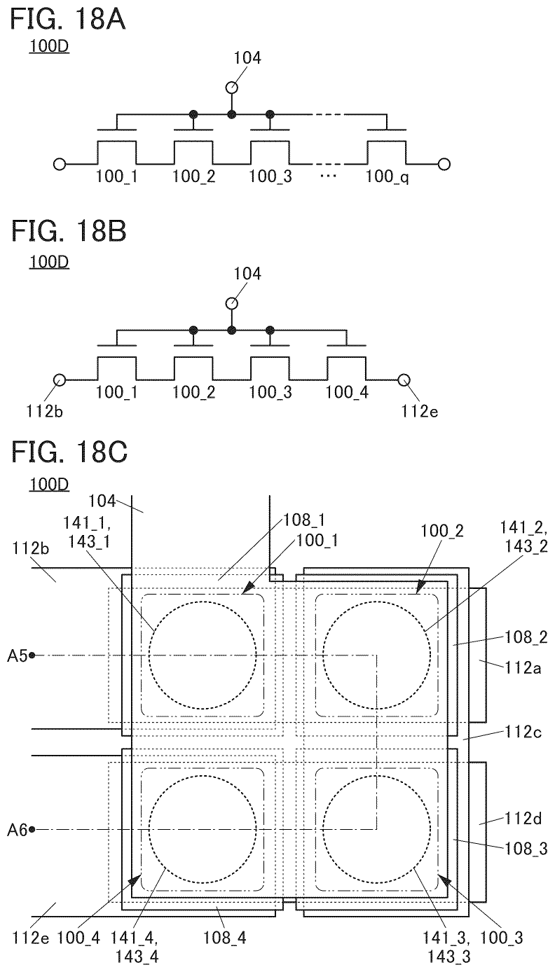

FIG. 18A is an equivalent circuit diagram of the transistor 100D that can be used in the semiconductor device of one embodiment of the present invention. The transistor 100D is a transistor group including the transistor 100_1 to a transistor 100_q (q is an integer greater than or equal to 2). The transistor 100D can be regarded as one transistor, in which the transistor 100_1 to the transistor 100_q are connected in series.

Although the transistor 100_1 to the transistor 100_q are illustrated as n-channel transistors in FIG. 18A, one embodiment of the present invention is not limited thereto. The transistor 100_1 to the transistor 100_q may be p-channel transistors.

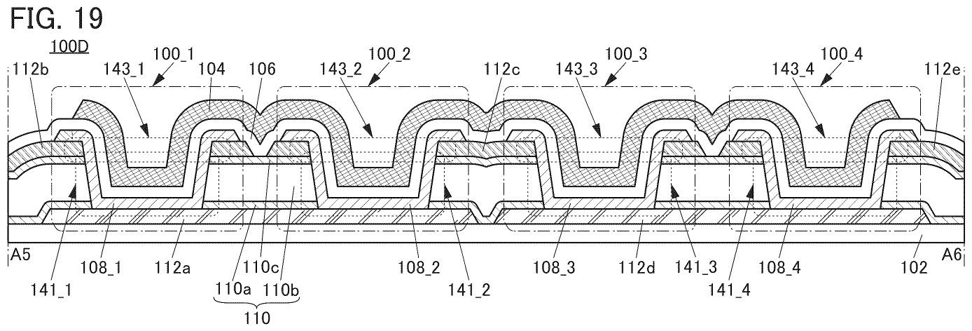

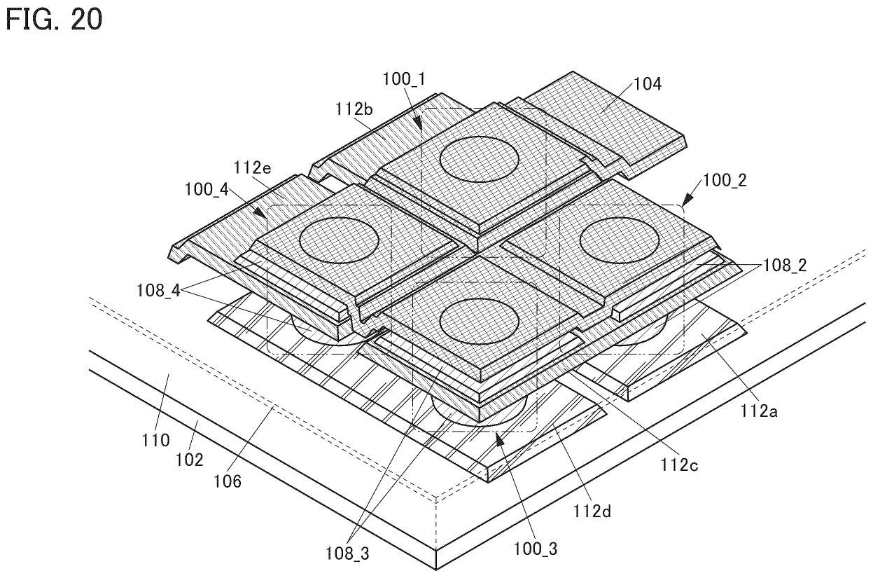

The case where q is 4 is specifically described as an example. FIG. 18B is an equivalent circuit diagram of the transistor 100D that is one embodiment of the present invention. FIG. 18C a top view of the transistor 100D. FIG. 19 is a cross-sectional view of a cut plane along the dashed-dotted line A5-A6 in FIG. 18C. FIG. 20 is a perspective view of the transistor 100D.

The transistor 100D includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100D may be used as the transistor 100_1 to the transistor 100_4.

Although the transistor 100_1 to the transistor 100_4 are arranged in two rows and two columns in FIG. 18C and the like, there is no limitation on the transistor arrangement. For example, the transistor 100_1 to the transistor 100_4 may be arranged in one row and four columns.

The transistor arrangement may be in a matrix and is not necessarily in a matrix.

The transistor 100_1 includes the conductive layer 104, the insulating layer 106, a semiconductor layer 108_1, the conductive layer 112a, and the conductive layer 112b. The conductive layer 112a functions as one of the source electrode and the drain electrode of the transistor 100_1, and the conductive layer 112b functions as the other.

The transistor 100_2 includes the conductive layer 104, the insulating layer 106, a semiconductor layer 108_2, the conductive layer 112a, and a conductive layer 112c. The conductive layer 112a functions as one of the source electrode and the drain electrode of the transistor 100_2, and the conductive layer 112c functions as the other. The conductive layer 112a is shared by the transistor 100_1 and the transistor 100_2.

The transistor 100_3 includes the conductive layer 104, the insulating layer 106, a semiconductor layer 108_3, the conductive layer 112c, and a conductive layer 112d. The conductive layer 112c functions as one of the source electrode and the drain electrode of the transistor 100_3, and the conductive layer 112d functions as the other. The conductive layer 112c is shared by the transistor 100_2 and the transistor 100_3.

The transistor 100_4 includes the conductive layer 104, the insulating layer 106, a semiconductor layer 108_4, the conductive layer 112d, and a conductive layer 112e. The conductive layer 112d functions as one of the source electrode and the drain electrode of the transistor 100_4, and the conductive layer 112e functions as the other. The conductive layer 112d is shared by the transistor 100_3 and the transistor 100_4.

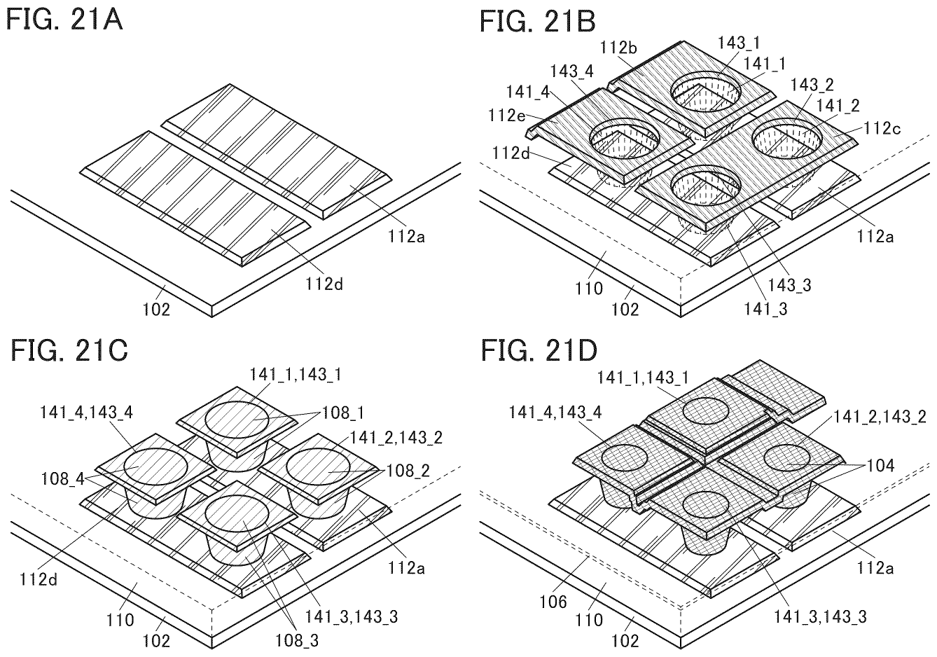

FIG. 21A is a perspective view selectively illustrating the conductive layer 112a and the conductive layer 112d. The conductive layer 112a and the conductive layer 112d can be formed in the same step.

FIG. 21B is a perspective view selectively illustrating the conductive layer 112a, the conductive layer 112b, the conductive layer 112c, the conductive layer 112d, the conductive layer 112e, the opening 141_1 to the opening 141_4, and the opening 143_1 to the opening 143_4. The conductive layer 112a to the conductive layer 112e can be formed in the same step. The opening 143_1 is provided in the conductive layer 112b, the opening 143_2 and the opening 143_3 are provided in the conductive layer 112c, and the opening 143_4 is provided in the conductive layer 112e.

FIG. 21C is a perspective view selectively illustrating the conductive layer 112a, the conductive layer 112d, and the semiconductor layer 108_1 to the semiconductor layer 108_4. The semiconductor layer 108_1 to the semiconductor layer 108_4 can be formed in the same step.

FIG. 21D is a perspective view selectively illustrating the conductive layer 112a, the conductive layer 112d, and the conductive layer 104. The conductive layer 104 functions as the gate electrode of each of the transistor 100_1 to the transistor 100_4.

One of the source electrode and the drain electrode of the transistor 100_1 is electrically connected to one of the source electrode and the drain electrode of the transistor 100_2. The other of the source electrode and the drain electrode of the transistor 100_2 is electrically connected to one of the source electrode and the drain electrode of the transistor 100_3. The other of the source electrode and the drain electrode of the transistor 100_3 is electrically connected to one of the source electrode and the drain electrode of the transistor 100_4.

In the case where the transistor 100D is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 100_4, the transistor 100D can be regarded as a transistor having a channel length of “L100×4” (see FIG. 4B). The transistor 100D composed of q transistors can be regarded as a transistor having a channel length of “L100×q”. Note that the transistor 100D can be regarded as a transistor having the channel width W100 (see FIG. 4A and FIG. 4B). A plurality of transistors connected in series can have a larger channel length and favorable saturation characteristics. By adjusting the number (q) of transistors connected in series, the channel length can be changed. The number (q) of transistors connected in series is determined so that desired saturation characteristics is obtained.

Note that the structure of the transistor 100D described in Structure example 9 can also be applied to other structure examples. For example, the transistor 100D may be used as one or more of the transistors included in the semiconductor devices illustrated in FIG. 1 to FIG. 13.

The transistor 100D may be used as each transistor included in the transistor 100C. That is, the groups of transistors connected in parallel can further be connected in series (hereinafter also referred to as series-parallel connection).

This embodiment can be combined with the other embodiments as appropriate. In this specification, in the case where a plurality of structure examples are shown in one embodiment, the structure examples can be combined as appropriate.

### Embodiment 2

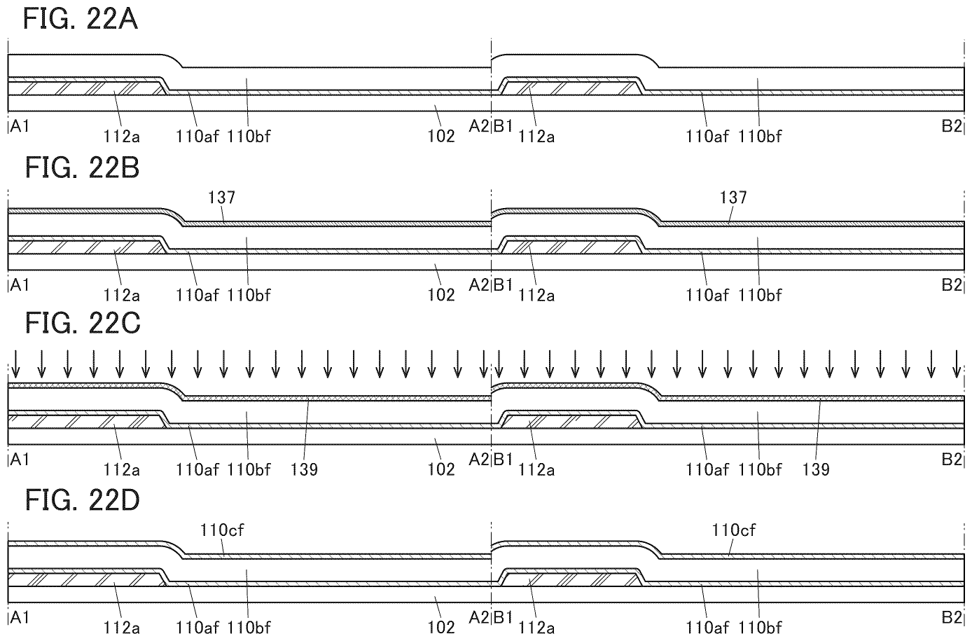

In this embodiment, a method for manufacturing a semiconductor device of one embodiment of the present invention will be described with reference to FIG. 22A to FIG. 26B. Note that as for a material and a formation method of each component, portions similar to the portions described in Embodiment 1 is omitted in some cases.

FIG. 22A to FIG. 26B each illustrate, side by side, a cross section along the dashed-dotted line A1-A2 and a cross section along the dashed-dotted line B1-B2 in FIG. 1A.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. As an example of the thermal CVD method, a metal organic chemical vapor deposition (MOCVD: Metal Organic CVD) method can be given.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light used for light exposure in a photolithography method, it is possible to use the i-line (wavelength: 365 nm), the g-line (wavelength: 436 nm), the h-line (wavelength: 405 nm), or combined light of them. Alternatively, ultraviolet light, KrF laser light, ArF laser light, or the like can be used. In addition, light exposure may be performed by liquid immersion exposure technique. As the light used for light exposure, extreme ultraviolet (EUV) light, X-rays, or the like may be used. Instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, one or more selected from a dry etching method, a wet etching method, and a sandblast method can be used.

First, a film to be the conductive layer 112a is formed over the substrate 102, and the film is processed to form the conductive layer 112a. For the formation of the film, a sputtering method can be suitably used.

Next, an insulating film 110af to be the insulating layer 110a and an insulating film 110bf to be the insulating layer 110b are formed over the conductive layer 112a (FIG. 22A).

A sputtering method or a PECVD method can be suitably used for the formation of the insulating film 110af and the insulating film 110bf. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

As described above, the amount of oxygen released from the insulating layer 110b is preferably large. Furthermore, the diffusion coefficient of a substance (in particular, oxygen) in the insulating layer 110b is preferably high. In the case where a PECVD method is used for forming the insulating film 110bf to be the insulating layer 110b, the F ratio is preferably within the above range. This facilitates diffusion of oxygen in the insulating layer 110b to efficiently supply oxygen contained in the insulating layer 110b to the semiconductor layer 108 (in particular, the channel formation region), and makes the amount of impurities released from the insulating layer 110b small.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, a transistor with favorable electrical characteristics and high reliability can be obtained.

Note that since the insulating film 110af and the insulating film 110bf are formed earlier than the semiconductor layer 108 and the semiconductor layer 208, there is no need to consider the probability of oxygen release from the semiconductor layer 108 and the semiconductor layer 208 due to heat applied thereto at the time of forming the insulating film 110af and the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere containing oxygen. For example, plasma treatment is preferably performed in an atmosphere containing one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110bf to the air. For example, in the case where a PECVD apparatus is used for forming the insulating film 110bf, the plasma treatment is preferably performed with the PECVD apparatus. Accordingly, the productivity can be increased. Specifically, after the insulating film 110bf is formed with the PECVD apparatus, N₂O plasma treatment can be successively performed in a vacuum.

Next, a metal oxide layer 137 is preferably formed over the insulating film 110bf (FIG. 22B). The formation of the metal oxide layer 137 enables oxygen supply to the insulating film 110bf.

There is no limitation on the conductivity of the metal oxide layer 137. As the metal oxide layer 137, at least one of an insulating film, a semiconductor film, and a conductive film can be used. For the metal oxide layer 137, aluminum oxide, hafnium oxide, hafnium aluminate, indium oxide, indium tin oxide (ITO), or indium tin oxide containing silicon (ITSO) can be used, for example.

An oxide material containing one or more elements that are the same as those in the semiconductor layer 108 and the semiconductor layer 208 is preferably used for the metal oxide layer 137. It is particularly preferable to use an metal oxide material that can be used for the semiconductor layer 108 and the semiconductor layer 208.

At the time of forming the metal oxide layer 137, the amount of oxygen supplied into the insulating film 110bf can be increased with a higher oxygen flow rate ratio in the film formation gas introduced into a processing chamber of a film formation apparatus or with a higher oxygen partial pressure in the processing chamber. The oxygen flow rate ratio or the oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 137 is formed by a sputtering method in an atmosphere containing oxygen in the above manner, oxygen can be supplied to the insulating film 110bf and release of oxygen from the insulating film 110bf can be prevented during the formation of the metal oxide layer 137. As a result, a large amount of oxygen can be enclosed in the insulating film 110bf. Moreover, a large amount of oxygen can be supplied to the semiconductor layer 108 by heat treatment performed later. As a result, oxygen vacancies and VₒH in the semiconductor layer 108 can be reduced, so that a highly reliable transistor exhibiting favorable electrical characteristics can be obtained.

After the metal oxide layer 137 is formed, heat treatment may be performed. By the heat treatment performed after the formation of the metal oxide layer 137, oxygen can be effectively supplied from the metal oxide layer 137 to the insulating film 110bf.

The temperature of the heat treatment is preferably higher than or equal to 150° C., higher than or equal to 200° C., higher than or equal to 230° C., or higher than or equal to 250° C. and lower than the strain point of the substrate, lower than or equal to 450° C., lower than or equal to 400° C., lower than or equal to 350° C., or lower than or equal to 300° C. The heat treatment can be performed in an atmosphere containing one or more of a noble gas, nitrogen, and oxygen. As an atmosphere containing nitrogen or an atmosphere containing oxygen, clean dry air (CDA) may be used. Furthermore, the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. The use of the RTA apparatus can shorten the heat treatment time.

After the formation of the metal oxide layer 137 or after the above-described heat treatment, oxygen may be further supplied to the insulating film 110bf through the metal oxide layer 137. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 137 is removed. There is no particular limitation on a method for removing the metal oxide layer 137, and a wet etching method can be suitably used. With use of a wet etching method, the insulating film 110bf can be inhibited from being etched at the time of removing the metal oxide layer 137. This can inhibit a reduction in the thickness of the insulating film 110bf and the thickness of the insulating layer 110b can be uniform.

After the metal oxide layer 137 is removed, oxygen may be further supplied to the insulating film 110bf. The above description can be referred to for a method for supplying oxygen. For example, as illustrated in FIG. 22C, a film 139 may be formed over the insulating film 110bf and oxygen may be supplied to the insulating film 110bf through the film 139. As the treatment, plasma treatment in an atmosphere containing oxygen can be used. FIG. 22C schematically illustrates a state where oxygen is supplied to the insulating film 110bf by arrows.

As the film 139, a conductive film or a semiconductor film is preferably used. As the film 139, a metal oxide film, a metal film, or an alloy film can be used. The film 139 is preferably formed using a metal oxide in an atmosphere containing oxygen by a sputtering method or the like, in which case oxygen can be supplied to the insulating film 110bf also at the time of forming the film 139.

The thickness of the film 139 is preferably small. Specifically, the thickness of the film 139 is preferably greater than or equal to 1 nm, greater than or equal to 2 nm, or greater than or equal to 3 nm and less than or equal to 20 nm, less than or equal to 15 nm, or less than or equal to nm. Typically, the thickness can be approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Accordingly, the amount of oxygen supplied to the insulating film 110bf can be increased.

By provision of the film 139, when a bias voltage is applied between a pair of electrodes at the time of supplying oxygen, ionized oxygen is easily drawn. Accordingly, the amount of oxygen supplied to the insulating film 110bf can be increased.

As a treatment apparatus for supplying oxygen, a dry etching apparatus, an ashing apparatus, or a PECVD apparatus can be suitably used. In particular, an ashing apparatus is preferably used. When a bias voltage is applied between a pair of electrodes in the treatment apparatus, the bias voltage may be higher than or equal to 10 V and lower than or equal to 1 kV, for example. The power density of the bias may be higher than or equal to 1 W/cm² and lower than or equal to 5 W/cm², for example.

Next, the film 139 is removed. For the removal of the film 139, a wet etching method can be suitably used.

The treatment for supplying oxygen to the insulating film 110bf is not necessarily performed in the above-described manner. For example, an oxygen radical, an oxygen atom, an oxygen atomic ion, or an oxygen molecular ion is supplied to the insulating film 110bf by an ion doping method, an ion implantation method, or plasma treatment. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

The amount of oxygen released from the insulating layer 110b in contact with the channel formation region of the transistor 100 having a short channel length is preferably larger than that of oxygen released from the insulating layer 120b in contact with the channel formation region of the transistor 200 having a long channel length. By supplying oxygen to the insulating film 110bf to be the insulating layer 110b, the amount of oxygen contained in the insulating layer 110b can be increased, so that the amount of oxygen supplied from the insulating layer 110b to the semiconductor layer 108 can be increased and the transistor 100 having a short channel length can have favorable electrical characteristics.

Next, an insulating film 110cf to be the insulating layer 110c is formed over the insulating film 110bf (FIG. 22D). The description of the formation of the insulating film 110af and the insulating film 110bf can be referred to for the formation of the insulating film 110cf; thus, the detailed description thereof is omitted.

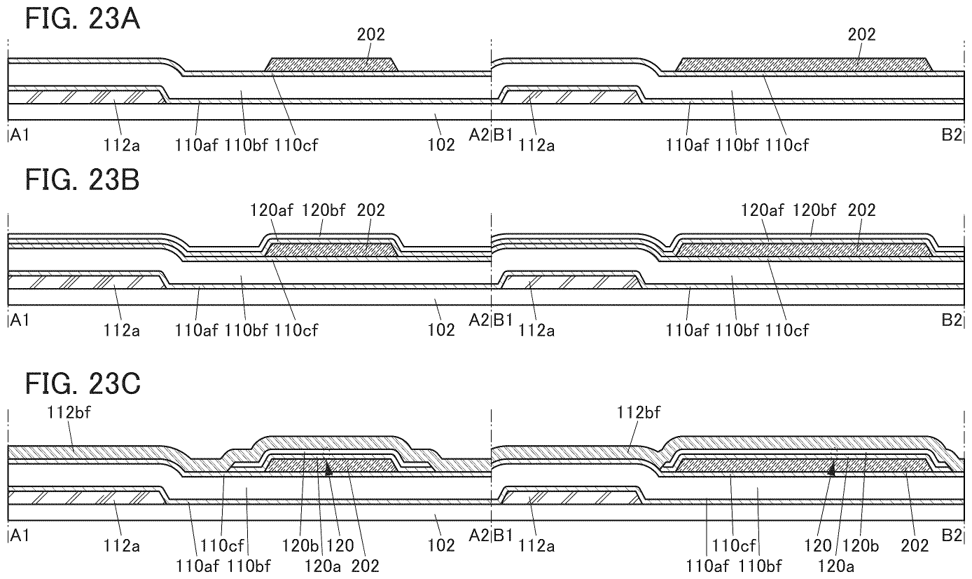

Next, a film to be the conductive layer 202 is formed over the insulating film 110cf and then the film is processed, so that the conductive layer 202 is formed (FIG. 23A). For the formation of the film, a sputtering method can be suitably used.

Then, an insulating film 120af to be the insulating layer 120a and an insulating film 120bf to be the insulating layer 120b are formed to cover the conductive layer 202 (FIG. 23B).

For the formation of the insulating film 120af and the insulating film 120bf, a sputtering method or a PECVD method can be suitably used. It is preferable that the insulating film 120bf be formed in a vacuum successively after the formation of the insulating film 120af, without exposure of a surface of the insulating film 120af to the air. By forming the insulating film 120af and the insulating film 120bf successively, attachment of impurities derived from the air to the surface of the insulating film 120af can be inhibited. Examples of the impurities include water and organic substances.

As described above, the amount of oxygen released from the insulating layer 120b may be smaller than the amount of oxygen released from the insulating layer 110b. The diffusion coefficient of oxygen in the insulating layer 120b may be lower than the diffusion coefficient of the oxygen in the insulating layer 110b. In the case where a PECVD method is used for forming the insulating film 120bf to be the insulating layer 120b, the F ratio is preferably within the above range.

The substrate temperatures at the time of forming the insulating film 120af and the insulating film 120bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 120af and the insulating film 120bf are in the above range, impurities (e.g., water and hydrogen) released from the insulating films themselves can be reduced, which inhibits diffusion of the impurities into the semiconductor layer 108. Consequently, a transistor with favorable electrical characteristics and high reliability can be obtained.

Note that since the insulating film 120af and the insulating film 120bf are formed earlier than the semiconductor layer 108 and the semiconductor layer 208, there is no need to consider the probability of oxygen release from the semiconductor layer 108 and the semiconductor layer 208 due to heat applied thereto at the time of forming the insulating film 120af and the insulating film 120bf.

After the insulating film 120bf is formed, oxygen may be supplied to the insulating film 120bf. The above description can be referred to for the method for supplying oxygen.

Next, the insulating film 120af and the insulating film 120bf are processed to form the insulating layer 120 including the insulating layer 120a and the insulating layer 120b. For the processing of the insulating film 120af and the insulating film 120bf, a dry etching method can be suitably used, for example.

Then, a conductive film 112bf to be the conductive layer 112b is formed over the insulating film 110cf and the insulating layer 120 (FIG. 23C). For the formation of the conductive film 112bf, a sputtering method can be suitably used, for example.

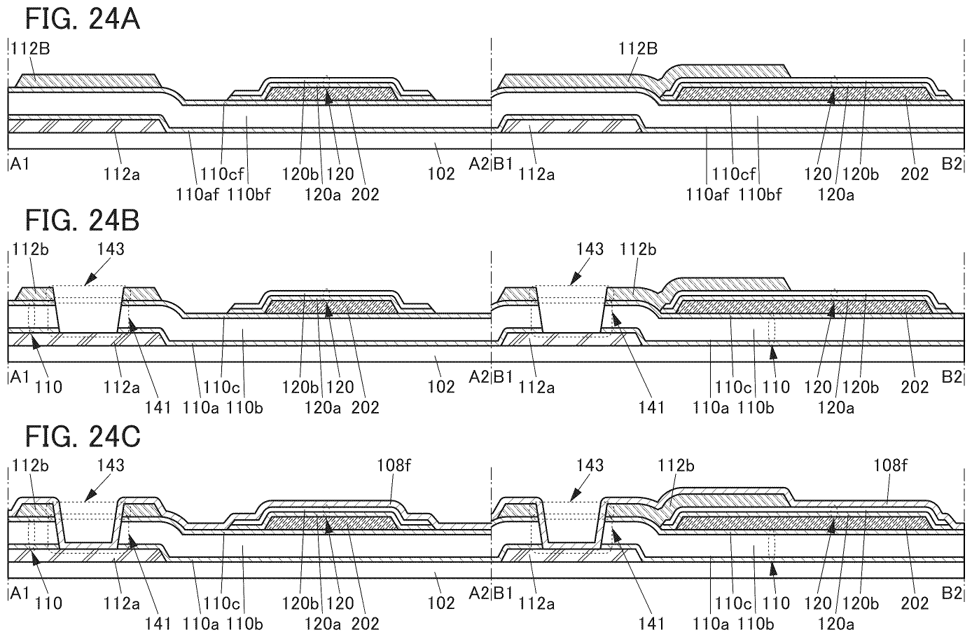

Next, the conductive film 112bf is processed to form a conductive layer 112B (FIG. 24A). The conductive layer 112B becomes the conductive layer 112b later. For the formation of the conductive layer 112B, a wet etching method can be suitably used, for example.

Next, the conductive layer 112B is partly removed, so that the conductive layer 112b including the opening 143 is formed. For the formation of the conductive layer 112b, a wet etching method can be suitably used, for example.

Next, the insulating film 110af, the insulating film 110bf, and the insulating film 110cf are partly removed, so that the insulating layer 110 including the opening 141 is formed (FIG. 24B). The opening 141 is provided in a region overlapping with the opening 143. The conductive layer 112a is exposed by the formation of the opening 141. For the formation of the insulating layer 110, a dry etching method can be suitably used, for example.

The opening 141 can be formed using a resist mask used for the formation of the opening 143, for example. Specifically, the resist mask is formed over the conductive layer 112B, part of the conductive layer 112B is removed using the resist mask to form the opening 143, and part of the insulating film 110af, part of the insulating film 110bf, and part of the insulating film 110cf are removed using the resist mask, so that the opening 141 can be formed. The opening 141 may be formed using a resist mask that is different from the resist mask used for the formation of the opening 143.

Note that in the formation of the opening 141 or after the formation of the opening 141, part of the conductive layer 112a in a region overlapping with the opening 141 may be removed. When the thickness of the region of the conductive layer 112a that is in contact with the bottom surface of the semiconductor layer 108 is smaller than the thickness of the region of the conductive layer 112a that is not in contact with the semiconductor layer 108, the electric field of the gate electrode applied to the channel formation region in the vicinity of the conductive layer 112a can be intensified, leading to a high on-state current of the transistor.

Next, a metal oxide film 108f to be the semiconductor layer 108 and the semiconductor layer 208 is formed to cover the opening 141 and the opening 143 (FIG. 24C). The metal oxide film 108f is provided in contact with the top surface and the side surface of the insulating layer 110, the top surface and the side surface of the conductive layer 112a, the top surface and the side surface of the conductive layer 112b, and the top surface and the side surface of the insulating layer 120.

The metal oxide film 108f is preferably formed by a sputtering method using a metal oxide target. Alternatively, the metal oxide film 108f is preferably formed by an ALD method. An ALD method offers high coverage, and thus can be suitably used for forming the metal oxide film 108f provided to cover the opening 141 and the opening 143. By an ALD method, a metal oxide film can be formed also on the side surface of the insulating layer 110 with high coverage. In an ALD method, the film formation rate can be easily controlled, so that a thin film can be formed with high yield.

The metal oxide film 108f is preferably a dense film with as few defects as possible. The metal oxide film 108f is preferably a highly purified film in which impurities including a hydrogen element are reduced as much as possible. It is particularly preferable to use a metal oxide film having crystallinity as the metal oxide film 108f.

In forming the metal oxide film 108f, an oxygen gas is preferably used. With use of an oxygen gas, oxygen can be suitably supplied into the insulating layer 110 and the insulating layer 120. For example, in the case of using an oxide or an oxynitride for the insulating layer 110b, oxygen can be suitably supplied into the insulating layer 110b. Similarly, in the case of using an oxide or an oxynitride for the insulating layer 120b, oxygen can be suitably supplied into the insulating layer 120b.

By the supply of oxygen to the insulating layer 110b, oxygen is supplied to the channel formation region of the semiconductor layer 108 in a later step, so that oxygen vacancies and VₒH in the channel formation region can be reduced. In addition, by the supply of oxygen to the insulating layer 120b, oxygen is supplied to the channel formation region of the semiconductor layer 208 in a later step, so that oxygen vacancies and VₒH in the channel formation region can be reduced.

In forming the metal oxide film 108f, an oxygen gas and an inert gas (e.g., a helium gas, an argon gas, or a xenon gas) may be mixed. Note that when the oxygen flow rate ratio of the film formation gas or the oxygen partial pressure in the treatment chamber is higher in forming the metal oxide film, the metal oxide film can have higher crystallinity and the transistor can have higher reliability. On the other hand, when the oxygen flow rate ratio or the oxygen partial pressure is lower, the metal oxide film can have lower crystallinity and higher electrical conductivity and the transistor can have a higher on-state current.

Here, when the oxygen flow rate ratio or the oxygen partial pressure is high, the metal oxide film has a polycrystalline structure in some cases. In the case of a metal oxide film having a polycrystalline structure, the grain boundary becomes a recombination center and captures carriers and thus might reduce the on-state current of the transistor. Therefore, the oxygen flow rate ratio or the oxygen partial pressure is preferably adjusted so that the metal oxide film 108f does not have a polycrystalline structure. Since the ease of forming the polycrystalline structure depends on the composition of the metal oxide film, the oxygen flow rate ratio or the oxygen partial pressure is adjusted in accordance with the composition of the metal oxide film 108f.

When the substrate temperature is higher in forming the metal oxide film, a denser metal oxide film having higher crystallinity can be formed. On the other hand, as the substrate temperature becomes lower, a metal oxide film having lower crystallinity and higher electric conductivity can be formed.

The substrate temperature at the time of forming the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably higher than or equal to room temperature and lower than or equal to 140° C., in which case high productivity is achieved. When the metal oxide film 108f is formed with the substrate temperature set at room temperature or without heating the substrate, the metal oxide film 108f can have low crystallinity.

When the substrate temperature is high, the metal oxide film has a polycrystalline structure in some cases. The substrate temperature is preferably adjusted so that the metal oxide film 108f does not have a polycrystalline structure. The substrate temperature is adjusted in accordance with the composition employed for the metal oxide film 108f.

In the case of using an ALD method, a film formation method such as a thermal ALD method or a plasma enhanced ALD (PEALD) method is preferably used. The thermal ALD method is preferable because of its capability of offering extremely high coverage. The PEALD method is preferable because of its capability of forming a film at low temperatures, in addition to its capability of offering high coverage.

For example, the metal oxide film can be formed by an ALD method using a precursor containing a constituent metal element and an oxidizer.

For example, in the case where an In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

Examples of the precursor containing indium include triethylindium, tris(2,2,6,6-tetramethyl-3,5-heptanedionato) indium, cyclopentadienylindium, indium (III) chloride, and (3-(dimethylamino) propyl)dimethylindium.

Examples of the precursor containing gallium include trimethylgallium, triethylgallium, gallium trichloride, tris(dimethylamido)gallium(III), gallium(III) acetylacetonate, tris(2,2,6,6-tetramethyl-3,5-heptanedionato) gallium, dimethylchlorogallium, and diethylchlorogallium.

Examples of the precursor containing zinc include dimethylzinc, diethylzinc, bis(2,2,6,6-tetramethyl-3,5-heptanedionato) zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 108f can be controlled. Moreover, by adjusting these, a film whose composition is continuously changed can also be formed. The composition of the metal oxide film 108f may be continuously changed.

Before the formation of the metal oxide film 108f, at least one of treatment for desorbing water, hydrogen, an organic substance, and the like adsorbed on the surfaces of the insulating layer 110 and the insulating layer 120, and treatment for supplying oxygen into the insulating layer 110 is preferably performed. For example, heat treatment can be performed at a temperature higher than or equal to 70° C. and lower than or equal to 200° C. in a reduced-pressure atmosphere. Alternatively, plasma treatment may be performed in an atmosphere containing oxygen. Alternatively, oxygen may be supplied to the insulating layer 110 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

Note that in the case where each of the semiconductor layer 108 and the semiconductor layer 208 has a stacked-layer structure, an upper metal oxide film is preferably formed successively after the formation of a lower metal oxide film without exposure of the surface of the lower metal oxide layer to the air.

In the case where the semiconductor layer 108 and the semiconductor layer 208 each have a stacked-layer structure, all the layers included in the semiconductor layer 108 and the semiconductor layer 208 may be formed by the same film formation method (e.g., a sputtering method or an ALD method) or the layers may be formed by different film formation methods. For example, the first metal oxide layer may be formed by a sputtering method and the second metal oxide layer may be formed by an ALD method.

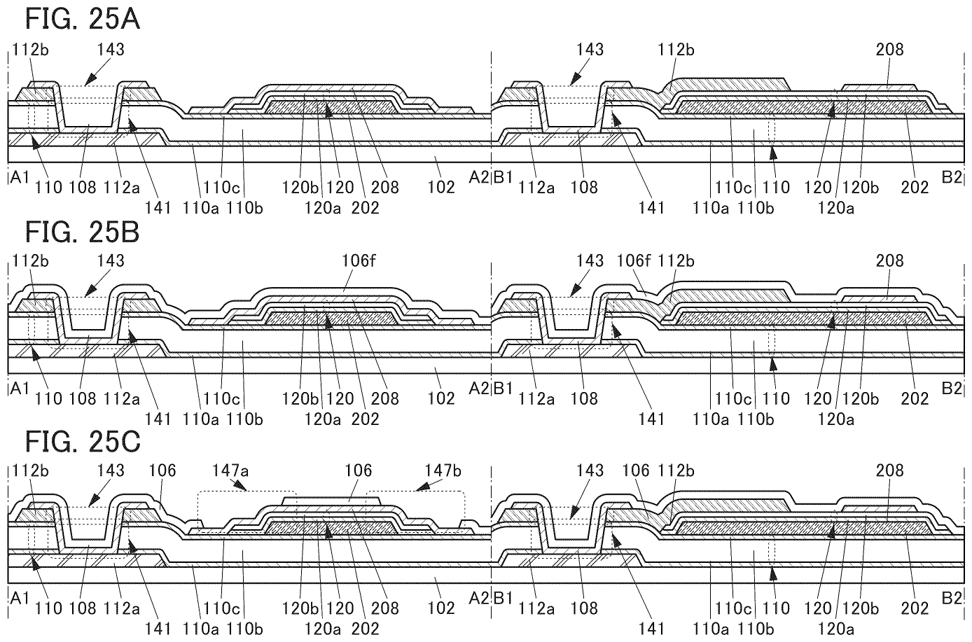

Next, the metal oxide film 108f is processed into an island shape, so that the semiconductor layer 108 and the semiconductor layer 208 are formed (FIG. 25A).

For the formation of each of the semiconductor layer 108 and the semiconductor layer 208, a wet etching method can be suitably used, for example. At this time, part of the insulating layer 110 in a region overlapping with neither the semiconductor layer 108 nor the semiconductor layer 208 is etched and thinned in some cases. Note that a material having high selectivity is preferably used for the insulating layer 110c in etching of the metal oxide film 108f, in which case a reduction in the thickness of the insulating layer 110c can be inhibited. The same applies to the insulating layer 120.

Heat treatment is preferably performed after the metal oxide film 108f is formed or after the metal oxide film 108f is processed into the semiconductor layer 108 and the semiconductor layer 208. By the heat treatment, hydrogen and water contained in the metal oxide film 108f or the semiconductor layer 108 and the semiconductor layer 208 or adsorbed onto the surface thereof can be removed. Furthermore, the film quality of the metal oxide film 108f or the semiconductor layer 108 and the semiconductor layer 208 is improved (e.g., the number of defects is reduced or the crystallinity is increased) by the heat treatment in some cases.

Oxygen can be supplied from the insulating layer 110b to the metal oxide film 108f or the semiconductor layer 108 by heat treatment. Thus, oxygen vacancies (Vₒ) in the channel formation region can be reduced. In this case, it is further preferable that the heat treatment be performed before processing the metal oxide film 108f into the semiconductor layer 108 and the semiconductor layer 208. The above description can be referred to for the heat treatment; thus, the detailed description thereof is omitted. Note that supply of oxygen to the channel formation region may be performed not only through the heat treatment but also in a heat application step in and after the formation of the metal oxide film 108f (e.g., the step of forming the insulating layer 106).

Note that the heat treatment is not necessarily performed. The heat treatment in this step may be omitted, and heat treatment performed in a later step may also serve as the heat treatment in this step. In some cases, heat application treatment in a later step (e.g., a film formation step) or the like can serve as the heat treatment in this step.

Next, an insulating film 106f to be the insulating layer 106 is formed to cover the semiconductor layer 108, the semiconductor layer 208, and the insulating layer 110 (FIG. 25B). For the formation of the insulating film 106f, a PECVD method or an ALD method can be suitably used, for example.

In the case of using a metal oxide for the insulating layer 108 and the semiconductor layer 208, the insulating layer 106 preferably functions as a barrier film inhibiting diffusion of oxygen. When the insulating layer 106 has a function of inhibiting diffusion of oxygen, oxygen contained in the semiconductor layer 108 and the semiconductor layer 208 is inhibited from being diffused to above the insulating layer 106, and an increase in oxygen vacancies (Vₒ) in the semiconductor layer 108 and the semiconductor layer 208 can be suppressed. Consequently, the transistor can have favorable electrical characteristics and high reliability.

In this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) the substance.

By increasing the temperature at the time of forming the insulating film 106f, the insulating layer including a small number of defects can be obtained. However, the high temperature at the time of forming the insulating film 106f sometimes allows release of oxygen from the semiconductor layer 108 and the semiconductor layer 208, which increases oxygen vacancies (Vₒ) and VₒH in the semiconductor layer 108 and the semiconductor layer 208 in some cases. The substrate temperature at the time of forming the insulating film 106f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 106f is within the above range, release of oxygen from the semiconductor layer 108 and the semiconductor layer 208 can be inhibited while the defects in the insulating layer 106 can be reduced. Consequently, a transistor with favorable electrical characteristics and high reliability can be obtained.

t is preferable to perform plasma treatment on the surfaces of the semiconductor layer 108 and the semiconductor layer 208 before the formation of the insulating film 106f. By the plasma treatment, impurities such as water adsorbed on the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air after the formation of the semiconductor layer 108 and the semiconductor layer 208 and before the formation of the insulating film 106f. For example, plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

Next, the insulating film 106f is processed to form the insulating layer 106 (FIG. 25C). The opening 147a and the opening 147b reaching the semiconductor layer 208 are provided in the insulating layer 106. For the formation of the insulating layer 106, a dry etching method can be suitably used.

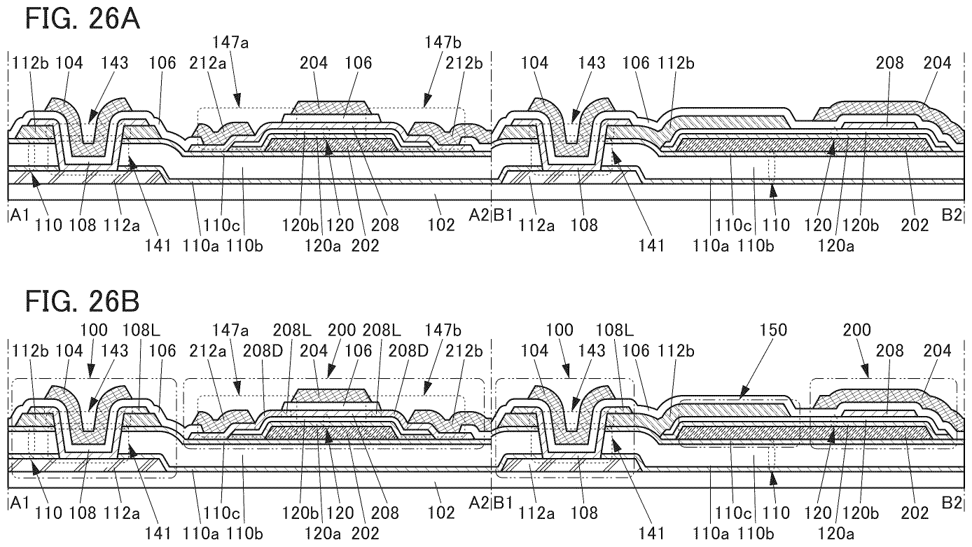

Next, a film to be the conductive layer 104, the conductive layer 204, the conductive layer 212a, and the conductive layer 212b is formed over the insulating layer 106 and the film is processed, so that the conductive layer 104, the conductive layer 204, the conductive layer 212a, and the conductive layer 212b are formed (FIG. 26A). For the formation of the film, a sputtering method, a thermal CVD method (including an MOCVD method), or an ALD method can be suitably used, for example.

Next, an impurity is supplied (or added or implanted) to the semiconductor layer 208 using the conductive layer 204, the conductive layer 212a, and the conductive layer 212b as masks. Thus, the region 208D is formed in the region of the semiconductor layer 208 that overlaps with none of the conductive layer 204, the conductive layer 212a, the conductive layer 212b, and the insulating layer 106, and the region 208L is formed in the region of the semiconductor layer 208 that overlaps with none of the conductive layer 204, the conductive layer 212a, and the conductive layer 212b and overlaps with the insulating layer 106 (FIG. 26B). At this time, the conditions for supplying the impurity are preferably determined in consideration of the material and thickness of the conductive layer 204 serving as the mask so that the impurity is supplied as little as possible to the region of the semiconductor layer 208 that overlaps with the conductive layer 204. In that case, a channel formation region with a sufficiently reduced impurity concentration can be formed in the region of the semiconductor layer 208 that overlaps with the conductive layer 204.

Similarly, the semiconductor layer 108 may also be supplied with an impurity using the conductive layer 104 as a mask. The region 108L is formed in the region of the semiconductor layer 108 that does not overlap with the conductive layer 104 and overlap with the insulating layer 106.

A plasma ion doping method or an ion implantation method can be suitably used for the supply of the impurity. In these methods, the concentration profile in the depth direction can be controlled with high accuracy by the acceleration voltage and the dosage of ions, for example. Using a plasma ion doping method can increase productivity. In addition, using an ion implantation method with mass separation can increase the purity of the impurity to be supplied.

The conditions for supplying the impurity are preferably adjusted such that the impurity concentration is highest at a surface of the semiconductor layer 208 or a portion near the surface. As a source material used for supplying the impurity, a gas containing the above impurity element can be used, for example. In the case where boron is supplied, typically, one or more of a B₂H₆ gas and a BF₃ gas can be used. In the case where phosphorus is supplied, typically, a PH₃ gas can be used. A mixed gas in which any of these source gases is diluted with a noble gas may be used.

For example, any of CH₄, N₂, NH₃, AlH₃, AlCl₃, SiH₄, Si₂H₆, F₂, HF, H₂, (C₅H₅)₂Mg, and a noble gas can be used as the source material used for supplying the impurity. Note that the source material is not limited to a gas, and a solid or a liquid that is vaporized by heating may be used.

Addition of the impurity can be controlled by setting the conditions such as the acceleration voltage and the dosage in consideration of the compositions, densities, thicknesses, and the like of the insulating layer 106 and the semiconductor layer 208.

For example, in the case where boron is added by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus is added by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity is not limited thereto; plasma treatment, treatment using thermal diffusion by heating, or the like may be used, for example. In a plasma treatment method, plasma is generated in a gas atmosphere containing an impurity to be added and plasma treatment is performed, so that the impurity can be added. A dry etching apparatus, an ashing apparatus, a plasma CVD apparatus, a high-density plasma CVD apparatus, or the like can be used as an apparatus for generating the plasma.

For example, when plasma treatment is performed with a plasma CVD apparatus in an atmosphere containing hydrogen, hydrogen can be supplied as the impurity to the region of the semiconductor layer 208 that does not overlap with the conductive layer 204. With the use of a plasma CVD apparatus for the supply of the impurity and the formation of the insulating layer 195, the supply of the impurity and the formation of the insulating layer 195 can be successively performed in the apparatus, so that the productivity can be increased.

The capacitor 150 is formed in a region where the conductive layer 202, the insulating layer 120, and the conductive layer 112b overlap with each other.

Next, the insulating layer 195 is formed to cover the conductive layer 104, the conductive layer 204, the conductive layer 212a, the conductive layer 212b, the insulating layer 106, and the semiconductor layer 208 (FIG. 1B and FIG. 1C). For the formation of the insulating layer 195, a PECVD method can be favorably used.

If the film formation temperature of the insulating layer 195 is too high, impurities contained in the region 108L, the region 208L, and the region 208D might be diffused into peripheral portions, which include the channel formation regions of the semiconductor layer 108 and the semiconductor layer 208. Furthermore, the electrical resistance of the region 108L, the region 208L, and the region 208D might be increased. Thus, the film formation temperature of the insulating layer 195 is determined in consideration of the impurity diffusion.

The film formation temperature of the insulating layer 195 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Formation of the insulating layer 195 at low temperatures enables the transistors to have favorable electrical characteristics even when they have short channel lengths.

Heat treatment may be performed after the formation of the insulating layer 195. The heat treatment can reduce the electric resistance of the region 108L, the region 208L, and the region 208D in some cases. For example, by the heat treatment, an impurity is diffused moderately, so that the region 208L and the region 208D each having an ideal concentration gradient of the impurity can be formed. The above description can be referred to for the heat treatment; thus, the detailed description thereof is omitted. Note that when the temperature of the heat treatment is too high (e.g., higher than or equal to 500° C.), the impurity might also be diffused into the channel formation region to degrade the electrical characteristics and reliability of the transistors.

Note that the heat treatment is not necessarily performed. The heat treatment in this step may be omitted, and heat treatment performed in a later step may also serve as the heat treatment in this step. In the case where heat application treatment (e.g., a film formation step) is performed in a later step, such treatment can serve as the heat treatment in this step in some cases.

Through the above steps, the semiconductor device of one embodiment of the present invention can be manufactured.

This embodiment can be combined with the other embodiments as appropriate.

### Embodiment 3

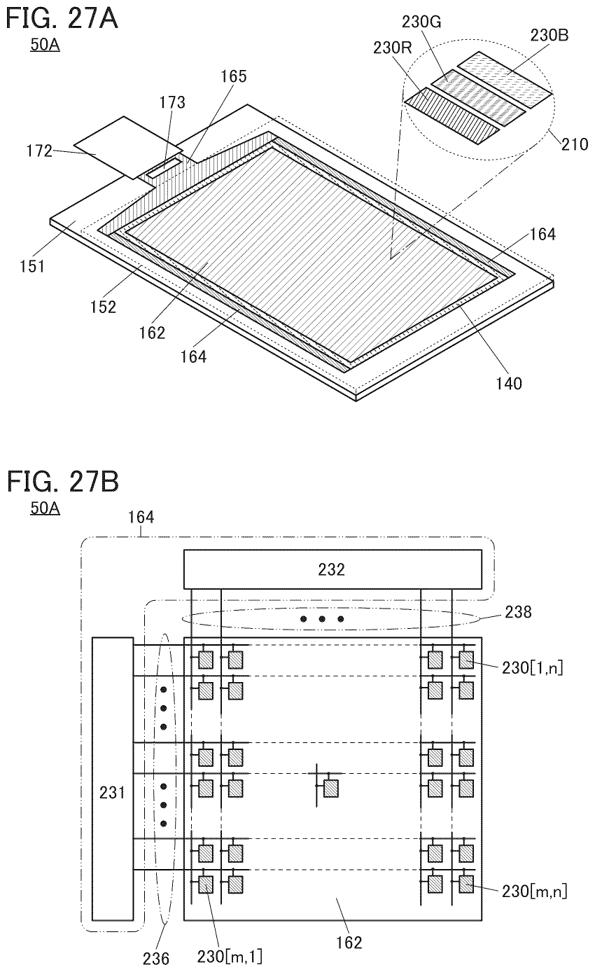

In this embodiment, display apparatuses of one embodiment of the present invention will be described with reference to FIG. 27 to FIG. 51.

The display apparatus of this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display apparatus or a module including the display apparatus. Examples of the module including the display apparatus are a module in which a connector such as a flexible printed circuit board (hereinafter referred to as an FPC) or a tape carrier package (TCP) is attached to the display apparatus and a module in which the display apparatus is mounted with an integrated circuit (IC) by a chip on glass (COG) method, a chip on film (COF) method, or the like.

The display apparatus of this embodiment may have a function of a touch panel. The display apparatus can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element (also referred to as a display device) and a counter substrate.

FIG. 27A is a perspective view of a display apparatus 50A.

In the display apparatus 50A, a substrate 152 and a substrate 151 are attached to each other. In FIG. 27A, the substrate 152 is denoted by a dashed line.

The display apparatus 50A includes a display portion 162, a connection portion 140, a circuit portion 164, a conductive layer 165, and the like. FIG. 27A illustrates an example where an IC 173 and an FPC 172 are mounted onto the display apparatus 50A. Thus, the structure illustrated in FIG. 27A can be regarded as a display module including the display apparatus 50A, the IC, and the FPC.

The connection portion 140 is provided outside the display portion 162. The connection portion 140 can be provided along one or more sides of the display portion 162. The number of the connection portions 140 can be one or more. FIG. 27A illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173.

FIG. 27A illustrates an example where the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The semiconductor device of one embodiment of the present invention can be used for one or both of the display portion 162 and the circuit portion 164 of the display apparatus 50A, for example.

When the semiconductor device of one embodiment of the present invention is used for a pixel circuit of a display apparatus, for example, the area occupied by the pixel circuit can be reduced and a high-resolution display apparatus can be obtained. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel, for example. Since the semiconductor device of one embodiment of the present invention has favorable electrical characteristics, a display apparatus can have increased reliability by using the semiconductor device.

The display portion 162 of the display apparatus 50A is a region where an image is to be displayed, and includes a plurality of pixels 210 that are periodically arranged. FIG. 27A is an enlarged view of one pixel 210.

There is no particular limitation on the arrangement of the pixels in the display apparatus of this embodiment, and a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 27A includes a pixel 230R emitting red light, a pixel 230G emitting green light, and a pixel 230B emitting blue light. The pixel 230R, the pixel 230G, and the pixel 230B form one pixel 210, which achieves full-color display. The pixel 230R, the pixel 230G, and the pixel 230B each function as a subpixel. The display apparatus 50A illustrated in FIG. 27A shows an example where the pixels 230 each functioning as a subpixel are arranged in a stripe pattern. The number of subpixels forming one pixel 210 is not limited to three, and may be four or more. For example, four subpixels emitting light of R, G, B, and white (W) may be included. Alternatively, four subpixels emitting light of four colors, R, G, B, and Y may be included.

The pixel 230R, the pixel 230G, and the pixel 230B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display apparatus using a liquid crystal element, a transmissive liquid display apparatus, a reflective liquid display apparatus, and a transflective liquid display apparatus can be given.

Examples of a mode that can be used for a display apparatus using a liquid crystal element include a vertical alignment (VA) mode, an FFS (Fringe Field Switching) mode, an IPS

(In-Plane Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance emitting fluorescent light (a fluorescent material), a substance emitting phosphorescent light (a phosphorescent material), a substance exhibiting thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode, and the other electrode functions as a cathode.

The display apparatus of one embodiment of the present invention can have any of the following structures: a top-emission structure where light is emitted in a direction opposite to the substrate where the light-emitting element is formed, a bottom-emission structure where light is emitted toward the substrate where the light-emitting element is formed, and a dual-emission structure where light is emitted toward both surfaces.

In this embodiment, the case where a light-emitting element is used as the display element is mainly described as an example.

FIG. 27B is a block diagram illustrating the display apparatus 50A. The display apparatus 50A includes the display portion 162 and the circuit portion 164. The display portion 162 includes a plurality of pixels 230 arranged periodically (a pixel 230 [1,1] to a pixel 230 [m,n], where each of m and n is independently an integer greater than or equal to 2). The circuit portion 164 includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 162 therebetween. Some sort of circuit may be provided at a position facing the second driver circuit portion 232 with the display portion 162 therebetween.

Any of various circuits such as a shift register circuit, a level shifter circuit, an inverter circuit, a latch circuit, an analog switch circuit, a demultiplexer circuit, and a logic circuit can be used for the circuit portion 164. In the circuit portion 164, a transistor, a capacitor, and the like can be used. Transistors included in the circuit portion 164 may be formed in the same step as transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 27B illustrates an example where the wirings 236 and the wirings 238 are connected to the pixels 230. Note that the wirings 236 and the wirings 238 are examples, and the wirings connected to the pixels 230 are not limited to the wirings 236 and the wirings 238.

In the semiconductor device of one embodiment of the present invention, some formation steps can be common between a vertical transistor (VFET) having a submicron-sized channel length and a high on-state current and a TGSA transistor having a long channel length and favorable saturation characteristics. An oxide semiconductor (OS) can be suitably used for the channel formation regions of these transistors, so that the transistors can have a low off-state current. The semiconductor device of one embodiment of the present invention can be used for one or both of the display portion 162 and the circuit portion 164. Alternatively, the semiconductor device of one embodiment of the present invention can be used for both the display portion 162 and the circuit portion 164, that is, all the transistors included in the display apparatus can be OS transistors. Using OS transistors as all the transistors included in the display apparatus as described above has an effect of reducing the manufacturing cost.

### <Structure Example of Driver Circuit>

Using a latch circuit as an example, a structure example of a circuit that can be used as a driver circuit will be described.

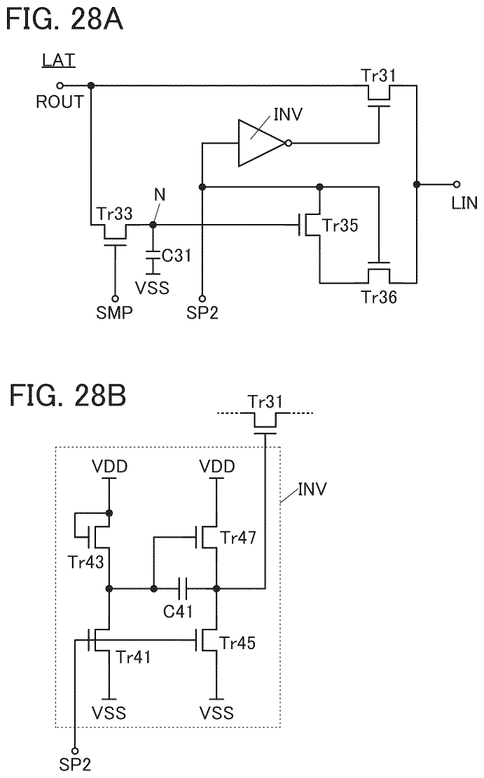

FIG. 28A is a circuit diagram illustrating a structure example of a latch circuit LAT. The latch circuit LAT illustrated in FIG. 28A includes a transistor Tr31, a transistor Tr33, a transistor Tr35, a transistor Tr36, a capacitor C31, and an inverter circuit INV. In FIG. 28A, a node where one of a source and a drain of the transistor Tr33, a gate of the transistor Tr35, and one electrode of the capacitor C31 are electrically connected to each other is referred to as a node N.

In the latch circuit LAT illustrated in FIG. 28A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is retained and the data written to the latch circuit LAT is retained. Specifically, when the potential of the node N is a low potential, data having a value “0” is retained in the latch circuit LAT and when the potential of the node N is a high potential, data having a value “1” is retained in the latch circuit LAT, for example.

A transistor with a low off-state current is preferably used as the transistor Tr33. An OS transistor can be suitably used as the transistor Tr33. In that case, the latch circuit LAT can retain data for a long period. Thus, the frequency of rewriting data to the latch circuit LAT can be lowered.

In this specification and the like, writing data to the latch circuit LAT such that a signal input from a terminal SP2 is output to the terminal LIN is simply referred to as “writing data to the latch circuit LAT”, in some cases. That is, writing data having a value “1”, for example, to the latch circuit LAT is simply referred to as “writing data to the latch circuit LAT”, in some cases.

The semiconductor device of one embodiment of the present invention can be suitably used for the latch circuit LAT. For example, the transistor 100 or the transistor 200 illustrated in FIG. 1B or the like can be used as one or more of the transistor Tr31, the transistor Tr33, the transistor Tr35, and the transistor Tr36.

FIG. 28B illustrates a structure example of the inverter circuit INV. The inverter circuit INV includes a transistor Tr41, a transistor Tr43, a transistor Tr45, a transistor Tr47, and a capacitor C41.

When the latch circuit LAT has the structure illustrated in FIG. 28A and the inverter circuit INV has the structure illustrated in FIG. 28B, all the transistors included in the latch circuit LAT can be transistors having the same polarity, for example, n-channel transistors. In that case, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same step.

The semiconductor device of one embodiment of the present invention can be suitably used for the inverter circuit INV. For example, the transistor 100 or the transistor 200 illustrated in FIG. 1B or the like can be used as one or more of the transistor Tr41, the transistor Tr43, the transistor Tr45, and the transistor Tr47.

Using one or more types of transistors among the transistor 100 to the transistor 100D can reduce the occupied area, so that a display apparatus with a narrow bezel can be obtained. One or more types of transistors among the transistor 100 to the transistor 100D can be suitably used as the transistors that are required to have a high on-state current. Furthermore, one or more types of transistors among the transistor 200 to the transistor 200B can be suitably used as the transistors that are required to have favorable saturation characteristics. In that case, a high-performance display apparatus can be provided.

### <Structure Example 1 of Pixel Circuit>

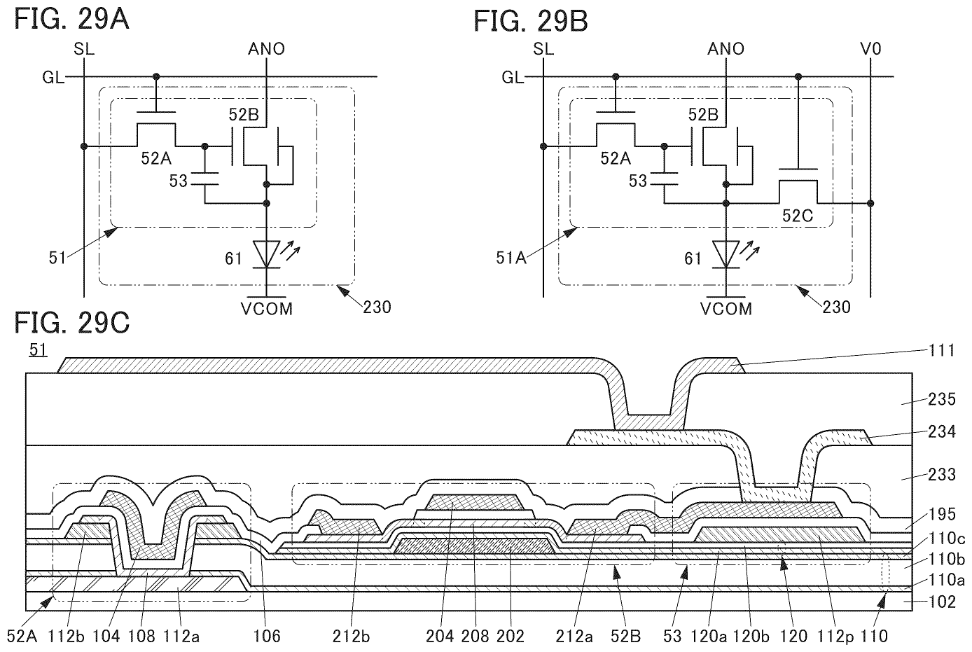

FIG. 29A illustrates a structure example of the pixel 230. The pixel 230 includes a pixel circuit 51 and a light-emitting device 61.

The pixel circuit 51 illustrated in FIG. 29A includes a transistor 52A, a transistor 52B, and a capacitor 53. The pixel circuit 51 is a 2Tr1C-type pixel circuit including two transistors and one capacitor. Note that there is no particular limitation on the pixel circuit that can be used for the display apparatus of one embodiment of the present invention.

An anode of the light-emitting device 61 is electrically connected to one of a source and a drain of the transistor 52B and one electrode of the capacitor 53. The other of the source and the drain of the transistor 52B is electrically connected to a wiring ANO. A gate of the transistor 52B is electrically connected to one of a source and a drain of the transistor 52A and the other electrode of the capacitor 53. The other of the source and the drain of the transistor 52A is electrically connected to a wiring GL. A gate of the transistor 52A is electrically connected to the wiring GL. A cathode of the light-emitting device 61 is electrically connected to a wiring VCOM.

The wiring GL corresponds to the wiring 236, and the wiring SL corresponds to the wiring 238. The wiring VCOM is a wiring supplying a potential for supplying a current to the light-emitting device 61. The transistor 52A has a function of controlling electrical continuity and discontinuity between the wiring SL and the gate of the transistor 52B in accordance with the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of retaining a gate potential of the transistor 52B. The intensity of light emitted by the light-emitting device 61 is controlled in accordance with an image signal supplied to the gate of the transistor 52B.

Some or all of the transistors included in the pixel circuit 51 may be provided with back gates. In the pixel circuit 51 illustrated in FIG. 29A, the transistor 52B includes a back gate, and the back gate is electrically connected to one of the source and the drain of the transistor 52B. Note that a structure where the back gate of the transistor 52B is electrically connected to the gate of the transistor 52B may be employed as well.

The above-described semiconductor device can be suitably used for the pixel circuit 51. The transistor 52B functioning as a driving transistor that controls a current flowing through the light-emitting device 61 preferably has more favorable saturation characteristics than the transistor 52A functioning as a selection transistor for controlling a selection state of the pixel 230. The use of one type of transistor among the transistor 200 to the transistor 200B having a long channel length as the transistor 52B enables the display apparatus to have high reliability. Furthermore, the use of one type of transistor among the transistor 100 to the transistor 100D as the transistor 52A can reduce the area occupied by the pixel circuit 51A, so that the display apparatus can have high resolution.

Note that one type of transistor among the transistor 100 to the transistor 100D may also be used as the transistor 52B. The use of the transistor having a short channel length as the transistor 52B enables the display apparatus to have high luminance. Furthermore, the area occupied by the pixel circuit 51 can be reduced, so that a high-resolution display apparatus can be obtained.

FIG. 29B illustrates a structure example of the pixel 230 different from that illustrated in FIG. 29A. The pixel 230 includes the pixel circuit 51A and the light-emitting device 61.

The pixel circuit 51A illustrated in FIG. 29B is different from the pixel circuit 51 illustrated in FIG. 29A mainly in including a transistor 52C. The pixel circuit 51A includes the transistor 52A, the transistor 52B, the transistor 52C, and the capacitor 53. The pixel circuit 51A is a 3Tr1C-type pixel circuit including three transistors and one capacitor.

One of a source and a drain of the transistor 52C is electrically connected to the one of the source and the drain of the transistor 52B. The other of the source and the drain of the transistor 52C is electrically connected to a wiring V0. For example, a reference potential is supplied to the wiring V0. A gate of the transistor 52C is electrically connected to the wiring GL.

The transistor 52C has a function of controlling electrical continuity and discontinuity between the wiring V0 and the one of the source electrode and the drain electrode of the transistor 52B in accordance with the potential of the wiring GL. Furthermore, variation in the gate-source potential of the transistor 52B can be inhibited by the reference potential of the wiring V0 supplied through the transistor 52C.

A current value that can be used for setting pixel parameters can be obtained with the use of the wiring V0. Specifically, the wiring V0 can function as a monitor line for outputting, to the outside, a current flowing through the transistor 52B or a current flowing through the light-emitting device 61. A current output to the wiring V0 is converted into a voltage by a source follower circuit and can be output to the outside. Alternatively, the current is converted into a digital signal by an A/D converter, and can be output to the outside.

The above-described semiconductor device can be suitably used for the pixel circuit 51A. The use of one type of transistor among the transistor 200 to the transistor 200B having a long channel length as the transistor 52B enables the display apparatus to have high reliability. Furthermore, the use of one type of transistor among the transistor 100 to the transistor 100D as each of the transistor 52A and the transistor 52C can reduce the area occupied by the pixel circuit 51A, so that the display apparatus can have high resolution. Note that one type of transistor among the transistor 100 to the transistor 100D may also be used as the transistor 52B.

FIG. 29C illustrates a structure example of the pixel circuit 51. FIG. 29C is a cross-sectional view of the pixel circuit 51. FIG. 29C selectively illustrates the transistor 52A, the transistor 52B, the capacitor 53, and the pixel electrode included in the light-emitting device 61. Note that the electrical connection between the transistor 52A and the transistor 52B is not illustrated.

The transistor 52A includes the conductive layer 104, the insulating layer 106, the semiconductor layer 108, the conductive layer 112a, and the conductive layer 112b. The transistor 52B includes the conductive layer 202, the insulating layer 106, the semiconductor layer 208, the insulating layer 120, the conductive layer 204, the conductive layer 212a, and the conductive layer 212b. The above description can be referred to for the transistor 52A and the transistor 52B; thus, the detailed description is omitted.

The capacitor 53 includes the conductive layer 212a, a conductive layer 112p, and the insulating layer 106 interposed therebetween. The conductive layer 112p is provided over the insulating layer 120. The conductive layer 112p can be formed in the same step as the conductive layer 112b, for example. The insulating layer 106 is provided over the conductive layer 112p, and the conductive layer 212a is provided over the insulating layer 106. The conductive layer 212a functions as one of the source electrode and the drain electrode of the transistor 52B and functions as one electrode of the capacitor 53. Note that there is no particular limitation on the structure of the capacitor 53.

The insulating layer 195 is provided to cover the transistor 52A, the transistor 52B, and the capacitor 53, an insulating layer 233 is provided to cover the insulating layer 195, and an insulating layer 235 is provided to cover the insulating layer 233. The light-emitting device 61 can be provided over the insulating layer 235. FIG. 29C illustrates a pixel electrode 111 functioning as one electrode of the light-emitting device 61. The insulating layer 195 and the insulating layer 233 include a first opening reaching the conductive layer 212a, and a conductive layer 234 is provided to cover the opening. The conductive layer 234 is electrically connected to the conductive layer 212a through the first opening. The insulating layer 235 includes a second opening reaching the conductive layer 234, and the pixel electrode 111 is provided to cover the second opening. The pixel electrode 111 is electrically connected to the conductive layer 234 through the second opening. The above description can be referred to for the insulating layer 195; thus, the detailed description thereof is omitted. The insulating layer 233 and the insulating layer 235 have a function of reducing unevenness due to the transistor 52A, the transistor 52B, and the transistor 52C and making the formation surface of the light-emitting device 61 flatter. Note that in this specification and the like, each of the insulating layer 233 and the insulating layer 235 is referred to as a planarization layer in some cases.

An organic insulating film is suitable for each of the insulating layer 233 and the insulating layer 235. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The insulating layer 235 preferably has a stacked-layer structure of an organic insulating film and an inorganic insulating film over the organic insulating film. Thus, the inorganic insulating film can function as an etching protective layer at the time of forming the light-emitting device 61. Specifically, partial etching of the insulating layer 235, which forms a depressed portion in the insulating layer 235, can be inhibited at the time of forming the pixel electrode 111. Alternatively, a depressed portion may be formed in the insulating layer 235 at the time of forming the pixel electrode 111. Similarly, the insulating layer 233 may have a stacked-layer structure of an organic insulating film and an inorganic insulating film.

### <Structure Example 2 of Pixel Circuit>

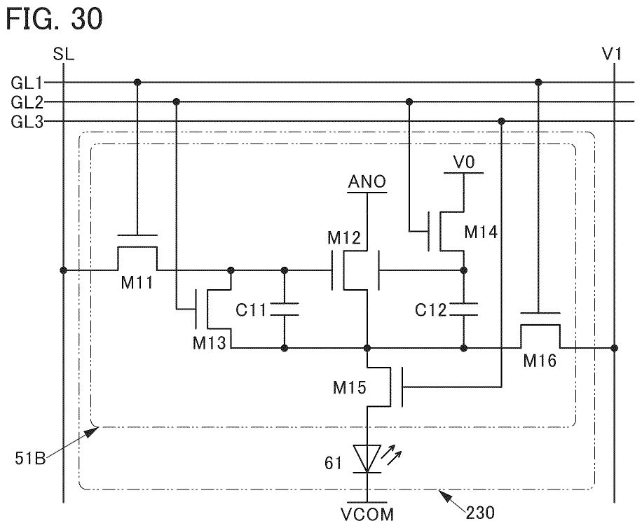

FIG. 30 illustrates a structure example different from that of the above-described pixel 230. The pixel 230 includes a pixel circuit 51B and the light-emitting device 61.

The pixel circuit 51B includes a transistor M11, a transistor M12, a transistor M13, a transistor M14, a transistor M15, a transistor M16, a capacitor C11, and a capacitor C12. The pixel circuit 51B is a 6Tr2C-type pixel circuit including six transistors and two capacitors.

The anode of the light-emitting device 61 is electrically connected to one of a source and a drain of the transistor M15. The cathode of the light-emitting device 61 is electrically connected to the wiring VCOM. The other of the source and the drain of the transistor M15 is electrically connected to one of a source and a drain of the transistor M12, one of a source and a drain of the transistor M13, one of a source and a drain of the transistor M16, one electrode of the capacitor C11, and one electrode of the capacitor C12. A gate of the transistor M12 is electrically connected to one of a source and a drain of the transistor M11, the other of the source and the drain of the transistor M13, and the other electrode of the capacitor C11. A back gate of the transistor M12 is electrically connected to one of a source and a drain of the transistor M14 and the other electrode of the capacitor C12.

The other of the source and the drain of the transistor M11 is electrically connected to the wiring SL. The other of the source and the drain of the transistor M12 is electrically connected to the wiring ANO. The other of the source and the drain of the transistor M14 is electrically connected to the wiring V0. The other of the source and the drain of the transistor M16 is electrically connected to a wiring V1. For example, a constant potential is supplied to the wiring V1. A gate of the transistor M11 and a gate of the transistor M16 are electrically connected to a wiring GL1. A gate of the transistor M13 and a gate of the transistor M14 are electrically connected to a wiring GL2. A gate of the transistor M15 is electrically connected to a wiring GL3.

The transistor M11 functions as a selection transistor that controls electrical continuity and discontinuity between the gate of the transistor M12 and the wiring SL. The transistor M12 functions as a driving transistor that controls current flowing through the light-emitting device 61. The transistor M14 has a function of supplying a potential of the wiring V0 to the back gate of the transistor M12. When a constant potential is supplied to the back gate of the transistor M12, the threshold voltage can be controlled. The capacitor C11 has a function of retaining a gate potential of the transistor M12. The capacitor C12 has a function of retaining a back gate potential of the transistor M12. The pixel circuit 51B has a function of correcting the threshold voltage of the transistor M12 with use of the back gate thereof, what is called an internal correcting function of the threshold voltage. Specifically, a back gate potential that makes the threshold voltage of the transistor M12 be 0 V is retained in the capacitor C12. Accordingly, regardless of variation in the threshold voltage and over-time deterioration of the transistor, the threshold voltage of the transistor M12 can be corrected to be constant at 0 V or the vicinity thereof.

The above-described semiconductor device can be suitably used for the pixel circuit 51B. For example, one or more types of transistors among the transistor 100 to the transistor 100D illustrated in FIG. 1B and the like can be used as the transistor M11, the transistor M13, the transistor M14, the transistor M15, and the transistor M16, and one or more types of transistors among the transistor 200 to the transistor 200B can be used as the transistor M12.

The transistor M12 functioning as a driving transistor preferably has favorable saturation characteristics. When one type of transistor among the transistor 200 to the transistor 200B having a long channel length is used as the transistor M12, a highly reliable display apparatus can be obtained. Furthermore, when one or more types of transistors among the transistor 100 to the transistor 100D are used as the transistor M11, the transistor M13, the transistor M14, the transistor M15, and the transistor M16, the area occupied by the pixel circuit 51B can be reduced, so that a high-resolution display apparatus can be obtained.

Note that one type of transistor among the transistor 100 to the transistor 100D may also be used as the transistor M12. The use of the transistor having a short channel length as the transistor M12 enables the display apparatus to have high luminance. Furthermore, the area occupied by the pixel circuit 51B can be reduced, so that a high-resolution display apparatus can be obtained.

The use of a plurality of transistors and a plurality of capacitors in the pixel circuit achieves a high-performance display apparatus. With the use of the semiconductor device of one embodiment of the present invention, the occupation area can be reduced even when the numbers of the transistors and the capacitors are increased, so that a high-performance and high-resolution display apparatus can be obtained. For example, the resolution of the display apparatus can be higher than or equal to 300 ppi, higher than or equal to 500 ppi, higher than or equal to 1000 ppi, higher than or equal to 2000 ppi, or higher than or equal to 3000 ppi.

Since the occupation area can be reduced with the use of the semiconductor device of one embodiment of the present invention, the aperture ratio of a pixel can be increased in a display apparatus having a bottom-emission structure. For example, the aperture ratio can be higher than or equal to 50%, higher than or equal to 55%, or higher than or equal to 60% in the display apparatus.

In this specification and the like, the aperture ratio refers to a ratio of the area of a region, where light is emitted, to the area of a pixel.

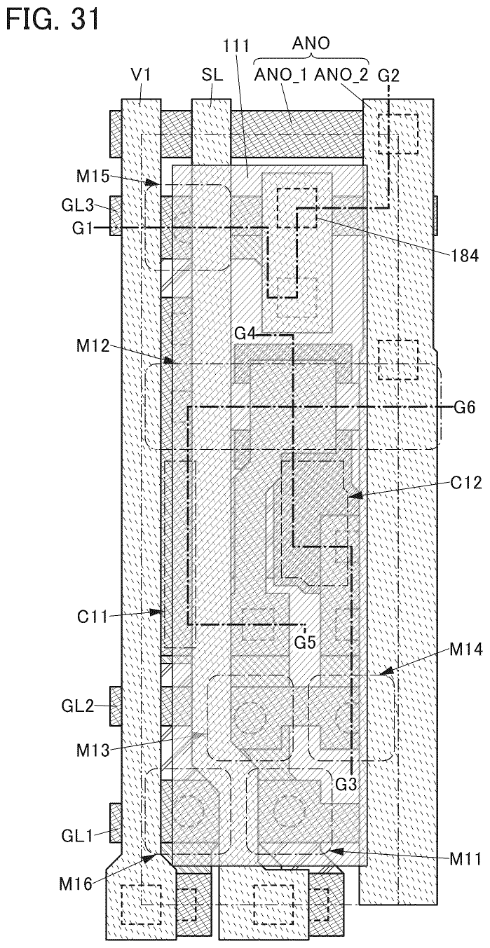

FIG. 31 to FIG. 33 illustrate a layout structure example of the pixel 230. FIG. 31 is a top view corresponding to the circuit diagram in FIG. 30. FIG. 31 illustrates the transistor M11, the transistor M12, the transistor M13, the transistor M14, the transistor M15, the transistor M16, the capacitor C11, the capacitor C12, the wiring GL1, the wiring GL2, the wiring GL3, the wiring SL, the wiring V1, the wiring ANO, and the pixel electrode 111 included in the light-emitting device 61. Note that in FIG. 31, hatching of the pixel electrode 111 is illustrated transparently so that components under the pixel electrode 111 are clearly shown. The wiring ANO includes a wiring ANO_1 and a wiring ANO_2. The wiring ANO_1 and the wiring ANO_2 are electrically connected to each other and serve as the wiring ANO. In FIG. 31, the wiring V0 is omitted.

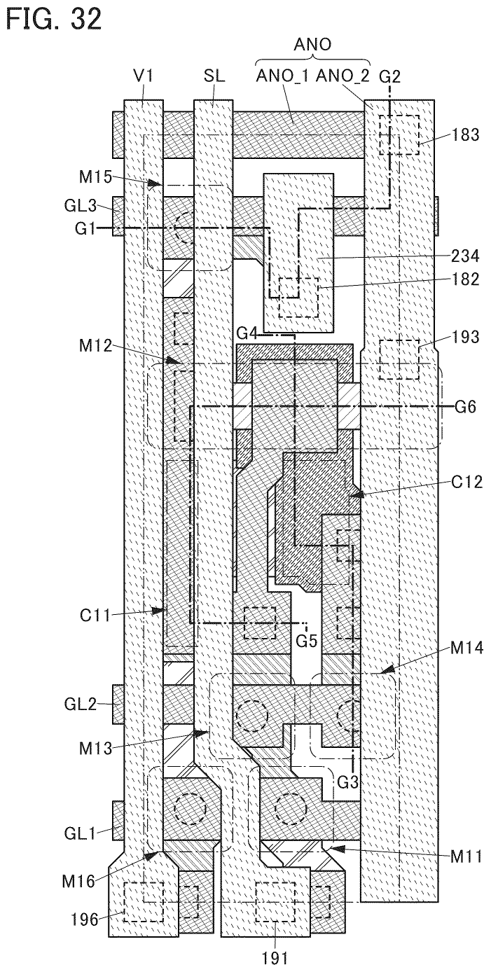

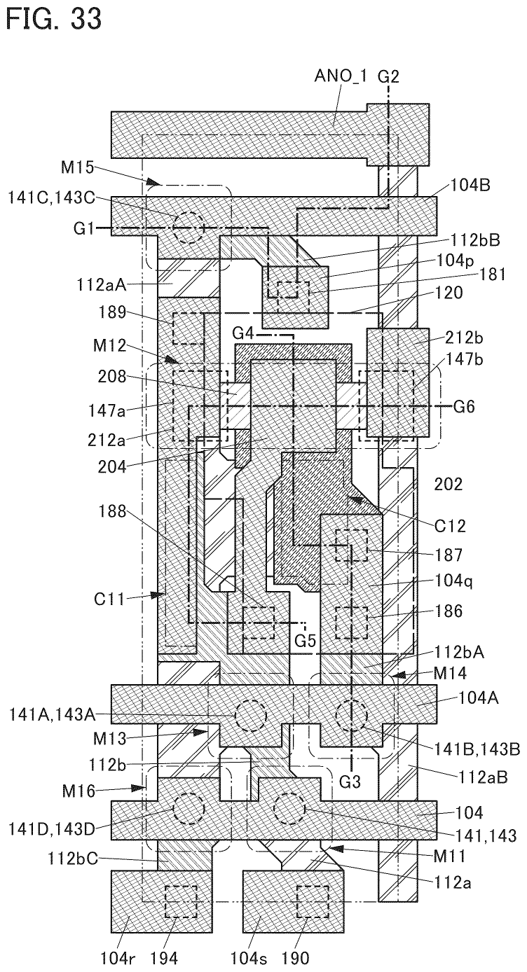

FIG. 32 is a top view where the pixel electrode 111 is omitted from FIG. 31. FIG. 33 is a top view where the wiring V1, the wiring SL, and the wiring ANO_2 are further omitted from FIG. 32. Note that in FIG. 31 to FIG. 33, the range of one pixel 230 is indicated by a dashed double-dotted line.

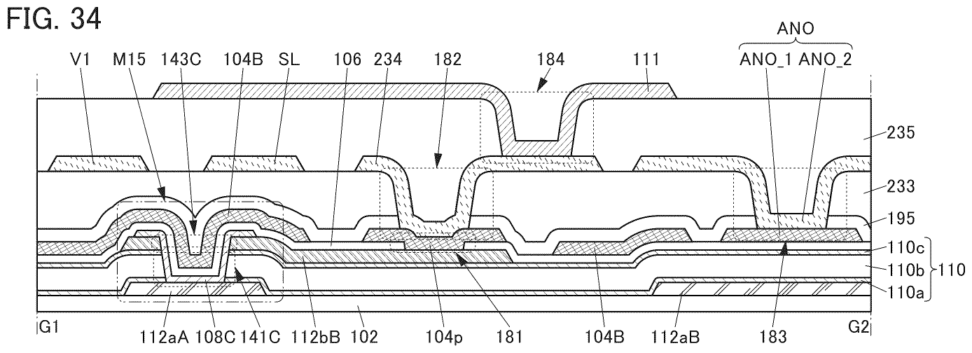

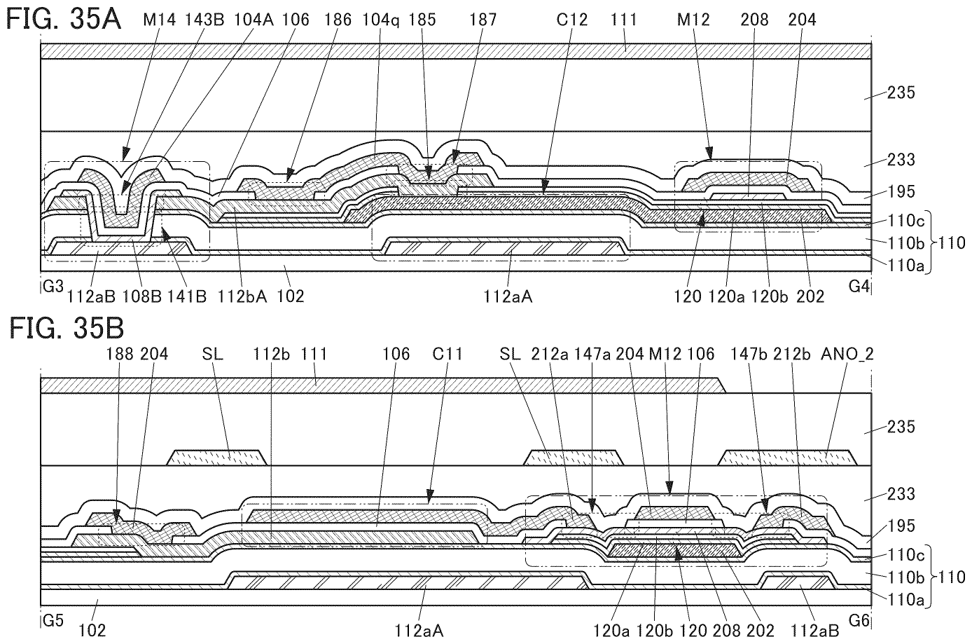

FIG. 34 is a cross-sectional view of a cut plane along the dashed-dotted line G1-G2 in FIG. 31, FIG. 35A is a cross-sectional view of a cut plane along the dashed-dotted line B3-G4, and FIG. 35B is a cross-sectional view of a cut plane along the dashed-dotted line G5-G6.

In the example illustrated in FIG. 31 to FIG. 35, the structure of the transistor 100 illustrated in FIG. 1B and the like is employed for the transistor M11, the transistor M13, the transistor M14, the transistor M15, and the transistor M16, and the structure of the transistor 200 is employed for the transistor M12.

The transistor M11 includes the conductive layer 112a, the conductive layer 112b, the semiconductor layer 108, the insulating layer 106, and the conductive layer 104. In the transistor M11, the conductive layer 112b functions as one of the source electrode and the drain electrode, and the conductive layer 112a functions as the other. Part of the insulating layer 106 functions as a gate insulating layer, and the conductive layer 104 functions as a gate electrode. The conductive layer 104 functions as the wiring GL1.

The conductive layer 112b and the insulating layer 110 have the opening 143 and the opening 141 in a region overlapping with the conductive layer 112a. The semiconductor layer 108 is provided to cover the opening 143 and the opening 141. The insulating layer 106 is provided over the semiconductor layer 108, and the conductive layer 104 is provided over the insulating layer 106.

The transistor M12 includes the conductive layer 202, the insulating layer 120, the semiconductor layer 208, the insulating layer 106, the conductive layer 204, the conductive layer 212a, and the conductive layer 212b. In the transistor M12, the conductive layer 204 functions as a gate electrode (also referred to as a first gate electrode), and part of the insulating layer 106 functions as a gate insulating layer (also referred to as a first gate insulating layer). The conductive layer 202 functions as a back gate electrode (also referred to as a second gate electrode), and part of the insulating layer 120 functions as a back gate insulating layer (also referred to as a second gate insulating layer). The conductive layer 212a functions as one of the source electrode and the drain electrode, and the conductive layer 212b functions as the other.

The conductive layer 202 is provided over the insulating layer 110, and the insulating layer 120 is provided over the conductive layer 202. The semiconductor layer 208 is provided over the insulating layer 120, and the insulating layer 106 is provided to cover the semiconductor layer 208. The conductive layer 204, the conductive layer 212a, and the conductive layer 212b are provided over the insulating layer 106. The insulating layer 106 includes the opening 147a and the opening 147b each reaching the semiconductor layer 208, and the conductive layer 212a and the conductive layer 212b are in contact with the semiconductor layer 208 through the opening 147a and the opening 147b, respectively.

The insulating layer 106 includes an opening 188 reaching the conductive layer 112b, and the conductive layer 204 is provided to cover the opening 188. The conductive layer 204 is electrically connected to the conductive layer 112b through the opening 188.

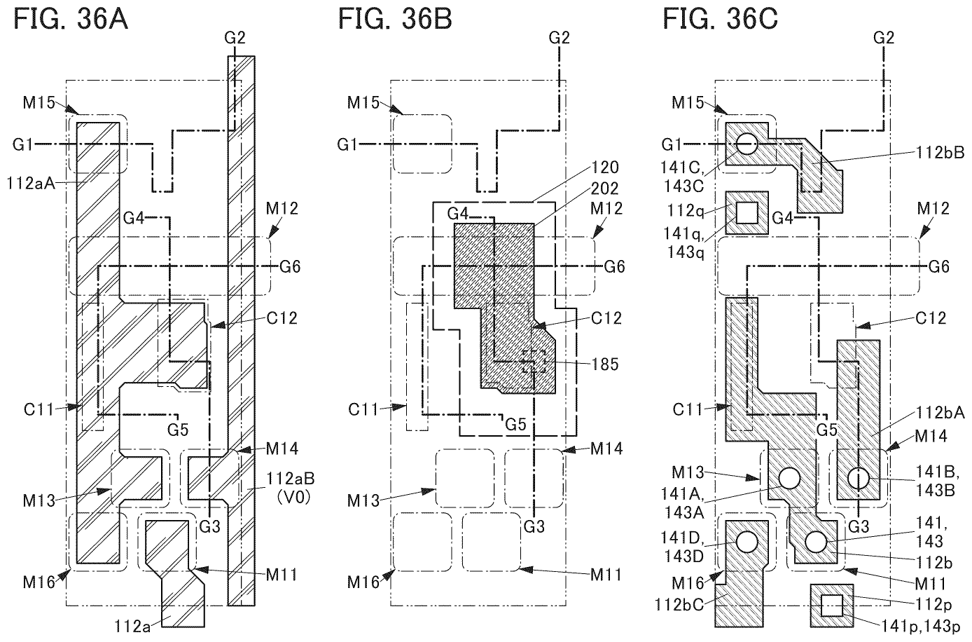

FIG. 36A is a top view of the conductive layer 112a. FIG. 36A illustrates, in addition to the conductive layer 112a, a conductive layer 112aA and a conductive layer 112aB, which can be formed in the same step. The conductive layer 112aB functions as the wiring V0. The conductive layer 112aB (wiring V0) extends in the column direction.

The horizontal direction in a drawing is the row direction and the vertical direction is the column direction; however, one embodiment of the present invention is not limited thereto and the row direction and the column direction can be replaced with each other.

FIG. 36B is a top view of the conductive layer 202 and the insulating layer 120. In FIG. 36B, the insulating layer 120 is indicated by a dashed line.

FIG. 36C is a top view of the conductive layer 112b. FIG. 36C illustrates, in addition to the conductive layer 112b, a conductive layer 112bA, a conductive layer 112bB, a conductive layer 112bC, the conductive layer 112p, and a conductive layer 112q, which can be formed in the same step. In the conductive layer 112b, an opening 143A of the transistor M13 is provided in addition to the opening 143 of the transistor M11. In the conductive layer 112bA, an opening 143B of the transistor M14 is provided. In the conductive layer 112bB, an opening 143C of the transistor M15 is provided. In the conductive layer 112bC, an opening 143D of the transistor M16 is provided. An opening 143p is provided in the conductive layer 112p, and an opening 143q is provided in the conductive layer 112q. The opening 143 to the opening 143D, the opening 143p, and the opening 143q can be formed in the same step. Although the top surface shapes of the opening 143p and the opening 143q are different from those of the opening 143 to the opening 143D in FIG. 36C, there is no particular limitation on the top surface shapes of the opening 143p and the opening 143q. For example, the top surface shapes of the opening 143 to the opening 143D, the opening 143p, and the opening 143q can each be a circle. Moreover, the opening 141 to an opening 141D, an opening 141p, and an opening 141q are provided in regions of the insulating layer 110 which overlap with the opening 143 to the opening 143D, the opening 143p, and the opening 143q.

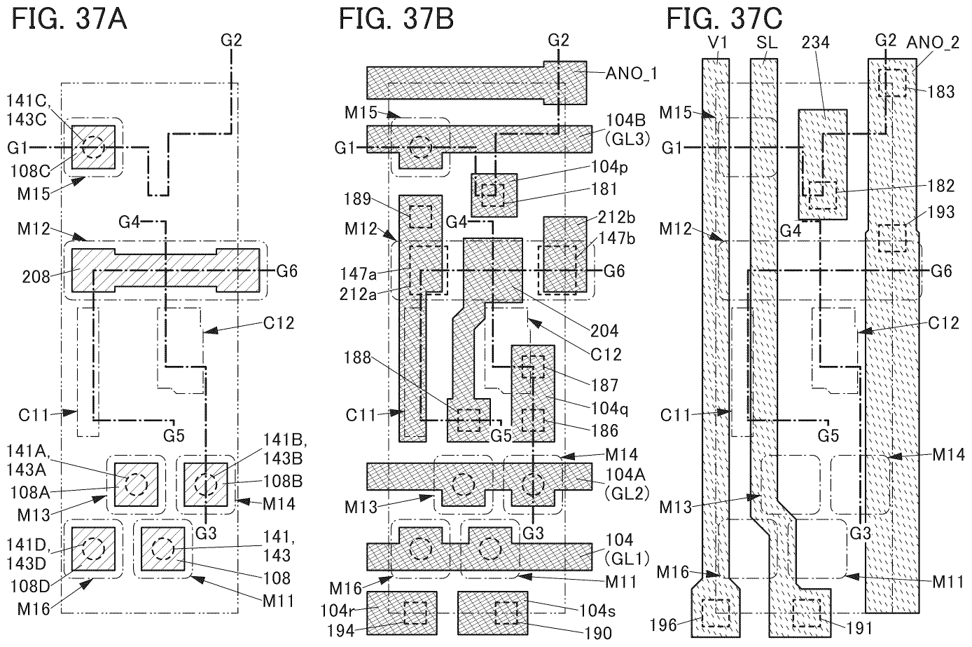

FIG. 37A is a top view of the semiconductor layer 108 and the semiconductor layer 208. FIG. 37A illustrates, in addition to the semiconductor layer 108 and the semiconductor layer 208, a semiconductor layer 108A, a semiconductor layer 108B, a semiconductor layer 108C, and a semiconductor layer 108D, which can be formed in the same step.

FIG. 37B is a top view of the conductive layer 104, the conductive layer 204, the conductive layer 212a, and the conductive layer 212b. FIG. 37B illustrates, in addition to the conductive layer 104, the conductive layer 204, the conductive layer 212a, and the conductive layer 212b, a conductive layer 104A, a conductive layer 104B, a conductive layer 104p, a conductive layer 104q, a conductive layer 104r, a conductive layer 104s, and a wiring ANO_1, which can be formed in the same step. The conductive layer 104 functions as the wiring GL1, the conductive layer 104A functions as the wiring GL2, and the conductive layer 104B functions as the wiring GL3. The conductive layer 104 (wiring GL1), the conductive layer 104A (wiring GL2), the conductive layer 104B (wiring GL3), and the wiring ANO_1 extend in the row direction.

FIG. 37C is a top view of the wiring V1, the wiring SL, and the wiring ANO_2. FIG. 37C illustrates, in addition to the wiring V1, the wiring SL, and the wiring ANO_2, the conductive layer 234, which can be formed in the same step. The wiring V1, the wiring SL, and the wiring ANO_2 extend in the column direction.

As illustrated in FIG. 34, the insulating layer 195 and the insulating layer 233 are provided over the wiring ANO_1. The insulating layer 195 and the insulating layer 233 include an opening 183 reaching the wiring ANO_1, and the wiring ANO_2 is provided to cover the opening 183. The wiring ANO_1 and the wiring ANO_2 are electrically connected to each other through the opening 183 and function as the wiring ANO.

The conductive layer 112a included in the transistor M11 is electrically connected to the wiring SL through the conductive layer 104s. The conductive layer 104s is electrically connected to the conductive layer 112a through the opening 190, the opening 143p, and the opening 141p. The opening 141p reaching the conductive layer 112a is provided in the insulating layer 110, and the conductive layer 112p including the opening 143p is provided over the insulating layer 110. The insulating layer 106 is provided over the conductive layer 112p, and the opening 190 is provided in a region of the insulating layer 106 overlapping with the opening 143p. The conductive layer 104s is provided to cover the opening 190, the opening 143p, and the opening 141p. The insulating layer 195 and the insulating layer 233 are provided over the conductive layer 104s, an opening 191 is provided in regions of the insulating layer 195 and the insulating layer 233 overlapping with the conductive layer 104s, and the wiring SL is provided to cover the opening 191.

The conductive layer 212a included in the transistor M12 is electrically connected to the conductive layer 112aA through an opening 189, the opening 143q, and the opening 141q. The opening 141q reaching the conductive layer 212a is provided in the insulating layer 110, and the conductive layer 112q including the opening 143q is provided over the insulating layer 110. The insulating layer 106 is provided over the conductive layer 112q, and the opening 189 is provided in a region of the insulating layer 106 overlapping with the opening 143q. The conductive layer 212a is provided to cover the opening 189, the opening 143q, and the opening 141q.

The transistor M13 includes the conductive layer 112aA, the conductive layer 112b, the semiconductor layer 108A, the insulating layer 106, and the conductive layer 104A. In the transistor M13, the conductive layer 112aA functions as one of the source electrode and the drain electrode, and the conductive layer 112b functions as the other of the source and the drain electrode. Part of the insulating layer 106 functions as a gate insulating layer, and the conductive layer 104A functions as a gate electrode. The conductive layer 112b functions as the other of the source electrode and the drain electrode of the transistor M11 and also functions as the other of the source electrode and the drain electrode of the transistor M13.

The conductive layer 112b and the insulating layer 110 include the opening 141A and the opening 143A in a region overlapping with the conductive layer 112aA. The semiconductor layer 108A is provided to cover the opening 143A and the opening 141A. The insulating layer 106 is provided over the semiconductor layer 108A, and the conductive layer 104A is provided over the insulating layer 106.

The transistor M14 includes the conductive layer 112aB, the conductive layer 112bA, the semiconductor layer 108B, the insulating layer 106, and the conductive layer 104A. In the transistor M14, the conductive layer 112bA functions as one of the source electrode and the drain electrode, and the conductive layer 112aB functions as the other. Part of the insulating layer 106 functions as a gate insulating layer, and the conductive layer 104A functions as a gate electrode. The conductive layer 104A functions as the gate electrode of the transistor M13 and also functions as the gate electrode of the transistor M14.

The conductive layer 112bA and the insulating layer 110 include the opening 141B and the opening 143B in a region overlapping with the conductive layer 112aB. The semiconductor layer 108B is provided to cover the opening 143B and the opening 141B. The insulating layer 106 is provided over the semiconductor layer 108B, and the conductive layer 104A is provided over the insulating layer 106.

The transistor M15 includes the conductive layer 112aA, the conductive layer 112bB, the semiconductor layer 108C, the insulating layer 106, and the conductive layer 104B. In the transistor M15, the conductive layer 112bB functions as one of the source electrode and the drain electrode, and the conductive layer 112aA functions as the other. Part of the insulating layer 106 functions as a gate insulating layer, and the conductive layer 104B serves as a gate electrode. The conductive layer 112aA functions as the one of the source electrode and the drain electrode of the transistor M13 and also functions as the other of the source electrode and the drain electrode of the transistor M15.

The conductive layer 112bB and the insulating layer 110 include the opening 143C and the opening 141C in a region overlapping with the conductive layer 112aA. The semiconductor layer 108C is provided to cover the opening 143C and the opening 141C. The insulating layer 106 is provided over the semiconductor layer 108C, and the conductive layer 104B is provided over the insulating layer 106.

As illustrated in FIG. 34, the conductive layer 112bB included in the transistor M15 is electrically connected to the pixel electrode 111 through the conductive layer 104p and the conductive layer 234. The insulating layer 106 includes an opening 181 reaching the conductive layer 112bB, and the conductive layer 104p is provided to cover the opening 181. The insulating layer 195 and the insulating layer 233 are provided over the conductive layer 104p. The insulating layer 195 and the insulating layer 233 include an opening 182 reaching the conductive layer 104p, and the conductive layer 234 is provided to cover the opening 182. The insulating layer 235 is provided over the conductive layer 234. The insulating layer 235 includes an opening 184 reaching the conductive layer 234, and the pixel electrode 111 is provided to cover the opening 184.

The transistor M16 includes the conductive layer 112aA, the conductive layer 112bC, the semiconductor layer 108D, the insulating layer 106, and the conductive layer 104. In the transistor M16, the conductive layer 112aA functions as one of the source electrode and the drain electrode, and the conductive layer 112bC functions as the other of the source and the drain electrode. Part of the insulating layer 106 functions as a gate insulating layer, and the conductive layer 104 functions as a gate electrode. The conductive layer 112aA functions as the one of the source electrode and the drain electrode of the transistor M13 and the other of the source electrode and the drain electrode of the transistor M15, and also functions as one of the source electrode and the drain electrode of the transistor M16. The conductive layer 104 functions as the gate electrode of the transistor M11 and also functions as the gate electrode of the transistor M16.

The conductive layer 112bC and the insulating layer 110 include the opening 143D and the opening 141D in a region overlapping with the conductive layer 112aA. The semiconductor layer 108D is provided to cover the opening 143D and the opening 141D. The insulating layer 106 is provided over the semiconductor layer 108D, and the conductive layer 104 is provided over the insulating layer 106.

As illustrated in FIG. 35A, the capacitor C12 includes the conductive layer 112aA, the conductive layer 202, the insulating layer 110 interposed between the conductive layer 112aA and the conductive layer 202, and the insulating layer 120 provided over the conductive layer 202.

The insulating layer 120 includes an opening 185 reaching the conductive layer 202, and the conductive layer 112bA is provided to cover the opening 185. There is no particular limitation on the top surface shape of the opening 185. The insulating layer 106 is provided over the conductive layer 112bA, and the conductive layer 104q is provided over the insulating layer 106. The conductive layer 104q is electrically connected to the conductive layer 112bA through an opening 186 and an opening 187 provided in the insulating layer 106. The conductive layer 104q can be formed in the same step as the conductive layer 104 and the conductive layer 204. For the conductive layer 104q, a material having lower electrical resistivity than the conductive layer 112bA is preferably used, for example. Accordingly, wiring resistance between the capacitor C12 and the transistor M14 can be reduced. Note that the conductive layer 104q is not necessarily Although a structure is illustrated where the conductive layer 112bA and the provided conductive layer 202 include a contact region and thus are electrically connected to each other, one embodiment of the present invention is not limited to this. A structure may be employed where the conductive layer 112bA and the conductive layer 202 include no contact region and are electrically connected to each other through the conductive layer 104q. Specifically, the conductive layer 104q may be provided to cover the opening 185 and the opening 187 while the conductive layer 112bA is not provided in the opening 185.

As illustrated in FIG. 35B, the capacitor C11 includes the conductive layer 112b, the conductive layer 212a, and the insulating layer 106 interposed between the conductive layer 112b and the conductive layer 212a.

The conductive layer 112a functioning as the other of the source electrode and the drain electrode of the transistor M11 is electrically connected to the wiring SL through the conductive layer 104s. The opening 190 reaching the conductive layer 112a is provided in the insulating layer 110 and the insulating layer 106, and the conductive layer 104s is provided to cover the opening 190. The insulating layer 195 and the insulating layer 233 are provided over the conductive layer 104s, the opening 191 reaching the conductive layer 104s is provided in the insulating layer 195 and the insulating layer 233, and the wiring SL is provided to cover the opening 191.

The conductive layer 212b functioning as the other of the source electrode and the drain electrode of the transistor M12 is electrically connected to the wiring ANO_2 through an opening 193. The opening 193 reaching the conductive layer 212b is provided in the insulating layer 195 and the insulating layer 233, and the wiring ANO_2 is provided to cover the opening 193.

The conductive layer 112bC functioning as the other of the source electrode and the drain electrode of the transistor M16 is electrically connected to the wiring V1 through the conductive layer 104r. An opening 194 reaching the conductive layer 112bC is provided in the insulating layer 106, and the conductive layer 104r is provided to cover the opening 194. The insulating layer 195 and the insulating layer 233 are provided over the conductive layer 104r, an opening 196 reaching the conductive layer 104r is provided in the insulating layer 195 and the insulating layer 233, and the wiring V1 is provided to cover the opening 196.

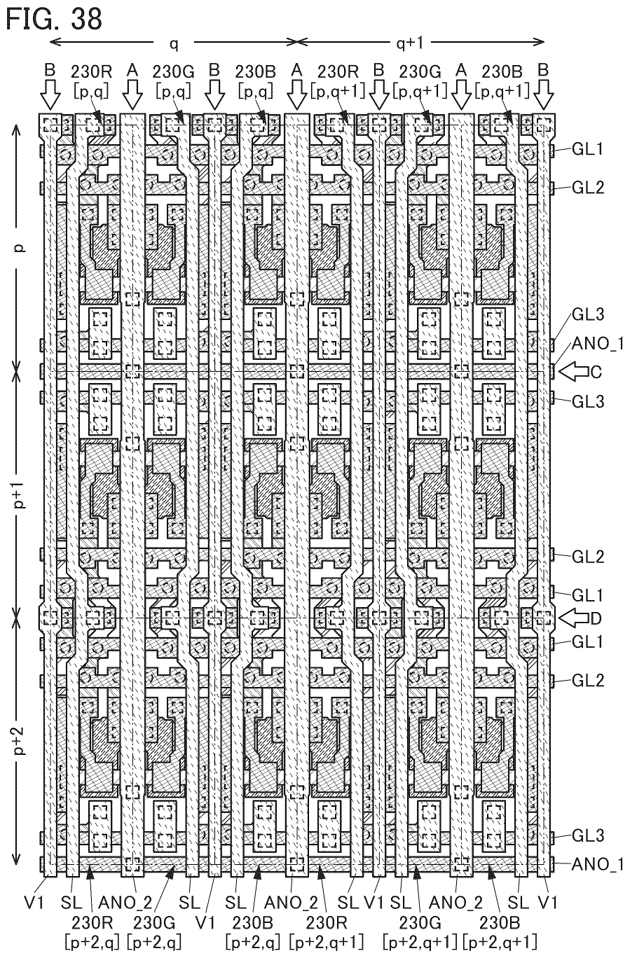

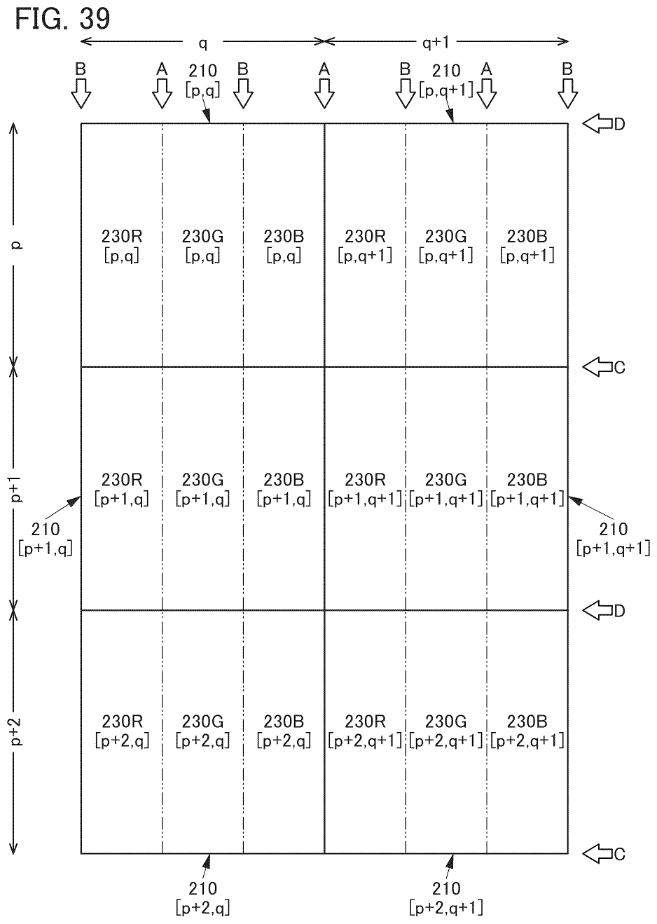

FIG. 38 illustrates a layout in which subpixels are arranged in three rows and six columns. FIG. 38 illustrates six pixels 230R (a pixel 230R[p,q] to a pixel 230R[p+2,q+1], where each of p and q is independently an integer greater than or equal to 2), six pixels 230G (a pixel 230G[p,q] to a pixel 230G[p+2,q+1]), and six pixels 230B (a pixel 230B [p,q] to a pixel 230B [p+2,q+1]), which function as subpixels, and these subpixels employ stripe arrangement. One pixel 230R, one pixel 230G, and one pixel 230B function as one pixel 210, and FIG. 38 illustrates the pixels 210 in three rows and two columns (a pixel 210 [p,q] to a pixel 210 [p+2,q+1]). FIG. 39 illustrates the arrangement of the pixels 230R, the pixels 230G, and the pixels 230B corresponding to FIG. 38. The pixel 230R, the pixel 230G, and the pixel 230B can employ the above-described layout of the pixel 230.

FIG. 38 illustrates a structure where the layouts of the adjacent pixels 230 are line-symmetric with the boundary therebetween as the axis. Specifically, the layouts of the pixel 230R[p,q], the pixel 230R[p+1,q], and the pixel 230R[p+2,q] provided in the same column and the layouts of the pixel 230G[p,q], the pixel 230G[p+1,q], and the pixel 230G[p+2,q] provided in the adjacent column are line-symmetric with the boundary between these columns as the axis (see an arrow A in FIG. 38). Similarly, the layouts of the pixel 230G[p,q], the pixel 230G[p+1,q], and the pixel 230G[p+2,q] and the layouts of the pixel 230B [p,q], the pixel 230B [p+1,q], and the pixel 230B [p+2,q] provided in the adjacent column are line-symmetric with the boundary between these columns as the axis (see an arrow B in FIG. 38). Hereinafter, the detailed descriptions are omitted to avoid repetition of similar descriptions.

The layouts of the pixel 230R[p,q], the pixel 230G[p,q], the pixel 230B [p,q], the pixel 230R[p,q+1], the pixel 230G[p,q+1], and the pixel 230B [p,q+1] provided in the same row are line-symmetric with respect to the layouts of the pixel 230R[p+1,q], the pixel 230G[p+1,q], the pixel 230B [p+1,q], the pixel 230R[p+1,q+1], the pixel 230G[p+1,q+1], and the pixel 230B [p+1,q+1] provided in the adjacent row with the boundary between these rows as the axis (see an arrow C in FIG. 38). Similarly, the layouts of the pixel 230R[p+1,q], the pixel 230G[p+1,q], the pixel 230B [p+1,q], the pixel 230R[p+1,q+1], the pixel 230G[p+1,q+1], and the pixel 230B [p+1,q+1] are line-symmetric with respect to the layouts of the pixel 230R[p+2,q], the pixel 230G[p+2,q], the pixel 230B [p+2,q], the pixel 230R[p+2,q+1], the pixel 230G[p+2,q+1], and the pixel 230B [p+2,q+1] provided in the adjacent row with the boundary between these rows as the axis (see an arrow D in FIG. 38). Hereinafter, the detailed descriptions are omitted to avoid repetition of similar descriptions.

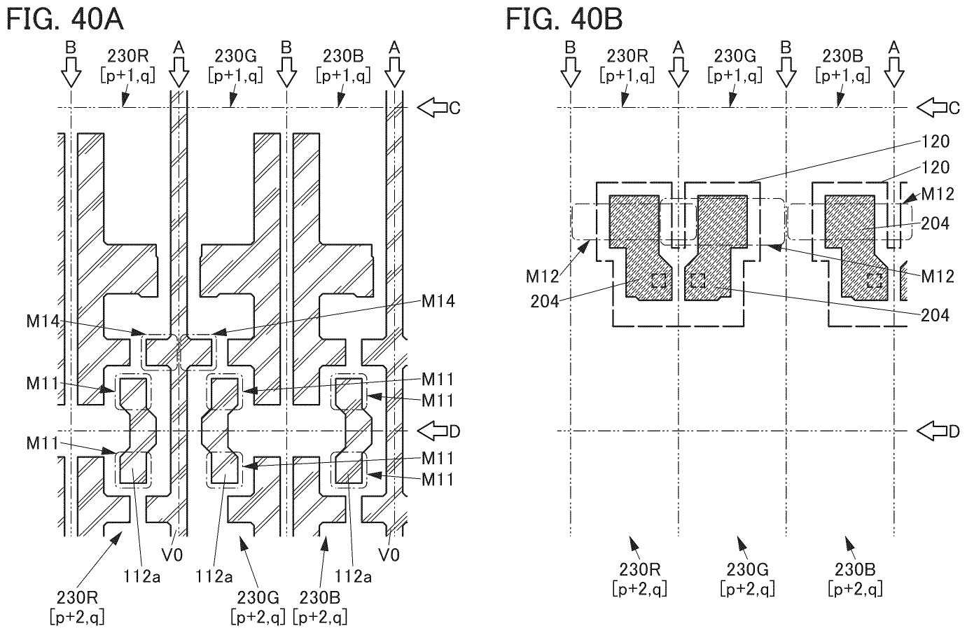

The pixel 230 shares a wiring and the like with the adjacent pixel 230. FIG. 40A to FIG. 42B are enlarged views of the pixel 230R[p+1,q], the pixel 230G[p+1,q], the pixel 230B [p+1,q], and the vicinity thereof.

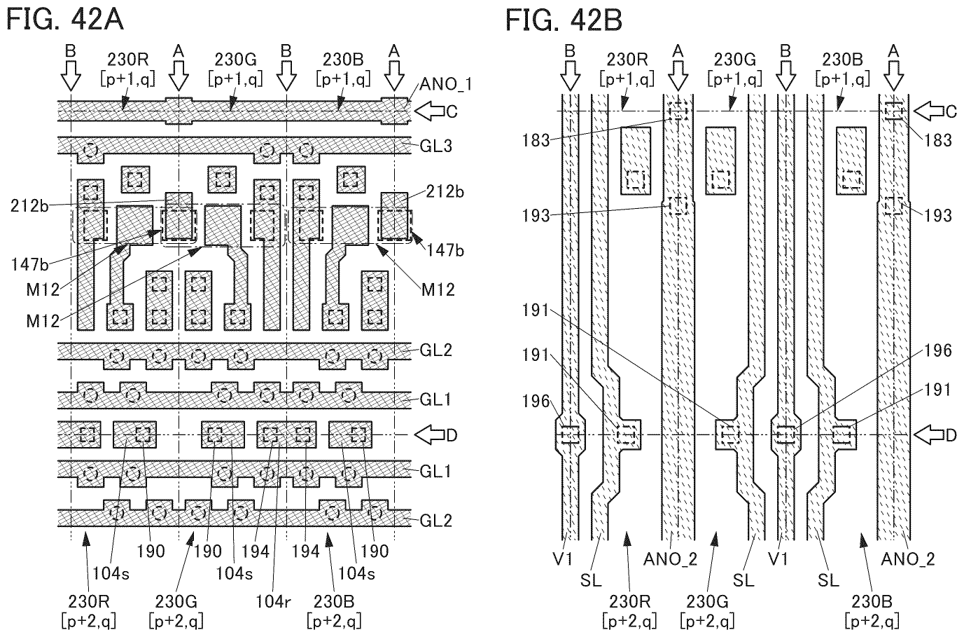

The pixels 230 provided in the same column share the wiring ANO_2 and the wiring V0 with the pixels 230 provided in the adjacent column. In addition, the pixel 230 shares the opening 183 and the opening 193 with the pixel 230 provided in the adjacent column. Specifically, the pixel 230R[p+1,q] and the pixel 230R[p+2,q] provided in the same column share the wiring ANO_2 and the wiring V0 with the pixel 230G[p+1,q] and the pixel 230G[p+2,q] provided in the adjacent column (see the arrow A in FIG. 40A and FIG. 42B). Similarly, the pixel 230R[p+1,q] shares the opening 183 and the opening 193 with the pixel 230G[p+1,q] provided in the adjacent column (see the arrow A in FIG. 40A and FIG. 42B).

The pixels 230 provided in the same column share the wiring V1 with the pixels 230 provided in the adjacent column. Specifically, the pixel 230G[p+1,q] and the pixel 230G[p+2,q] provided in the same column share the wiring V1 with the pixel 230B [p+1,q] and the pixel 230B [p+2,q] provided in the adjacent column (see the arrow B in FIG. 42B). The wiring ANO_2 and the wiring V0 shared by the pixels 230 and the wiring V1 shared by other pixels 230 are alternately provided (see the arrow A and the arrow B in FIG. 38 and FIG. 42B).

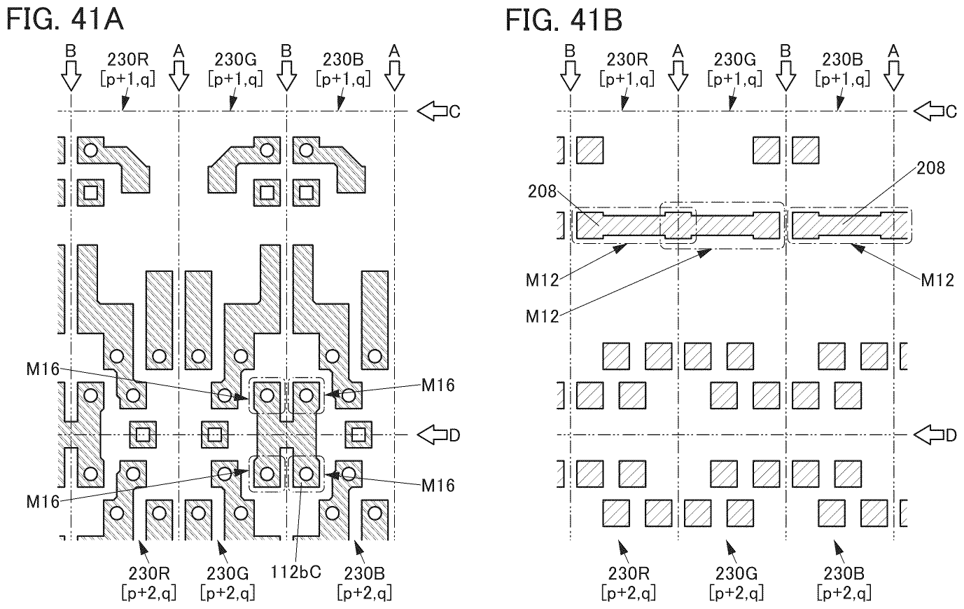

The wiring V0 corresponds to the conductive layer 112aB illustrated in FIG. 36A and the like. It can be said that the pixels 230 provided in the same column share the conductive layer 112aB (wiring V0) included in the transistor M14 with the pixels 230 provided in the adjacent column (see the arrow A in FIG. 40A). In addition, the pixel 230 shares the semiconductor layer 208, the conductive layer 212b, and the opening 147b included in the transistor M12 with the pixel 230 provided in the adjacent column (see the arrow A in FIG. 41B and FIG. 42A). Furthermore, the pixel 230 may share the insulating layer 120 with the pixel 230 provided in the adjacent column. FIG. 40B illustrates an example where the pixel 230R[p+1,q] shares the insulating layer 120 with the pixel 230G[p+1,q] provided in the adjacent column (see the arrow A in FIG. 40B). The insulating layer 120 is provided to encompass the conductive layer 204 provided in the pixel 230R[p+1,q] and the conductive layer 204 provided in the pixel 230G[p+1,q]. The insulating layer 120 is provided in contact with the top surface and the side surface of the conductive layer 204 provided in the pixel 230R[p+1,q] and the top surface and the side surface of the conductive layer 204 provided in the pixel 230G[p+1,q]. Note that the insulating layer 120 is not necessarily shared by the adjacent pixels 230.

The pixels 230 provided in the same row share the wiring ANO_1 with the pixels 230 provided in the adjacent row. Specifically, the pixel 230R[p,q], the pixel 230G[p,q], the pixel 230B [p,q], the pixel 230R[p,q+1], the pixel 230G[p,q+1], and the pixel 230B [p,q+1] provided in the same row share the wiring ANO_1 with the pixel 230R[p+1,q], the pixel 230G[p+1,q], the pixel 230B [p+1,q], the pixel 230R[p+1,q+1], the pixel 230G[p+1,q+1], and the pixel 230B [p+1,q+1] provided in the adjacent row (see the arrow C in FIG. 42A).

The pixel 230 shares the conductive layer 112a, the conductive layer 104s, the opening 190, the opening 194, and the opening 191 included in the transistor M11 with the pixel 230 provided in the adjacent row (see the arrow D in FIG. 40A, FIG. 42A, and FIG. 42B).

The pixels 230 in adjacent two rows and two columns share the conductive layer 104r, the opening 196, and the conductive layer 112bC included in the transistor M16. Specifically, the pixel 230G[p+1,q], the pixel 230G[p+2,q], the pixel 230B [p+1,q], and the pixel 230B [p+2,q] share the conductive layer 104r and the conductive layer 112bC (see the arrow B and the arrow D in FIG. 41A, FIG. 42A, and FIG. 42B).

When components are shared by adjacent pixels, the area occupied by the pixel circuit can be reduced, so that a high-resolution display apparatus can be obtained. Although the structure where components are shared by adjacent pixels is described here, one embodiment of the present invention is not limited thereto. The components are not necessarily shared by adjacent pixels.

Structure examples different from that of the above-described display apparatus will be described.

### <Structure Example 1 of Display Apparatus>

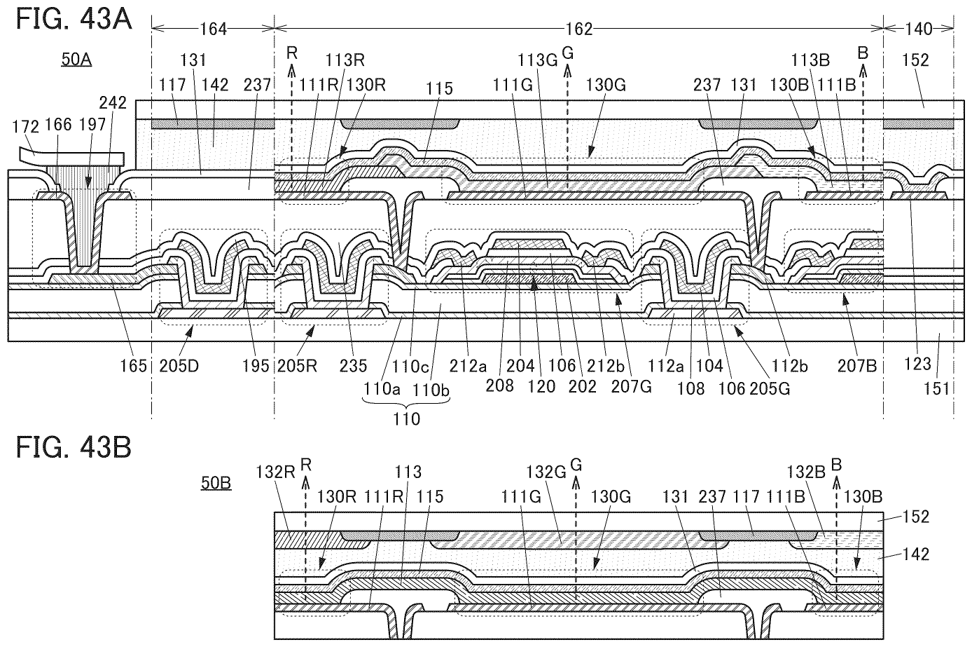

FIG. 43A illustrates an example of cross sections of part of a region including the FPC 172, part of the circuit portion 164, part of the display portion 162, part of the connection portion 140, and part of a region including an end portion of the display apparatus 50A.

The display apparatus 50A illustrated in FIG. 43A includes a transistor 205D, a transistor 205R, a transistor 205G, a transistor 207G, a transistor 207B, a light-emitting element 130R, a light-emitting element 130G, a light-emitting element 130B, and the like between the substrate 151 and the substrate 152. The light-emitting element 130R is a display element included in the pixel 230R emitting red light, the light-emitting element 130G is a display element included in the pixel 230G emitting green light, and the light-emitting element 130B is a display element included in the pixel 230B emitting blue light.

The display apparatus 50A employs an SBS structure. The SBS structure can optimize materials and structures of light-emitting elements and thus can increase the degree of freedom in selecting materials and structures, so that the luminance and the reliability can be easily improved.

The display apparatus 50A has a top-emission structure. The aperture ratio of pixels in a top-emission structure can be higher than that of pixels in a bottom-emission structure because a transistor and the like can be placed to overlap with a light-emitting region of a light-emitting element in the top-emission structure.

All of the transistor 205D, the transistor 205R, the transistor 205G, the transistor 207G, and the transistor 207B are formed over the substrate 151. Some of the formation steps can be common between these transistors.

One or more types of transistors among the transistor 100 to the transistor 100D and the transistor 200 to the transistor 200B described above can be used as one or more of the transistor 205D, the transistor 205R, the transistor 205G, the transistor 207G, and the transistor 207B. FIG. 43A illustrates a structure example where the above-described transistor 100 is used as each of the transistor 205D, the transistor 205R, and the transistor 205G and the above-described transistor 200 is used as each of the transistor 207G and the transistor 207B.

When one or more types of transistors among the transistor 100 to the transistor 100D described above are used as the transistor provided in the display portion 162, a high-resolution display apparatus can be obtained. One or more types of transistors among the transistor 200 to the transistor 200B with favorable saturation characteristics can be suitably used as the driving transistors of the light-emitting element 130R, the light-emitting element 130G, and the light-emitting element 130B. In that case, a highly reliable display apparatus can be obtained.

When one or more types of transistors among the transistor 100 to the transistor 100D described above are used in the circuit portion 164, the display apparatus can operate at high speed. The transistor provided in the circuit portion 164 is sometimes required to have a higher on-state current than the transistor provided in the display portion 162. A transistor having a short channel length is preferably used in the circuit portion 164. For example, one or more types of transistors among the transistor 100 to the transistor 100D described above can be suitably used in the circuit portion 164. When one or more types of transistors among the transistor 100 to the transistor 100D are used in the circuit portion 164, the occupied area can be reduced, so that the display apparatus can have a narrow bezel. Note that one or more types of transistors among the transistor 200 to the transistor 200B may be used in the circuit portion 164.

Note that the transistor included in the display apparatus of this embodiment is not limited to the transistor included in the semiconductor device of one embodiment of the present invention. For example, the display apparatus of this embodiment may include the transistor included in the semiconductor device of one embodiment of the present invention and a transistor having another structure in combination. The display apparatus of this embodiment may include any one or more of a planar transistor, a staggered transistor, and an inverted staggered transistor. A transistor included in the display apparatus of this embodiment may have either a top-gate structure or a bottom-gate structure. Alternatively, gates may be provided above and below the semiconductor layer where a channel is formed.

An OS transistor can be suitably used as each of the transistor 205D, the transistor 205R, the transistor 205G, the transistor 207G, and the transistor 207B.

A Si transistor may be included in the display apparatus of this embodiment.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of a light-emitting element vary, for example. In other words, when the OS transistor operates in the saturation region, the source-drain current hardly changes with a change in the source-drain voltage; hence, the emission luminance of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. A structure where an LTPS transistor and an OS transistor are used in combination is referred to as LTPO in some cases. As a more suitable example, a structure where the OS transistor is used as a transistor or the like functioning as a switch for controlling electrical continuity and discontinuity between wirings, and the LTPS transistor is used as a transistor or the like for controlling current, can be given.

For example, one of the transistors included in the display portion 162 functions as a transistor for controlling current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

The insulating layer 195 is provided to cover the transistor 205D, the transistor 205R, the transistor 205G, the transistor 207G, and the transistor 207B, and the insulating layer 235 is provided over the insulating layer 195.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 43A emits red light (R). The EL layer 113R includes a light-emitting layer emitting red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 43A emits green light (G). The EL layer 113G includes a light-emitting layer emitting green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 43A emits blue light (B). The EL layer 113B includes a light-emitting layer emitting blue light.

Although the EL layers 113R, 113G, and 113B have the same thickness in FIG. 43A, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 195, and the insulating layer 235. Similarly, the pixel electrode 111G is electrically connected to the conductive layer 112b included in the transistor 205G, and the pixel electrode 111B is electrically connected to the conductive layer 112b included in the transistor 205B (not illustrated).

End portions of the pixel electrodes 111R, 111G, and 111B are covered with an insulating layer 237. The insulating layer 237 functions as a partition. The insulating layer 237 can be provided to have a single-layer structure or a stacked-layer structure using one or both of an inorganic insulating material and an organic insulating material. A material that can be used for the insulating layer 195 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display apparatus 50A.

The common electrode 115 is a continuous film provided to be shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material in the same step as the pixel electrodes 111R, 111G, and 111B.

In the display apparatus of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted from the EL layer may be reflected by the reflective layer to be extracted from the display apparatus.

As a material forming the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 43A, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 43A; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display apparatus.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance emitting near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected to form an exciplex emitting light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance with a high hole-injection property (a hole-injection layer), a layer containing a hole-transport material (a hole-transport layer), a layer containing a substance with a high electron-blocking property (an electron-blocking layer), a layer containing a substance with a high electron-injection property (an electron-injection layer), a layer containing an electron-transport material (an electron-transport layer), and a layer containing a substance with a high hole-blocking property (a hole-blocking layer). The EL layer may further contain one or both of a bipolar substance and a TADF material.

Either a low molecular compound or a high molecular compound can be used for the light-emitting element, and an inorganic compound may also be included. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of high-luminance light emission. Furthermore, the amount of current needed for obtaining a predetermined luminance can be smaller in a tandem structure than in a single structure; thus, a tandem structure enables higher reliability. The tandem structure may be referred to as a stack structure.

In the case of using a light-emitting element having a tandem structure in FIG. 43A, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting elements 130R, 130G, and 130B. The protective layer 131 and the substrate 152 are bonded to each other with an adhesive layer 142 therebetween. The substrate 152 is provided with a light-blocking layer 117. For example, a solid sealing structure or a hollow sealing structure can be employed to seal the light-emitting elements. In FIG. 43A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is further preferable that the protective layer 131 be provided to extend to the end portion of the display apparatus 50A. Meanwhile, a connection portion 197 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display apparatus can be improved.

An inorganic insulating film can be used as the protective layer 131. Examples of a material that can be used for the inorganic insulating film include an oxide, a nitride, an oxynitride, and a nitride oxide. Specific examples of these inorganic insulating films are as described above. In particular, the protective layer 131 preferably includes a nitride or a nitride oxide, and further preferably includes a nitride.

An inorganic film containing ITO, In—Zn oxide, Ga—Zn oxide, Al—Zn oxide, IGZO, or the like can also be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) to the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. In this example, the conductive layer 165 has a single-layer structure of a conductive layer obtained by processing the same conductive film as the conductive layer 112b. An example where the conductive layer 166 is a single conductive layer obtained by processing the same conductive film as the pixel electrodes 111R, 111G, and 111B is shown. On the top surface of the connection portion 197, the conductive layer 166 is exposed. Thus, the connection portion 197 and the FPC 172 can be electrically connected to each other through the connection layer 242.

The display apparatus 50A has a top-emission structure. Light emitted from the light-emitting element is emitted to the substrate 152 side. For the substrate 152, a material having a high visible-light-transmitting property is preferably used. The pixel electrodes 111R, 111G, and 111B include a material reflecting visible light, and the counter electrode (the common electrode 115) includes a material transmitting visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of a scratch can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material transmitting the light is used. When the substrate 151 and the substrate 152 are formed using a flexible material, the flexibility of the display apparatus can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

### <Structure Example 2 of Display Apparatus>

FIG. 43B illustrates an example of a cross section of the display portion 162 of a display apparatus 50B. The display apparatus 50B is different from the display apparatus 50A mainly in that the subpixels of different colors include respective coloring layers (color filters or the like) and the light-emitting elements sharing the EL layer 113. The structure illustrated in FIG. 43B can be combined with the structure illustrated in FIG. 43A of the region including the FPC 172, the circuit portion 164, the stacked-layer structure from the substrate 151 to the insulating layer 235 in the display portion 162, the connection portion 140, and the end portion. As for the following description of the display apparatus, description of portions similar to those of the above-described display apparatus is omitted in some cases.

The display apparatus 50B illustrated in FIG. 43B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display apparatus 50B through the coloring layer 132B.

The EL layer 113 and the common electrode 115 are shared by the light-emitting elements 130R, 130G, and 130B. The number of manufacturing steps can be smaller in the structure where the EL layer 113 is provided to be shared by the subpixels of different colors than in the structure where the subpixels of different colors are provided with different EL layers.

The light-emitting elements 130R, 130G, and 130B illustrated in FIG. 43B emit white light, for example. When white light emitted from the light-emitting elements 130R, 130G, and 130B passes through the coloring layers 132R, 132G, and 132B, light of desired colors can be obtained.

The light-emitting element emitting white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light with a longer wavelength than blue light, for example. The EL layer 113 preferably includes a light-emitting layer emitting yellow light and a light-emitting layer emitting blue light, for example. Alternatively, the EL layer 113 preferably includes a light-emitting layer emitting red light, a light-emitting layer emitting green light, and a light-emitting layer emitting blue light, for example.

A light-emitting element emitting white light preferably has a tandem structure. Specifically, examples of applicable structures are as follows: a two-unit tandem structure including a light-emitting unit emitting yellow light and a light-emitting unit emitting blue light; a two-unit tandem structure including a light-emitting unit emitting red light and green light and a light-emitting unit emitting blue light; a three-unit tandem structure where a light-emitting unit emitting blue light, a light-emitting unit emitting yellow light, yellow-green light, or green light, and a light-emitting unit emitting blue light are stacked in this order; and a three-unit tandem structure where a light-emitting unit emitting blue light, a light-emitting unit emitting yellow light, yellow-green light, or green light and red light, and a light-emitting unit emitting blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength such as red, green, or blue is sometimes intensified and emitted.

Alternatively, the light-emitting elements 130R, 130G, and 130B illustrated in FIG. 43B emit blue light, for example. In this case, the EL layer 113 includes one or more light-emitting layers emitting blue light. In the pixel 230B emitting blue light, blue light emitted from the light-emitting element 130B can be extracted. In each of the pixel 230R emitting red light and the pixel 230G emitting green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element passes through the color conversion layer without being converted. When light passing through the color conversion layer is extracted through the coloring layer, light other than light of the desired color can be absorbed by the coloring layer, and color purity of light exhibited by the subpixel can be improved.

### <Structure Example 3 of Display Apparatus>

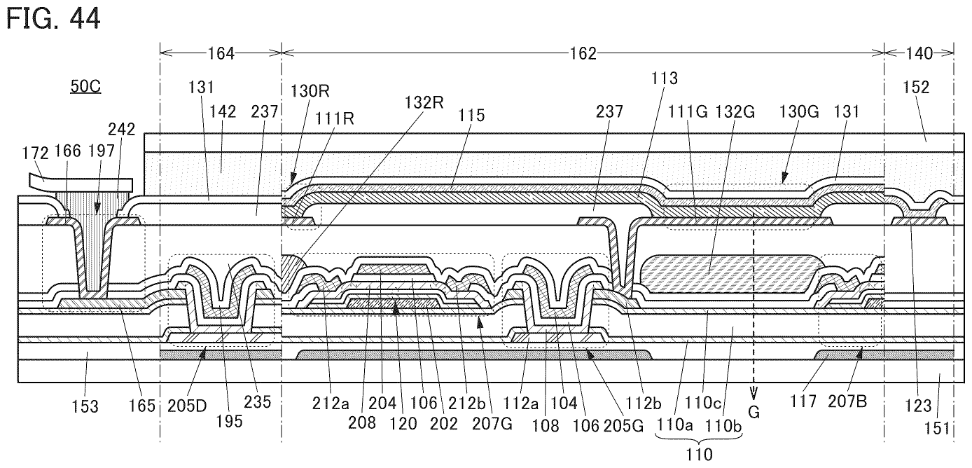

A display apparatus 50C illustrated in FIG. 44 is different from the display apparatus 50B mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 44 illustrates an example where the light-blocking layers 117 are provided over the substrate 151, an insulating layer 153 is provided over the light-blocking layers 117, and the transistor 205D, the transistor 205R (not illustrated), the transistor 205G, the transistor 207G, and the transistor 207B and the like are provided over the insulating layer 153. In addition, the coloring layer 132R and the coloring layer 132G are provided over the insulating layer 195, and the insulating layer 195 is provided over the coloring layer 132R and the coloring layer 132G.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material reflecting visible light is preferably used for the common electrode 115. In the display apparatus having a bottom-emission structure, a metal or the like having low electric resistivity can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display apparatus having a bottom-emission structure.

### <Structure Example 4 of Display Apparatus>

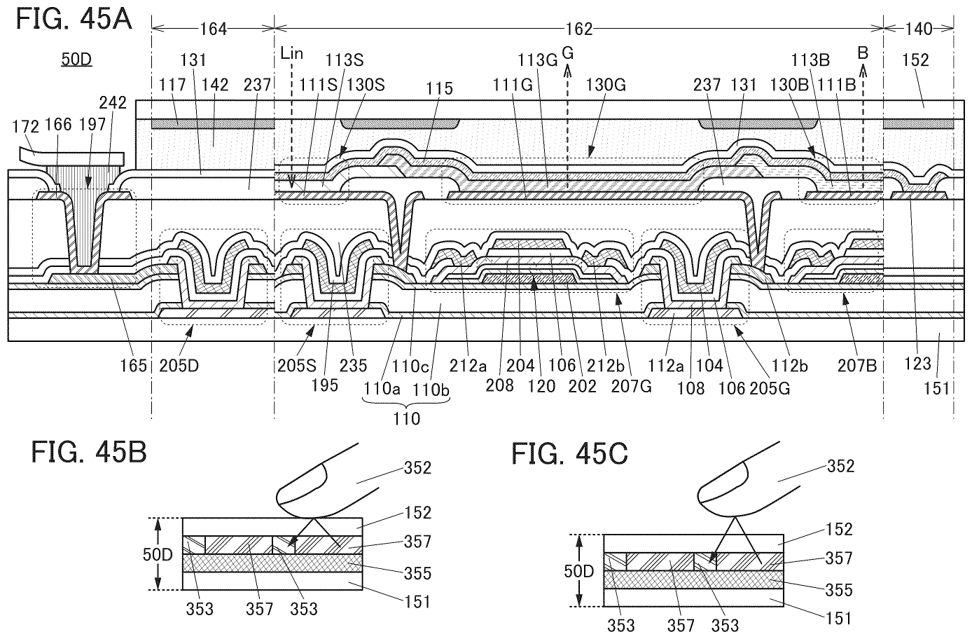

A display apparatus 50D illustrated in FIG. 45A is different from the display apparatus 50A mainly in including a light-receiving element 130S.

The display apparatus 50D includes light-emitting elements and a light-receiving element in a pixel. In the display apparatus 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in a display apparatus including the organic EL elements.

In the display apparatus 50D including light-emitting elements and a light-receiving element in each pixel, the pixel has a light-receiving function; thus, a contact or approach of an object can be detected while an image is displayed. Accordingly, the display portion 162 has one or both of an image capturing function and a sensing function in addition to an image displaying function. For example, all the subpixels included in the display apparatus 50D can display an image; alternatively, some of the subpixels can emit light as a light source, some of the rest of the subpixels can detect light, and the other subpixels can display an image.

Accordingly, a light-receiving portion and a light source do not need to be provided separately from the display apparatus 50D; hence, the number of components of an electronic device can be reduced. For example, a biometric authentication device provided in the electronic device, a capacitive touch panel for scroll operation, or the like is not necessarily provided separately. Thus, with the use of the display apparatus 50D, the electronic device can be provided at lower manufacturing cost.

When the light-receiving elements are used as an image sensor, the display apparatus 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display apparatus and the object come in direct contact with each other.

Furthermore, the contactless sensor can detect an object even when the object is not in contact with the display apparatus.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display apparatus 50D.

The pixel electrode 111S is electrically connected to the conductive layer 112b included in a transistor 205S through an opening provided in the insulating layer 106, the insulating layer 195, and the insulating layer 235.

An end portion of the pixel electrode 111S is covered with the insulating layer 237.

The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer containing a substance with a high hole-transport property, a substance with a high electron-transport property, a substance with a bipolar property, or the like. Without limitation to the above, the functional layer 113S may further include a layer containing a substance with a high hole-injection property, a hole-blocking material, a substance with a high electron-injection property, an electron-blocking material, or the like. The functional layer 113S can be formed using a material that can be used for the light-emitting element.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

In the display apparatus 50D illustrated in FIG. 45B and FIG. 45C, a layer 353 including a light-receiving element, a circuit layer 355, and a layer 357 including a light-emitting element are provided between the substrate 151 and the substrate 152.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. One or more of a switch, a capacitor, a resistor, a wiring, a terminal, and the like can be provided in the circuit layer 355.

FIG. 45B illustrates an example where the light-receiving element 130S is used as a touch sensor. Light emitted from the light-emitting element in the layer 357 is reflected by a finger 352 that touches the display apparatus 50D as illustrated in FIG. 45B, and the light-receiving element in the layer 353 detects the reflected light. Thus, the touch of the finger 352 on the display apparatus 50D can be detected.

FIG. 45C illustrates an example where the light-receiving element 130S is used as a contactless sensor. Light emitted from the light-emitting element in the layer 357 is reflected by the finger 352 that is close to (i.e., that does not touch) the display apparatus 50D as illustrated in FIG. 45C, and the light-receiving element in the layer 353 detects the reflected light.

### <Structure Example 5 of Light-Emitting Apparatus>

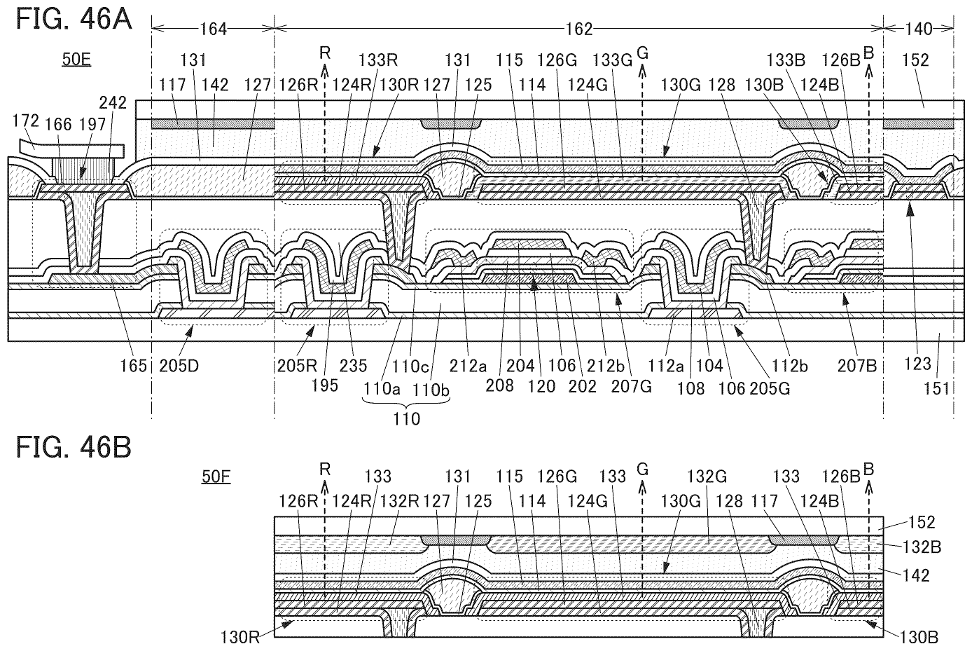

A display apparatus 50E illustrated in FIG. 46A is an example of a display apparatus having an MML (metal maskless) structure. In other words, the display apparatus 50E includes a light-emitting element that is formed without using a fine metal mask. The stacked-layer structure from the substrate 151 to the insulating layer 235 and the stacked-layer structure from the protective layer 131 to the substrate 152 are similar to those in the display apparatus 50A; thus, the description thereof is omitted.

In FIG. 46A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 46A emits red light (R). The layer 133R includes a light-emitting layer emitting red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 46A emits green light (G). The layer 133G includes a light-emitting layer emitting green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 46A emits blue light (B). The layer 133B includes a light-emitting layer emitting blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. In this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, a leakage current between adjacent light-emitting elements can be inhibited. This can prevent unintended light emission due to crosstalk, so that a display apparatus with extremely high contrast can be obtained.

Although the layers 133R, 133G, and 133B have the same thickness in FIG. 46A, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 195, and the insulating layer 235. Similarly, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 46A illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layers 126G are covered with the layer 133G, and the top surface and the side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, and the layer 133B and the insulating layers 125 and 127, and the common electrode 115 is provided over the common layer 114. The common layer 114 and the common electrode 115 are each a continuous film provided to be shared by a plurality of light-emitting elements.

In FIG. 46A, the insulating layer 237 illustrated in FIG. 43A or the like is not provided between the conductive layer 126R and the layer 133R. That is, an insulating layer (also referred to as a partition wall, a bank, a spacer, or the like) in contact with the pixel electrode and covering an end portion of the top surface of the pixel electrode is not provided in the display apparatus 50E. Thus, the distance between adjacent light-emitting elements can be extremely short. Accordingly, the display apparatus can have high resolution or high definition. In addition, a mask (e.g., a photomask) for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby unevenness with a large level difference on the formation surface of the layers (e.g., the carrier-injection layer and the common electrode) provided over the island-shaped layers can be reduced and higher flatness can be obtained. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to the step can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

An inorganic insulating film can be used for the insulating layer 125. Examples of a material that can be used for the inorganic insulating film include an oxide, a nitride, an oxynitride, and a nitride oxide. Specific examples of these inorganic insulating films are as described above.

The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that may be diffused into the light-emitting elements from the outside can be inhibited. With this structure, a highly reliable light-emitting element and a highly reliable display apparatus can be provided.

The insulating layer 125 preferably has a low impurity concentration. Accordingly, deterioration of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of reducing unevenness with a large level difference on the insulating layer 125 formed between the adjacent light-emitting elements. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite including an acrylic resin is preferably used. In this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### <Structure Example 6 of Display Apparatus>

FIG. 46B illustrates an example of a cross section of the display portion 162 of a display apparatus 50F. The display apparatus 50F is different from the display apparatus 50E mainly in that the subpixels of different colors are provided with coloring layers (color filters or the like). The structure illustrated in FIG. 46B can be combined with the structure of the region including the FPC 172, the circuit portion 164, the stacked-layer structure from the substrate 151 to the insulating layer 235 in the display portion 162, the connection portion 140, and the end portion, which is illustrated in FIG. 46A.

In the display apparatus 50F illustrated in FIG. 46B, the light-emitting elements 130R, 130G, and 130B, the coloring layer 132R transmitting red light, the coloring layer 132G transmitting green light, the coloring layer 132B transmitting blue light, and the like are provided.

Light emitted from the light-emitting element 130R is extracted as red light to the outside of the display apparatus 50F through the coloring layer 132R. Similarly, light emitted from the light-emitting element 130G is extracted as green light to the outside of the display apparatus 50F through the coloring layer 132G. Light emitted from the light-emitting element 130B is extracted as blue light to the outside of the display apparatus 50F through the coloring layer 132B.

The light-emitting elements 130R, 130G, and 130B each include the layer 133. These three layers 133 are formed using the same material in the same step. The three layers 133 are separated from each other. When the EL layer is provided to have an island shape for each light-emitting element, a leakage current between adjacent light-emitting elements can be inhibited. This can prevent unintended light emission due to crosstalk, so that a display apparatus with extremely high contrast can be obtained.

The light-emitting elements 130R, 130G, and 130B illustrated in FIG. 46B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 46B emit blue light, for example. In this case, the layer 133 includes one or more light-emitting layers emitting blue light. In the pixel 230B emitting blue light, blue light emitted from the light-emitting element 130B can be extracted. In each of the pixel 230R emitting red light and the pixel 230G emitting green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light passing through the color conversion layer is extracted through the coloring layer, light other than light of the desired color can be absorbed by the coloring layer, and color purity of light exhibited by the subpixel can be improved.

### <Structure Example 7 of Display Apparatus>

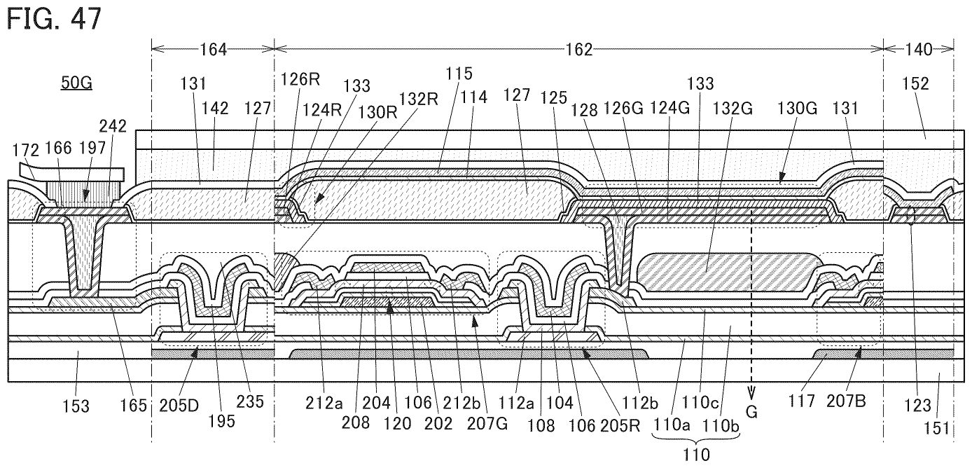

A display apparatus 50G illustrated in FIG. 47 is different from the display apparatus 50F mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 47 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 195 and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material reflecting visible light is preferably used for the common electrode 115. In the display apparatus having a bottom-emission structure, a metal or the like having low electric resistivity can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display apparatus having a bottom-emission structure.

### <Structure Example 8 of Display Apparatus>

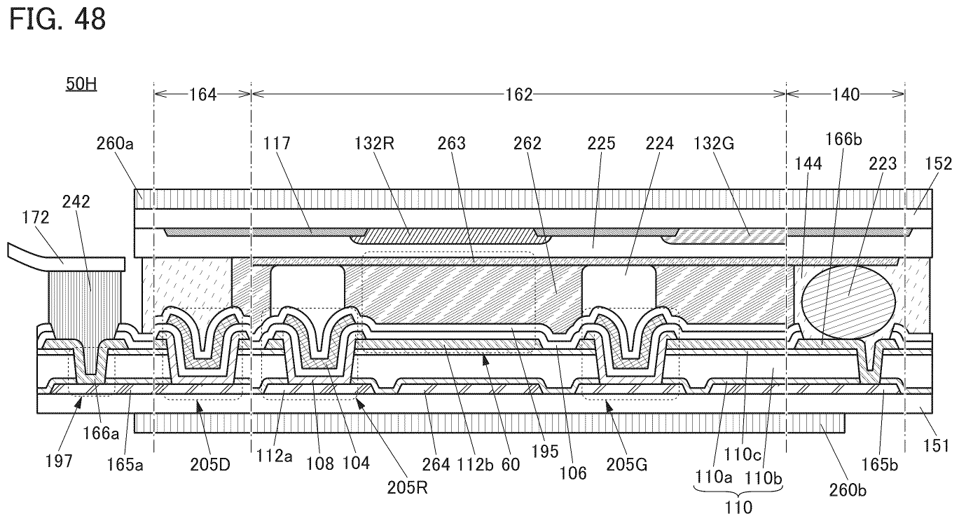

A display apparatus 50H illustrated in FIG. 48 is a liquid crystal display apparatus in a VA mode.

The substrate 151 and the substrate 152 are attached to each other with an adhesive layer 144. A liquid crystal 262 is encapsulated in a region surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or outside the polarizing plate 260b.

The substrate 151 is provided with the transistors 205D, 205R, and 205G, the connection portion 197, a spacer 224, and the like. The transistor 205D is provided in the circuit portion 164, and the transistor 205R and the transistor 205G are provided in the display portion 162. The conductive layers 112b included in the transistor 205R and the transistor 205G each function as a pixel electrode of a liquid crystal element 60.

The substrate 152 is provided with the coloring layer 132R, the coloring layer 132G, the light-blocking layer 117, an insulating layer 225, a conductive layer 263, and the like. The conductive layer 263 functions as a common electrode of the liquid crystal element 60.

The transistors 205D, 205R, and 205G each include the conductive layer 112a, the semiconductor layer 108, the insulating layer 106, the conductive layer 104, and the conductive layer 112b. The conductive layer 112a functions as one of a source electrode and a drain electrode and the conductive layer 112b functions as the other of the source electrode and the drain electrode. The conductive layer 104 functions as a gate electrode. Part of the insulating layer 106 functions as a gate insulating layer.

As described above, this embodiment describes an example where an OS transistor is used as each of the transistors 205D, 205R, and 205G. The transistor of one embodiment of the present invention can be used as each of the transistors 205D, 205R, and 205G. In other words, the display apparatus 50H includes the transistor of one embodiment of the present invention in both the display portion 162 and the circuit portion 164. When the transistor of one embodiment of the present invention is used in the display portion 162, the pixel size can be reduced and high resolution can be achieved. When the transistor of one embodiment of the present invention is used in the circuit portion 164, the area occupied by the circuit portion 164 can be reduced and a narrower bezel can be achieved. The description in the above embodiment can be referred to for the transistor of one embodiment of the present invention.

The transistors 205D, 205R, and 205G are covered with the insulating layer 195. The insulating layer 195 functions as a protective layer of the transistors 205D, 205R, and 205G.

A subpixel included in the display portion 162 includes a transistor, the liquid crystal element 60, and a coloring layer. For example, a subpixel emitting red light includes the transistor 205R, the liquid crystal element 60, and the coloring layer 132R transmitting red light. A subpixel emitting green light includes the transistor 205G, the liquid crystal element 60, and the coloring layer 132G transmitting green light. Similarly, although not illustrated, a subpixel emitting blue light includes a transistor, the liquid crystal element 60, and a coloring layer transmitting blue light.

The liquid crystal element 60 includes the conductive layer 112b, the conductive layer 263, and the liquid crystal 262 interposed therebetween.

Over the substrate 151, a conductive layer 264 positioned on the same plane as the conductive layer 112a is provided. The conductive layer 264 includes a portion overlapping with the conductive layer 112b with the insulating layer 110 (the insulating layer 110a, the insulating layer 110b, and the insulating layer 110c) therebetween. The conductive layer 112b, the conductive layer 264, and the insulating layer 110 positioned therebetween form a storage capacitor. Note that any one or two layers included in the insulating layer 110 may be removed by etching as long as at least one insulating layer is provided between the conductive layer 112b and the conductive layer 264.

The insulating layer 225 is provided on the substrate 152 side to cover the coloring layer 132R, the coloring layer 132G, and the light-blocking layer 117. The insulating layer 225 may have a function as a planarization layer. The conductive layer 263 can have a substantially flat surface owing to the insulating layer 225, resulting in a uniform alignment state of the liquid crystal 262.

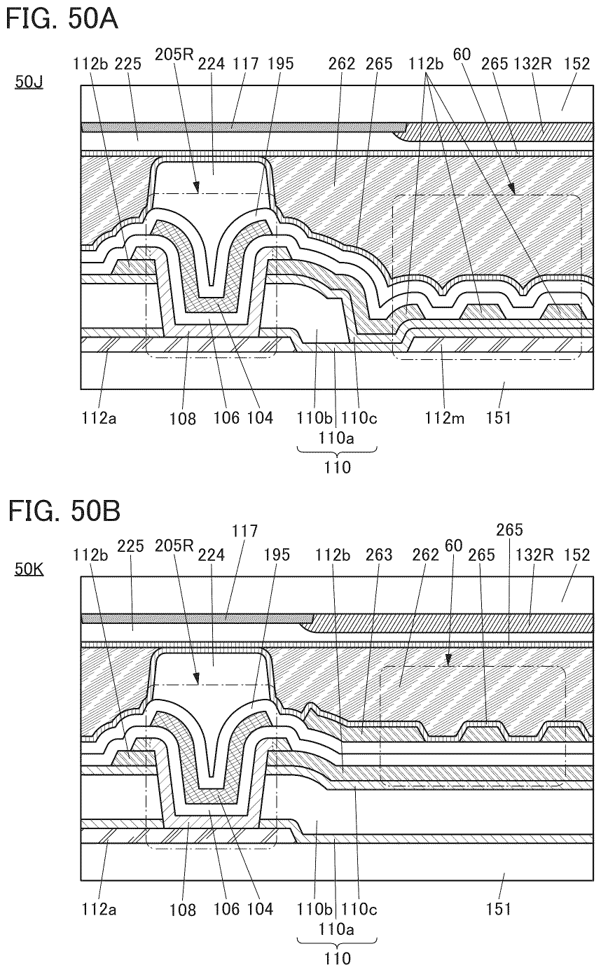

Note that in the conductive layer 263, the insulating layer 195, and the like, the surface in contact with the liquid crystal 262 may be provided with an alignment film for controlling the alignment of the liquid crystal 262 (see an alignment film 265 in FIG. 50A and FIG. 50B).

The conductive layer 112b and the conductive layer 263 transmit visible light. Thus, a transmissive liquid crystal display apparatus can be obtained. For example, in the case where a backlight is placed on the substrate 152 side, light from the backlight which is polarized by the polarizing plate 260a passes through the substrate 152, the conductive layer 263, the liquid crystal 262, the conductive layer 112b, and the substrate 151, and then reaches the polarizing plate 260b. In this case, optical modulation of the light can be controlled by controlling the alignment of the liquid crystal 262 with a voltage applied between the conductive layer 112b and the conductive layer 263. In other words, the intensity of light emitted through the polarizing plate 260b can be controlled. Light other than one in a particular wavelength region is absorbed by the coloring layer, and thus, extracted light is red light, for example.

As the polarizing plate 260b, a linear polarizing plate may be used or a circularly polarizing plate can also be used. As a circularly polarizing plate, a stack including a linear polarizing plate and a quarter-wave retardation plate can be used. Reflection of external light can be reduced with a circularly polarizing plate used as the polarizing plate 260b.

In the case where a circularly polarizing plate is used as the polarizing plate 260b, a circularly polarizing plate or a general linear polarizing plate may be used as the polarizing plate 260a. The cell gap, alignment, drive voltage, and the like of the liquid crystal element used as the liquid crystal element 60 are controlled depending on the kind of the polarizing plate used as the polarizing plate 260a and the polarizing plate 260b so that desirable contrast is obtained.

The conductive layer 263 is electrically connected to a conductive layer 166b provided on the substrate 151 side through a connector 223 in the connection portion 140. The conductive layer 166b is electrically connected to a conductive layer 165b through an opening provided in the insulating layer 110. Thus, a potential or a signal can be supplied to the conductive layer 263 from the FPC, the IC, or the like placed on the substrate 151 side. In the structure illustrated in FIG. 48, the conductive layer 165b is formed using the same material in the same step as the conductive layer 112a, and the conductive layer 166b is formed using the same material in the same step as the conductive layer 112b.

As the connector 223, a conductive particle can be used, for example. As the conductive particle, a particle of an organic resin, silica, or the like coated with a metal material can be used. It is preferable to use nickel or gold as the metal material because contact resistance can be reduced. It is also preferable to use a particle coated with layers of two or more kinds of metal materials, such as a particle coated with nickel and further with gold. For the connector 223, a material capable of elastic deformation or plastic deformation is preferably used. In this case, as illustrated in FIG. 48, the particle having a conduction property may have a shape that is vertically crushed. With the crushed shape, the contact area of the connector 223 and a conductive layer electrically connected thereto can be increased, whereby contact resistance can be reduced and occurrence of problems such as connection defects can be inhibited. The connector 223 is preferably placed to be covered with the adhesive layer 144. For example, the connectors 223 can be dispersed in the adhesive layer 144 before curing.

In a region near an end portion of the substrate 151, the connection portion 197 is provided. In the connection portion 197, a conductive layer 166a is electrically connected to the FPC 172 through the connection layer 242. The conductive layer 166a is electrically connected to a conductive layer 165a through an opening provided in the insulating layer 110. In the structure illustrated in FIG. 48, the conductive layer 165a is formed using the same material in the same step as the conductive layer 112a, and the conductive layer 166a is formed using the same material in the same step as the conductive layer 112b.

### <Structure Example 9 of Display Apparatus>

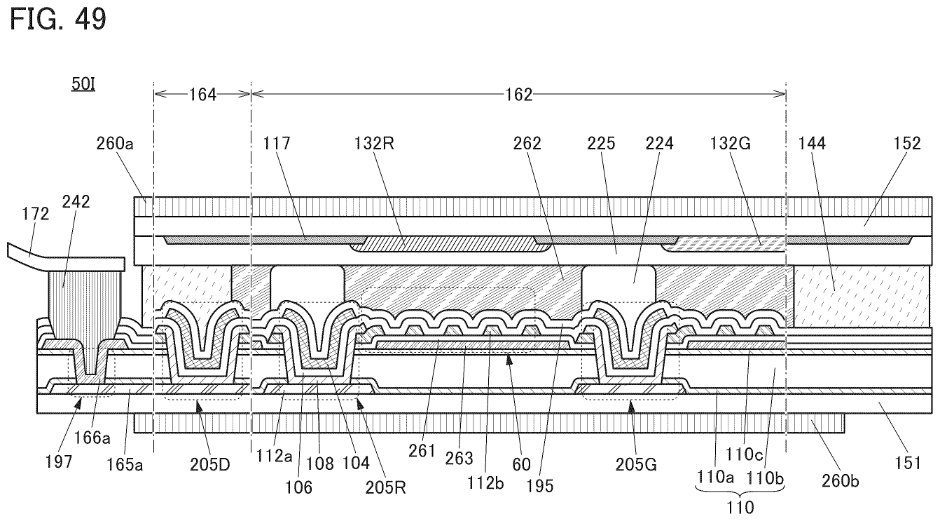

A display apparatus 50I illustrated in FIG. 49 is a liquid crystal display apparatus in an FFS mode. The display apparatus 50I is different from the display apparatus 50H mainly in the structure of the liquid crystal element 60.

The conductive layer 263 functioning as the common electrode of the liquid crystal element 60 is provided over the insulating layer 110, and an insulating layer 261 is provided over the conductive layer 263. The conductive layer 112b having a function of the other of the source electrode and the drain electrode of the transistor and a function of the pixel electrode of the liquid crystal element 60 is provided over the insulating layer 261. The insulating layer 195 is provided over the conductive layer 112b.

In a plan view, the conductive layer 112b has a comb-like shape or a shape with a slit. The conductive layer 263 is provided to overlap with the conductive layer 112b. There is a portion where the conductive layer 112b is not placed over the conductive layer 263 in a region overlapping with the coloring layer.

The conductive layer 112b and the conductive layer 263 are stacked with the insulating layer 261 therebetween, whereby a capacitor is formed. Therefore, it is not necessary to provide a capacitor additionally, and thus the aperture ratio can be increased.

Note that in the liquid crystal element 60, both the conductive layer 112b and the conductive layer 263 may have a comb-like top surface shape. Meanwhile, as illustrated in the display apparatus 50I, only one of the conductive layer 112b and the conductive layer 263 has a comb-like top surface shape in the liquid crystal element 60, whereby the conductive layer 112b and the conductive layer 263 partly overlap with each other. In this structure, capacitance between the conductive layer 112b and the conductive layer 263 can be used as a storage capacitor, so that another capacitor is not necessarily provided, and thus the aperture ratio of the display apparatus can be increased.

### <Structure Example 10 of Display Apparatus>

In a display apparatus 50J illustrated in FIG. 50A, a portion of the insulating layer 110b overlapping with the liquid crystal element 60 is removed by etching. The liquid crystal element 60 included in the display apparatus 50J includes a portion where the insulating layer 110a, the insulating layer 110c, and the conductive layer 112b are stacked in this order. The liquid crystal element 60 and the insulating layer 110b do not overlap with each other, which enables not only an increase in the light transmittance but also a reduction in the number of interfaces positioned on paths of light from the light source; accordingly, influences of interface reflection and interface scattering can be inhibited.

The conductive layer 112b functions as a pixel electrode of the liquid crystal element 60. A conductive layer 112m functions as a common electrode of the liquid crystal element 60. The conductive layer 112m and the conductive layer 112a are formed using the same conductive film.

Note that a portion of at least one of the insulating layer 106 and the insulating layer 195 overlapping with the liquid crystal element 60 may be removed by etching. The insulating layer 195 is not necessarily provided. This facilitates transmission of electric fields of the conductive layer 112b and the conductive layer 112m to the liquid crystal 262, which enables high-speed operation of the liquid crystal element 60. Furthermore, light transmittance of a portion overlapping with the liquid crystal element 60 can be increased and the influences of interface reflection and interface scattering can be inhibited. A portion of at least one of the insulating layer 110a and the insulating layer 110c overlapping with the liquid crystal element 60 may be removed by etching. This also facilitates transmission of the electric fields of the conductive layer 112b and the conductive layer 112m to the liquid crystal 262. Furthermore, the capacitance between the conductive layer 112b and the conductive layer 112m can be increased in some cases.

In the liquid crystal element 60, both the conductive layer 112b and the conductive layer 112m may have a comb-like top surface shape. Meanwhile, as illustrated in the display apparatus 50J, only one of the conductive layer 112b and the conductive layer 112m has a comb-like top surface shape in the liquid crystal element 60, whereby the conductive layer 112b and the conductive layer 112m partly overlap with each other. In this structure, capacitance between the conductive layer 112b and the conductive layer 112m can be used as a storage capacitor, so that another capacitor is not necessarily provided, and thus the aperture ratio of the display apparatus can be increased.

### <Structure Example 11 of Display Apparatus>

A display apparatus 50K illustrated in FIG. 50B is different from the display apparatus 50I mainly in that a common electrode is provided over a pixel electrode. The conductive layer 112b included in the transistor 100 functions as the pixel electrode of the liquid crystal element 60. The insulating layer 106 and the insulating layer 195 are provided over the conductive layer 112b, and the conductive layer 263 is provided over the insulating layer 195. The conductive layer 263 functions as the common electrode of the liquid crystal element 60. In a plan view, the conductive layer 263 has a comb-like shape or a shape with a slit.

### <Manufacturing Method Example of Display Apparatus>

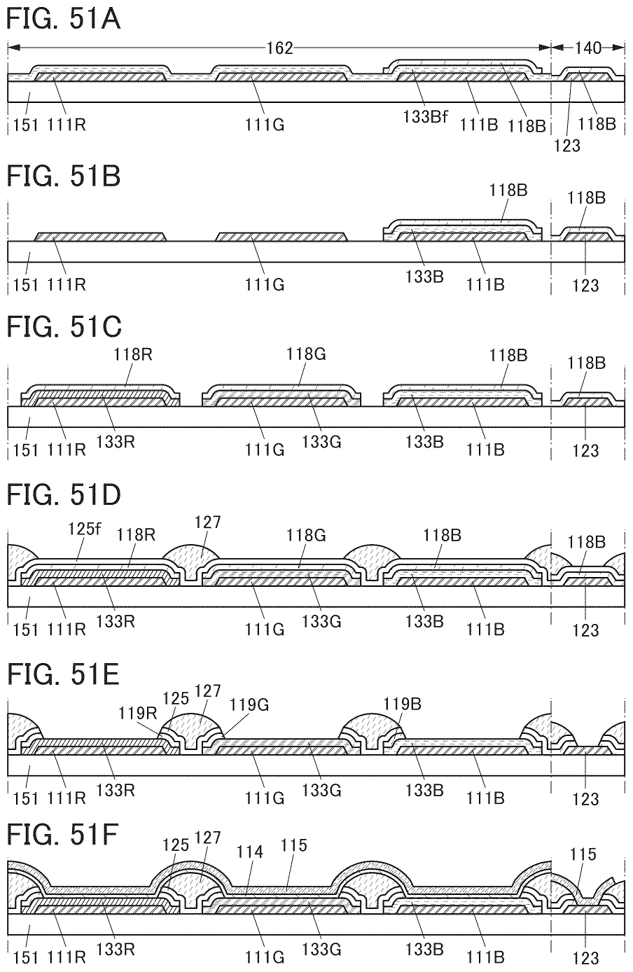

method for manufacturing a display apparatus having an MML (metal maskless) structure will be described below with reference to FIG. 51. Here, steps of manufacturing light-emitting elements without using a fine metal mask will be described in detail. FIG. 51 shows cross-sectional views of three light-emitting elements included in the display portion 162 and the connection portion 140 in the steps.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure method, or a micro-contact printing method).

In the method described below for manufacturing the display apparatus, the island-shaped layer (the layer including the light-emitting layer) is formed not by using a fine metal mask but by forming a light-emitting layer on the entire surface and then processing the light-emitting layer by a photolithography method. Accordingly, a high-resolution display apparatus or a display apparatus with a high aperture ratio, which has been difficult to achieve, can be obtained. Moreover, light-emitting layers can be formed separately for the respective colors, enabling the display apparatus to perform extremely clear display with high contrast and high display quality. In addition, a sacrificial layer provided over a light-emitting layer can reduce damage to the light-emitting layer in the manufacturing process of the display apparatus, increasing the reliability of the light-emitting element.

For example, in the case where the display apparatus includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B and the like (not illustrated) (FIG. 51A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, one or both of a wet etching method and a dry etching method can be used.

Next, a film 133Bf to be the layer 133B later is formed over the pixel electrodes 111R, 111G, and 111B (FIG. 51A). The film 133Bf (to be the layer 133B later) includes a light-emitting layer emitting blue light.

In an example described in this embodiment, an island-shaped EL layer included in the light-emitting element emitting blue light is formed first, and then island-shaped EL layers included in the light-emitting elements emitting light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display apparatus of one embodiment of the present invention, it is preferable that an island-shaped EL layer of a light-emitting element emitting light with the shortest wavelength (e.g., the blue-light-emitting element) be formed first. For example, it is preferable that island-shaped EL layers be formed in the order of blue, green, and red or in the order of blue, red, and green.

This enables the blue-light-emitting element to keep the favorable state of the interface between the pixel electrode and the EL layer, thereby inhibiting an increase in the driving voltage of the blue-light-emitting element. Furthermore, the lifetime of the blue-light-emitting element can be prolonged and the reliability can be increased. Note that the red-light-emitting element and the green-light-emitting element have a smaller increase in driving voltage or the like than the blue-light-emitting element, resulting in a lower driving voltage and higher reliability of the whole display apparatus.

Note that the formation order of the island-shaped EL layers is not limited to the above; for example, the island-shaped EL layers may be formed in the order of red, green, and blue.

As illustrated in FIG. 51A, the film 133Bf is not formed over the conductive layer 123. For example, by using an area mask, the film 133Bf can be formed only in a desired region. Employing a film formation step using an area mask and a processing step using a resist mask enables a light-emitting element to be manufactured by a relatively easy process.

The upper temperature limit of the compounds included in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display apparatus can be increased. Thus, the range of choices of the materials and the formation method of the display apparatus can be widened, thereby improving the yield and the reliability.

The upper temperature limit, for example, can be any of the glass transition point, the softening point, the melting point, the thermal decomposition temperature, and the 5% weight loss temperature, preferably the lowest temperature thereof.

The film 133Bf can be formed by an evaporation method, specifically a vacuum evaporation method, for example. Alternatively, the film 133Bf may be formed by a transfer method, a printing method, an inkjet method, a coating method, or the like.

Next, a sacrificial layer 118B is formed over the film 133Bf and the conductive layer 123 (FIG. 51A). A resist mask is formed over a film to be the sacrificial layer 118B by a photolithography process, and then the film is processed, whereby the sacrificial layer 118B can be formed.

The sacrificial layer 118B provided over the film 133Bf can reduce damage to the film 133Bf in the manufacturing process of the display apparatus, increasing the reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can inhibit variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged in the manufacturing process of the display apparatus.

As the sacrificial layer 118B, a film that is highly resistant to the process conditions for the film 133Bf, specifically, a film having high etching selectivity with the film 133Bf is used.

The sacrificial layer 118B is formed at a temperature lower than the upper temperature limit of each compound included in the film 133Bf. The typical substrate temperature at the time of forming the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high, in which case the film formation temperature of the sacrificial layer 118B can be high. For example, the substrate temperature at the time of forming the sacrificial layer 118B can be higher than or equal to 100° C., higher than or equal to 120° C., or higher than or equal to 140° C. An inorganic insulating film can have higher density and a higher barrier property as the film formation temperature becomes higher. Thus, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the aforementioned wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

The use of a wet etching method can reduce damage to the film 133Bf in processing of the sacrificial layer 118B, as compared with the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, diluted hydrofluoric acid, and nitric acid may be used. A chemical solution used for the wet etching treatment may be alkaline or acid.

For the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metal material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an oxide is preferable because its adhesion to the film 133Bf is higher than that of a nitride. For example, one or more of aluminum oxide, hafnium oxide, and silicon oxide can be suitably used for the sacrificial layer 118B. As the sacrificial layer 118B, an aluminum oxide film can be formed by an ALD method, for example. The use of an ALD method is preferable because damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. Here, for the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer most or all of which is to be removed in a later step, and thus is preferably easy to process. Thus, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet film formation method and an inorganic film (e.g., a silicon nitride film) formed by a sputtering method can be employed for the sacrificial layer 118B.

Note that in the display apparatus of one embodiment of the present invention, part of the sacrificial film remains as the sacrificial layer in some cases.

Then, the film 133Bf is processed using the sacrificial layer 118B as a hard mask, so that the layer 133B is formed (FIG. 51B).

Accordingly, as illustrated in FIG. 51B, a stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. In particular, anisotropic dry etching is preferable. Alternatively, wet etching may be employed.

After that, steps similar to the formation step of the film 133Bf, the formation step of the sacrificial layer 118B, and the formation step of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 51C). Specifically, the layer 133R and the layer 133G are formed to include a light-emitting layer emitting red light and a light-emitting layer emitting green light, respectively. The sacrificial layers 118R and 118G can be formed using a material usable for the sacrificial layer 118B, and may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between facing end portions of two adjacent layers among the layer 133B, the layer 133G, and the layer 133R. When the distance between the island-shaped EL layers is shortened in this manner, a display apparatus with a high resolution and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 51D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. The use of an ALD method is preferable, in which case damage by the film formation is reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation rate than an ALD method. In this case, a highly reliable display apparatus can be manufactured with high productivity.

For example, the insulating film to be the insulating layer 127 is preferably formed by the aforementioned wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays, so that the insulating film is partly exposed to light. Subsequently, the region of the insulating film exposed to light is removed by development. Then, heat treatment (also referred to as post-baking) is performed. Accordingly, the insulating layer 127 illustrated in FIG. 51D can be formed. Note that the shape of the insulating layer 127 is not limited to the shape illustrated in FIG. 51D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 51E, etching treatment is performed using the insulating layer 127 as a mask to remove parts of the insulating film 125f and the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Parts of the sacrificial layers 118B, 118G, and 118R may remain in positions overlapping with the insulating layer 127 and the insulating layer 125 (see a sacrificial layer 119B, a sacrificial layer 119G, and a sacrificial layer 119R).

The etching treatment can be performed by dry etching or wet etching. The insulating film 125f is preferably formed using a material similar to that for the sacrificial layers 118B, 118G, and 118R, in which case etching treatment can be performed collectively.

As described above, providing the insulating layer 127, the insulating layer 125, the sacrificial layer 118B, the sacrificial layer 118G, and the sacrificial layer 118R can inhibit the common layer 114 and the common electrode 115 between the light-emitting elements from having connection defects due to a disconnected portion and an increased electric resistance due to a locally thinned portion. Thus, the display quality of the display apparatus of one embodiment of the present invention can be improved.

Next, the common layer 114 and the common electrode 115 are formed in this order over the insulating layer 127, the layer 133B, the layer 133G, and the layer 133R (FIG. 51F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display apparatus of one embodiment of the present invention, the island-shaped layer 133B, the island-shaped layer 133G, and the island-shaped layer 133R are formed not by using a fine metal mask but by forming a film over the entire surface and processing the film; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. Accordingly, generation of a leakage current between the subpixels can be inhibited. This can prevent unintended light emission due to crosstalk, so that a display apparatus with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display apparatus of one embodiment of the present invention can have both a high resolution and high display quality.

This embodiment can be combined with the other embodiments as appropriate.

### Embodiment 4

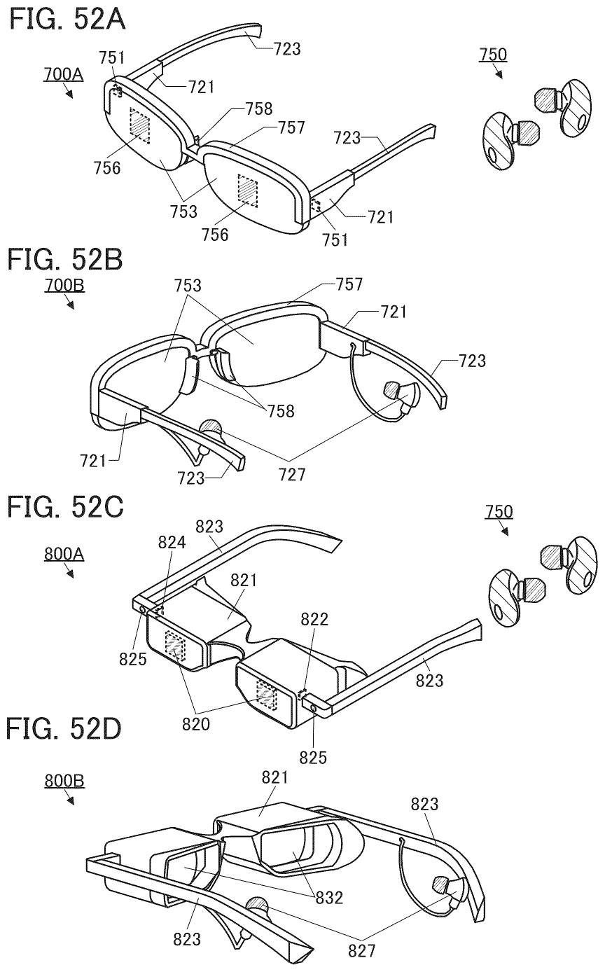

In this embodiment, electronic devices of one embodiment of the present invention will be described with reference to FIG. 52 to FIG. 54.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic device include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display apparatus of one embodiment of the present invention can have high resolution, and thus can be suitably used for an electronic device having a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 52A to FIG. 52D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 52A and an electronic device 700B illustrated in FIG. 52B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast-forward and fast-rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 52C and an electronic device 800B illustrated in FIG. 52D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 52D.

The display apparatus of one embodiment of the present invention can be used for the display portions 820. Thus, the electronic device can perform display with extremely high resolution. This enables a user to feel high sense of immersion.

The display portions 820 are positioned inside the housing 821 to be seen through the lenses 832. When the pair of display portions 820 display different images, three-dimensional display using parallax can be performed.

The electronic device 800A and the electronic device 800B can be regarded as electronic devices for VR. The user wearing the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 52C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 52A has a function of transmitting information to the earphones 750 with the wireless communication function. As another example, the electronic device 800A in FIG. 52C has a function of transmitting information to the earphones 750 with the wireless communication function.

The electronic device may include an earphone portion. The electronic device 700B illustrated in FIG. 52B includes earphone portions 727. For example, the earphone portion 727 and the control portion can be connected to each other by wire. Part of a wiring connecting the earphone portion 727 and the control portion may be positioned inside the housing 721 or the wearing portion 723.

Similarly, the electronic device 800B illustrated in FIG. 52D includes earphone portions 827. For example, the earphone portion 827 and the control portion 824 can be connected to each other by wire. Part of a wiring connecting the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

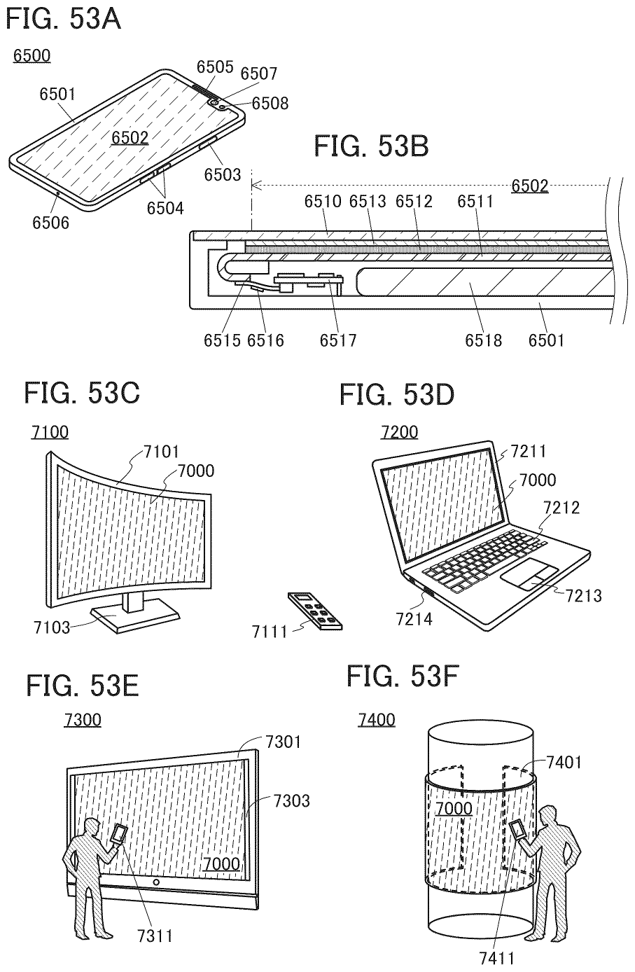

An electronic device 6500 illustrated in FIG. 53A is a portable information terminal that can be used as a smartphone.

The electronic device 6500 includes a housing 6501, a display portion 6502, a power button 6503, buttons 6504, a speaker 6505, a microphone 6506, a camera 6507, and a light source 6508. The display portion 6502 has a touch panel function.

The display apparatus of one embodiment of the present invention can be used for the display portion 6502.

FIG. 53B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 53C illustrates an example of a television device. In a television device 7100, a display portion 7000 is incorporated in a housing 7101. Here, a structure where the housing 7101 is supported by a stand 7103 is illustrated.

The display apparatus of one embodiment of the present invention can be used for the display portion 7000.

Operation of the television device 7100 illustrated in FIG. 53C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 53D illustrates an example of a laptop computer. A laptop computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 53E and FIG. 53F illustrate examples of digital signage.

Digital signage 7300 illustrated in FIG. 53E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 53F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 53E and FIG. 53F.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 53E and FIG. 53F, it is preferable that the digital signage 7300 or the digital signage 7400 work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

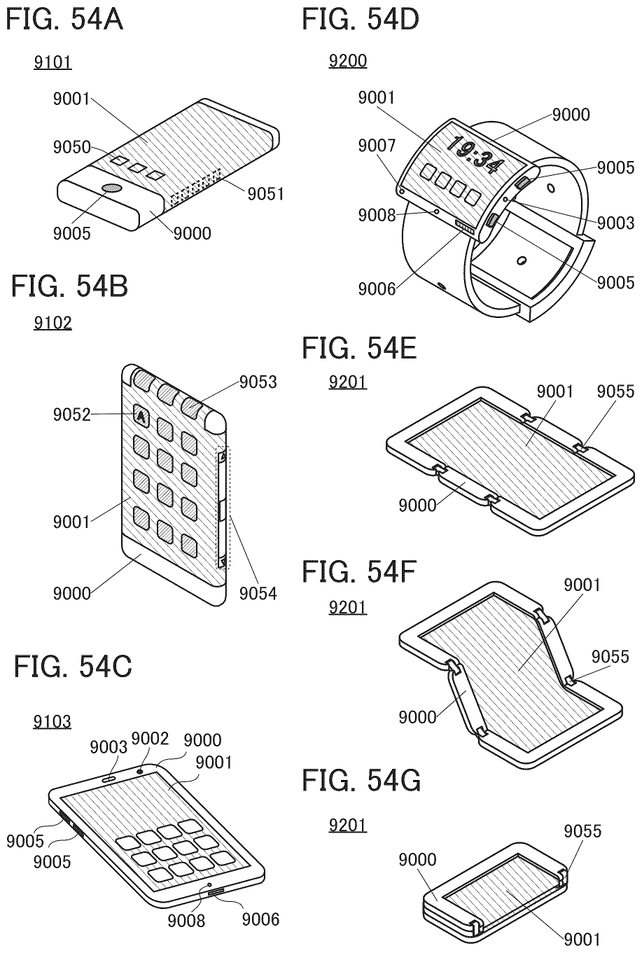

Electronic devices illustrated in FIG. 54A to FIG. 54G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 54A to FIG. 54G.

The electronic devices illustrated in FIG. 54A to FIG. 54G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. The functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 54A to FIG. 54G are described in detail below.

FIG. 54A is a perspective view illustrating a portable information terminal 9101. The portable information terminal 9101 can be used as a smartphone, for example. The portable information terminal 9101 may be provided with the speaker 9003, the connection terminal 9006, the sensor 9007, or the like. The portable information terminal 9101 can display characters and image information on its plurality of surfaces. FIG. 54A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 54B is a perspective view illustrating a portable information terminal 9102. The portable information terminal 9102 has a function of displaying information on three or more surfaces of the display portion 9001. Here, an example where information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 54C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 54D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 54E to FIG. 54G are perspective views illustrating a foldable portable information terminal 9201. FIG. 54E is a perspective view of an opened state of the portable information terminal 9201, FIG. 54G is a perspective view of a folded state thereof, and FIG. 54F is a perspective view of a state in the middle of change from one of FIG. 54E and FIG. 54G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example 1

In this example, a transistor was fabricated, and its shape was evaluated.

In this example, Sample A including the transistor of one embodiment of the present invention was fabricated. For the structure of the transistor included in Sample A, the description of the transistor 100 illustrated in FIG. 1B can be referred to. For a method for fabricating Sample A, the description in Embodiment 2 can be referred to.

### <Fabrication of Sample>

First, an In—Sn—Si oxide (ITSO) film with a thickness of approximately 100 nm was formed over the substrate 102 by a sputtering method, and then processed to obtain the conductive layer 112a. A glass substrate was used as the substrate 102.

Next, an approximately 30-nm-thick silicon nitride film was formed as the insulating film 110af, and an approximately 500-nm-thick silicon oxynitride film was formed as the insulating film 110bf. For the formation of the insulating film 110af and the insulating film 110bf, a PECVD method was used.

Next, an approximately 20-nm-thick metal oxide layer was formed as the metal oxide layer 137 over the insulating film 110bf. The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 30-nm-thick silicon nitride film was formed as the insulating film 110cf over the insulating film 110bf by a PECVD method.

Then, an approximately 100-nm-thick In—Sn—Si oxide (ITSO) film was formed as the conductive film 112bf over the insulating film 110cf by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the insulating film 110af, the insulating film 110bf, and the insulating film 110cf in a region overlapping with the conductive layer 112a were removed to form the insulating layer 110 including the opening 141. The conductive layer 112B was removed by a wet etching method. The insulating film 110af, the insulating film 110bf, and the insulating film 110cf were removed by a dry etching method.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to obtain the semiconductor layer 108.

Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Through the above process, Sample A was obtained.

### <SEM Observation>

Then, Sample A was observed by scanning electron microscopy (SEM). Here, the transistor including the opening 141 and the opening 143 with circular top surface shapes and having the channel width W100 of approximately 6.3 μm (the width D141 of the opening 141 of 2.0 μm) was observed. Note that the channel length L100 was approximately 0.5 μm.

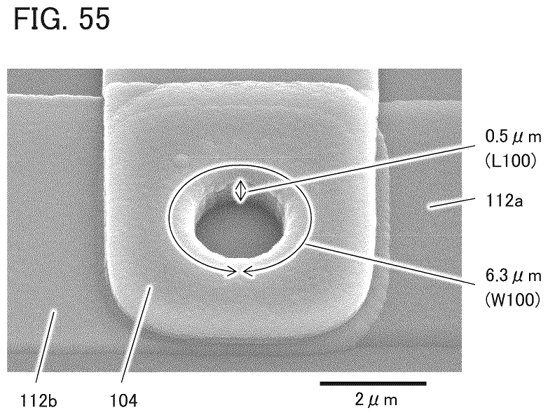

FIG. 55 shows a SEM image of Sample A. FIG. 55 is an image (Tilt View) obtained at a magnification of 15,000 times with the stage being tilted. As shown in FIG. 55, it was confirmed that Sample A had a favorable shape.

### <STEM Observation>

Next, Sample A was thinned by focused ion beam (FIB) and a cross section was observed with a scanning transmission electron microscope (by STEM: Scanning Transmission Electron Microscopy).

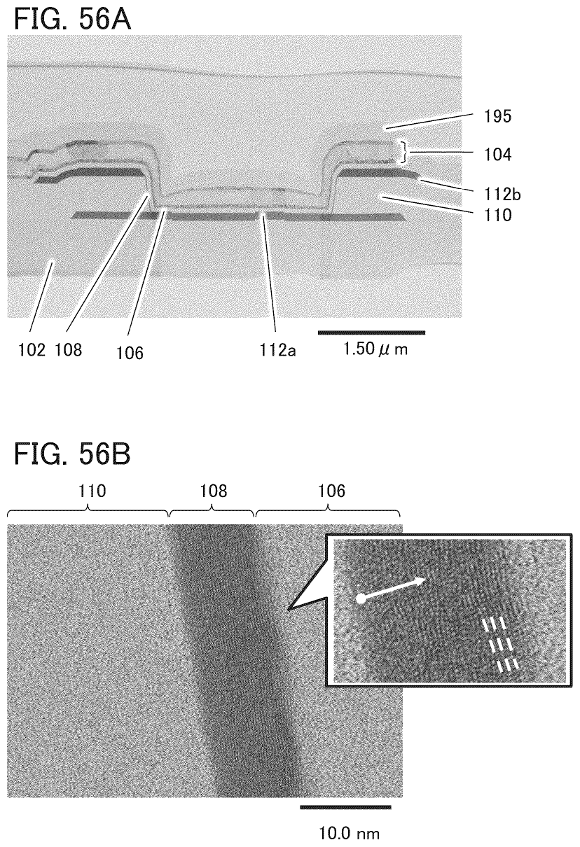

FIG. 56A shows a STEM image of the cross section of Sample A. FIG. 56A is a transmission electron (TE) image at a magnification of 20,000 times. As shown in FIG. 56A, it was confirmed that Sample A had a favorable cross-sectional shape.

FIG. 56B shows a STEM image of a cross section of a region of the semiconductor layer 108 that is in contact with the side surface of the insulating layer 110b. FIG. 56B is a transmission electron (TE) image at a magnification of 3,000,000 times. FIG. 56B also shows an enlarged STEM image of the semiconductor layer 108 and the vicinity thereof. As shown in FIG. 56B, a crystal lattice image was observed in the semiconductor layer 108. As shown in FIG. 56B, a layered crystal parallel or substantially parallel to the formation surface of the semiconductor layer 108, i.e., the side surface of the insulating layer 110, was observed. Note that in FIG. 56B, nine solid lines are shown as auxiliary lines for easy understanding of the layered crystal. It was confirmed that the semiconductor layer 108 had the c-axis alignment of the crystals in the normal direction of the formation surface (see an arrow in FIG. 56B) and thus had the CAAC structure.

### Example 2

In this example, transistors were fabricated, and their electrical characteristics were evaluated.

In this example, Sample B including the transistors of one embodiment of the present invention was fabricated. For the structures of the transistors included in Sample B, the description of the transistor 100 illustrated in FIG. 11A can be referred to.

### <Fabrication of Sample>

First, an In—Sn—Si oxide (ITSO) film with a thickness of approximately 100 nm was formed over the substrate 102 by a sputtering method, and then processed to obtain the conductive layer 112a. A glass substrate with a size of 600 mm×720 mm was used as the substrate 102.

Next, an approximately 70-nm-thick silicon nitride film was formed as a first insulating film to be the insulating layer 110d, an approximately 100-nm-thick silicon nitride film was formed as a second insulating film (the insulating film 110af) to be the insulating layer 110a, and an approximately 500-nm-thick silicon oxynitride film was formed as a third insulating film (the insulating film 110bf) to be the insulating layer 110b. The first insulating film, the second insulating film, and the third insulating film were successively formed in a vacuum by a PECVD method. Note that silane (SiH₄), nitrogen (N₂), and ammonia (NH₃) were used as film formation gases for forming the first insulating film and the second insulating film (the insulating film 110af). The ammonia flow rate ratio at the time of forming the first insulating film was made higher than the ammonia flow rate ratio at the time of forming the second insulating film (the insulating film 110af).

Next, an approximately 20-nm-thick metal oxide layer was formed as the metal oxide layer 137 over the third insulating film (the insulating film 110bf). The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 50-nm-thick silicon nitride film was formed as a fourth insulating film (the insulating film 110cf) to be the insulating layer 110c over the third insulating film (the insulating film 110bf), and an approximately 100-nm-thick silicon nitride film was formed as a fifth insulating film to be the insulating layer 110e. The fourth insulating film and the fifth insulating film were successively formed in a vacuum by a PECVD method. Note that silane (SiH₄), nitrogen (N₂), and ammonia (NH₃) were used as film formation gases for forming the fourth insulating film (the insulating film 110cf) and the fourth insulating film. The ammonia flow rate ratio at the time of forming the fifth insulating film was made higher than the ammonia flow rate ratio at the time of forming the fourth insulating film (the insulating film 110cf).

Then, an approximately 100-nm-thick In—Sn—Si oxide (ITSO) film was formed as the conductive film 112bf over the fifth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to obtain the semiconductor layer 108.

Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Through the above process, Sample B was obtained.

### <Id-Vg Characteristics>

Then, the Id-Vg characteristics of the transistors of Sample B fabricated in the above manner were measured.

For the measurement of the Id-Vg characteristics of the transistors, a voltage applied to the gate electrode (hereinafter also referred to as gate voltage (Vg or Vgs)) was applied from −10 V to +10 V in increments of 0.25 V. Moreover, a voltage applied to the source electrode (hereinafter also referred to as source voltage (Vs)) was 0 V (comm), and a voltage applied to the drain electrode (hereinafter also referred to as drain voltage (Vd or Vds)) was 0.1 V and 5.1 V.

Here, the measurement was performed on the transistor with the channel width W100 of approximately 6.3 μm (the width D141 of the opening 141 of 2.0 μm). The number of measurements was set to 120 in a substrate plane of 600 mm×720 mm. Note that the channel length L100 was approximately 0.5 μm.

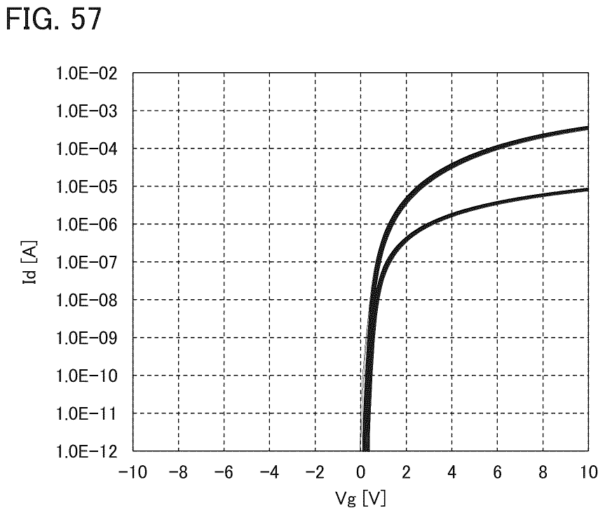

FIG. 57 shows the Id-Vg characteristics. In FIG. 57, the horizontal axis represents the gate voltage (Vg) and the vertical axis represents the drain current (Id). FIG. 57 shows superimposed Id-Vg characteristics of the 120 transistors.

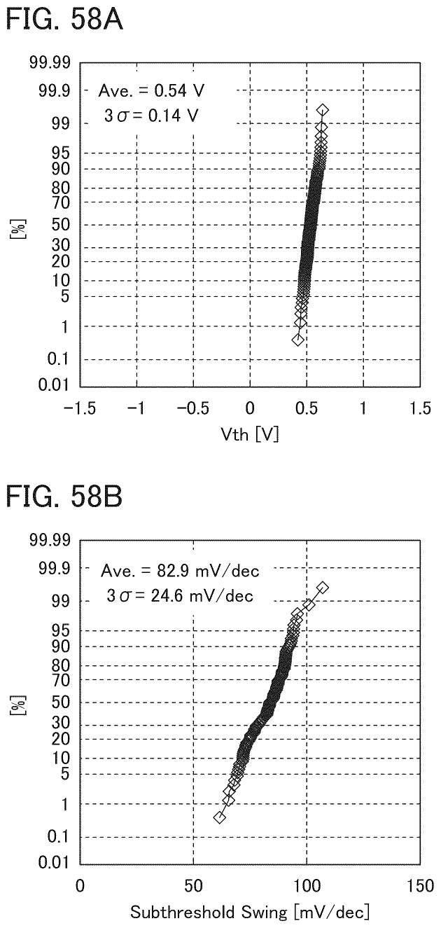

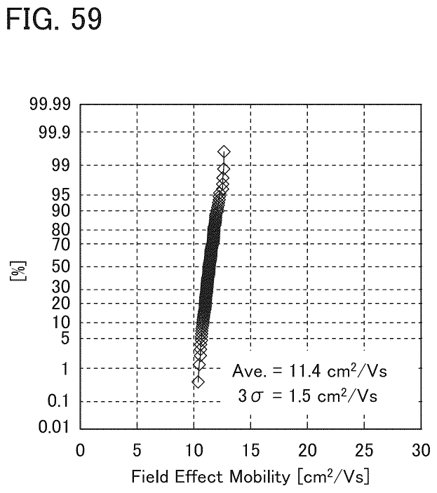

FIG. 58A, FIG. 58B, and FIG. 59 respectively show probability distributions of the threshold voltage (Vth), the S value (also referred to as Subthreshold Swing Value or SS), and the field-effect mobility (also referred to as uFE) obtained from the above Id-Vg characteristics. In FIG. 58A, the horizontal axis represents the threshold voltage (Vth) and the vertical axis represents the cumulative probability. In FIG. 58B, the horizontal axis represents the S value and the vertical axis represents the cumulative probability. In FIG. 59, the horizontal axis represents the field-effect mobility and the vertical axis represents the cumulative probability.

As shown in FIG. 58A, FIG. 58B, and FIG. 59, it was confirmed that all of normally-off characteristics, a high on-state current, and a low off-state current were achieved in Sample B. It was also confirmed that an in-plane variation in electrical characteristics was small. The average S value was 82.9 mV/dec, showing that the interface between the semiconductor layer 108 and the gate insulating layer (the insulating layer 106) was formed favorably.

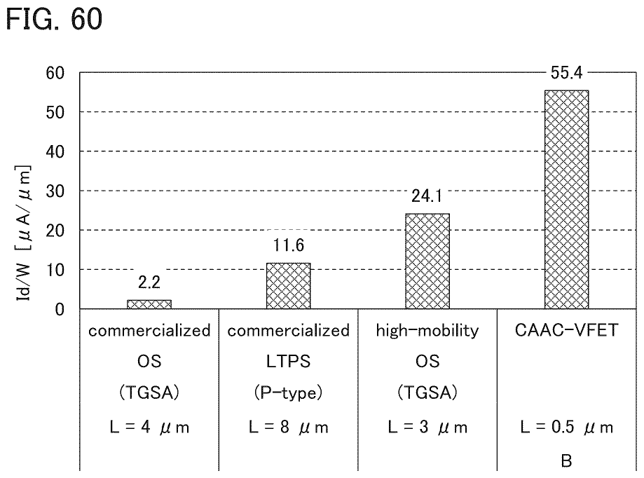

FIG. 60 shows the on-state current per channel width. In FIG. 60, the horizontal axis represents the sample condition, and the vertical axis represents the value (Id/W) obtained by dividing the on-state current by the channel width. For the on-state current, a value at a drain voltage (Vd) of 5.1 V and a gate voltage (Vg) of 10 V was used. FIG. 60 shows the value of Sample B (denoted as CAAC-VFET L=0.5 μm in FIG. 60) and the value of an n-channel TGSA transistor (denoted as high-mobility OS (TGSA) L=3 μm in FIG. 60). In addition, the values of an n-channel TGSA transistor using an In—Ga—Zn oxide for its semiconductor layer (denoted as commercialized OS (TGSA) L=4 μm in FIG. 60) and a p-channel TGSA transistor using LTPS for its semiconductor layer (denoted as commercialized LTPS (P-type) L=8 μm in FIG. 60), which are transistors each included in a commercial display apparatus, are also shown.

As shown in FIG. 60, it was confirmed that the transistor of Sample B with a submicron-sized channel length had an on-state current approximately five times that of the p-channel LTPS transistor included in a commercial display apparatus.

### <Reliability>

Next, the reliability of Sample B fabricated in the above manner was evaluated.

For the reliability evaluation, a GBT (Gate Bias Temperature) stress test was performed.

In this example, a PBTS (Positive Bias Temperature Stress) test and an NBTIS (Negative Bias Temperature Illumination Stress) test were performed.

Note that a test in which a state where a positive potential (positive bias) relative to a source potential and a drain potential is supplied to a gate is maintained at high temperatures is referred to as a PBTS test, and a test in which a state where a negative potential (negative bias) is supplied to a gate is maintained at high temperatures is referred to as an NBTS (Negative Bias Temperature Stress) test. The PBTS test and the NBTS test performed in a state where irradiation with light is performed are respectively referred to as a PBTIS (Positive Bias Temperature Illumination Stress) test and an NBTIS test.

In the PBTS test, a substrate over which the transistors were formed was held at 60° C., a voltage of 0.1 V was applied to the sources and the drains of the transistors, and a voltage of 20 V was applied to the gates; this state was maintained for one hour. The test was performed in a dark environment. In the NBTIS test, a substrate over which the transistors were formed was held at 60° C., a voltage of 0 V was applied to the sources and the drains of the transistors, and a voltage of −20 V was applied to the gates in a state where irradiation with white LED light at 5000 lx was performed; this state was maintained for one hour. The irradiation with white LED light was performed from the glass substrate side. In the PBTS test and the NBTIS test, the transistor with the channel width W100 of approximately 6.3 μm (the width D141 of the opening 141 of 2.0 μm) was used. The channel length L100 was approximately 0.5 μm.

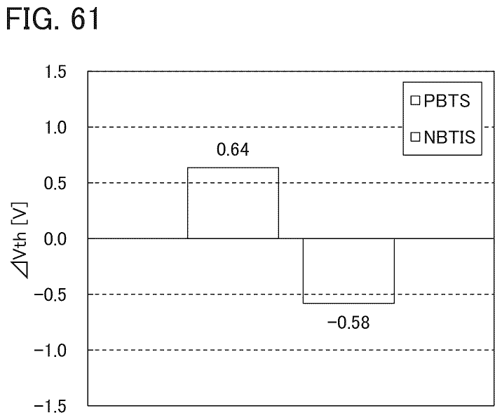

FIG. 61 shows the amounts of change in the threshold voltage between before and after the PBTS test and between before and after the NBTIS test. As shown in FIG. 61, the amount of change in the threshold voltage was small in both the PBTS test and the NBTIS test, which confirmed high reliability.

From the above results, it was confirmed that a transistor with a short channel length, favorable electrical characteristics, and high reliability was obtained.

### Example 3

In this example, an OLED panel (also referred to as an OLED display, an organic EL panel, or an organic EL display) was fabricated as the display apparatus of one embodiment of the present invention. Here, an OLED panel having a resolution of 513 ppi, an RGB stripe pixel arrangement, and an internal correction circuit was fabricated using a glass substrate with a size of 600 mm×720 mm. Table 1 shows the specifications of the fabricated OLED panel.

TABLE 1

| | Specifications | |
|---|---|---|
| Screen diagonal | 5.72 | inches |
| Resolution | 1440 (H) × RGB × 2560 (V) | |
| Pixel density | 513 | ppi |

| | |
|---|---|
| Pixel size | 49.5 μm (H) × 49.5 μm (V) |
| Pixel arrangement | RGB stripe |
| Pixel circuit | 6Tr + 2C |
| Aperture ratio | 39% |
| Coloring method | White Tanden: OLED + Color Filter |
| Emission type | Top emission |
| Source driver | External IC |
| Demultiplexer | Two-divided |
| Scan driver | Integrated |

For the structures of the transistors used in the OLED panel, the structures of the transistor 100 and the transistor 200 illustrated in FIG. 11A can be referred to. An oxide semiconductor (OS) was used for the semiconductor layer 108 and the semiconductor layer 208. The transistor 100, which is a VFET, had the channel length L100 of approximately 0.5 μm and the channel width W100 of approximately 6.3 μm (the width D141 of the opening 141 of 2.0 μm). For the structure of the pixel circuit, the description of FIG. 30 to FIG. 42 can be referred to. A VFET including an oxide semiconductor (OS) was also used for a gate driver and a demultiplexer (DeMUX). The use of the VFET enabled layout of six transistors (6Tr) and two capacitors (2C) in one subpixel (size: 16.5 μm×49.5 μm).

A white-light-emitting OLED having a tandem structure was used as a light-emitting element, and full-color display was achieved with color filters.

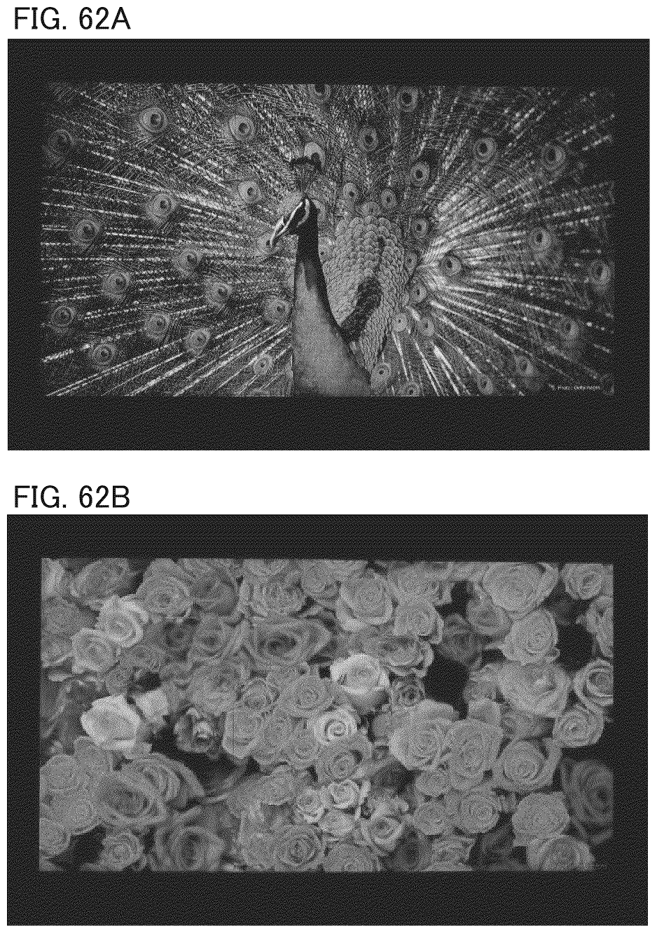

FIG. 62A and FIG. 62B are photographs showing the display states of the OLED panel.

It was confirmed that the pixel circuit, the gate driver, and the DeMUX each operated without any problems and various images were displayed.

### Example 4

In this example, the contact resistance between the material that can be used for the conductive layer 112a and the conductive layer 112b and the metal oxide that can be used for the semiconductor layer 108 was evaluated. The evaluation was performed by a transfer length method (TLM). In this example, two kinds of samples (Sample C1 and Sample C2) were fabricated.

### <Fabrication of Samples>

First, a conductive film was formed over a glass substrate by a sputtering method, and then processed to form a conductive layer. In Sample C1, an approximately 100-nm-thick tungsten film was formed as the conductive film. In Sample C2, an approximately 300-nm-thick copper film and an approximately 100-nm-thick In—Sn—Si oxide (ITSO) film over the copper film were formed as the conductive film.

Next, an approximately 100-nm-thick metal oxide film was formed over the conductive layer, and then processed to form a semiconductor layer. The metal oxide film was formed by a sputtering method using an IGZO sputtering target with an atomic ratio of metal elements of In:Ga:Zn=1:1:1.

Then, heat treatment was performed at 350° C. in a nitrogen atmosphere for one hour. An oven apparatus was used for the heat treatment.

Next, an approximately 100-nm-thick silicon oxynitride film was formed by a PECVD method.

Then, an opening reaching the conductive layer was formed in the silicon oxynitride film.

Through the above process, Sample C1 and Sample C2 were formed.

### <I-V Characteristics>

Next, the I-V characteristics of the samples fabricated in the above manner were measured.

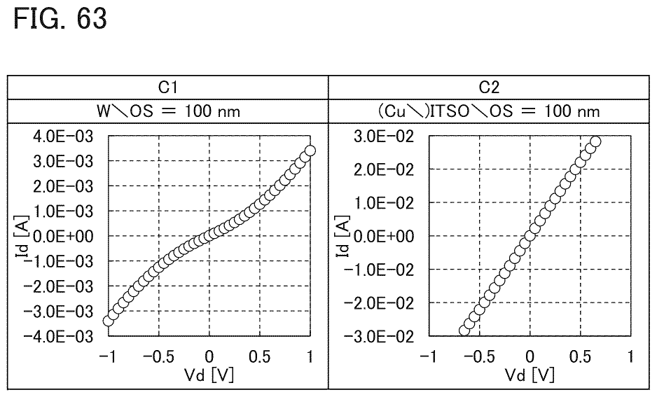

FIG. 63 shows the I-V characteristics. In FIG. 63, the I-V characteristics of Sample C1 (denoted as W\OS=100 nm in FIG. 63) are shown on the left side, and the I-V characteristics of Sample C2 (denoted as (Cu\) ITSO\OS=100 nm in FIG. 63) are shown on the right side. In addition, in FIG. 63, the horizontal axis represents the source-drain voltage (Vd) and the vertical axis represents the drain current (Id).

As shown in FIG. 63, in Sample C2 using the In—Sn—Si oxide (ITSO) for the conductive film on the side in contact with the metal oxide film, the drain current (Id) was proportional to the source-drain voltage and the I-V characteristics were linear. This confirmed that an ohmic contact was made between the In—Sn—Si oxide (ITSO) film and the metal oxide film. Meanwhile, in Sample C1 using tungsten for the conductive film, the drain current (Id) was not proportional to the source-drain voltage and the I-V characteristics were nonlinear. This confirmed that non-ohmic contact was made between the tungsten film and the metal oxide film. Since tungsten has a high work function, Schottky contact is probably made at the interface between the tungsten film and the metal oxide film.

### Example 5

In this example, the ease of generation of oxygen vacancies (Vₒ) in the metal oxide when the material that can be used for the conductive layer 112a and the conductive layer 112b and the metal oxide that can be used for the semiconductor layer 108 are bonded to each other was evaluated. In this example, five kinds of samples (Sample D1 to Sample D5) were fabricated.

### <Fabrication of Samples>

First, an approximately 100-nm-thick metal oxide film was formed over a glass substrate. The metal oxide film was formed by a sputtering method using an IGZO sputtering target with an atomic ratio of metal elements of In:Ga:Zn=1:1:1.

Then, a conductive film was formed over the metal oxide film by a sputtering method. In Sample D1, an approximately 100-nm-thick aluminum film was formed as the conductive film. In Sample D2, an approximately 100-nm-thick molybdenum film was formed as the conductive film. In Sample D3, an approximately 100-nm-thick tungsten film was formed as the conductive film. In Sample D4, an approximately 100-nm-thick titanium film was formed as the conductive film. In Sample D5, an approximately 100-nm-thick In—Sn—Si oxide (ITSO) film was formed as the conductive film.

Then, heat treatment was performed at 350° C. in a nitrogen atmosphere for one hour. An oven apparatus was used for the heat treatment.

Then, the conductive film was removed to expose the metal oxide film. The conductive film was removed by a wet etching method.

Through the above process, Sample D1 to Sample D5 were formed.

### <Sheet Resistance>

Next, the sheet resistance of the samples fabricated in the above manner was measured.

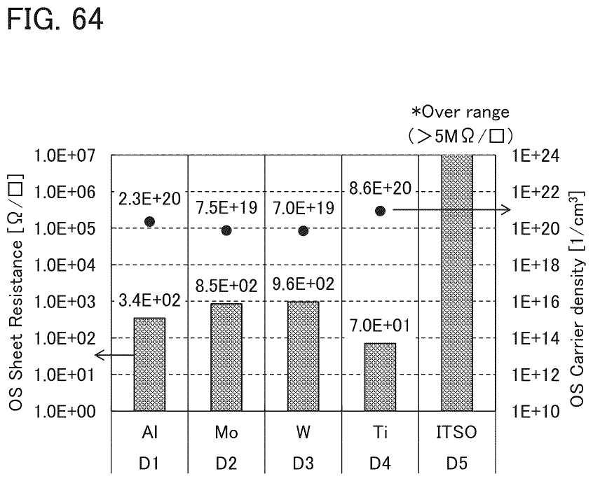

FIG. 64 shows the sheet resistance. In FIG. 64, the horizontal axis represents the conductive film material and the left vertical axis represents the sheet resistance of the metal oxide film (OS Sheet Resistance). The right vertical axis represents the carrier concentration of the metal oxide (OS Carrier Density) estimated from the sheet resistance.

As shown in FIG. 64, the sheet resistance of Sample D5 using an In—Sn—Si oxide (ITSO) film was higher than the upper measurement limit and thus unmeasurable, which confirmed that the metal oxide film had high electric resistance. The upper measurement limit of the sheet resistance was 5 MQ/square. Note that the carrier concentration of Sample D5, whose sheet resistance was unmeasurable (denoted as Over range in FIG. 64), is not shown in FIG. 64. It was confirmed that Samples D1 to D4 had lower electric resistance of the metal oxide film than Sample D5.

ITSO, which is an oxide and thus is not easily oxidized, probably inhibited generation of oxygen vacancies (Vₒ) in the metal oxide even when bonded to the metal oxide, and accordingly inhibit a decrease in the electric resistance of the metal oxide.

### Example 6

In this example, transistors were fabricated, and their electrical characteristics were evaluated.

In this example, samples including the transistors of one embodiment of the present invention were fabricated. For the structures of the transistors included in the samples, the description of the transistor 100 illustrated in FIG. 11A can be referred to. In this example, four kinds of samples (Sample E1 to Sample E4) were fabricated.

### <Fabrication of Samples>

First, a film to be the conductive layer 112a was formed over the substrate 102 by a sputtering method, and then the film was processed to form the conductive layer 112a. A glass substrate with a size of 600 mm×720 mm was used as the substrate 102. In Sample E1, an approximately 200-nm-thick aluminum film was formed as the film. In Sample E2, an approximately 200-nm-thick tungsten film was formed as the film. In Sample E3, an approximately 200-nm-thick molybdenum film was formed as the film. In Sample E4, an approximately 100-nm-thick In—Sn—Si oxide (ITSO) film was formed as the film.

Next, an approximately 70-nm-thick silicon nitride film was formed as the first insulating film to be the insulating layer 110d, an approximately 100-nm-thick silicon nitride film was formed as the second insulating film (the insulating film 110af) to be the insulating layer 110a, and an approximately 500-nm-thick silicon oxynitride film was formed as the third insulating film (the insulating film 110bf) to be the insulating layer 110b. The first insulating film, the second insulating film, and the third insulating film were successively formed in a vacuum by a PECVD method. Note that silane (SiH₄), nitrogen (N₂), and ammonia (NH₃) were used as film formation gases for forming the first insulating film and the second insulating film (the insulating film 110af). The ammonia flow rate ratio at the time of forming the first insulating film was made higher than the ammonia flow rate ratio at the time of forming the second insulating film (the insulating film 110af).

Next, an approximately 20-nm-thick metal oxide layer was formed as the metal oxide layer 137 over the third insulating film (the insulating film 110bf). The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 50-nm-thick silicon nitride film was formed as the fourth insulating film (the insulating film 110cf) to be the insulating layer 110c over the third insulating film (the insulating film 110bf), and an approximately 100-nm-thick silicon nitride film was formed as the fifth insulating film to be the insulating layer 110e. The fourth insulating film and the fifth insulating film were successively formed in a vacuum by a PECVD method. Note that silane (SiH₄), nitrogen (N₂), and ammonia (NH₃) were used as film formation gases for forming the fourth insulating film (the insulating film 110cf) and the fourth insulating film. The ammonia flow rate ratio at the time of forming the fifth insulating film was made higher than the ammonia flow rate ratio at the time of forming the fourth insulating film (the insulating film 110cf).

Next, the conductive film 112bf was formed over the fifth insulating film by a sputtering method. In Sample E1, an approximately 100-nm-thick aluminum film was formed as the conductive film 112bf. In Sample E2, an approximately 100-nm-thick tungsten film was formed as the conductive film 112bf. In Sample E3, an approximately 100-nm-thick molybdenum film was formed as the conductive film 112bf. In Sample E4, an approximately 100-nm-thick In—Sn—Si oxide (ITSO) film was formed as the conductive film 112bf.

Subsequently, the conductive film 112bf was processed to form the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to form the semiconductor layer 108.

Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to form the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Through the above process, Sample E1 to Sample E4 were formed.

### <Id-Vg Characteristics>

Next, the Id-Vg characteristics of the transistors of Sample E1 to Sample E4 fabricated in the above manner were measured.

For the measurement of the Id-Vg characteristics of the transistors, the gate voltage (Vg) was applied from −10 V to +10 V in increments of 0.25 V. In addition, the source voltage (Vs) was 0 V (comm), and the drain voltage (Vd) was 0.1 V.

Here, the measurement was performed on the transistor with the channel width W100 of approximately 6.3 μm (the width D141 of the opening 141 of 2.0 μm). Note that the number of measurements was set to 20 in a substrate plane of 600 mm×720 mm. The channel length L100 was approximately 0.5 μm.

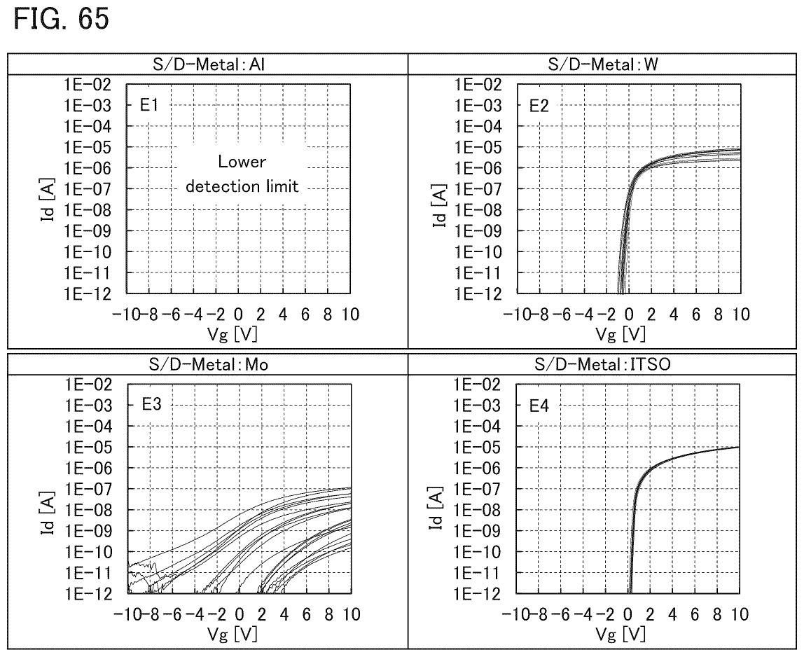

FIG. 65 shows the Id-Vg characteristics of Sample E1 to Sample E4. In FIG. 65, the horizontal axis represents the gate voltage (Vg) and the vertical axis represents the drain current (Id). FIG. 65 shows superimposed Id-Vg characteristics of the 20 transistors.

As shown in FIG. 65, it was confirmed that Sample E4 using an In—Sn—Si oxide (ITSO) for the conductive layer 112a and the conductive layer 112b had favorable electrical characteristics and high reliability. In the measurement of the Id-Vg characteristics of Sample E1 using aluminum, the drain current (Id) was below the lower measurement limit and thus unmeasurable (denoted as Lower detection limit in FIG. 65). Note that the lower measurement limit of the drain current (Id) was approximately 1×10⁻¹³ A.

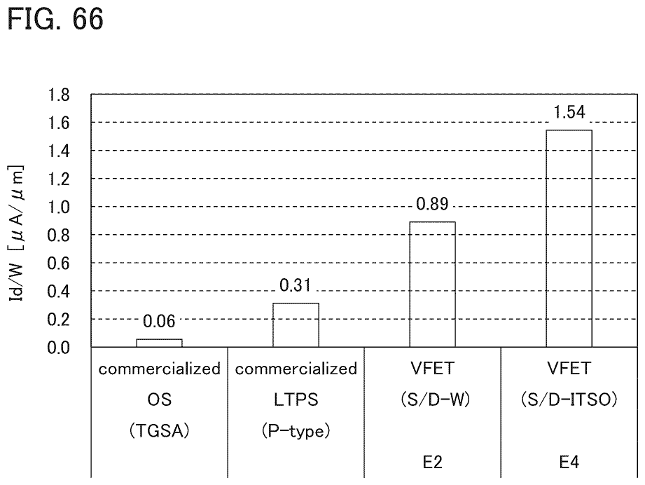

FIG. 66 shows the on-state current per channel width. FIG. 66 shows, with the horizontal axis representing the sample condition, the value (Id/W) obtained by dividing the on-state current at a drain current (Vd) of 0.1 V and a gate voltage (Vg) of 10 V by the channel width. FIG. 66 shows the values of Sample E2 using tungsten for the conductive layer 112a and the conductive layer 112b (denoted by VFET (S/D−W) in FIG. 66) and Sample E4 using an In—Sn—Si oxide (ITSO) (denoted by VFET (S/D-ITSO) in FIG. 66). For reference, FIG. 66 also shows the values of an n-channel TGSA transistor using an In—Ga—Zn oxide for its semiconductor layer (denoted as commercialized OS (TGSA) in FIG. 66) and a p-channel TGSA transistor using LTPS for its semiconductor layer (denoted as commercialized LTPS (P-type) in FIG. 66), which are transistors each included in a commercial display apparatus.

As shown in FIG. 66, it was confirmed that Sample E4 using an In—Sn—Si oxide (ITSO) for the conductive layer 112a and the conductive layer 112b had a high on-state current.

### Example 7

In this example, transistors were fabricated, and their electrical characteristics were evaluated.

In this example, a sample (Sample F) including the transistors of one embodiment of the present invention was fabricated. For the structures of the transistors included in Sample F, the description of the transistor 100C illustrated in FIG. 14A can be referred to. In this example, the number (p) of transistors connected in parallel was varied, and the transistors 100C having different channel widths W100 were fabricated. For the transistors connected in parallel, the description of FIG. 14A to FIG. 17 can be referred to. Note that the conductive layer 112a had the stacked-layer structure illustrated in FIG. 6B.

### <Fabrication of Sample>

First, an approximately 300-nm-thick copper film to be the conductive layer 112a_1 was formed over the substrate 102 by a sputtering method, and then processed to form the conductive layer 112a_1. Next, an approximately 100-nm-thick In—Sn—Si oxide (ITSO) film to be the conductive layer 112a_2 was formed by a sputtering method, and then processed to form the conductive layer 112a_2, whereby the conductive layer 112a was formed. A glass substrate with a size of 600 mm×720 mm was used as the substrate 102.

Next, an approximately 70-nm-thick silicon nitride film was formed as the first insulating film to be the insulating layer 110d, an approximately 100-nm-thick silicon nitride film was formed as the second insulating film (the insulating film 110af) to be the insulating layer 110a, and an approximately 500-nm-thick silicon oxynitride film was formed as the third insulating film (the insulating film 110bf) to be the insulating layer 110b. The first insulating film, the second insulating film, and the third insulating film were successively formed in a vacuum by a PECVD method. Note that silane (SiH₄), nitrogen (N₂), and ammonia (NH₃) were used as film formation gases for forming the first insulating film and the second insulating film (the insulating film 110af). The ammonia flow rate ratio at the time of forming the first insulating film was made higher than the ammonia flow rate ratio at the time of forming the second insulating film (the insulating film 110af).

Next, an approximately 20-nm-thick metal oxide layer was formed as the metal oxide layer 137 over the third insulating film (the insulating film 110bf). The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 50-nm-thick silicon nitride film was formed as the fourth insulating film (the insulating film 110cf) to be the insulating layer 110c over the third insulating film (the insulating film 110bf), and an approximately 100-nm-thick silicon nitride film was formed as the fifth insulating film to be the insulating layer 110e. The fourth insulating film and the fifth insulating film were successively formed in a vacuum by a PECVD method. Note that silane (SiH₄), nitrogen (N₂), and ammonia (NH₃) were used as film formation gases for forming the fourth insulating film (the insulating film 110cf) and the fourth insulating film. The ammonia flow rate ratio at the time of forming the fifth insulating film was made higher than the ammonia flow rate ratio at the time of forming the fourth insulating film (the insulating film 110cf).

Then, an approximately 100-nm-thick In—Sn—Si oxide (ITSO) film was formed as the conductive film 112bf over the fifth insulating film by a sputtering method.

Subsequently, the conductive film 112bf was processed to form the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to form the semiconductor layer 108.

Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to form the conductive layer 104.

Thus, a transistor corresponding to the transistor 100C was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Through the above process, Sample F was formed.

### <Id-Vg Characteristics>

Then, the Id-Vg characteristics of the transistors of Sample F fabricated in the above manner were measured.

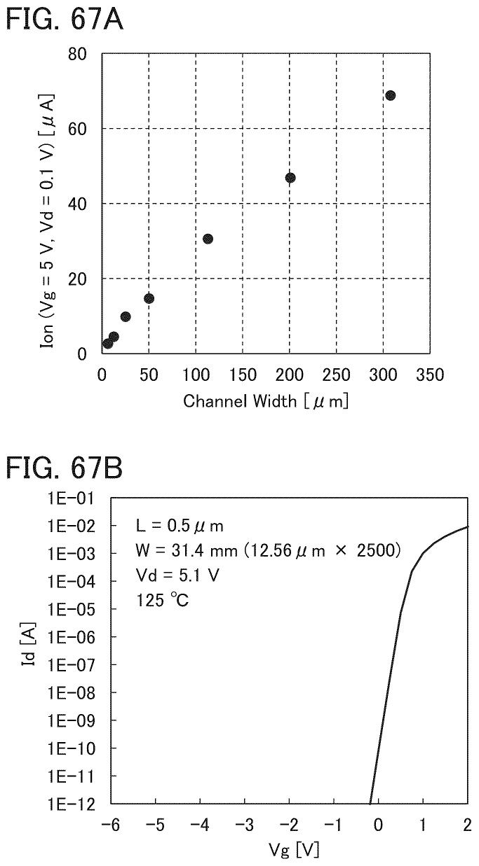

Here, the measurement was performed on the transistor 100C in which the width D141 of the opening 141 of each of the transistor 100_1 to the transistor 100_p was 2.0 μm (the channel width W100 of each of the transistor 100_1 to the transistor 100_p was approximately 6.3 μm) and the transistor 100C in which the width D141 was 4.0 μm (the channel width W100 of each of the transistor 100_1 to the transistor 100_p was approximately 12.6 μm). In addition, the measurement was performed on the transistors 100C different in the number p of transistors connected in parallel. Note that the channel length L100 was approximately 0.5 μm. FIG. 67A shows the on-state current of Sample F at a drain voltage (Vd) of 0.1 V and a gate voltage (Vg) of 5 V. In FIG. 67A, the horizontal axis represents the channel width and the vertical axis represents the on-state current (Ion).

As shown in FIG. 67A, it was confirmed that the on-state current of the transistors connected in parallel increased in proportion to the channel width.

FIG. 67B shows the Id-Vg characteristics of transistors connected in parallel, which are different from the transistors described above. For the measurement of the Id-Vg characteristics, the gate voltage (Vg) was applied from −10 V to +3 V in increments of 0.25 V. In addition, the source voltage (Vs) was 0 V (comm), and the drain voltage (Vd) was 5.1 V. The measurement temperature was set at 125° C. In FIG. 67B, the horizontal axis represents the gate voltage (Vg) and the vertical axis represents the drain current (Id). FIG. 67B shows the range of the gate voltage (Vg) from −6 V to +3 V. Here, the measurement was performed on the transistor 100C in which the width D141 of the opening 141 of each of the transistor 100_1 to the transistor 100_p was 4.0 μm (the channel width W100 of each of the transistor 100_1 to the transistor 100_p was approximately 12.6 μm) and the number p of transistors connected in parallel was 2500, that is, the channel width W100 was approximately 31.4 mm. Note that the channel length L100 was approximately 0.5 μm.

As shown in FIG. 67B, the drain current (Id) when the transistor was off was below the lower measurement limit. Note that the lower measurement limit of the drain current (Id) was approximately 1×10⁻¹³ A.

As described above, it was confirmed that even the transistor with a large channel width W100 had an extremely low off-state current.

### Example 8

In this example, transistors were fabricated, and their electrical characteristics were evaluated.

In this example, Sample G including the transistors of one embodiment of the present invention was fabricated. For the structures of the transistors included in Sample G, the description of the transistor 100 illustrated in FIG. 11A can be referred to.

### <Fabrication of Sample>

First, an approximately 300-nm-thick copper film to be the conductive layer 112a_1 was formed over the substrate 102 by a sputtering method, and then processed to form the conductive layer 112a_1. Next, an approximately 100-nm-thick In—Sn—Si oxide (ITSO) film to be the conductive layer 112a_2 was formed by a sputtering method, and then processed to form the conductive layer 112a_2, whereby the conductive layer 112a was obtained. A glass substrate with a size of 600 mm×720 mm was used as the substrate 102.

Next, an approximately 70-nm-thick silicon nitride film was formed as the first insulating film to be the insulating layer 110d, an approximately 100-nm-thick silicon nitride film was formed as the second insulating film (the insulating film 110af) to be the insulating layer 110a, and an approximately 500-nm-thick silicon oxynitride film was formed as the third insulating film (the insulating film 110bf) to be the insulating layer 110b. The first insulating film to the third insulating film were successively formed in a vacuum by a PECVD method.

Next, an approximately 20-nm-thick metal oxide layer was formed as the metal oxide layer 137 over the third insulating film (the insulating film 110bf). The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 50-nm-thick silicon nitride film was formed as the fourth insulating film (the insulating film 110cf) to be the insulating layer 110c over the third insulating film (the insulating film 110bf), and an approximately 100-nm-thick silicon nitride film was formed as the fifth insulating film to be the insulating layer 110e. The fourth insulating film and the fifth insulating film were successively formed in a vacuum by a PECVD method. Note that silane (SiH₄), nitrogen (N₂), and ammonia (NH₃) were used as film formation gases for forming the fourth insulating film (the insulating film 110cf) and the fifth insulating film. The ammonia flow rate ratio at the time of forming the fifth insulating film was made higher than the ammonia flow rate ratio at the time of forming the fourth insulating film (the insulating film 110cf).

Then, an approximately 100-nm-thick In—Sn—Si oxide (ITSO) film was formed as the conductive film 112bf over the fifth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1. Note that the oxygen flow rate ratio at the time of forming the metal oxide film 108f in Sample G was different from the oxygen flow rate ratio at the time of forming the metal oxide film 108f in Sample B described in Example 2.

Next, heat treatment was performed at 350° C. in a dry air atmosphere for one hour. An oven apparatus was used for the heat treatment.

Then, the metal oxide film 108f was processed to obtain the semiconductor layer 108. Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Through the above process, Sample G was obtained.

### <Id-Vg Characteristics>

Then, the Id-Vg characteristics of the transistors of Sample G fabricated in the above manner were measured.

For the measurement of the Id-Vg characteristics of the transistors, the gate voltage (Vg) was applied from −10 V to +10 V in increments of 0.1 V. In addition, the source voltage (Vs) was 0 V (comm), and the drain voltage (Vd) was 0.1 V and 5.1 V.

Here, the measurement was performed on the transistor with the channel width W100 of approximately 6.3 μm (the width D141 of the opening 141 of 2.0 μm). The number of measurements was set to 120 in a substrate plane of 600 mm×720 mm. Note that the channel length L100 was approximately 0.5 μm.

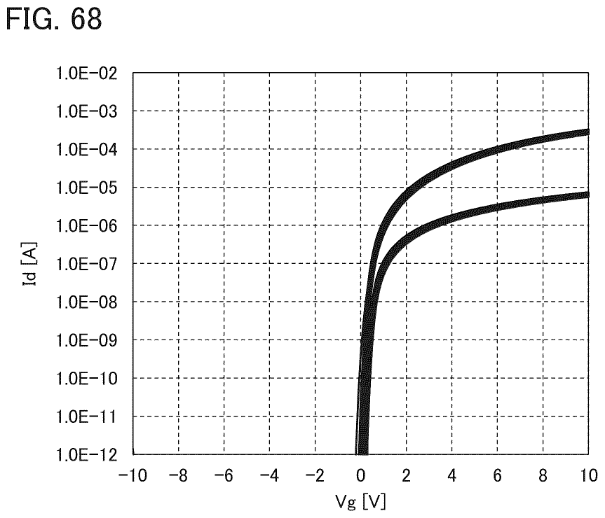

FIG. 68 shows the Id-Vg characteristics. In FIG. 68, the horizontal axis represents the gate voltage (Vg) and the vertical axis represents the drain current (Id). FIG. 68 shows superimposed Id-Vg characteristics of the 120 transistors.

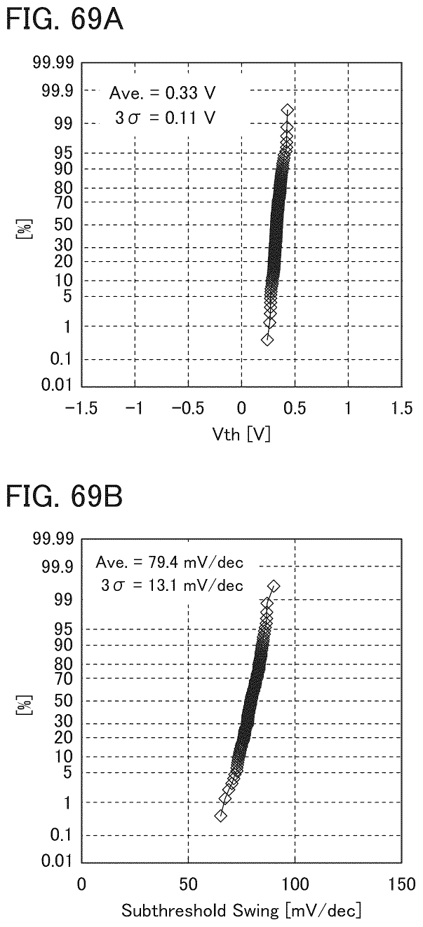

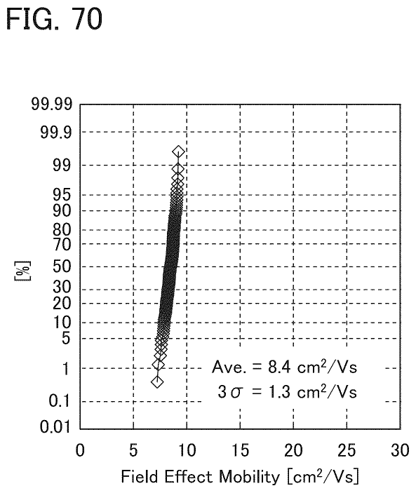

FIG. 69A, FIG. 69B, and FIG. 70 respectively show probability distributions of the threshold voltage, the S value, and the field-effect mobility (uFE) obtained from the above Id-Vg characteristics. In FIG. 69A, the horizontal axis represents the threshold voltage (Vth) and the vertical axis represents the cumulative probability. In FIG. 69B, the horizontal axis represents the S (Subthreshold Swing) value and the vertical axis represents the cumulative probability. In FIG. 70, the horizontal axis represents the field effect mobility and the vertical axis represents the cumulative probability.

As shown in FIG. 69A, FIG. 69B, and FIG. 70, it was confirmed that all of normally-off characteristics, a high on-state current, and a low off-state current were achieved in Sample G. It was also confirmed that an in-plane variation in electrical characteristics was small. The average S value was 79.4 mV/dec, showing that the interface between the semiconductor layer 108 and the gate insulating layer (the insulating layer 106) was formed favorably.

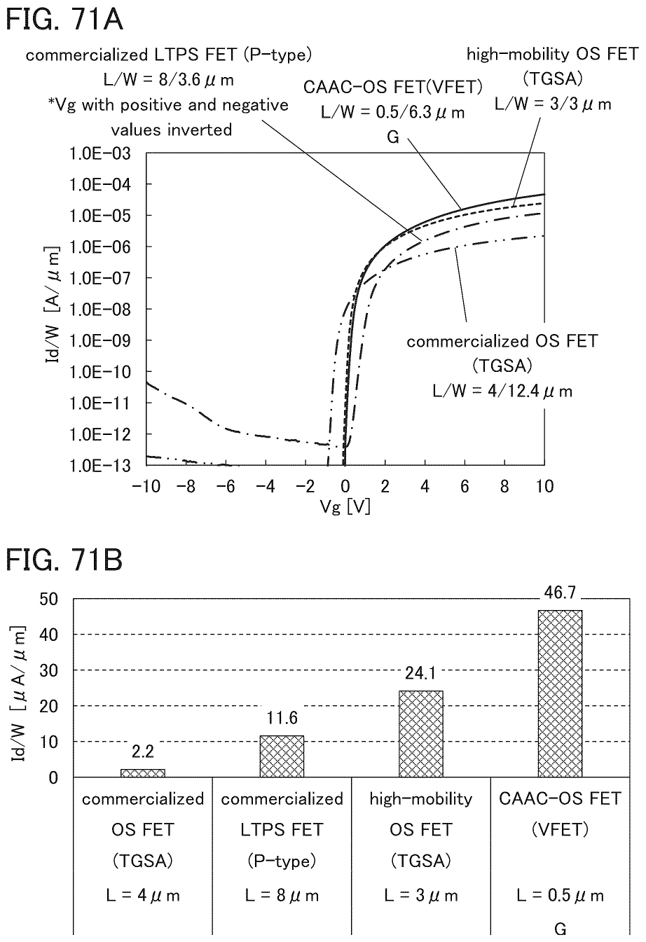

FIG. 71A shows the Id-Vg characteristics. In FIG. 71A, the horizontal axis represents the gate voltage (Vg) and the vertical axis represents the drain current (Id). FIG. 71B shows the on-state current per channel width. In FIG. 71B, the horizontal axis represents the sample condition and the vertical axis represents the value (Id/W) obtained by dividing the on-state current by the channel width. For the on-state current, a value at a drain voltage (Vd) of 5.1 V and a gate voltage (Vg) of 10 V was used.

FIG. 71A and FIG. 71B show the data of Sample G (indicated by a solid line, and denoted as “CAAC-OS FET (VFET) L/W=0.5/6.3 μm” in FIG. 71A and denoted as “CAAC-OS FET (VFET) L=0.5 μm” in FIG. 71B), and also show the data of an n-channel TGSA transistor (indicated by a dashed line, and denoted as “high-mobility OS FET (TGSA) L/W=3/3 μm” in FIG. 71A and denoted as “high-mobility OS FET (TGSA) L=3 μm” in FIG. 71B). Furthermore, as the data of transistors each included in a commercial display apparatus, an n-channel TGSA transistor using an In—Ga—Zn oxide for its semiconductor layer (indicated by a dashed-dotted line, and denoted as “commercialized OS FET (TGSA) L/W=4/12.4 μm” in FIG. 71A and denoted as “commercialized OS FET (TGSA) L=4 μm” in FIG. 71B) and a p-channel TGSA transistor using LTPS for its semiconductor layer (indicated by a dashed double-dotted line, and denoted as “commercialized LTPS FET (P-type) L/W=8/3.6 μm” in FIG. 71A and denoted as “commercialized LTPS FET (P-type) L=8 μm” in FIG. 71B) are also shown. Note that in FIG. 71A, the Id-Vg characteristics of the p-channel TGSA transistor using LTPS are shown with the positive and negative values of Vg inverted. The data other than that of Sample G in FIG. 71B is the same as the data shown in FIG. 60.

As shown in FIG. 71B, it was confirmed that the transistor of Sample B with a submicron-sized channel length had an on-state current approximately four times that of the p-channel LTPS transistor included in a commercial display apparatus.

### <Reliability>

Next, the reliability of Sample G fabricated in the above manner was evaluated.

For the reliability evaluation, a GBT stress test was performed. In this example, a PBTS test and an NBTIS test were performed.

In the PBTS test, a substrate over which the transistors were formed was held at 60° C., a voltage of 0.1 V was applied to the sources and the drains of the transistors, and a voltage of 20 V was applied to the gates; this state was maintained for one hour. The test was performed in a dark environment. In the NBTIS test, a substrate over which the transistors were formed was held at 60° C., a voltage of 0 V was applied to the sources and the drains of the transistors, and a voltage of −20 V was applied to the gates in a state where irradiation with white LED light at 5000 lx was performed; this state was maintained for one hour. The irradiation with white LED light was performed from the glass substrate side. In the PBTS test and the NBTIS test, the transistor with the channel width W100 of approximately 6.3 μm (the width D141 of the opening 141 of 2.0 μm) was used. Note that the channel length L100 was approximately 0.5 μm.

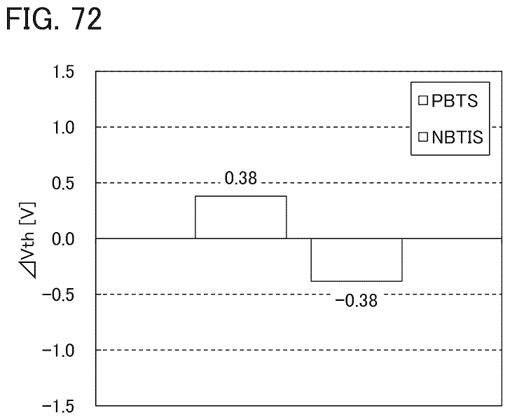

FIG. 72 shows the amounts of change in the threshold voltage between before and after the PBTS test and between before and after the NBTIS test. As shown in FIG. 72, the amount of change in the threshold voltage was small in both the PBTS test and the NBTIS test, which confirmed high reliability.

From the above results, it was confirmed that a transistor with a short channel length, favorable electrical characteristics, and high reliability was obtained.

### Example 9

In this example, an OLED panel (also referred to as an OLED display, an organic EL panel, or an organic EL display) was fabricated as the display apparatus of one embodiment of the present invention. Here, an OLED panel having a resolution of 513 ppi, an RGB stripe pixel arrangement, and an internal correction circuit was fabricated using a glass substrate with a size of 600 mm×720 mm. Table 2 shows the specifications of the fabricated OLED panel.

TABLE 2

| | Specifications | |
|---|---|---|
| Screen diagonal | 5.72 | inches |
| Resolution | 1440 (H) × RGB × 2560 (V) | |
| Pixel density | 513 | ppi |

| | |
|---|---|
| Pixel size | 49.5 μm (H) × 49.5 μm (V) |
| Pixel arrangement | RGB stripe |
| Pixel circuit | 6Tr + 2C |
| Aperture ratio | 39% |
| Coloring method | MML |
| Emission type | Top emission |
| Source driver | External IC |
| Demultiplexer | Two-divided |
| Scan driver | Integrated |

For the structures of the transistors used in the OLED panel, the structures of the transistor 100 and the transistor 200 illustrated in FIG. 11A can be referred to. An oxide semiconductor (OS) was used for the semiconductor layer 108 and the semiconductor layer 208. The transistor 100, which is a VFET, had the channel length L100 of approximately 0.5 μm and the channel width W100 of approximately 6.3 μm (the width D141 of the opening 141 of 2.0 μm). For the structure of the pixel circuit, the description of FIG. 30 to FIG. 42 can be referred to. A VFET including an oxide semiconductor (OS) was also used for a gate driver and a demultiplexer (DeMUX). The use of the VFET enabled layout of six transistors (6Tr) and two capacitors (2C) in one subpixel (size: 16.5 μm×49.5 μm).

The MML structure was employed for the light-emitting element. For the structure of the light-emitting element, the description of FIG. 46A can be referred to. Note that the light-blocking layer 117 was not provided. In addition, for the fabrication method, the description of FIG. 51A to FIG. 51F can be referred to.

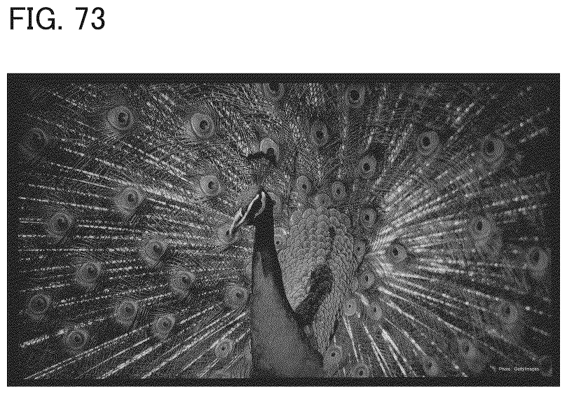

FIG. 73 is a photograph showing the display state of the OLED panel. It was confirmed that the pixel circuit, the gate driver, and the DeMUX each operated without any problems and various images were displayed.

### Example 10

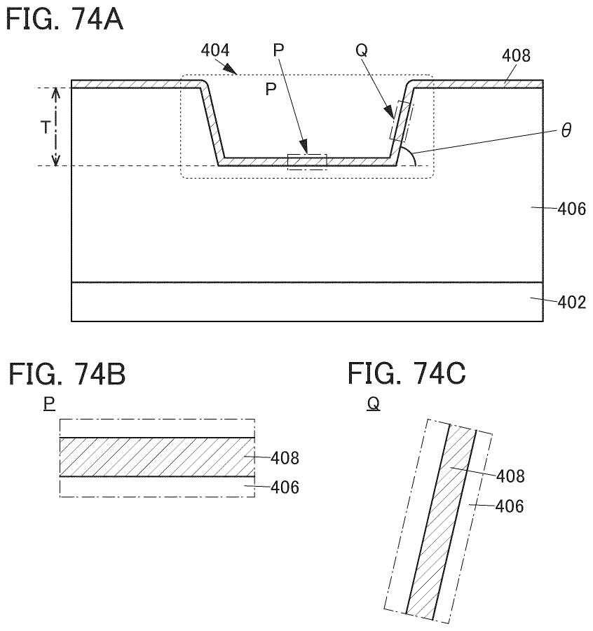

In this example, samples (Sample H1 and Sample H₂) each imitating the VFET described in Embodiment 1 were fabricated, and the crystal orientation of a metal oxide was evaluated. FIG. 74A is a cross-sectional view illustrating the structure of the sample. FIG. 74B is an enlarged view of a region P indicated by a dashed-dotted line in FIG. 74A, and FIG. 74C is an enlarged view of a region Q indicated by a dashed-dotted line.

### <Fabrication of Samples>

First, an insulating layer 406 with a thickness of approximately 500 nm was formed over a substrate 402. As the insulating layer 406, a silicon oxynitride film was formed by PECVD. A silicon wafer was used as the substrate 402.

Then, a groove 404 (corresponding to the opening 141) was formed in the insulating layer 406. The groove 404 was formed by a dry etching method. An angle θ of the side surface of the groove 404 with respect to the top surface of the insulating layer 406 (corresponding to θ110 in FIG. 3) was approximately 77°. A depth T of the groove 404 was approximately 200 nm.

Next, a metal oxide layer 408 (corresponding to the semiconductor layer 108) was formed over the insulating layer 406. The metal oxide layer 408 of Sample H1 was formed by a sputtering method using an IGZO sputtering target with an atomic ratio of metal elements of In:Ga:Zn=1:1:1. The metal oxide layer 408 of Sample H₂ was formed by a sputtering method using an ITZO sputtering target with an atomic ratio of metal elements of In:Sn:Zn=40:1:10 (4:0.1:1). Note that the thickness of the metal oxide layer 408 was approximately 20 nm in the bottom portion (the region P) of the groove 404 and approximately 12 nm in the sidewall portion (the region Q) of the groove 404. Note that the thickness of the metal oxide layer 408 in the region P was the shortest distance between the formation surface of the metal oxide layer 408 (here, the top surface of the insulating layer 406) and the top surface of the metal oxide layer 408 in the cross-sectional view, and the thickness in the region Q was the shortest distance between the formation surface of the metal oxide layer 408 (here, the side surface of the insulating layer 406) and the side surface of the metal oxide layer 408 in the cross-sectional view.

### <STEM Observation and Evaluation of Crystal Orientation>

Next, Sample H1 and Sample H₂ were thinned by focused ion beam (FIB) and cross sections were observed with a transmission electron microscope (by TEM: scanning transmission electron microscopy). The region P and the region Q were observed in each of Sample H1 and Sample H₂.

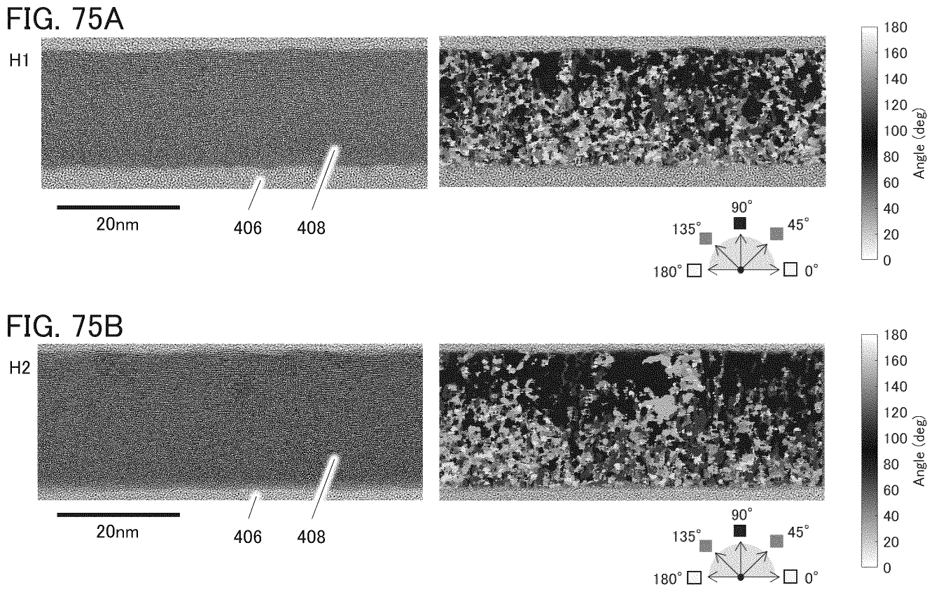

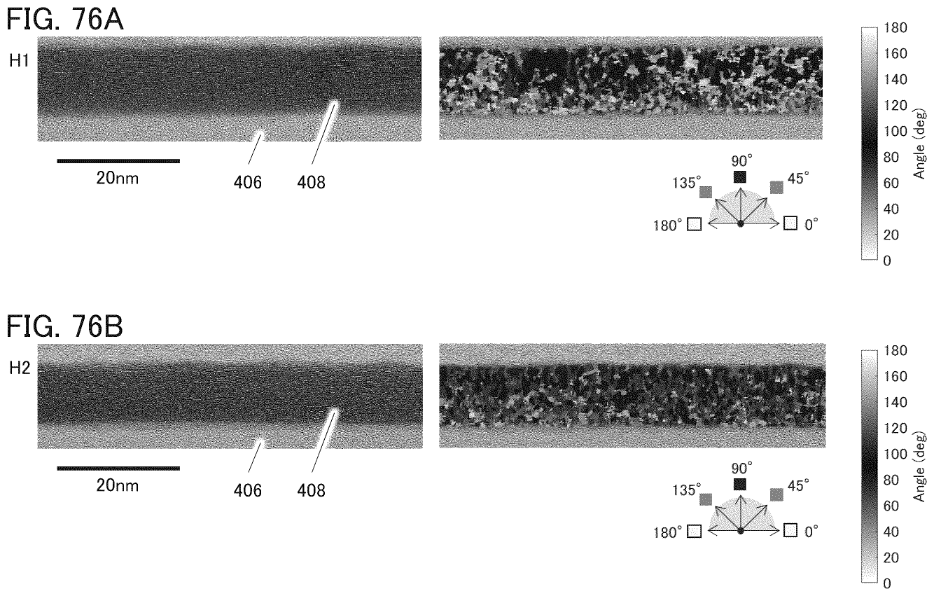

FIG. 75A shows a cross-sectional TEM image and crystal orientations in the region P of Sample H1. FIG. 75B shows a cross-sectional TEM image and crystal orientations in the region P of Sample H₂. FIG. 76A shows a cross-sectional TEM image and crystal orientations in the region Q of Sample H1. FIG. 76B shows a cross-sectional TEM image and crystal orientations in the region Q of Sample H₂.

In FIG. 75A to FIG. 76B, the images on the left side are transmission electron (TE) images at a magnification of 2,000,000 times. In each of the regions P and the regions Q of Sample H1 and Sample H₂, a layered lattice image was observed. It was confirmed that Sample H1 and Sample H₂ had crystallinity in each of the region P and the region Q.

In FIG. 75A to FIG. 76B, the diagrams on the right side show the crystal orientations obtained from the cross-sectional TEM images. The cross-sectional TEM images were subjected to fast Fourier transform (FFT) processing on the region basis to obtain FFT patterns, and the directions of crystal axes in each region were obtained; thus, the diagrams showing crystal orientations (also referred to as maps showing crystal orientations) were obtained. Note that a region where FFT was performed (also referred to as an FFT window) was a circle with a diameter of 1.0 nm. The FFT pattern obtained by the FFT processing reflects reciprocal lattice space information like an electron diffraction pattern.

In the diagrams on the right side in FIG. 75A to FIG. 76B, the directions of the crystal axes with respect to the formation surface of the metal oxide layer 408 (the top surface of the insulating layer 406 in the region P and the side surface of the insulating layer 406 in the region Q) are represented by a gray scale. Specifically, the angle of the crystal axis with respect to the formation surface of the metal oxide layer 408 is shown; 90° is represented by black (dark color), and 0° and 180° are represented by white (light color). As shown in FIG. 75A and FIG. 75B, it was confirmed that the region P, which is the bottom surface portion of the groove 404, had the crystal orientation in the direction perpendicular to the top surface of the insulating layer 406, which is the formation surface of the metal oxide layer 408. As shown in FIG. 76A and FIG. 76B, it was confirmed that the region Q, which is the side surface portion of the groove 404, had the crystal orientation in the direction perpendicular to the side surface of the insulating layer 406, which is the formation surface of the metal oxide layer 408.

### Example 11

In this example, transistors were fabricated, and the electrical characteristics were evaluated.

In this example, a sample (Sample J) including the transistors of one embodiment of the present invention was fabricated. For the structures of the transistors included in Sample J, the description of the transistor 100 illustrated in FIG. 11A and the transistor 100C illustrated in FIG. 14A can be referred to. Note that the conductive layer 112a had the stacked-layer structure illustrated in FIG. 6B.

### <Fabrication of Sample>

First, an approximately 100-nm-thick tungsten film to be the conductive layer 112a_1 was formed over the substrate 102 by a sputtering method, and then processed to form the conductive layer 112a_1. Next, an approximately 100-nm-thick In—Sn—Si oxide (ITSO) film to be the conductive layer 112a_2 was formed by a sputtering method, and then processed to form the conductive layer 112a_2, whereby the conductive layer 112a was obtained. A glass substrate with a size of 600 mm×720 mm was used as the substrate 102.

Next, an insulating film to be the insulating layer 110 was formed. The above description in Example 7 can be referred to for the steps from the formation of the insulating film to the formation of the semiconductor layer 108.

Subsequently, as the insulating layer 106, an approximately 60-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to form the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Through the above process, Sample J was formed.

### <Id-Vg Characteristics>

Then, the Id-Vg characteristics of the transistors of Sample J fabricated in the above manner were measured.

For the measurement of the Id-Vg characteristics of the transistors, the gate voltage (Vgs) was applied from −6 V to +6 V in increments of 0.1 V. In addition, the source voltage (Vs) was 0 V (comm), and the drain voltage (Vds) was 1.2 V. The Id-Vg characteristics of the case where the conductive layer 112a serves as the source and the conductive layer 112b serves as the drain and the Id-Vg characteristics of the case where the conductive layer 112b serves as the source and the conductive layer 112a serves as the drain were measured. The measurement temperature was set at 27° C.

Here, the measurement was performed on the transistor with the channel width W100 of approximately 6.3 μm (the width D141 of the opening 141 of 2.0 μm), which corresponds to the transistor 100 illustrated in FIG. 11A. Note that the channel length L100 was approximately 0.5 μm.

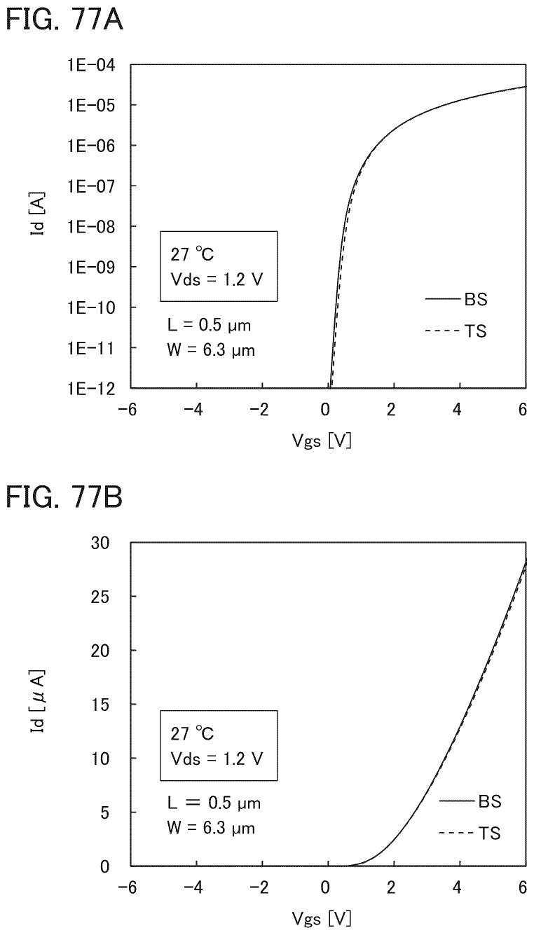

FIG. 77A and FIG. 77B show the Id-Vg characteristics of Sample J. In FIG. 77A and FIG. 77B, the horizontal axis represents the gate voltage (Vgs) and the vertical axis represents the drain current (Id). In FIG. 77A, the vertical axis is shown with a logarithmic scale, and in FIG. 77B, the vertical axis is shown with a linear scale. In FIG. 77A and FIG. 77B, the Id-Vg characteristics of the case where the conductive layer 112a serves as the source and the conductive layer 112b serves as the drain are denoted as “BS” and indicated by solid lines. The Id-Vg characteristics of the case where the conductive layer 112b serves as the source and the conductive layer 112a serves as the drain are denoted as “TS” and indicated by dashed lines. In FIG. 77A and FIG. 77B, the channel length is denoted as “L=0.5 μm” and the channel width is denoted as “W=6.3 μm”.

Table 3 shows the threshold voltage (Vth), the on-state current (Ion), and the S value (SS) obtained from the above Id-Vg characteristics. Note that the on-state current (Ion) is the drain current (Id) at a gate voltage (Vgs) of “Vth+5 V”.

TABLE 3

| | BS | TS |
|---|---|---|
| Vth [V] | 0.57 | 0.58 |
| Ion* [μA] | 24.6 | 24.3 |
| SS [mV/dec] | 90.0 | 89.0 |

*Ion = Id (Vds = 1.2 V, Vgs = Vth + 5 V)

As shown in FIG. 77A, FIG. 77B, and Table 3, it was confirmed that the difference in the threshold voltage (Vth) between the Id-Vg characteristics of the case where the conductive layer 112a serves as the source and the conductive layer 112b serves as the drain and the Id-Vg characteristics of the case where the conductive layer 112b serves as the source and the conductive layer 112a serves as the drain was as small as approximately 10 mV. It was also confirmed that the difference in the on-state currents (Ion) was as small as approximately 1.2%. The drain current (Id) when the transistor was off was below the lower measurement limit. Note that the lower measurement limit of the drain current (Id) was approximately 1×10⁻¹³ A.

### <Off-State Current>

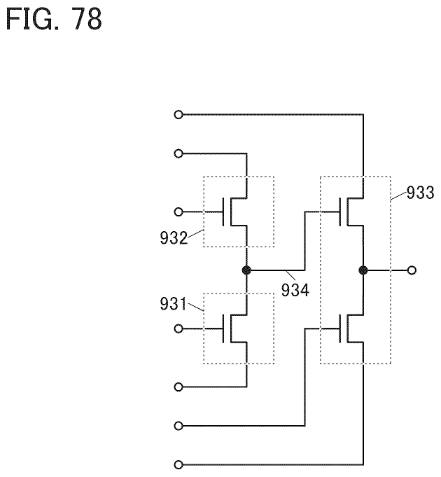

Next, the off-state current of the transistor was evaluated using a TEG (Test Element Group). FIG. 78 is a circuit diagram of the TEG used for the evaluation. With the use of the TEG, the off-state current was calculated from the time taken for the potential of a floating node connected to the drain of the transistor in an off state to be changed. In FIG. 78, a transistor 931 is a transistor serving as an evaluation target (DUT: Device under test).

A method for calculating the off-state current is described. First, in the TEG illustrated in FIG. 78, the transistor 931 is turned off. Next, a transistor 932 is turned on to initialize the potential of a wiring 934 to be a floating node to a predetermined potential, and then the transistor 932 is turned off to bring the wiring 934 into a floating state. Consequently, the potential of the floating node is gradually changed by the off-state current of the transistor 931. This potential change is observed with a source follower of a circuit portion 933, whereby the off-state current of the transistor 931, which is the DUT, can be calculated.

Here, a transistor corresponding to the transistor 100C illustrated in FIG. 14A was used as the transistor 931, which was the DUT. The width D141 of the opening 141 of each of the transistor 100_1 to the transistor 100_p was 2.0 μm (the channel width W100 of each of the transistor 100_1 to the transistor 100_p was approximately 6.3 μm), and the number p of transistors connected in parallel was 4000, that is, the channel width W100 was approximately 2.5 cm. Note that the channel length L100 was approximately 0.5 μm.

The transistor 931 was turned off by application of −3 V to the gate, and the off-state current was calculated from the change in the potential of the floating node initialized to 1.2 V. The Id-Vg characteristics of the case where the conductive layer 112a serves as the source and the conductive layer 112b serves as the drain and the Id-Vg characteristics of the case where the conductive layer 112b serves as the source and the conductive layer 112a serves as the drain were measured. The measurement temperature was set at 125° C., 100° C., and 85° C.

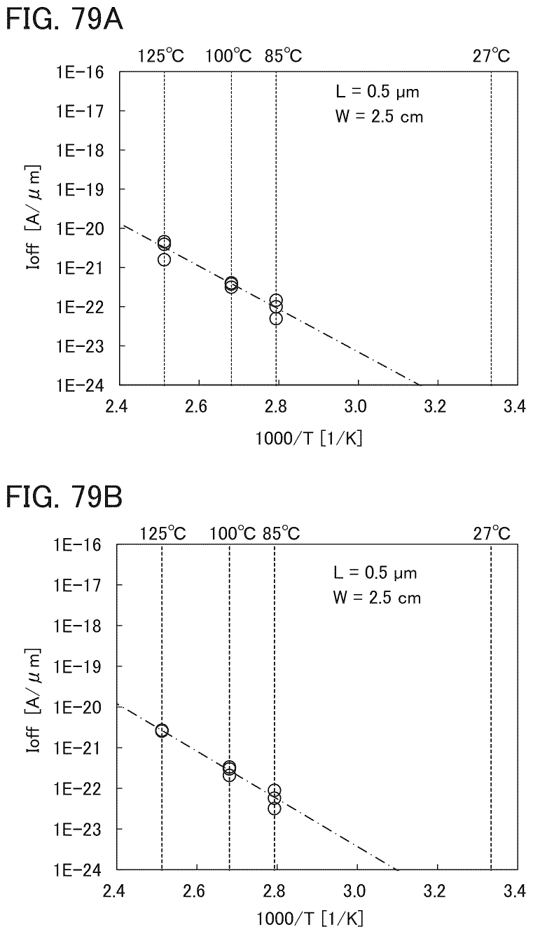

FIG. 79A and FIG. 79B show Arrhenius plots of the off-state current of the transistor 931. FIG. 79A is an Arrhenius plot of the case where the conductive layer 112a serves as the source and the conductive layer 112b serves as the drain. FIG. 79B is an Arrhenius plot of the case where the conductive layer 112b serves as the source and the conductive layer 112a serves as the drain. In FIG. 79A and FIG. 79B, the horizontal axis represents the inverse of temperature T (1000/T) and the vertical axis represents the calculated value of an off-state current (Ioff) per micrometer of channel width. A regression line obtained from the calculated values of the off-state current is indicated by a dashed-dotted line. In FIG. 79A and FIG. 79B, the channel length is denoted as “L=0.5 μm” and the channel width is denoted as “W=2.5 cm”. As shown in FIG. 79A and FIG. 79B, the off-state current of the fabricated transistor at 85° C. was lower than 1.0×10⁻²¹ A/μm. The off-state current at room temperature (e.g., 27° C.) was estimated to be lower than 1.0×10⁻²⁴ A/μm.

From the above results, it was confirmed that a transistor with a short channel length and an extremely low off-state current was obtained.

### Example 12

In this example, a TGSA transistor applicable to one embodiment of the present invention was fabricated, and its electrical characteristics were evaluated.

In this example, a sample (Sample K) including the transistor was fabricated. For the structure of the transistor included in Sample K, the description of the transistor 200 illustrated in FIG. 1B can be referred to. Note that the conductive layer 212a and the conductive layer 212b were formed in steps different from that in which the conductive layer 204 is formed.

### <Fabrication of Sample>

The transistor was formed over a substrate. A glass substrate with a size of 600 mm×720 mm was used as the substrate. An approximately 100-nm-thick tungsten film was used as the conductive layer 202. An approximately 300-nm-thick silicon nitride film was used as the insulating layer 120a, and an approximately 5-nm-thick silicon oxynitride film was used as the insulating layer 120b. As the semiconductor layer 208, an approximately 20-nm-thick metal oxide film was used. The metal oxide film was formed by a sputtering method using an IGZO sputtering target with an atomic ratio of metal elements of In:Ga:Zn=1:1:1. As the insulating layer 106, an approximately 100-nm-thick silicon oxynitride film was used. For the conductive layer 204, a stacked-layer structure where a 50-nm-thick molybdenum film, a 200-nm-thick aluminum film, and a 50-nm-thick titanium film were formed in this order was used. A source region and a drain region were formed by supplying an impurity element (here, boron) to the semiconductor layer 208 using the conductive layer 204 as a mask. An insulating film was formed over the conductive layer 204, and openings reaching the semiconductor layer 208 were formed in the insulating film. The conductive layer 212a and the conductive layer 212b were formed to cover the openings. For the insulating film, a stacked-layer structure where an approximately 300-nm-thick silicon nitride oxide film and an approximately 2-μm-thick polyimide film were formed in this order was used. For each of the conductive layer 212a and the conductive layer 212b, a stacked-layer structure where an approximately 50-nm-thick titanium film, an approximately 300-nm-thick aluminum film, and an approximately 50-nm-thick titanium film were formed in this order was used.

Through the above process, Sample K including the TGSA transistor corresponding to the transistor 200 was formed.

### <Id-Vg Characteristics>

Then, the Id-Vg characteristics of the transistor of Sample K fabricated in the above manner were measured.

For the measurement of the Id-Vg characteristics of the transistor, the gate voltage (Vgs) was applied from −6 V to +6 V in increments of 0.1 V. In addition, the source voltage (Vs) was 0 V (comm), and the drain voltage (Vds) was 1.2 V. The measurement temperature was set at 27° C.

Here, the measurement was performed on the transistor with the channel length L200 of approximately 3 μm and the channel width W200 of approximately 3 μm.

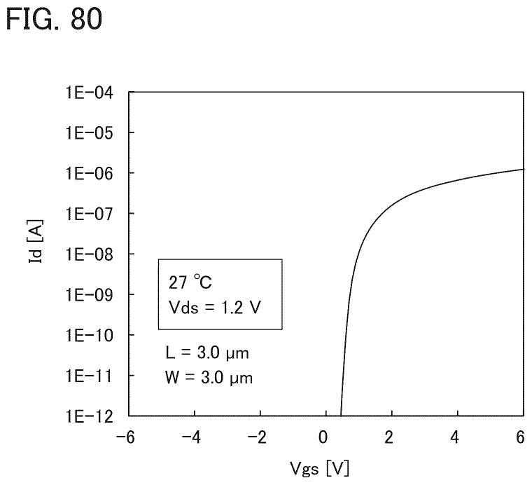

FIG. 80 shows the Id-Vg characteristics of Sample K. In FIG. 80, the horizontal axis represents the gate voltage (Vgs) and the vertical axis represents the drain current (Id). In FIG. 80, the vertical axis is shown with a logarithmic scale. In FIG. 80, the channel length is denoted as “L=3.0 μm” and the channel width is denoted as “W=3.0 μm”.

As shown in FIG. 80, it was confirmed that a transistor with favorable electrical characteristics was obtained.

### Example 13

In this example, the diffusion coefficient of oxygen in an insulating film was evaluated. In this example, seven kinds of samples (Sample L1 to Sample L7) were fabricated.

### <Fabrication of Samples>

First, an approximately 30-nm-thick silicon nitride film and an approximately 300-nm-thick silicon oxynitride film over the silicon nitride film were formed over a glass substrate by a PECVD method. The silicon oxynitride film corresponds to the insulating layer 110b. Silane (SiH₄) and dinitrogen monoxide (N₂O) were used as film formation gases for forming the silicon oxynitride film, and the flow rate of silane was 200 sccm. The F ratio at the time of forming the silicon oxynitride film was varied among Sample L1 to Sample L7. For Sample L1, the RF power was set to 800 W and the F ratio was set to 4. For Sample L2, the RF power was set to 900 W and the F ratio was set to 4.5. For Sample L3, the RF power was set to 1000 W and the F ratio was set to 5. For Sample L4, the RF power was set to 1200 W and the F ratio was set to 6. For Sample L5, the RF power was set to 1400 W and the F ratio was set to 7. For Sample L6, the RF power was set to 2000 W and the F ratio was set to 10. For Sample L7, the RF power was set to 3000 W and the F ratio was set to 15. Note that in the calculation of the F ratio here, the unit of the flow rate of the deposition gas was sccm, which is the unit of flow rate of silane gas, and the unit of the RF power was W (Watt).

Next, an approximately 20-nm-thick metal oxide layer was formed over the silicon oxynitride film. The metal oxide layer 137 was formed by a sputtering method using an IGZO sputtering target with an atomic ratio of metal elements of In:Ga:Zn=1:1:1. The metal oxide layer corresponds to the metal oxide layer 137.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Through the above process, Sample L1 to Sample L7 were obtained.

### <TDS Analysis>

By thermal desorption spectroscopy (TDS), the TDS spectra of the samples were obtained. In the TDS, the substrate temperature was increased from approximately 50° C. to approximately 550° C. Note that in the TDS, the desorbed amount (also referred to as the released amount) can be quantified from the detection intensity of the mass analyzer. To convert the detected intensity (here, the current value) into the desorbed amount, a standard sample in which the desorbed amount of hydrogen (¹H₂, m/z=2) is known can be used, for example.

A method for calculating a diffusion coefficient from a TDS spectrum is described.

A diffusion coefficient D(T) of a substance in a solid at the temperature T can be represented by Arrhenius equation shown in Formula (1).

$$\begin{matrix}[ Formla 1 ] & \\ D ( T ) = {D}_{0} exp ( - \frac{E}{kT} ) & ( 1 )\end{matrix}$$

In Formula (1) above, Do represents a frequency factor, E represents the activation energy of diffusion, and k represents the Boltzmann constant. The temperature T is an absolute temperature.

In the case where diffusion of a substance in a solid is a bottleneck process for desorption of the substance from the solid, a desorption rate q(T) of the substance at the temperature T can be represented by Formula (2). The desorption rate q(T) represented by Formula (2) is the desorbed amount per unit time. In addition, a function φ(T) in Formula (2) is a p-function of Doyle, and can be represented by Formula (3).

$$\begin{matrix}[ Formla 2 ] & \\ q ( T ) = \frac{2 {C}_{0} {D}_{0}}{d} exp ( - \frac{E}{kT} ) \times {\sum }_{m = 0}^{∞} exp \{ - {[ \frac{( 2 m + 1 ) π T}{2 d} ]}^{2} ( \frac{{kD}_{0}}{β E} ) exp ( - \frac{E}{kT} ) ψ ( T ) & ( 2 )\end{matrix}$$

$$ψ ( T ) = {\sum }_{j = 1}^{∞} j ! {( - \frac{kT}{E} )}^{j - 1} \qquad ( 3 )$$

In Formula (2) and Formula (3) above, C₀ represents the initial concentration, d represents the thickness, E represents the activation energy of diffusion, and B represents the temperature rising rate. A variable m is an integer greater than or equal to 0, and a variable j is an integer greater than or equal to 1. Note that in Formula (2) above, the concentration (initial concentration) of a substance in a solid before heating (also referred to as an initial state) is uniform at “C₀”.

Here, the diffusion coefficient D of oxygen in the insulating film (specifically, the silicon oxynitride film) can be represented by Formula (1). The desorption rate q(T) of oxygen from the insulating film at the temperature T can be represented by Formula (2).

The obtained TDS spectrum was fitted with Formula (2) and Formula (3) above, whereby the values of the initial concentration C₀, the frequency factor Do, and the activation energy E were obtained. A least squares method was used for the fitting. Note that the thickness of the silicon oxynitride film (here, 3.0×10⁻⁵ cm) was used as the thickness d, and the temperature rising rate of the sample (here, 0.292 K/sec) was used as the temperature rising rate 8. The variable m was set from 0 to 100, and the variable j was set from 1 to 3.

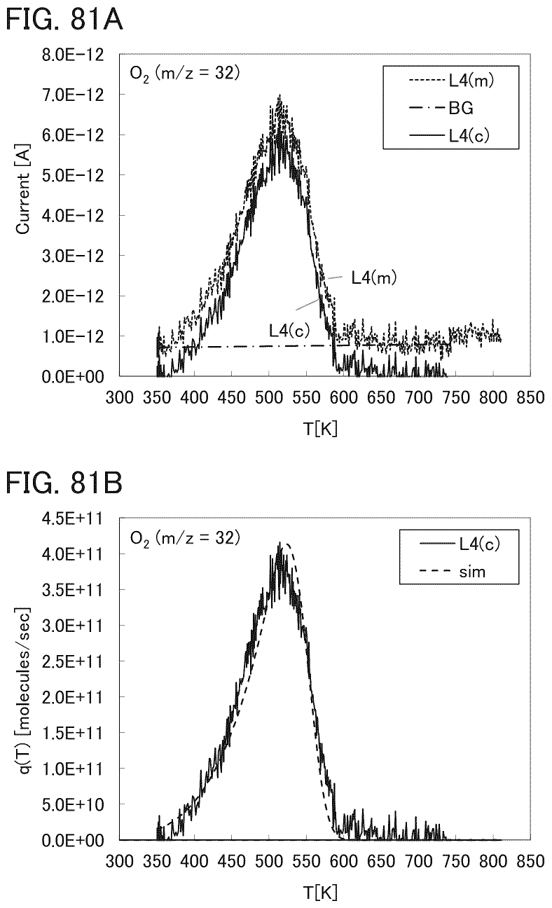

FIG. 81A shows the TDS spectra of oxygen (¹⁶O₂, m/z=32) in Sample L4. In FIG. 81A, the horizontal axis represents the temperature T of the sample and the vertical axis represents the current value (Current) of the mass analyzer. FIG. 81A shows the measured current values (denoted as L4(m)) and the correction values (denoted as L4(c)) obtained by background processing.

As shown in FIG. 81A, a peak due to release of oxygen was observed at the temperature T of approximately 370 to 600 K (approximately 97 to 327° C.), and the peak top was at approximately 515 K (approximately 242° C.). Note that in the above-mentioned background processing, the measured value (L4(m)) at a temperature where no peak is observed (here, a temperature lower than approximately 370 K and a temperature higher than approximately 600 K) was fitted with a primary function, and the obtained value was subtracted from the measured value (L4(m)) as a background value (denoted as BG in FIG. 81A) to obtain the correction value (L4(c)).

FIG. 81B shows the correction values (L4(c)) of Sample L4 and calculation values obtained from Formula (2) and Formula (3) above. In FIG. 81B, the horizontal axis represents the temperature T and the vertical axis represents the desorption rate q(T). The desorption rate q(T) is a value obtained by converting the current value of the mass analyzer into the released amount per unit time.

As shown in FIG. 81B, the correction values (L4(c)) and the calculation values (denoted as sim) are substantially the same, indicating that diffusion is the bottleneck for desorbing oxygen (O₂) from the silicon oxynitride film. That is, it was confirmed that oxygen exists as O₂ in the silicon oxynitride film, O₂ is diffused in the silicon oxynitride film by application of heat, and then released from the silicon oxynitride film. As a result of the calculation, the initial concentration C₀ was approximately 4.7×10¹⁸ molecules/cm³, the frequency factor Do was approximately 2.3×10⁻⁵ cm²/sec, and the activation energy E was approximately 0.71 eV. According to the obtained frequency factor Do, the activation energy E, and Formula (1) above, the diffusion coefficient D of Sample L4 at 350° C. was calculated to be approximately 4.0×10⁻¹¹ cm²/sec.

Similarly, the TDS spectra of oxygen in Sample L1 to Sample L3 and Sample L5 to Sample L7 were fitted with Formula (2) and Formula (3) above, whereby the values of the initial concentration C₀, the frequency factor Do, and the activation energy E were obtained. It was confirmed that the correction values and the calculation values were substantially the same also in Sample L1 to Sample L3 and Sample L5 to Sample L7. The diffusion coefficient D at 350° C. and a diffusion length X at 350° C. for 1 hr were calculated from the obtained frequency factor Do and activation energy E.

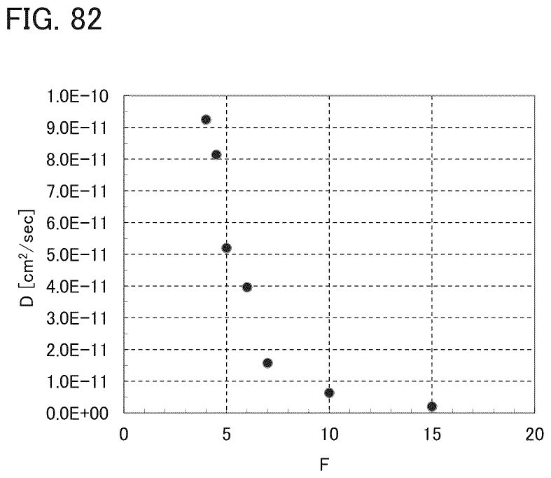

Table 4 shows the frequency factors Do, the activation energy E, the diffusion coefficients D at 350° C., and the diffusion lengths X at 350° C. for 1 hr of Sample L1 to Sample L7. FIG. 82 shows the diffusion coefficient D at 350° C. FIG. 82 shows the diffusion coefficient D with the horizontal axis representing the F ratio (denoted as F).

TABLE 4

| | | D₀ | E | D | X |
|---|---|---|---|---|---|
| | F | [cm²/sec] | [eV] | [cm²/sec] | [μm] |
| L1 | 4 | 5.7 × 10⁻⁵ | 0.72 | 9.2 × 10⁻¹¹ | 11.5 |
| L2 | 4.5 | 3.8 × 10⁻⁵ | 0.70 | 8.1 × 10⁻¹¹ | 10.8 |
| L3 | 5 | 2.9 × 10⁻⁵ | 0.71 | 5.2 × 10⁻¹¹ | 8.6 |
| L4 | 6 | 2.3 × 10⁻⁵ | 0.71 | 4.0 × 10⁻¹¹ | 7.6 |
| L5 | 7 | 1.0 × 10⁻⁵ | 0.72 | 1.6 × 10⁻¹¹ | 4.8 |
| L6 | 10 | 4.2 × 10⁻⁶ | 0.72 | 6.3 × 10⁻¹² | 3.0 |
| L7 | 15 | 1.3 × 10⁻⁶ | 0.72 | 2.0 × 10⁻¹² | 1.7 |
| | | | | *350° C. | *350° C., 1 hr |

The activation energy E of oxygen diffusion in the silicon oxynitride film was 0.70 to 0.72 eV in each sample. The diffusion coefficient D of oxygen at 350° C. was approximately 9.2× 10⁻¹¹ cm²/sec when the F ratio was 4; approximately 8.1×10⁻¹¹ cm²/sec when the F ratio was 4.5; approximately 5.2×10⁻¹¹ cm²/sec when the F ratio was 5; approximately 4.0×10⁻¹¹ cm²/sec when the F ratio was 6; approximately 1.6×10⁻¹¹ cm²/sec when the F ratio was 7; approximately 6.3×10⁻¹² cm²/sec when the F ratio was 10; and approximately 2.0×10⁻¹² cm²/sec when the F ratio was 15.

As described above, it was confirmed that the diffusion coefficient D of oxygen in the silicon oxynitride film was higher as the F ratio at the time of forming the silicon oxynitride film was lower. That is, it was confirmed that oxygen was diffused more easily as the F ratio was lower.

### Example 14

In this example, the amounts of hydrogen and ammonia released from an insulating film were evaluated. In this example, four kinds of samples (Sample M1 to Sample M4) were fabricated.

### <Fabrication of Samples>

An approximately 100-nm-thick silicon oxynitride film was formed over a glass substrate by a PECVD method. The silicon oxynitride film corresponds to the insulating layer 110b. Silane (SiH₄) and dinitrogen monoxide (N₂O) were used as deposition gases for forming the silicon oxynitride film, and the flow rate of silane was 290 sccm. The F ratio at the time of forming the silicon oxynitride film was varied among Sample M1 to Sample M4. For Sample M1, the RF power was set to 870 W and the F ratio was set to 3. For Sample M2, the RF power was set to 1160 W and the F ratio was set to 4. For Sample M3, the RF power was set to 1450 W and the F ratio was set to 5. For Sample M4, the RF power was set to 1740 W and the F ratio was set to 6. Note that in the calculation of the F ratio here, the unit of the flow rate of the deposition gas was sccm, which is the unit of flow rate of silane gas, and the unit of the RF power was W (Watt).

Through the above process, Sample M1 to Sample M4 were obtained.

### <TDS Analysis>

By thermal desorption spectroscopy (TDS), the TDS spectra of the samples were obtained. In the TDS measurement, the substrate temperature was increased from approximately 50° C. to approximately 500° C. at a substrate temperature rising rate of approximately 14° C./min.

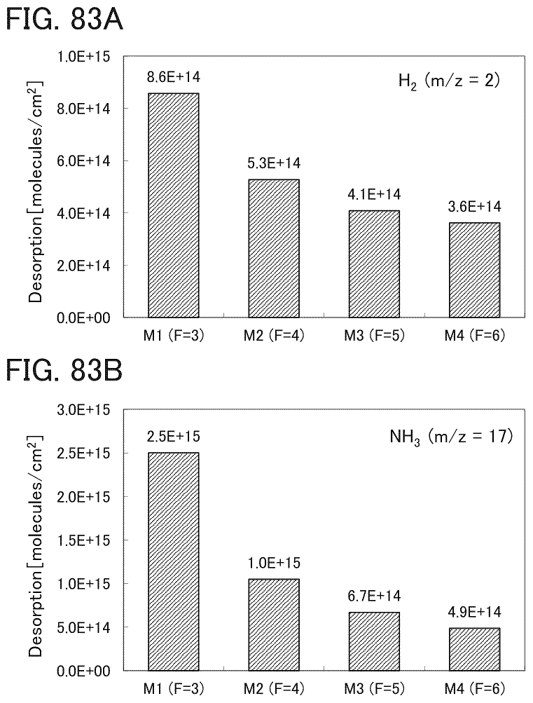

FIG. 83A and FIG. 83B show the TDS analysis results of Sample A1 to Sample A6. In FIG. 83A, the horizontal axis represents the sample name and the F ratio (denoted as F), and the vertical axis represents the desorbed amount (denoted as Desorption) of hydrogen (H₂, m/z=2). In FIG. 83B, the horizontal axis represents the sample name and the F ratio (denoted as F), and the vertical axis represents the desorbed amount (denoted as Desorption) of ammonia (NH₃, m/z=17).

As shown in FIG. 83A and FIG. 83B, it was confirmed that the desorbed amounts of hydrogen and ammonia were larger as the F ratio at the time of forming the silicon oxynitride film was lower.

### Example 15

In this example, transistors were fabricated, and their electrical characteristics were evaluated.

In this example, samples including the transistors of one embodiment of the present invention were fabricated. For the structures of the transistors included in the samples, the description of the transistor 100 illustrated in FIG. 11A can be referred to. The conductive layer 112a had the stacked-layer structure illustrated in FIG. 6B. In this example, four kinds of samples (Sample N1 to Sample N4) were fabricated.

### <Fabrication of Samples>

First, an approximately 100-nm-thick tungsten film to be the conductive layer 112a_1 was formed over the substrate 102 by a sputtering method, and then processed to form the conductive layer 112a_1. Next, an approximately 50-nm-thick In—Sn—Si oxide (ITSO) film to be the conductive layer 112a_2 was formed by a sputtering method, and then processed to form the conductive layer 112a_2, whereby the conductive layer 112a was obtained. A glass substrate with a size of 600 mm×720 mm was used as the substrate 102.

Next, an approximately 70-nm-thick silicon nitride film was formed as the first insulating film to be the insulating layer 110d, an approximately 100-nm-thick silicon nitride film was formed as the second insulating film (the insulating film 110af) to be the insulating layer 110a, and an approximately 500-nm-thick silicon oxynitride film was formed as the third insulating film (the insulating film 110bf) to be the insulating layer 110b. The first insulating film, the second insulating film, and the third insulating film were successively formed in a vacuum by a PECVD method. Note that silane (SiH₄), nitrogen (N₂), and ammonia (NH₃) were used as film formation gases for forming the first insulating film and the second insulating film (the insulating film 110af). The ammonia flow rate ratio at the time of forming the first insulating film was made higher than the ammonia flow rate ratio at the time of forming the second insulating film (the insulating film 110af).

Silane (SiH₄) and dinitrogen monoxide (N₂O) were used as film formation gases for forming the third insulating film (the insulating film 110bf), and the flow rate of silane was 290 sccm. The F ratio at the time of forming the third insulating film (the insulating film 110bf) was varied among Sample N1 to Sample N4. For Sample N1, the RF power was set to 870 W and the F ratio was set to 3. For Sample N2, the RF power was set to 1160 W and the F ratio was set to 4. For Sample N3, the RF power was set to 1450 W and the F ratio was set to 5. For Sample N4, the RF power was set to 1760 W and the F ratio was set to 6. Note that in the calculation of the F ratio here, the unit of the flow rate of the deposition gas was sccm, which is the unit of flow rate of silane gas, and the unit of the RF power was W (Watt).

Next, an approximately 20-nm-thick metal oxide layer was formed as the metal oxide layer 137 over the third insulating film (the insulating film 110bf). The metal oxide layer 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 137 was removed. The metal oxide layer 137 was removed by a wet etching method.

Next, an approximately 50-nm-thick silicon nitride film was formed as the fourth insulating film (the insulating film 110cf) to be the insulating layer 110c over the third insulating film (the insulating film 110bf), and an approximately 100-nm-thick silicon nitride film was formed as the fifth insulating film to be the insulating layer 110e. The fourth insulating film and the fifth insulating film were successively formed in a vacuum by a PECVD method. Note that silane (SiH₄), nitrogen (N₂), and ammonia (NH₃) were used as film formation gases for forming the fourth insulating film (the insulating film 110cf) and the fourth insulating film. The ammonia flow rate ratio at the time of forming the fifth insulating film was made higher than the ammonia flow rate ratio at the time of forming the fourth insulating film (the insulating film 110cf).

Next, the conductive film 112bf was formed over the fifth insulating film by a sputtering method. As the conductive film 112bf, an approximately 100-nm-thick In—Sn—Si oxide (ITSO) film was formed.

Subsequently, the conductive film 112bf was processed to form the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to form the semiconductor layer 108.

Subsequently, as the insulating layer 106, an approximately 50-nm-thick silicon oxynitride film was formed by a PECVD method.

Next, an approximately 50-nm-thick titanium film, an approximately 200-nm-thick aluminum film, and an approximately 50-nm-thick titanium film were each formed by a sputtering method. After that, the conductive films were processed to form the conductive layer 104.

Thus, a transistor corresponding to the transistor 100 was formed.

Next, as the insulating layer 195, an approximately 300-nm-thick silicon nitride oxide film was formed by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Through the above process, Sample N1 to Sample N4 were obtained.

### <Id-Vg Characteristics>

Next, the Id-Vg characteristics of the transistors of Sample N1 to Sample N4 fabricated in the above manner were measured.

For the measurement of the Id-Vg characteristics of the transistors, the gate voltage (Vg) was applied from −3 V to +3 V in increments of 0.1 V. In addition, the source voltage (Vs) was 0 V (comm), and the drain voltage (Vd) was 0.1 V and 1.2 V.

Here, the measurement was performed on the transistor with the channel width W100 of approximately 6.3 μm (the width D141 of the opening 141 of 2.0 μm). Note that the number of measurements was set to 10 in a substrate plane of 600 mm×720 mm. The channel length L100 was approximately 0.5 μm.

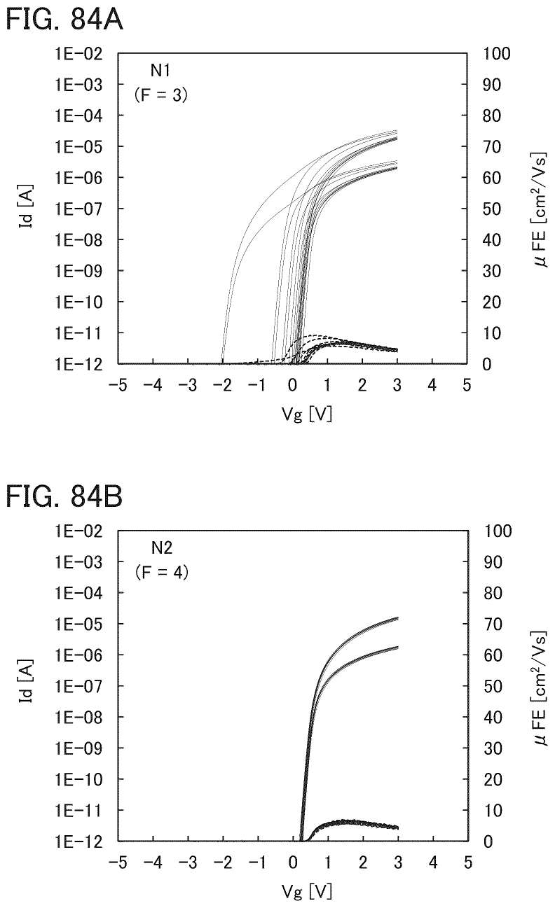

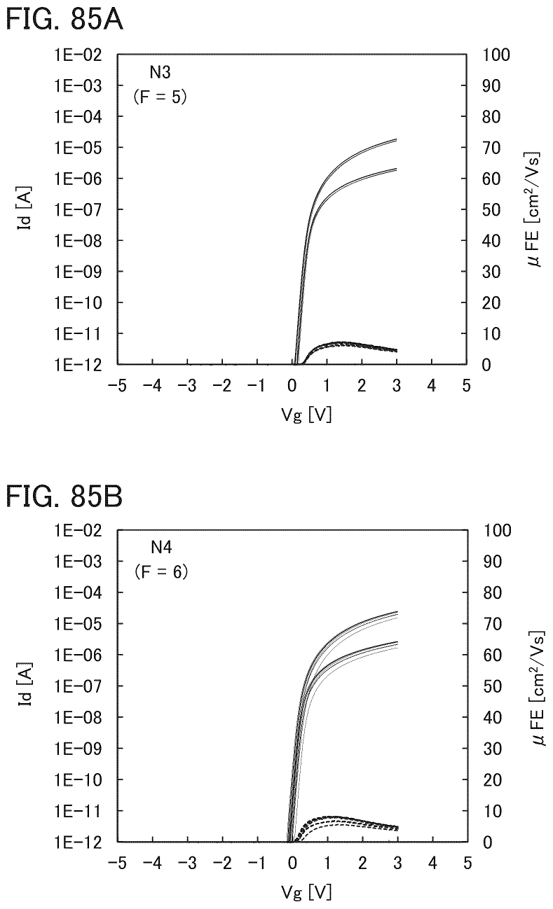

FIG. 84A to FIG. 85B show the Id-Vg characteristics of Sample N1 to Sample N4. In FIG. 84A to FIG. 85B, the horizontal axis represents the gate voltage (Vg), the left vertical axis represents the drain current (Id), and the right vertical axis represents the field-effect mobility (uFE) at a drain voltage (Vd) of 1.2 V. FIG. 84A to FIG. 85B show superimposed Id-Vg characteristics of the 10 transistors.

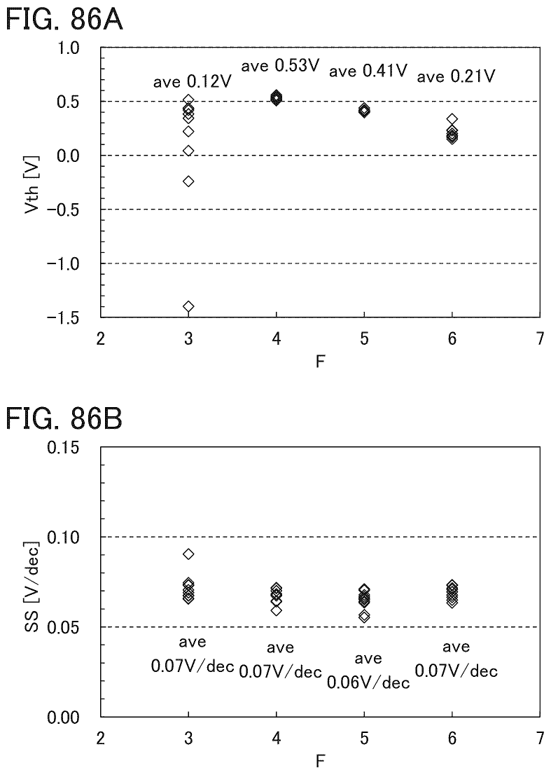

FIG. 86A shows the threshold voltage (Vth) obtained from the above Id-Vg characteristics, and FIG. 86B shows the S value (SS). In FIG. 86A, the horizontal axis represents the F ratio (denoted as F) and the vertical axis represents the threshold voltage (Vth). In FIG. 86B, the horizontal axis represents the F ratio and the vertical axis represents the S value (SS). FIG. 86A and FIG. 86B show the average values of the samples.

As shown in FIG. 84A to FIG. 86B, it was confirmed that in Sample N2 to Sample N4 for which the F ratio was set to 4 or higher, the threshold voltage increased in the positive direction as the F ratio decreased. Meanwhile, it was confirmed that Sample N1 for which the F ratio was set to 3 had a large variation in electrical characteristics. It was also confirmed that each sample had a small S value. As described in Example 13, when the F ratio is low, oxygen is easily diffused in the insulating layer 110b and efficiently supplied from the insulating layer 110b to the semiconductor layer 108 (in particular, the channel formation region), which probably enabled the transistors of Sample N2 to Sample N4 to have favorable electrical characteristics. Meanwhile, as described in Example 14, when the F ratio is too low, the amount of impurities (e.g., hydrogen and ammonia) released from the insulating layer 110b becomes too large, which probably increased variation in electrical characteristics of the transistors of Sample N1.

As described above, it was confirmed that a transistor with favorable electrical characteristics was obtained by setting the F ratio at the time of forming the insulating film to be the insulating layer 110b within the above range.

### Example 16

In this example, transistors were fabricated, and the release temperature of nitrogen from the insulating layer 110b was evaluated.

In this example, samples including the transistors of one embodiment of the present invention were fabricated. For the structures of the transistors included in the samples, the description of the transistor 100 illustrated in FIG. 11A can be referred to. The conductive layer 112a had the stacked-layer structure illustrated in FIG. 6B. In this example, seven kinds of samples (Sample R1 to Sample R7) were fabricated.

### <Fabrication of Samples>

For the fabrication of the transistors of Sample R1 to Sample R7, the above description in Example 15 can be referred to. Silane (SiH₄) and dinitrogen monoxide (N₂O) were used as film formation gases for forming the insulating film 110bf to be the insulating layer 110b, and the flow rate of silane was 290 sccm. The F ratio at the time of forming the insulating film 110bf was varied among Sample R1 to Sample R7. For Sample R1, the RF power was set to 870 W and the F ratio was set to 3. For Sample R2, the RF power was set to 1160 W and the F ratio was set to 4. For Sample R3, the RF power was set to 1450 W and the F ratio was set to 5. For Sample R4, the RF power was set to 1760 W and the F ratio was set to 6. For Sample R5, the RF power was set to 2030 W and the F ratio was set to 7. For Sample R6, the RF power was set to 2320 W and the F ratio was set to 8. For Sample R7, the RF power was set to 2900 W and the F ratio was set to 10. Note that in the calculation of the F ratio here, the unit of the flow rate of the deposition gas was sccm, which is the unit of flow rate of silane gas, and the unit of the RF power was W (Watt).

As the insulating layer 195, an approximately 300-nm-thick silicon nitride oxide film was formed over the transistor by a PECVD method.

Then, heat treatment was performed at 300° C. in a dry air atmosphere for one hour. An oven apparatus was used for the heat treatment.

Then, an approximately 1.5-μm-thick polyimide film was formed.

Then, heat treatment was performed at 250° C. in a nitrogen atmosphere for one hour. An oven apparatus was used for the heat treatment.

Next, the layers above the insulating layer 110b (here, the insulating layer 110c, the insulating layer 110e, the conductive layer 112b, the semiconductor layer 108, the insulating layer 106, the conductive layer 104, the insulating layer 195, and the polyimide film) were removed to expose the insulating layer 110b. These layers were removed by a dry etching method and a wet etching method.

Through the above process, Sample R1 to Sample R7 were obtained.

### <TDS Analysis>

By thermal desorption spectroscopy (TDS), the TDS spectra of the samples were obtained. In the TDS measurement, the substrate temperature was increased from approximately 50° C. to approximately 500° C. at a substrate temperature rising rate of approximately 14° C./min.

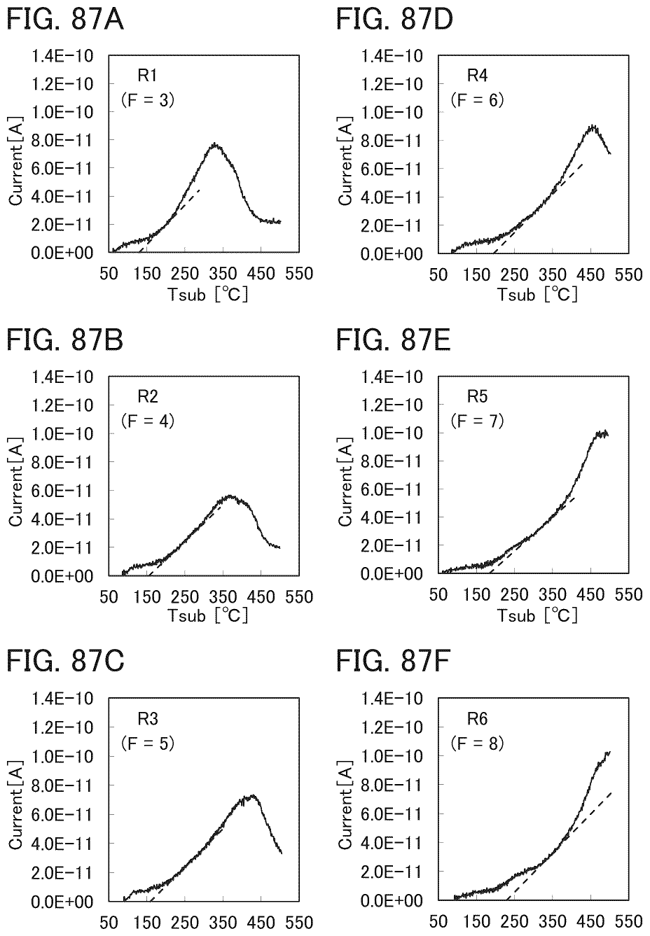

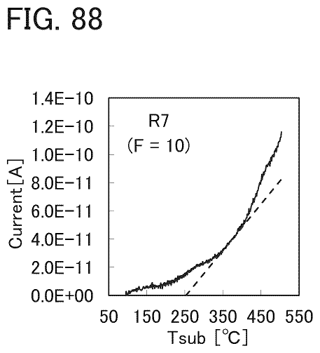

FIG. 87A to FIG. 88 show the TDS spectra of nitrogen (¹⁴N₂, m/z=28) in Sample R1 to Sample R7. In FIG. 87A to FIG. 88, the horizontal axis represents the temperature (Tsub) of the sample and the vertical axis represents the current value (Current) of the mass analyzer. FIG. 87A to FIG. 88 show the values obtained by subtracting the background value from the measured current values. As the background value, the minimum value of the measured values in the entire measurement temperature range was used.

The release temperature of nitrogen was calculated from the obtained TDS spectrum. A tangent was drawn at a point where the slope on a low temperature side of the nitrogen peak becomes the maximum, and the intersection of the tangent and the X-axis (Y=0) was regarded as the release temperature. In FIG. 87A to FIG. 88, the tangent is indicated by a dashed line.

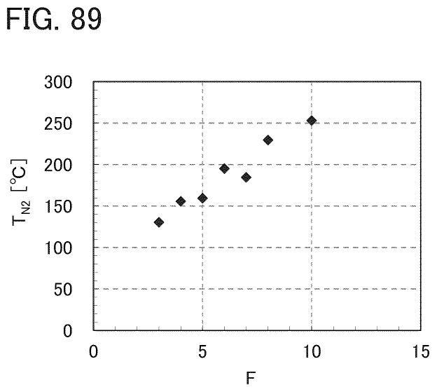

FIG. 89 shows the release temperature of nitrogen in each sample. In FIG. 89, the horizontal axis represents the F ratio (denoted as F), and the horizontal axis represents the release temperature of nitrogen (denoted as T_{N2}). The release temperature of nitrogen was approximately 130° C. when the F ratio was 3, approximately 156° C. when the F ratio was 4.5, approximately 159° C. when the F ratio was 5, approximately 195° C. when the F ratio was 6, approximately 185° C. when the F ratio was 7, approximately 230° C. when the F ratio was 10, and approximately 253° C. when the F ratio was 15.

As described above, it was confirmed that the release temperature of nitrogen was lower as the F ratio was lower. It is probable that nitrogen is diffused more easily as the F ratio is lower. Similarly, the release temperature of oxygen is also probably low. The release temperature of oxygen is presumed to be low because the diffusion coefficient of oxygen is higher as the F ratio is lower as described above.

### Example 17

In this example, transistors were fabricated, and their electrical characteristics were evaluated.

In this example, Sample S including the transistors of one embodiment of the present invention was fabricated. For the structures of the transistors included in Sample S, the description of the transistor 100 illustrated in FIG. 11A can be referred to. Note that the conductive layer 112a had the stacked-layer structure illustrated in FIG. 6B.

The description in Example 8 can be referred to for the fabrication method of Sample S; thus, the detailed description thereof is omitted.

### <Id-Vg Characteristics>

The Id-Vg characteristics of the transistors of Sample S were measured.

Here, the measurement was performed on transistors different in the number (p) of transistors connected in parallel, that is, different in the channel width W100. For the transistors connected in parallel, the description of FIG. 14A to FIG. 17 can be referred to. The measurement was performed on transistors where the width D141 of the opening 141 of each of the transistor 100_1 to the transistor 100_p was 2.0 μm and transistors where the width D141 of the opening 141 of each of the transistor 100_1 to the transistor 100_p was 4.0 μm. Specifically, in the transistors where the width D141 was 2.0 μm (the channel width W100 of each of the transistor 100_1 to the transistor 100_p was approximately 6.3 μm), the numbers p of transistors connected in parallel were 1, 4, 9, 16, and 49. In the transistors where the width D141 was 4.0 μm (the channel width W100 of each of the transistor 100_1 to the transistor 100_p was approximately 12.6 μm), the numbers p of transistors connected in parallel were 1, 4, 9, and 16. That is, the channel widths W100 were approximately 6.3 μm, approximately 12.6 μm, approximately 25.1 μm, approximately 50.3 μm, approximately 56.5 μm, approximately 100.5 μm, approximately 113.1 μm, approximately 201.1 μm, and approximately 307.9 μm. Note that the channel length L100 was approximately 0.5 μm.

For the measurement of the Id-Vg characteristics of the transistors, the gate voltage (Vg) was applied from −10 V to +10 V in increments of 0.1 V. In addition, the source voltage (Vs) was 0 V (comm), and the drain voltage (Vd) was 5.1 V.

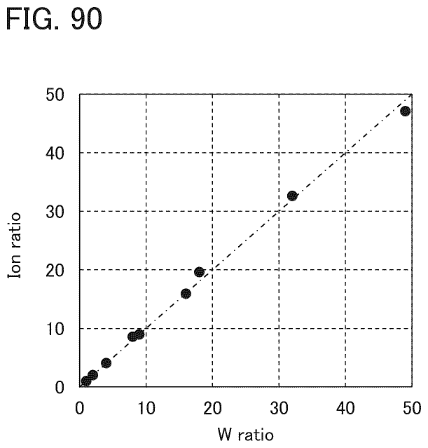

FIG. 90 shows the ratio of on-state current of Sample S at a drain voltage (Vd) of 5.1 V and a gate voltage (Vg) of 5 V. In FIG. 90, the horizontal axis represents the ratio of the channel width (W ratio) and the vertical axis represents the ratio of on-state current (Ion ratio). The ratio of the channel width is the ratio of the channel width W100 of each transistor to approximately 6.3 μm, which is the minimum value of the channel width W100 of the measured transistors. The ratio of the on-state current is the ratio of the on-state current of each transistor to the on-state current when the channel width W100 is approximately 6.3 μm.

As shown in FIG. 90, it was confirmed that the on-state current of the transistors connected in parallel increased in proportion to the channel width. That is, it was confirmed that the transistor of one embodiment of the present invention had low contact resistance between the semiconductor layer 108 and each of the source electrode and the drain electrode (the conductive layer 112a and the conductive layer 112b) and low external resistance such as the wiring resistance. It was also confirmed that, by adjusting one or both of the width D141 and the number p of transistors connected in parallel, the channel width W100 can be varied and a desired on-state current can be obtained.

### <Reliability>

Next, the reliability of Sample S was evaluated.

For the reliability evaluation, a GBT stress test was performed. In this example, a PBTS test and an NBTIS tests were performed.

In the PBTS test, a substrate over which the transistors were formed was held at 60° C., a voltage of 0.1 V was applied to the sources and the drains of the transistors, and a voltage of 20 V was applied to the gates; this state was maintained for one hour. The test was performed in a dark environment. In the NBTIS test, a substrate over which the transistors were formed was held at 60° C., a voltage of 0 V was applied to the sources and the drains of the transistors, and a voltage of −20 V was applied to the gates in a state where irradiation with white LED light at 5000 lx was performed; this state was maintained for one hour. The irradiation with white LED light was performed from the glass substrate side. In the PBTS test and the NBTIS test, the transistor with the channel width W100 of approximately 6.3 μm (the width D141 of the opening 141 of 2.0 μm) was used. Note that the channel length L100 was approximately 0.5 μm.

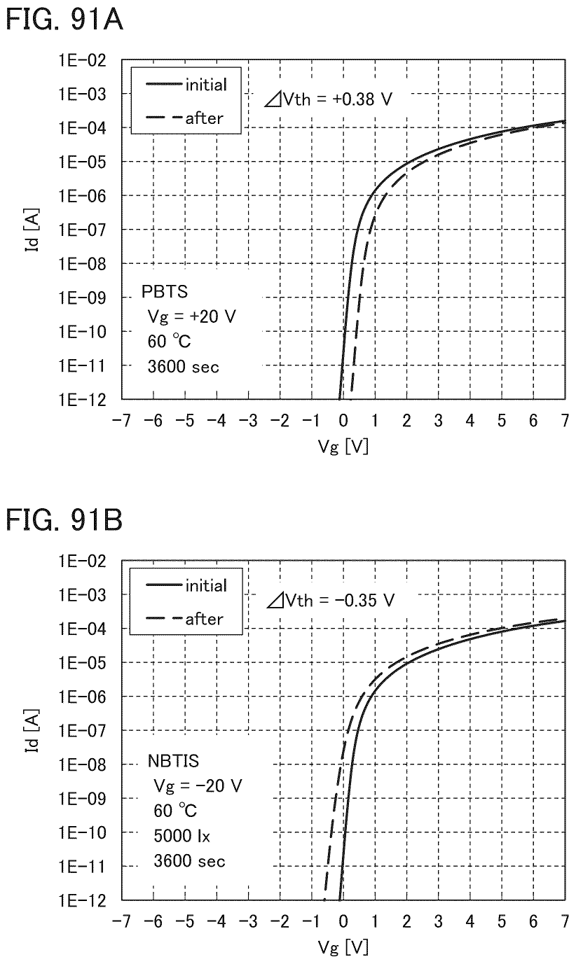

FIG. 91A shows the Id-Vg characteristics before and after the PBTS test. FIG. 91B shows Id-Vg before and after the NBTIS test. In FIG. 91A and FIG. 91B, the horizontal axis represents the gate voltage (Vg) and the vertical axis represents the drain current (Id). FIG. 91A and FIG. 91B show the Id-Vg characteristics before the reliability test (denoted as initial) and the Id-Vg characteristics after the reliability test (denoted as after), which are superimposed on each other.

As shown in FIG. 91A and FIG. 91B, the amount of change in the threshold voltage (ΔVth) in the PBTS test was approximately +0.38 V, and the amount of change in the threshold voltage (ΔVth) in the NPBTIS test was approximately-0.35 V, which confirmed the favorable reliability.

From the above results, it was confirmed that a transistor with a short channel length, favorable electrical characteristics, and high reliability was obtained.

### Example 18

In this example, transistors were fabricated, and their drain withstand voltages were evaluated.

In this example, Sample T including the transistors of one embodiment of the present invention was fabricated. For the structure of the transistors included in Sample T, the description of the transistor 100 illustrated in FIG. 11A can be referred to. Note that the conductive layer 112a had the stacked-layer structure illustrated in FIG. 6B.

Sample T fabricated in this example is similar to Sample G fabricated in Example 8 except that the thickness of the insulating layer 110b is approximately 300 nm.

### <Drain Withstand Voltage Test>

A drain withstand voltage test was performed on the transistors of Sample T.

Here, a transistor including series-connected transistors each having the width D141 of the opening 141 of 2.0 μm was used. For the series-connected transistors, the description of FIG. 18A to FIG. 21 can be referred to. The number (q) of series-connected transistors was 2. In other words, the channel length L100 was approximately 0.6 μm and the channel width was approximately 6.3 μm.

In the drain withstand voltage test, the source voltage (Vs) and the gate voltage (Vg) were each 0 V (comm), and the drain voltage (Vd) was applied from 0 V to +30 V in increments of 0.1 V.

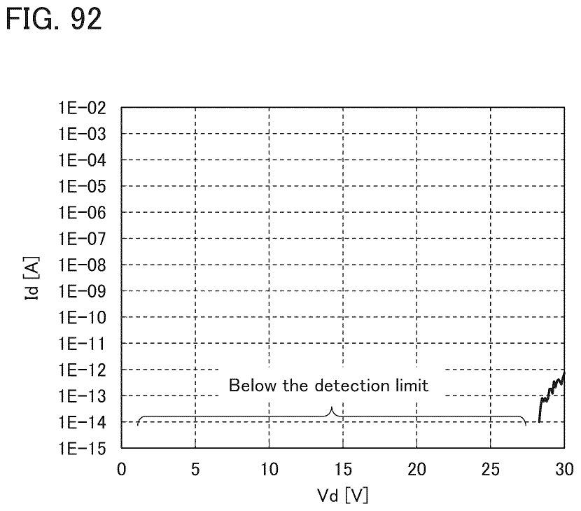

FIG. 92 shows the results of the drain withstand voltage test on Sample T. In FIG. 92, the horizontal axis represents the drain voltage (Vd) and the vertical axis represents the drain current (Id).

As shown in FIG. 92, the drain current (Id) was below the lower measurement limit (denoted as Below the detection limit in FIG. 92) at a drain voltage (Vd) of approximately +28 V or lower, which confirmed the off-leakage current. No clear breakdown was observed within the range of the drain voltage (Vd) from 0 V to +30 V. Note that the lower measurement limit of the drain current (Id) was approximately 1×10⁻¹³ A.

From the above results, it was confirmed that a transistor with a short channel length and a high drain withstand voltage in an off state was obtained.

[Reference Numerals]

ANO_1: wiring, ANO_2: wiring, ANO: wiring, C11: capacitor, C12: capacitor, C31: capacitor,
C41: capacitor, GL: wiring, INV: inverter circuit, LAT: latch circuit, LIN: terminal, M11:
transistor, M12: transistor, M13: transistor, M14: transistor, M15: transistor, M16: transistor,
ROUT: terminal, SL: wiring, SMP: terminal, Tr31: transistor, Tr33: transistor, Tr35: transistor,
Tr36: transistor, Tr41: transistor, Tr43: transistor, Tr45: transistor, Tr47: transistor, VCOM: wiring,
10A: semiconductor device, 10B: semiconductor device, 10C: semiconductor device, 10D:
semiconductor device, 10E: semiconductor device, 10: semiconductor device, 50A: display
apparatus, 50B: display apparatus, 50C: display apparatus, 50D: display apparatus, 50E: display
apparatus, 50F: display apparatus, 50G: display apparatus, 50H: display apparatus, 50I: display
apparatus, 50J: display apparatus, 50K: display apparatus, 51A: pixel circuit, 51B: pixel circuit,
51: pixel circuit, 52A: transistor, 52B: transistor, 52C: transistor, 53: capacitor, 60: liquid crystal
element, 61: light-emitting device, 100_1: transistor, 100_2: transistor, 100_3: transistor, 100_4:
transistor, 100_p: transistor, 100_q: transistor, 100A: transistor, 100B: transistor, 100C: transistor,
100D: transistor, 100: transistor, 102: substrate, 103: conductive layer, 104A: conductive layer,
104B: conductive layer, 104p: conductive layer, 104q: conductive layer, 104r: conductive layer,
104s: conductive layer, 104: conductive layer, 106f: insulating film, 106: insulating layer, 107:
insulating layer, 108_1: semiconductor layer, 108_2: semiconductor layer, 108_3: semiconductor
layer, 108_4: semiconductor layer, 108A: semiconductor layer, 108B: semiconductor layer, 108C:
semiconductor layer, 108D: semiconductor layer, 108f: metal oxide film, 108L: region, 108:
semiconductor layer, 110a: insulating layer, 110af: insulating film, 110b: insulating layer, 110bf:
insulating film, 110c: insulating layer, 110cf: insulating film, 110d: insulating layer, 110e:
insulating layer, 110: insulating layer, 111B: pixel electrode, 111G: pixel electrode, 111R: pixel
electrode, 111S: pixel electrode, 111: pixel electrode, 112a: conductive layer, 112a_1: conductive
layer, 112a_2: conductive layer, 112aA: conductive layer, 112aB: conductive layer, 112B:
conductive layer, 112b: conductive layer, 112bA: conductive layer, 112bB: conductive layer,
112bC: conductive layer, 112bf: conductive film, 112c: conductive layer, 112d: conductive layer,
112e: conductive layer, 112m: conductive layer, 112p: conductive layer, 112q: conductive layer,
113B: EL layer, 113G: EL layer, 113R: EL layer, 113S: functional layer, 113: EL layer, 114:
common layer, 115: common electrode, 117: light-blocking layer, 118B: sacrificial layer, 118G:
sacrificial layer, 118R: sacrificial layer, 119B: sacrificial layer, 119G: sacrificial layer, 120a:
insulating layer, 120af: insulating film, 120b: insulating layer, 120bf: insulating film, 120:
insulating layer, 123: conductive layer, 124B: conductive layer, 124G: conductive layer, 124R:
conductive layer, 125f: insulating film, 125: insulating layer, 126B: conductive layer, 126G:
conductive layer, 126R: conductive layer, 127: insulating layer, 128: layer, 130B: light-emitting
element, 130G: light-emitting element, 130R: light-emitting element, 130S: light-receiving
element, 130: light-emitting element, 131: protective layer, 132B: coloring layer, 132G: coloring
layer, 132R: coloring layer, 133B: layer, 133Bf: film, 133G: layer, 133R: layer, 133: layer, 137:
metal oxide layer, 139: film, 140: connection portion, 141_1: opening, 141_2: opening, 141_3:
opening, 141_4: opening, 141A: opening, 141B: opening, 141C: opening, 141D: opening, 141p:
opening, 141q: opening, 141: opening, 142: adhesive layer, 143_1: opening, 143_2: opening,
143_3: opening, 143_4: opening, 143A: opening, 143B: opening, 143C: opening, 143D: opening,
143p: opening, 143q: opening, 143: opening, 144: adhesive layer, 147a: opening, 147b: opening,
148: opening, 150A: capacitor, 150B: capacitor, 150: capacitor, 151: substrate, 152: substrate, 153:
insulating layer, 162: display portion, 164: circuit portion, 165a: conductive layer, 165b:
conductive layer, 165: conductive layer, 166a: conductive layer, 166b: conductive layer, 166:
conductive layer, 172: FPC, 173: IC, 181: opening, 182: opening, 183: opening, 184: opening,
185: opening, 186: opening, 187: opening, 188: opening, 189: opening, 190: opening, 191: opening,
193: opening, 194: opening, 195: insulating layer, 196: opening, 197: connection portion, 200A:
transistor, 200B: transistor, 200: transistor, 202: conductive layer, 204: conductive layer, 205B:
transistor, 205D: transistor, 205G: transistor, 205R: transistor, 205S: transistor, 207B: transistor,
207G: transistor, 208D: region, 208L: region, 208: semiconductor layer, 210: pixel, 212a:
conductive layer, 212b: conductive layer, 223: connector, 224: spacer, 225: insulating layer, 230B:
pixel, 230G: pixel, 230R: pixel, 230: pixel, 231: first driver circuit portion, 232: second driver
circuit portion, 233: insulating layer, 234: conductive layer, 235: insulating layer, 236: wiring,
237: insulating layer, 238: wiring, 242: connection layer, 260a: polarizing plate, 260b: polarizing
plate, 261: insulating layer, 262: liquid crystal, 263: conductive layer, 264: conductive layer, 265:
alignment film, 352: finger, 353: layer, 355: circuit layer, 357: layer, 402: substrate, 404: groove,
406: insulating layer, 408: metal oxide layer, 700A: electronic device, 700B: electronic device,
721: housing, 723: wearing portion, 727: earphone portion, 750: earphone, 751: display panel,
753: optical member, 756: display region, 757: frame, 758: nose pad, 800A: electronic device,
800B: electronic device, 820: display portion, 821: housing, 822: communication portion, 823:
wearing portion, 824: control portion, 825: image capturing portion, 827: earphone portion, 832:
lens, 931: transistor, 932: transistor, 933: circuit portion, 934: wiring, 6500: electronic device,
6501: housing, 6502: display portion, 6503: power button, 6504: button, 6505: speaker, 6506:
microphone, 6507: camera, 6508: light source, 6510: protection member, 6511: display panel,
6512: optical member, 6513: touch sensor panel, 6515: FPC, 6516: IC, 6517: printed circuit board,
6518: battery, 7000: display portion, 7100: television device, 7101: housing, 7103: stand, 7111:
remote control, 7200: laptop computer, 7211: housing, 7212: keyboard, 7213: pointing device,
7214: external connection port, 7300: digital signage, 7301: housing, 7303: speaker, 7311:
information terminal, 7400: digital signage, 7401: pillar, 7411: information terminal, 9000:
housing, 9001: display portion, 9002: camera, 9003: speaker, 9005: operation key, 9006:
connection terminal, 9007: sensor, 9008: microphone, 9050: icon, 9051: information, 9052:
information, 9053: information, 9054: information, 9055: hinge, 9101: portable information
terminal, 9102: portable information terminal, 9103: tablet terminal, 9200: portable information
terminal, 9201: portable information terminal

1. A semiconductor device comprising:
a transistor and a first insulating layer,
wherein the transistor comprises a first conductive layer, a second conductive layer comprising a region overlapping with the first conductive layer with the first insulating layer therebetween, and a semiconductor layer,
wherein the second conductive layer comprises a first opening in the region overlapping with the first conductive layer,
wherein the first insulating layer comprises a second opening reaching the first conductive layer in a region overlapping with the first opening,
wherein in the first opening and the second opening, the semiconductor layer is in contact with a top surface of the first conductive layer, a side surface of the first insulating layer, and a side surface of the second conductive layer, and
wherein a diffusion coefficient of oxygen in the first insulating layer at 350° C. is higher than or equal to 5×10⁻¹² cm²/sec.

2. The semiconductor device according to claim 1, wherein the diffusion coefficient of oxygen is calculated by thermal desorption spectroscopy or secondary ion mass spectrometry.

3. The semiconductor device according to claim 1, wherein the semiconductor layer comprises a metal oxide.

4. The semiconductor device according to claim 1, further comprising a second insulating layer and a third insulating layer,
wherein the second insulating layer is between the first insulating layer and the first conductive layer,
wherein the third insulating layer is between the first insulating layer and the second conductive layer,
wherein the first insulating layer comprises an oxide or an oxynitride, and
wherein each of the second insulating layer and the third insulating layer comprises one of a nitride and a nitride oxide.

5. The semiconductor device according to claim 4, further comprising a fourth insulating layer,
wherein the fourth insulating layer is positioned between the second insulating layer and the first conductive layer, and
wherein the fourth insulating layer comprises a region comprising more hydrogen than the second insulating layer.

6. The semiconductor device according to claim 4, further comprising a fifth insulating layer,
wherein the fifth insulating layer is between the third insulating layer and the second conductive layer, and
wherein the fifth insulating layer comprises a region comprising more hydrogen than the third insulating layer.

7. A semiconductor device comprising:
a first transistor, a second transistor and a first insulating layer,
wherein the first transistor comprises a first conductive layer, a second conductive layer comprising a region overlapping with the first conductive layer with the first insulating layer therebetween, and a first semiconductor layer,
wherein the second conductive layer comprises a first opening in the region overlapping with the first conductive layer,
wherein the first insulating layer comprises a second opening reaching the first conductive layer in a region overlapping with the first opening,
wherein in the first opening and the second opening, the first semiconductor layer is in contact with a top surface of the first conductive layer, a side surface of the first insulating layer, and a side surface of the second conductive layer,
wherein the second transistor comprises a third conductive layer over the first insulating layer, a second semiconductor layer, and a second insulating layer positioned between the third conductive layer and the second semiconductor layer,
wherein the second insulating layer is in contact with a top surface and a side surface of the third conductive layer, and
wherein a diffusion coefficient of oxygen in the first insulating layer is higher than a diffusion coefficient of oxygen in the second insulating layer.

8. The semiconductor device according to claim 7, wherein the diffusion coefficient of oxygen is calculated by thermal desorption spectroscopy or secondary ion mass spectrometry.

9. The semiconductor device according to claim 7, wherein each of the first semiconductor layer and the second semiconductor layer comprises a metal oxide.

10. The semiconductor device according to claim 7, wherein the second conductive layer and the third conductive layer have different materials.

11. The semiconductor device according to claim 7, wherein the second conductive layer and the third conductive layer have the same material.

12. A semiconductor device comprising:
a first transistor, a second transistor and a first insulating layer,
wherein the first transistor comprises a first conductive layer, a second conductive layer comprising a region overlapping with the first conductive layer with the first insulating layer therebetween, and a first semiconductor layer,
wherein the second conductive layer comprises a first opening in the region overlapping with the first conductive layer,
wherein the first insulating layer comprises a second opening reaching the first conductive layer in a region overlapping with the first opening,
wherein in the first opening and the second opening, the first semiconductor layer is in contact with a top surface of the first conductive layer, a side surface of the first insulating layer, and a side surface of the second conductive layer,
wherein the second transistor comprises a third conductive layer over the first insulating layer, a second semiconductor layer, and a second insulating layer positioned between the third conductive layer and the second semiconductor layer,
wherein the second insulating layer is in contact with a top surface and a side surface of the third conductive layer, and
wherein an etching rate of the first insulating layer with respect to an etchant is higher than an etching rate of the second insulating layer.

13. The semiconductor device according to claim 12, wherein the etchant comprises hydrofluoric acid.

14. The semiconductor device according to claim 12, wherein each of the first semiconductor layer and the second semiconductor layer comprises a metal oxide.

15. The semiconductor device according to claim 12, wherein the second conductive layer and the third conductive layer have different materials.

16. The semiconductor device according to claim 12, wherein the second conductive layer and the third conductive layer have the same material.

17. The semiconductor device according to claim 7, further comprising a third insulating layer and a fourth insulating layer,
wherein the third insulating layer is between the first insulating layer and the first conductive layer,
wherein the fourth insulating layer is between the first insulating layer and the second conductive layer,
wherein the fourth insulating layer is between the first insulating layer and the third conductive layer,
wherein the first insulating layer comprises one of an oxide and an oxynitride, and
wherein each of the third insulating layer and the fourth insulating layer comprises one of a nitride and a nitride oxide.

18. The semiconductor device according to claim 17, further comprising a fifth insulating layer,
wherein the fifth insulating layer is between the third insulating layer and the first conductive layer, and
wherein the fifth insulating layer comprises a region comprising more hydrogen than the third insulating layer.

19. The semiconductor device according to claim 17, further comprising a sixth insulating layer,
wherein the sixth insulating layer is positioned between the fourth insulating layer and the second conductive layer,
wherein the sixth insulating layer is positioned between the fourth insulating layer and the third conductive layer, and
wherein the sixth insulating layer comprises a region comprising more hydrogen than the fourth insulating layer.
